(19) United States
(12) Patent Application Publication
(10) Pub. No.: US 2024/0160101 A1
(43) Pub. Date: May 16, 2024

(54) RESIST COMPOSITION AND PATTERN FORMING PROCESS

(71) Applicant: Shin-Etsu Chemical Co., Ltd., Tokyo (JP)

(72) Inventors: Jun Hatakeyama, Joetsu-shi (JP); Tatsuya Yamahira, Joetsu-shi (JP); Yuki Suda, Joetsu-shi (JP)

(73) Assignee: Shin-Etsu Chemical Co., Ltd., Tokyo (JP)

(21) Appl. No.: 18/370,555

(22) Filed: Sep. 20, 2023

(30) Foreign Application Priority Data
Oct. 7, 2022 (JP) 2022-162350

(51) Int. Cl. G03F 7/004; G03F 7/038; G03F 7/039; G03F 7/20

(52) U.S. Cl. CPC G03F 7/0045; G03F 7/0048; G03F 7/0382; G03F 7/0388; G03F 7/0397; G03F 7/2004

(57) ABSTRACT

A resist composition comprising a sulfonium salt composed of a sulfonate anion having a carbon atom to which an iodine atom is bonded and a sulfonium cation having the formula (1) exhibits a high sensitivity and reduced LWR or improved CDU.

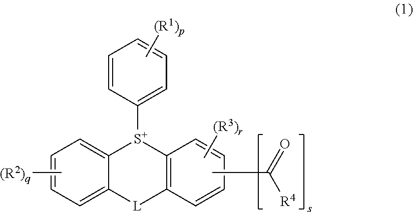

### CROSS-REFERENCE TO RELATED APPLICATIONS

This non-provisional application claims priority under 35 U.S.C. § 119(a) on Patent Application No. 2022-162350 filed in Japan on Oct. 7, 2022, the entire contents of which are hereby incorporated by reference.

### TECHNICAL FIELD

The present invention relates to a resist composition and a pattern forming process.

### BACKGROUND ART

To meet the demand for higher integration density and operating speed of LSIs, the effort to reduce the pattern rule is in rapid progress. As the use of 5G high-speed communications and artificial intelligence (AI) is widely spreading, high-performance devices are needed for their processing. As the advanced miniaturization technology, manufacturing of microelectronic devices at the 5-nm node by the lithography using EUV of wavelength 13.5 nm has been implemented in a mass scale. Studies are made on the application of EUV lithography to 3-nm node devices of the next generation and 2-nm node devices of the next-next-generation. IMEC in Belgium announced its successful development of 1-nm and 0.7-nm node devices.

As the feature size reduces, image blurs due to acid diffusion become a problem. To insure resolution for fine patterns of sub-45-nm size, not only an improvement in dissolution contrast is important as previously reported, but the control of acid diffusion is also important as reported in Non-Patent Document 1. Since chemically amplified resist compositions are designed such that sensitivity and contrast are enhanced by acid diffusion, an attempt to minimize acid diffusion by reducing the temperature and/or time of post exposure bake (PEB) fails, resulting in drastic reductions of sensitivity and contrast.

A triangular tradeoff relationship among sensitivity, resolution and edge roughness (LWR) has been pointed out. Specifically, a resolution improvement requires to suppress acid diffusion whereas a short acid diffusion distance leads to a decline of sensitivity.

The addition of an acid generator capable of generating a bulky acid is an effective means for suppressing acid diffusion. It was then proposed to incorporate repeat units derived from an onium salt having a polymerizable unsaturated bond in a polymer. Since this polymer functions as an acid generator, it is referred to as polymer-bound acid generator. Patent Document 1 discloses a sulfonium or iodonium salt having a polymerizable unsaturated bond, capable of generating a specific sulfonic acid. Patent Document 2 discloses a sulfonium salt having a sulfonic acid directly attached to the backbone.

A resist composition to which a sulfonium salt having a phenyldibenzothiophenium cation capable of generating a specific fluorosulfonic acid is added has been disclosed (Patent Documents 3 to 5). The phenyldibenzothiophenium cation has high degradation efficiency due to distortion of the ring and has high acid diffusion controlling ability due to the ring structure. However, to obtain properties of higher sensitivity and lower acid diffusion, properties of higher degradation efficiency and lower acid diffusion are required.

A resist composition containing an onium salt having an iodine atom in an anion has been disclosed (Patent Documents 6 to 10). Iodine atoms have strong absorption for EUV light, which improves the acid generation efficiency and contrast. If the acid generation efficiency and contrast are improved, a resist pattern having high sensitivity, high resolution and good critical dimension uniformity (CDU) can be formed. This application has led to successive disclosures for acid generators containing iodine atoms (Patent Documents 11 to 16).

### CITATION LIST

Patent Document 1: JP-A 2006-45311
Patent Document 2: JP-A 2006-178317
Patent Document 3: JP-A 2020-75919
Patent Document 4: JP-A 2021-35935
Patent Document 5: JP-A 2021-35936
Patent Document 6: JP-A 2018-5224
Patent Document 7: JP-A 2018-25789
Patent Document 8: JP-A 2018-155902
Patent Document 9: JP-A 2018-155908
Patent Document 10: JP-A 2018-159744
Patent Document 11: JP-A 2019-94323
Patent Document 12: JP-A 2020-181064
Patent Document 13: JP-A 2021-187843
Patent Document 14: JP-A 2020-187844
Patent Document 15: JP-A 2022-75556
Patent Document 16: JP-A 2022-77892
Non-Patent Document 1: SPIE Vol. 6520 65203L-1 (2007)

### SUMMARY OF THE INVENTION

Development of a resist composition that has higher sensitivity than conventional resist compositions and is capable of improving the LWR of a line pattern and the CDU of a hole pattern is desired.

The present invention has been made in view of the above circumstances, and an object of the present invention is to provide a resist composition having high sensitivity and improved LWR and CDU regardless of whether it is a positive tone or a negative tone, and a pattern forming process using the resist composition.

As a result of intensive studies to achieve the above object, the present inventors have found that a resist composition having high sensitivity, improved LWR and CDU, high contrast, excellent resolution and a wide process margin can be obtained by adding a sulfonium salt composed of a sulfonate anion having a carbon atom to which an iodine atom is bonded and a sulfonium cation having a specific structure having a hydrocarbylcarbonyl group or a hydrocarbyloxycarbonyl group, and have completed the present invention.

That is, the present invention provides the following resist composition and a pattern forming process.

1. A resist composition comprising an acid generator containing a sulfonium salt composed of a sulfonate anion having a carbon atom to which an iodine atom is bonded and a sulfonium cation having the formula (1):

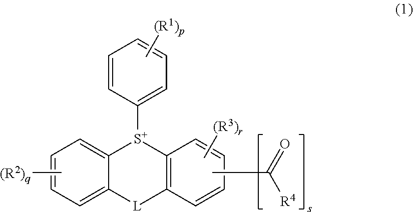

wherein p, q, and r are each independently an integer of 0 to 3, s is 1 or 2, and r+s is from 1 to 3,

R¹ and R² are each independently a halogen atom, a trifluoromethyl group, a trifluoromethoxy group, a trifluoromethylthio group, a nitro group, a cyano group, —C(═O)—R⁴, —O—C(═O)—R⁵, or —O—R⁵,

R³ is a halogen atom, a trifluoromethyl group, a trifluoromethoxy group, a trifluoromethylthio group, a nitro group, a cyano group, —O—C(═O)—R⁵, or —O—R⁵,

R⁴ is a C₁-C₁₀ hydrocarbyl group, a C₁-C₁₀ hydrocarbyloxy group, or —O—R^{4A}, the hydrocarbyl group and the hydrocarbyloxy group may be substituted with a fluorine atom or a hydroxy group, and R^{4A} is an acid labile group, and

R⁵ is a C₁-C₁₀ hydrocarbyl group,

L is a single bond, an ether bond, a carbonyl group, —N(R)—, a sulfide bond, or a sulfonyl group, and R is a hydrogen atom or a C₁-C₆ saturated hydrocarbyl group.

2. The resist composition of 1 wherein the sulfonate anion having a carbon atom to which an iodine atom is bonded has the formula (2)-1:

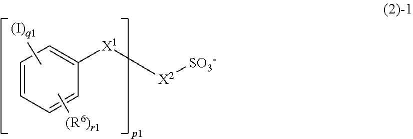

wherein p1 is an integer of 1 to 3, q1 is an integer of 1 to 5, r1 is an integer of 0 to 4, and q1+r1 is from 1 to 5,

R⁶ is a hydroxy group, a carboxy group, a halogen atom other than an iodine atom, or an amino group; or a C₁-C₂ hydrocarbyl group, a C₁-C₂ hydrocarbyloxy group, a C₂-C₂₀ hydrocarbylcarbonyl group, a C₂-C₁₀ hydrocarbyloxycarbonyl group, a C₂-C₂₀ hydrocarbylcarbonyloxy group, or a C₁-C₂₀ hydrocarbylsulfonyloxy group, which may contain a halogen atom, a hydroxy group, an amino group, or an ether bond; or —N(R^{6A})(R^{6B}), —N(R)—C(═O)—R^{6D}, or —N(R^{6C})—C(═O)—O—R^{6D}, R^{6A} and R^{6B} are each independently a hydrogen atom or a C₁-C₆ saturated hydrocarbyl group, R^{6C} is a hydrogen atom or a C₁-C₆ saturated hydrocarbyl group which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group, and R^{6D} is a C₁-C₁₆ aliphatic hydrocarbyl group, a C₆-C₁₂ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group,

X¹ is a single bond, an ether bond, an amide bond, a urethane bond, an ester bond, or a C₁-C₆ saturated hydrocarbylene group which may contain an ether bond or an ester bond, and

X² is a single bond or a C₁-C₂ divalent linking group when p1 is 1, and is a C₁-C₂₂ (p1+1)-valent linking group when p1 is 2 or 3, and the linking group may contain an oxygen atom, a sulfur atom, a nitrogen atom, or a halogen atom.

3. The resist composition of 1 wherein the sulfonate anion having a carbon atom to which an iodine atom is bonded has the formula (2)-2:

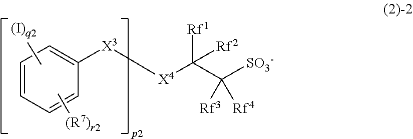

wherein p2 is an integer of 1 to 3, q2 is an integer of 1 to 5, r2 is an integer of 0 to 4, and q2+r2 is from 1 to 5,

R⁷ is a hydroxy group, a carboxy group, a halogen atom other than an iodine atom, or an amino group; or a C₁-C₂₀ hydrocarbyl group, a C₁-C₂₀ hydrocarbyloxy group, a C₂-C₂₀ hydrocarbylcarbonyl group, a C₂-C₁₀ hydrocarbyloxycarbonyl group, a C₂-C₂₀ hydrocarbylcarbonyloxy group, or a C₁-C₂₀ hydrocarbylsulfonyloxy group, which may contain a halogen atom, a hydroxy group, an amino group, or an ether bond; or —N(R^{7A})(R^{7B}), —N(R^{7C})—C(═O)—R^{7D}, or —N(R^{7C})—C(═O)—O—R^{7D}, R^{7A} and R^{7B} are each independently a hydrogen atom or a C₁-C₆ saturated hydrocarbyl group, R^{7C} is a hydrogen atom or a C₁-C₆ saturated hydrocarbyl group which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group, and R^{7D} is a C₁-C₁₆ aliphatic hydrocarbyl group, a C₆-C₁₂ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group,

X³ is a single bond, an ether bond, an amide bond, a urethane bond, an ester bond, or a C₁-C₆ saturated hydrocarbylene group which may contain an ether bond or an ester bond,

X⁴ is a single bond or a C₁-C₂₀ divalent linking group when p2 is 1, and is a C₁-C₂₀ (p2+1)-valent linking group when p2 is 2 or 3, and the linking group may contain an oxygen atom, a sulfur atom, or a nitrogen atom,

Rf¹ to Rf⁴ are each independently a hydrogen atom, a fluorine atom, or a trifluoromethyl group, at least one of Rf¹ to Rf⁴ is a fluorine atom or a trifluoromethyl group, and Rf¹ and Rf², taken together, may form a carbonyl group.

4. The resist composition of 1 to 3, further comprising a base polymer.

5. The resist composition of 4 wherein the base polymer further comprises repeat units having the formula (a1) or (a2):

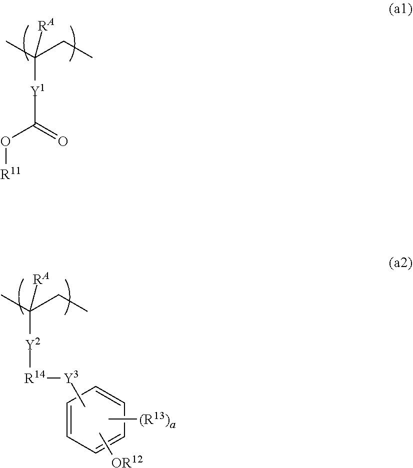

wherein R^{A} is each independently a hydrogen atom or a methyl group.

Y¹ is a single bond, a phenylene group, a naphthylene group, or a C₁-C₁₂ linking group containing at least one moiety selected from an ester bond, an ether bond and a lactone ring,

Y² is a single bond or an ester bond,

Y³ is a single bond, an ether bond, or an ester bond,

R¹¹ and R¹² are each independently an acid labile group,

R¹³ is a C₁-C₄ saturated hydrocarbyl group, a halogen atom, a C₂-C₅ saturated hydrocarbylcarbonyl group, a cyano group, or a C₂-C₅ saturated hydrocarbyloxycarbonyl group,

R¹⁴ is a single bond or a C₁-C₆ alkanediyl group which may contain an ether bond or an ester bond, and

a is an integer of 0 to 4.

6. The resist composition of 5 which is a chemically amplified positive resist composition.

7. The resist composition of 4 wherein the base polymer is free of an acid labile group.

8. The resist composition of claim 7 which is a chemically amplified negative resist composition.

9. The resist composition of any one of 1 to 8, further comprising an organic solvent.

10. The resist composition of any one of 1 to 9, further comprising a quencher.

11. The resist composition of any one of 1 to 10, further comprising a surfactant.

12. A pattern forming process comprising the steps of applying the resist composition of any of 1 to 11 onto a substrate to form a resist film thereon, exposing the resist film to high-energy radiation, and developing the exposed resist film in a developer.

13. The pattern forming process of 12 wherein the high-energy radiation is ArF excimer laser of wavelength 193 nm, KrF excimer laser of wavelength 248 nm, EB, or EUV of wavelength 3 to 15 nm.

### Advantageous Effects of the Invention

In a resist film comprising a sulfonium salt composed of a sulfonate anion having a carbon atom to which an iodine atom is bonded and a sulfonium cation having the formula (1) as an acid generator, the degradation efficiency of the cation during exposure is high, and the carbonyl group has a high acid diffusion controlling effect due to the electron-withdrawing effect of the hydrocarbylcarbonyl group and the hydrocarbyloxycarbonyl group. By the presence of an iodine atom having a large absorption of EUV light on the anion side, the absorption by the acid generator is increased, this also improves the degradation efficiency in exposure, a variation in the number of photons is reduced by an increase in the number of absorbed photons, and the absorption contrast is improved. This makes it possible to prevent the decrease of resolution due to blurring by acid diffusion and to improve LVR and CDU. The effect of the improvement of LWR and CDU by the acid generator is effective in both positive pattern formation and negative pattern formation by alkaline aqueous solution development and negative pattern formation in organic solvent development.

### DETAILED DESCRIPTION OF THE INVENTION

Resist Composition

The resist composition of the present invention comprises an acid generator containing a sulfonium salt composed of a sulfonate anion having a carbon atom to which an iodine atom is bonded and a sulfonium cation having a specific structure having a hydrocarbylcarbonyl group or a hydrocarbyloxycarbonyl group as an acid generator.

Acid Generator

The sulfonium cation has the formula (1).

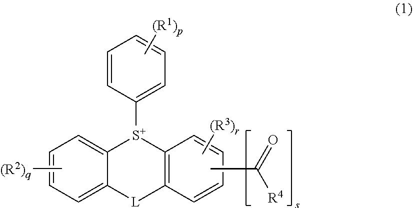

In the formula (1), p, q, and r are each independently an integer of 0 to 3, s is 1 or 2, and r+s is from 1 to 3.

In the formula (1), R¹ and R² are each independently a halogen atom, a trifluoromethyl group, a trifluoromethoxy group, a trifluoromethylthio group, a nitro group, a cyano group, —C(═O)—R⁴, —O—C(═O)—R⁵, or —O—R⁵.

In the formula (1), R³ is a halogen atom, a trifluoromethyl group, a trifluoromethoxy group, a trifluoromethylthio group, a nitro group, a cyano group. —O—C(═O)—R¹, or —O—R.

In the formula (1), R⁴ is a C₁-C₁₀ hydrocarbyl group, a C₁-C₁₀ hydrocarbyloxy group, or —O—R^{4A}, the hydrocarbyl group and the hydrocarbyloxy group may be substituted with a fluorine atom or a hydroxy group. R^{4A} is an acid labile group.

In the formula (1), R⁵ is a C₁-C₁₀ hydrocarbyl group.

The hydrocarbyl group of R⁴ and R⁵ and the hydrocarbyl moiety of the hydrocarbyloxy group of R⁴ may be saturated or unsaturated, and may be linear, branched, or cyclic. Examples thereof include C₁-C₁₀ alkyl groups such as a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a 3-pentyl group, a tert-pentyl group, a neopentyl group, an n-hexyl group, an n-octyl group, an n-nonyl group and an n-decyl group; C₃-C₁₀ cyclic saturated hydrocarbyl groups such as cyclopropyl group, a cyclobutyl group, a cyclopentyl group, a cyclohexyl group, an adamantyl group, a norbornyl group, a cyclopropylmethyl group, a cyclopropylethyl group, a cyclobutylmethyl group, a cyclobutylethyl group, a cyclopentylmethyl group, a cyclopentylethyl group, a cyclohexylmethyl group, a cyclohexylethyl group, a methylcyclopropyl group, a methylcyclobutyl group, a methylcyclopentyl group, a methylcyclohexyl group, an ethylcyclopropyl group, an ethylcyclobutyl group, an ethylcyclopentyl group and an ethylcyclohexyl group; C₂-C₁₀ alkenyl groups such as a vinyl group, a 1-propenyl group, a 2-propenyl group, a butenyl group, a pentenyl group, a hexenyl group, a heptenyl group, a nonenyl group and a decenyl group; C₂-C₁₀ alkynyl groups such as an ethynyl group, a propynyl group, a butynyl group, a pentynyl group, a hexynyl group, a heptynyl group, an octynyl group, a nonynyl group and a decynyl group; C₃-C₁₀ cyclic unsaturated aliphatic hydrocarbyl groups such as a cyclopentenyl group, a cyclohexenyl group, a methylcyclopentenyl group, a methylcyclohexenyl group, an ethylcyclopentenyl group, an ethylcyclohexenyl group and a norbornenyl group; C₇-C₁₀ aryl groups such as a phenyl group, a methylphenyl group, an ethylphenyl group, an n-propylphenyl group, an isopropylphenyl group, an n-butylphenyl group, an isobutylphenyl group, a sec-butylphenyl group, a tert-butylphenyl group and a naphthyl group; C₇-C₁₀ aralkyl groups such as a benzyl group, a phenethyl group, a phenylpropyl group and a phenylbutyl group; and combinations thereof.

Examples of the acid labile group of R^{4A} include acid labile groups having formulae (AL-1) to (AL-3) described later.

In the formula (1), L is a single bond, an ether bond, a carbonyl group, —N(R)—, a sulfide bond, or a sulfonyl group. R is a hydrogen atom or a C₁-C₆ saturated hydrocarbyl group.

Examples of the sulfonium cation having the formula (1) are shown below, but not limited thereto.

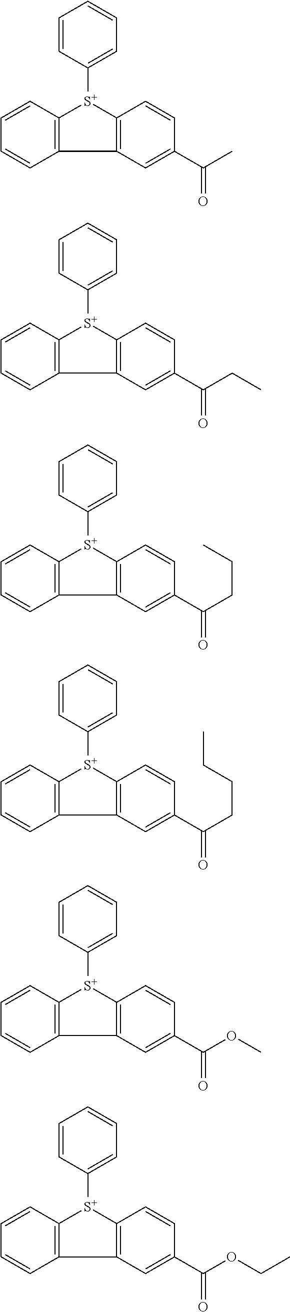 [SMILES: CC(=O)c1ccc2c(c1)c1ccccc1[s+]2-c1ccccc1 ; CCC(=O)c1ccc2c(c1)c1ccccc1[s+]2-c1ccccc1 ; CCCC(=O)c1ccc2c(c1)c1ccccc1[s+]2-c1ccccc1 ; CCCCC(=O)c1ccc2c(c1)c1ccccc1[s+]2-c1ccccc1 ; COC(=O)c1ccc2c(c1)c1ccccc1[s+]2-c1ccccc1 ; CCOC(=O)c1ccc2c(c1)c1ccccc1[s+]2-c1ccccc1]

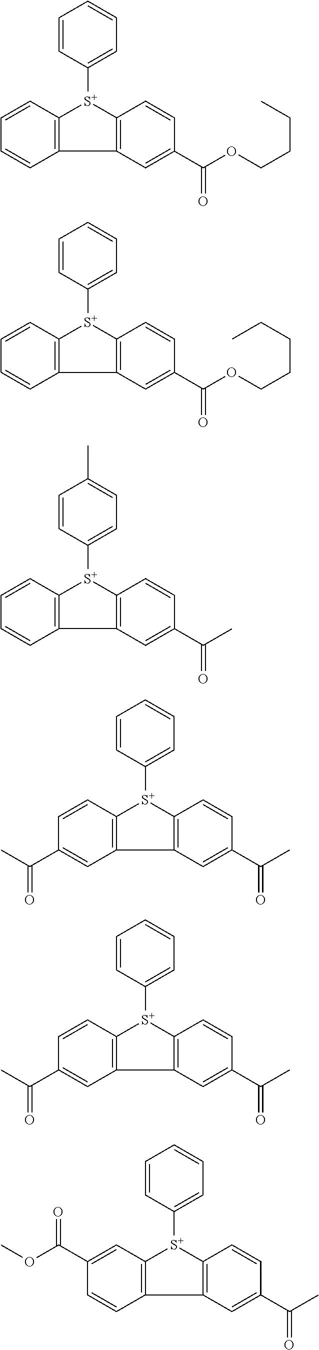

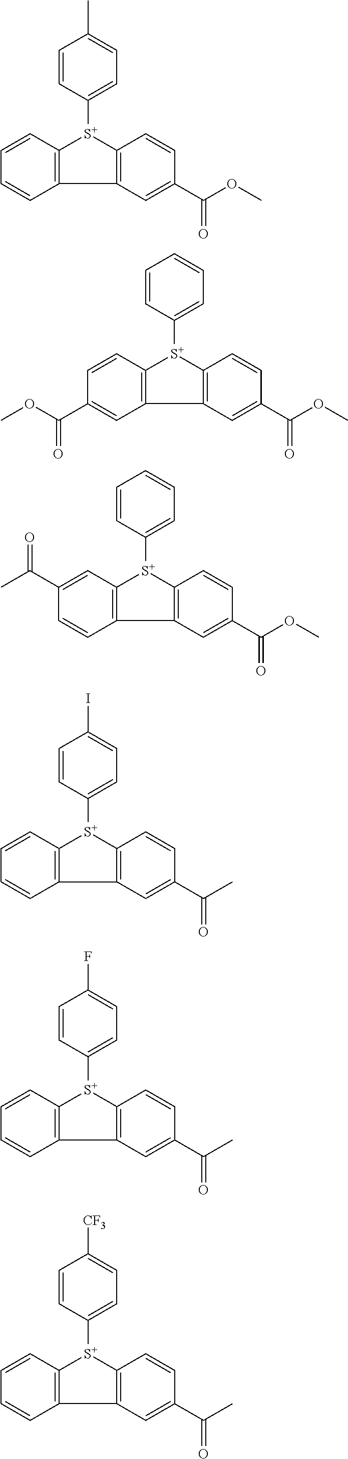

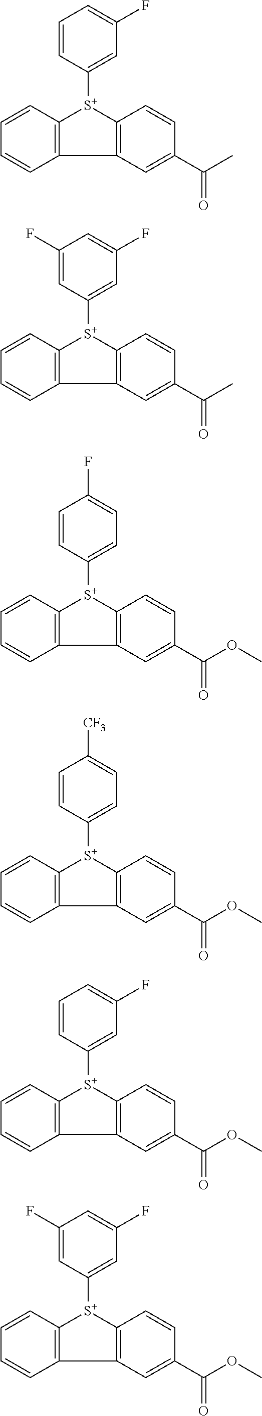 [SMILES: CC(=O)c1ccc2c(c1)c1ccccc1[s+]2-c1cccc(F)c1 ; CC(=O)c1ccc2c(c1)c1ccccc1[s+]2-c1cc(F)cc(F)c1 ; COC(=O)c1ccc2c(c1)c1ccccc1[s+]2-c1ccc(F)cc1 ; COC(=O)c1ccc2c(c1)c1ccccc1[s+]2-c1ccc(C(F)(F)F)cc1 ; COC(=O)c1ccc2c(c1)c1ccccc1[s+]2-c1cccc(F)c1 ; COC(=O)c1ccc2c(c1)c1ccccc1[s+]2-c1cc(F)cc(F)c1]

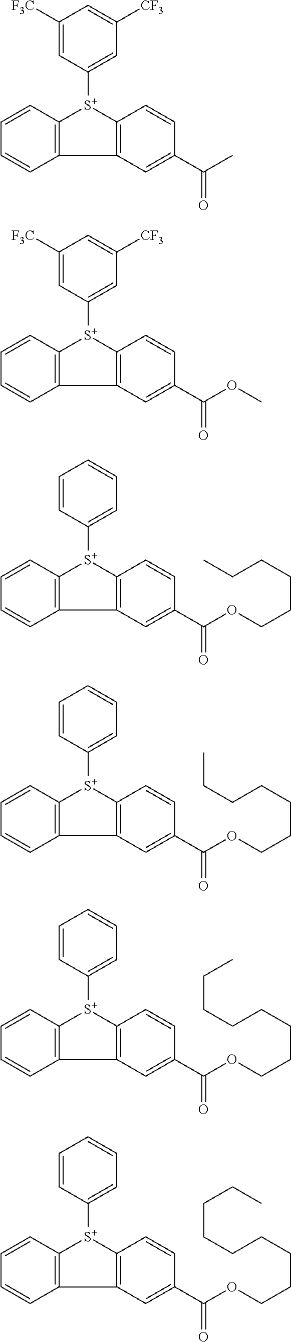 [SMILES: CC(=O)c1ccc2c(c1)c1ccccc1[s+]2-c1cc(C(F)(F)F)cc(C(F)(F)F)c1 ; COC(=O)c1ccc2c(c1)c1ccccc1[s+]2-c1cc(C(F)(F)F)cc(C(F)(F)F)c1 ; CCCCCCOC(=O)c1ccc2c(c1)c1ccccc1[s+]2-c1ccccc1 ; CCCCCCCOC(=O)c1ccc2c(c1)c1ccccc1[s+]2-c1ccccc1 ; CCCCCCCCOC(=O)c1ccc2c(c1)c1ccccc1[s+]2-c1ccccc1 ; CCCCCCCCCOC(=O)c1ccc2c(c1)c1ccccc1[s+]2-c1ccccc1]

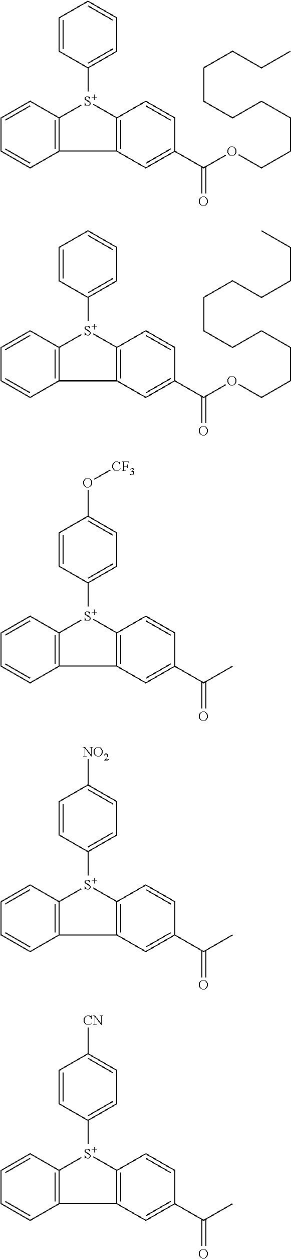 [SMILES: CCCCCCCCCCOC(=O)c1ccc2c(c1)c1ccccc1[s+]2-c1ccccc1 ; CCCCCCCCCCCCOC(=O)c1ccc2c(c1)c1ccccc1[s+]2-c1ccccc1 ; CC(=O)c1ccc2c(c1)c1ccccc1[s+]2-c1ccc(OC(F)(F)F)cc1 ; CC(=O)c1ccc2c(c1)c1ccccc1[s+]2-c1ccc([N+](=O)[O-])cc1 ; CC(=O)c1ccc2c(c1)c1ccccc1[s+]2-c1ccc(C#N)cc1]

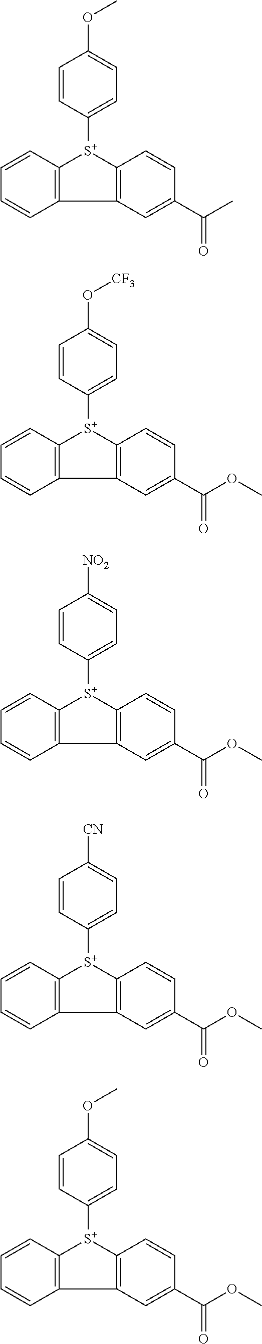 [SMILES: COc1ccc(-[s+]2c3ccccc3c3cc(C(C)=O)ccc32)cc1 ; COC(=O)c1ccc2c(c1)c1ccccc1[s+]2-c1ccc(OC(F)(F)F)cc1 ; COC(=O)c1ccc2c(c1)c1ccccc1[s+]2-c1ccc([N+](=O)[O-])cc1 ; COC(=O)c1ccc2c(c1)c1ccccc1[s+]2-c1ccc(C#N)cc1 ; COC(=O)c1ccc2c(c1)c1ccccc1[s+]2-c1ccc(OC)cc1]

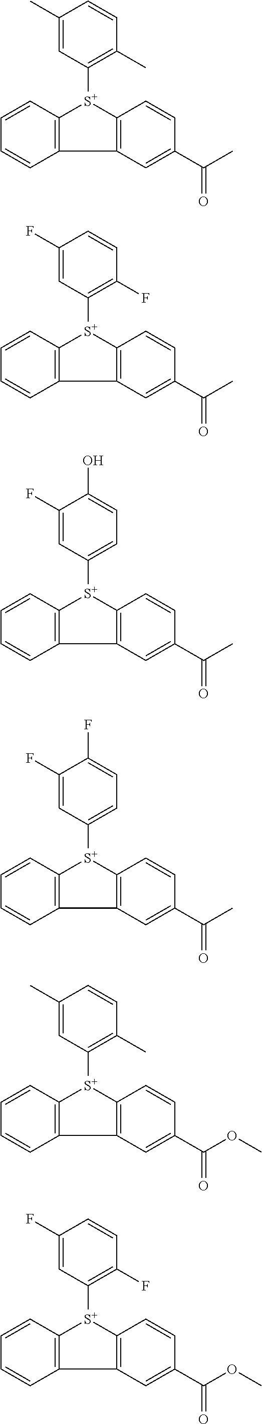 [SMILES: CC(=O)c1ccc2c(c1)c1ccccc1[s+]2-c1cc(C)ccc1C ; CC(=O)c1ccc2c(c1)c1ccccc1[s+]2-c1cc(F)ccc1F ; CC(=O)c1ccc2c(c1)c1ccccc1[s+]2-c1ccc(O)c(F)c1 ; CC(=O)c1ccc2c(c1)c1ccccc1[s+]2-c1ccc(F)c(F)c1 ; COC(=O)c1ccc2c(c1)c1ccccc1[s+]2-c1cc(C)ccc1C ; COC(=O)c1ccc2c(c1)c1ccccc1[s+]2-c1cc(F)ccc1F]

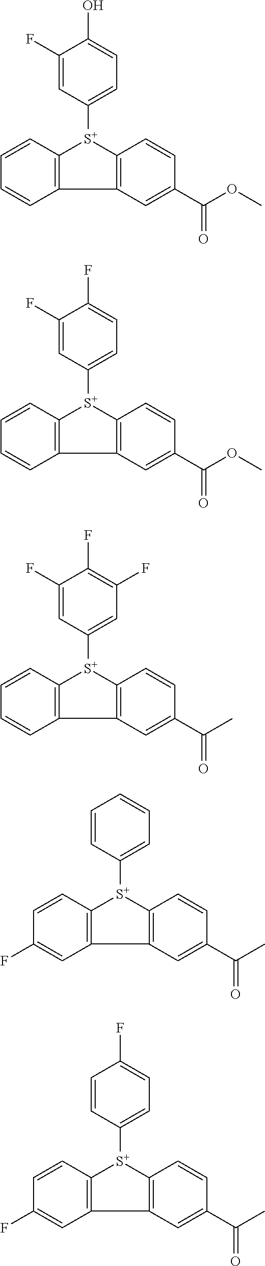 [SMILES: COC(=O)c1ccc2c(c1)c1ccccc1[s+]2-c1ccc(O)c(F)c1 ; COC(=O)c1ccc2c(c1)c1ccccc1[s+]2-c1ccc(F)c(F)c1 ; CC(=O)c1ccc2c(c1)c1ccccc1[s+]2-c1cc(F)c(F)c(F)c1 ; CC(=O)c1ccc2c(c1)c1cc(F)ccc1[s+]2-c1ccccc1 ; CC(=O)c1ccc2c(c1)c1cc(F)ccc1[s+]2-c1ccc(F)cc1]

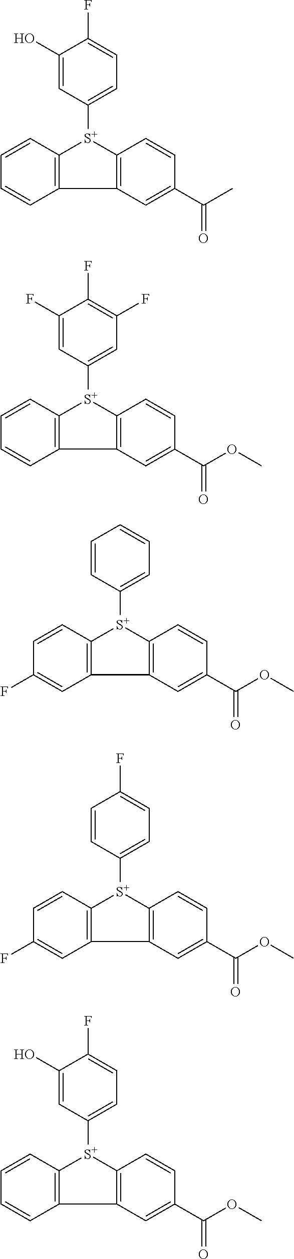 [SMILES: CC(=O)c1ccc2c(c1)c1ccccc1[s+]2-c1ccc(F)c(O)c1 ; COC(=O)c1ccc2c(c1)c1ccccc1[s+]2-c1cc(F)c(F)c(F)c1 ; COC(=O)c1ccc2c(c1)c1cc(F)ccc1[s+]2-c1ccccc1 ; COC(=O)c1ccc2c(c1)c1cc(F)ccc1[s+]2-c1ccc(F)cc1 ; COC(=O)c1ccc2c(c1)c1ccccc1[s+]2-c1ccc(F)c(O)c1]

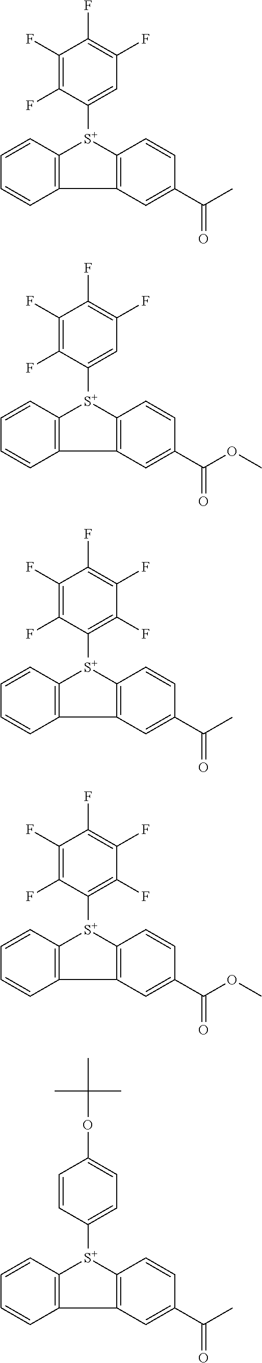 [SMILES: CC(=O)c1ccc2c(c1)c1ccccc1[s+]2-c1cc(F)c(F)c(F)c1F ; COC(=O)c1ccc2c(c1)c1ccccc1[s+]2-c1cc(F)c(F)c(F)c1F ; CC(=O)c1ccc2c(c1)c1ccccc1[s+]2-c1c(F)c(F)c(F)c(F)c1F ; COC(=O)c1ccc2c(c1)c1ccccc1[s+]2-c1c(F)c(F)c(F)c(F)c1F ; CC(=O)c1ccc2c(c1)c1ccccc1[s+]2-c1ccc(OC(C)(C)C)cc1]

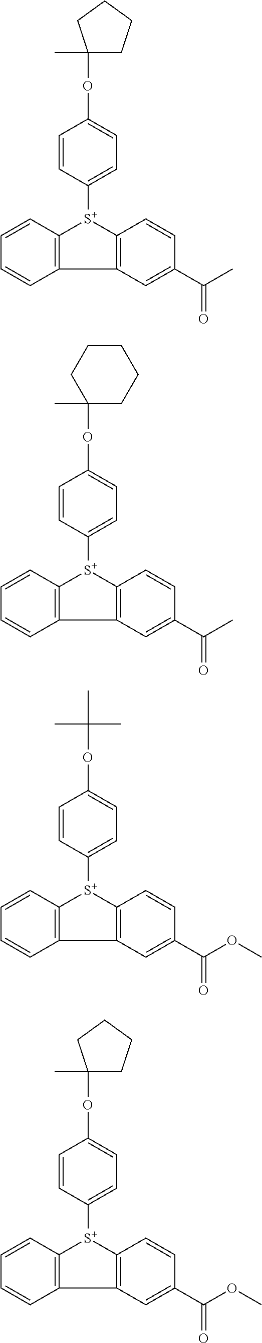 [SMILES: CC(=O)c1ccc2c(c1)c1ccccc1[s+]2-c1ccc(OC2(C)CCCC2)cc1 ; CC(=O)c1ccc2c(c1)c1ccccc1[s+]2-c1ccc(OC2(C)CCCCC2)cc1 ; COC(=O)c1ccc2c(c1)c1ccccc1[s+]2-c1ccc(OC(C)(C)C)cc1 ; COC(=O)c1ccc2c(c1)c1ccccc1[s+]2-c1ccc(OC2(C)CCCC2)cc1]

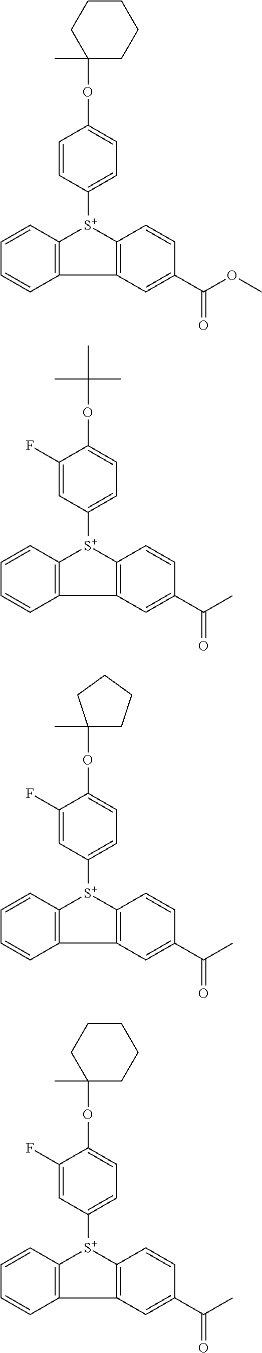 [SMILES: COC(=O)c1ccc2c(c1)c1ccccc1[s+]2-c1ccc(OC2(C)CCCCC2)cc1 ; CC(=O)c1ccc2c(c1)c1ccccc1[s+]2-c1ccc(OC(C)(C)C)c(F)c1 ; CC(=O)c1ccc2c(c1)c1ccccc1[s+]2-c1ccc(OC2(C)CCCC2)c(F)c1 ; CC(=O)c1ccc2c(c1)c1ccccc1[s+]2-c1ccc(OC2(C)CCCCC2)c(F)c1]

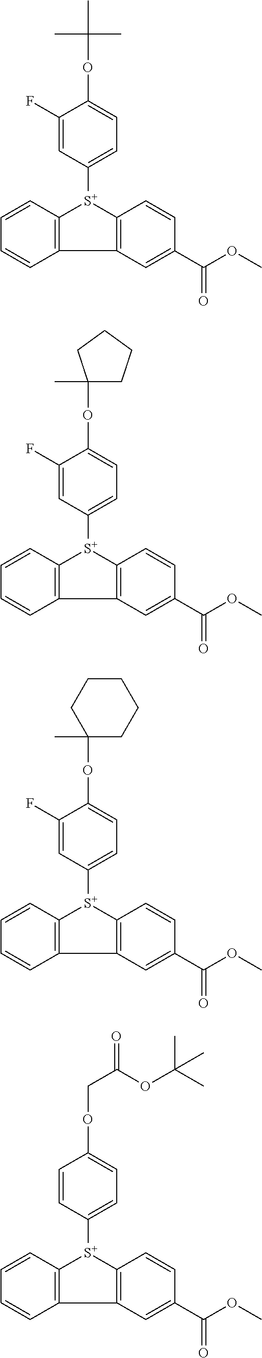 [SMILES: COC(=O)c1ccc2c(c1)c1ccccc1[s+]2-c1ccc(OC(C)(C)C)c(F)c1 ; COC(=O)c1ccc2c(c1)c1ccccc1[s+]2-c1ccc(OC2(C)CCCC2)c(F)c1 ; COC(=O)c1ccc2c(c1)c1ccccc1[s+]2-c1ccc(OC2(C)CCCCC2)c(F)c1 ; COC(=O)c1ccc2c(c1)c1ccccc1[s+]2-c1ccc(OCC(=O)OC(C)(C)C)cc1]

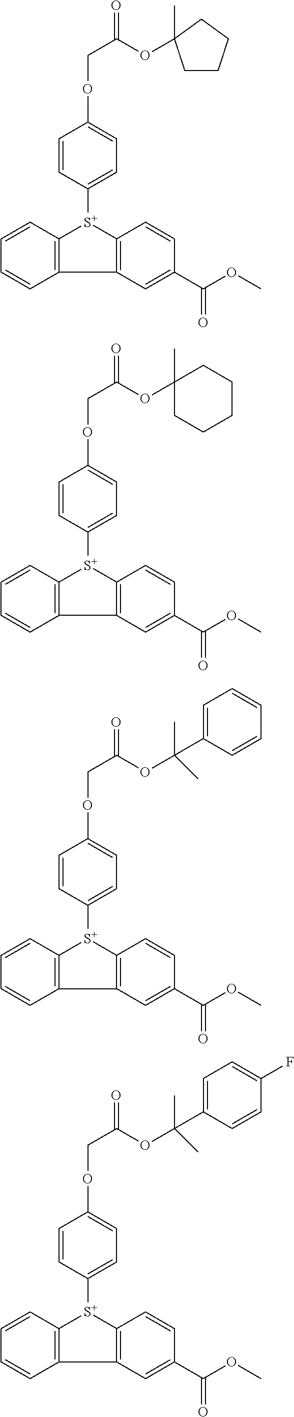 [SMILES: COC(=O)c1ccc2c(c1)c1ccccc1[s+]2-c1ccc(OCC(=O)OC2(C)CCCC2)cc1 ; COC(=O)c1ccc2c(c1)c1ccccc1[s+]2-c1ccc(OCC(=O)OC2(C)CCCCC2)cc1 ; COC(=O)c1ccc2c(c1)c1ccccc1[s+]2-c1ccc(OCC(=O)OC(C)(C)c2ccccc2)cc1 ; COC(=O)c1ccc2c(c1)c1ccccc1[s+]2-c1ccc(OCC(=O)OC(C)(C)c2ccc(F)cc2)cc1]

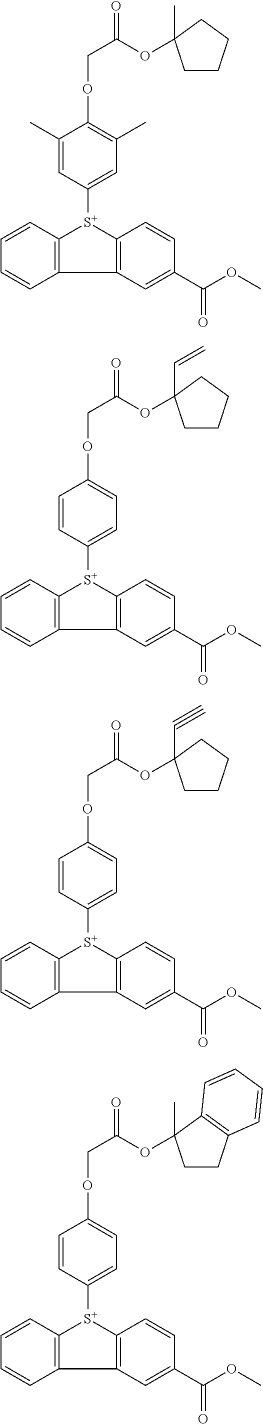 [SMILES: COC(=O)c1ccc2c(c1)c1ccccc1[s+]2-c1cc(C)c(OCC(=O)OC2(C)CCCC2)c(C)c1 ; C=CC1(OC(=O)COc2ccc(-[s+]3c4ccccc4c4cc(C(=O)OC)ccc43)cc2)CCCC1 ; C#CC1(OC(=O)COc2ccc(-[s+]3c4ccccc4c4cc(C(=O)OC)ccc43)cc2)CCCC1 ; COC(=O)c1ccc2c(c1)c1ccccc1[s+]2-c1ccc(OCC(=O)OC2(C)CCc3ccccc32)cc1]

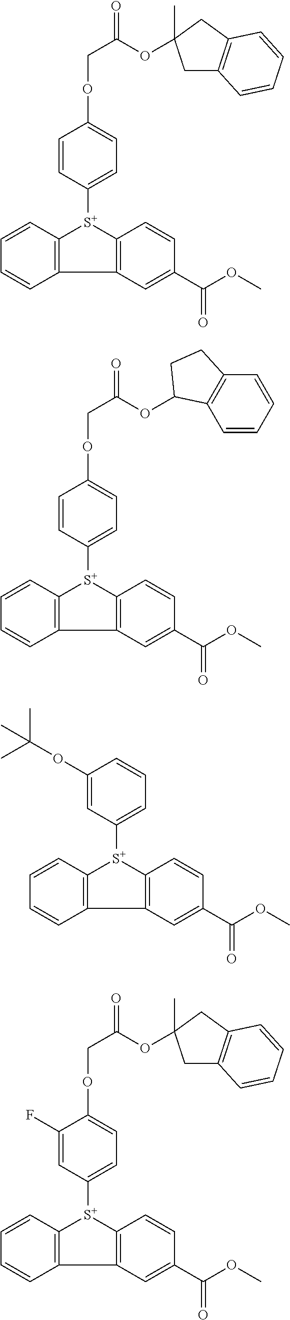 [SMILES: COC(=O)c1ccc2c(c1)c1ccccc1[s+]2-c1ccc(OCC(=O)OC2(C)Cc3ccccc3C2)cc1 ; COC(=O)c1ccc2c(c1)c1ccccc1[s+]2-c1ccc(OCC(=O)OC2CCc3ccccc32)cc1 ; COC(=O)c1ccc2c(c1)c1ccccc1[s+]2-c1cccc(OC(C)(C)C)c1 ; COC(=O)c1ccc2c(c1)c1ccccc1[s+]2-c1ccc(OCC(=O)OC2(C)Cc3ccccc3C2)c(F)c1]

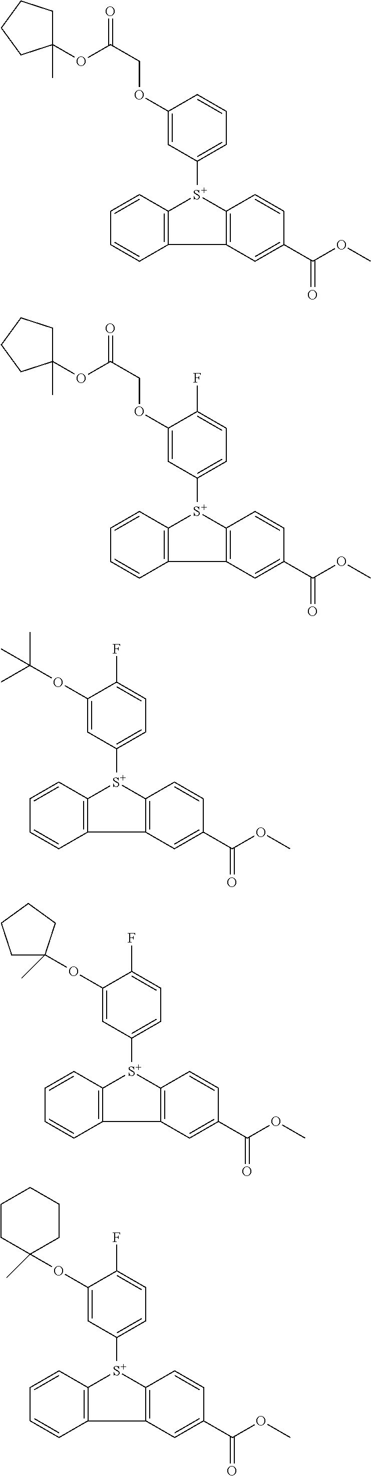

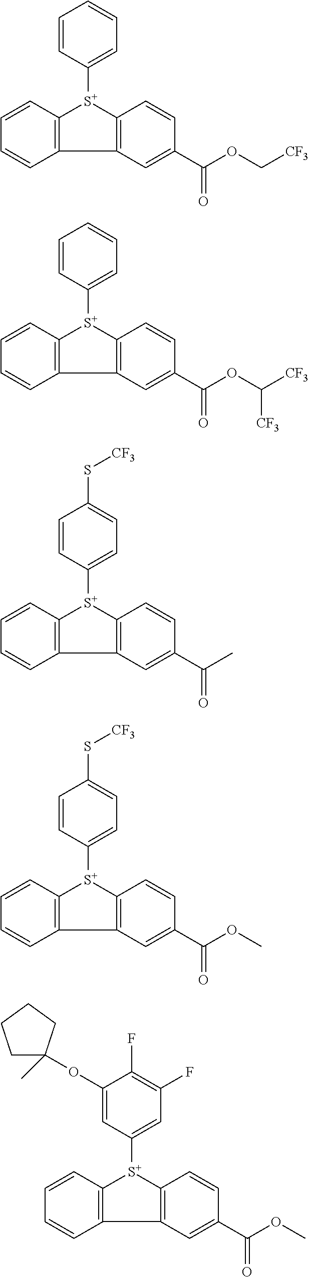 [SMILES: O=C(OCC(F)(F)F)c1ccc2c(c1)c1ccccc1[s+]2-c1ccccc1 ; O=C(OC(C(F)(F)F)C(F)(F)F)c1ccc2c(c1)c1ccccc1[s+]2-c1ccccc1 ; CC(=O)c1ccc2c(c1)c1ccccc1[s+]2-c1ccc(SC(F)(F)F)cc1 ; COC(=O)c1ccc2c(c1)c1ccccc1[s+]2-c1ccc(SC(F)(F)F)cc1 ; COC(=O)c1ccc2c(c1)c1ccccc1[s+]2-c1cc(F)c(F)c(OC2(C)CCCC2)c1]

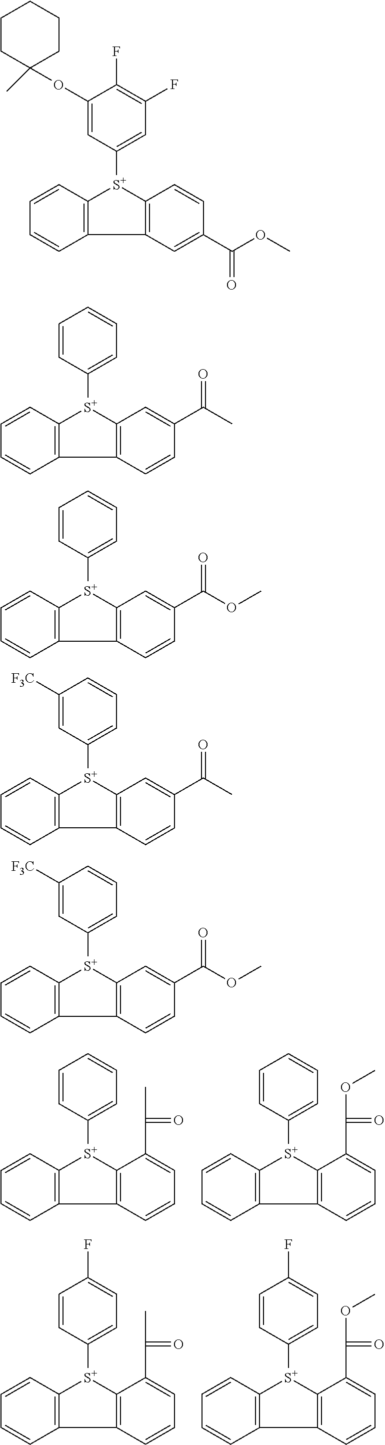

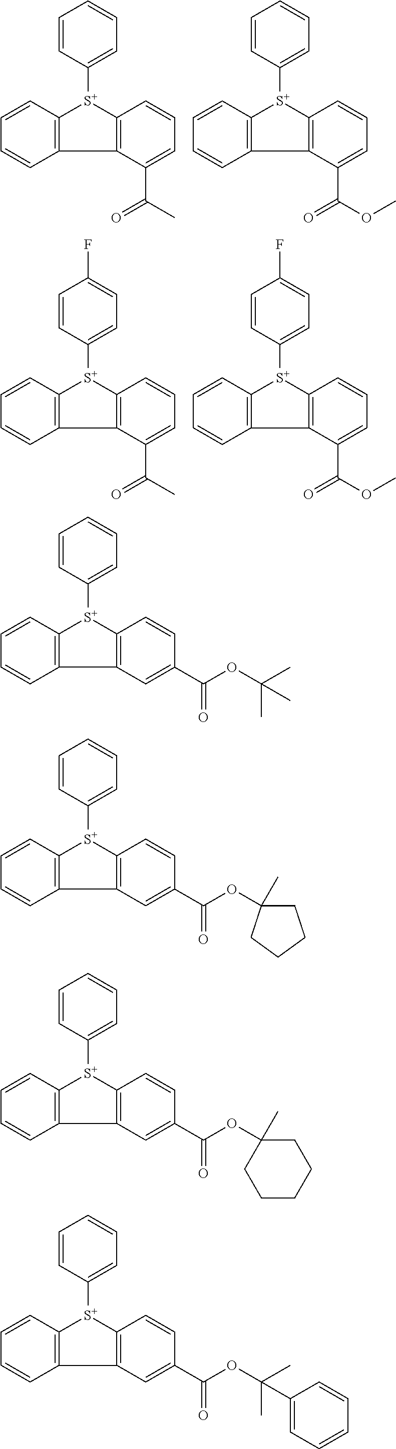

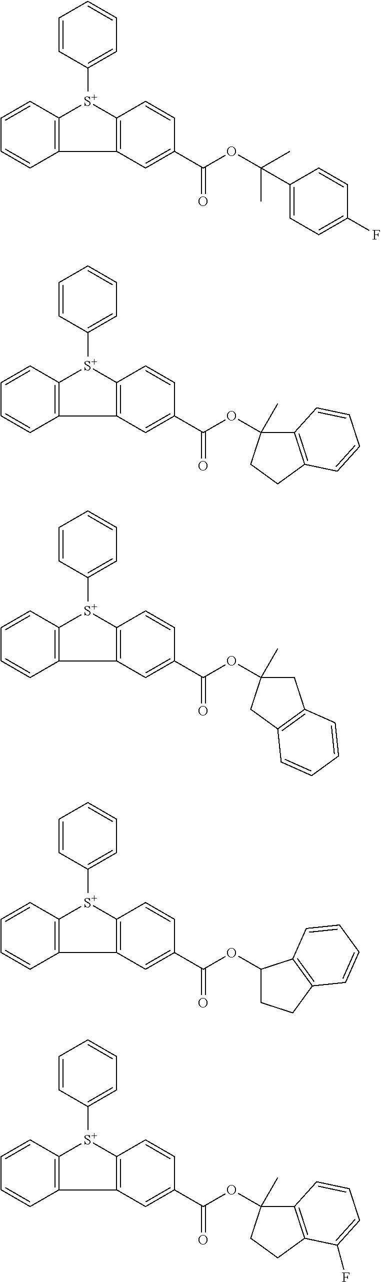 [SMILES: CC(C)(OC(=O)c1ccc2c(c1)c1ccccc1[s+]2-c1ccccc1)c1ccc(F)cc1 ; CC1(OC(=O)c2ccc3c(c2)c2ccccc2[s+]3-c2ccccc2)CCc2ccccc21 ; CC1(OC(=O)c2ccc3c(c2)c2ccccc2[s+]3-c2ccccc2)Cc2ccccc2C1 ; O=C(OC1CCc2ccccc21)c1ccc2c(c1)c1ccccc1[s+]2-c1ccccc1 ; CC1(OC(=O)c2ccc3c(c2)c2ccccc2[s+]3-c2ccccc2)CCc2c(F)cccc21]

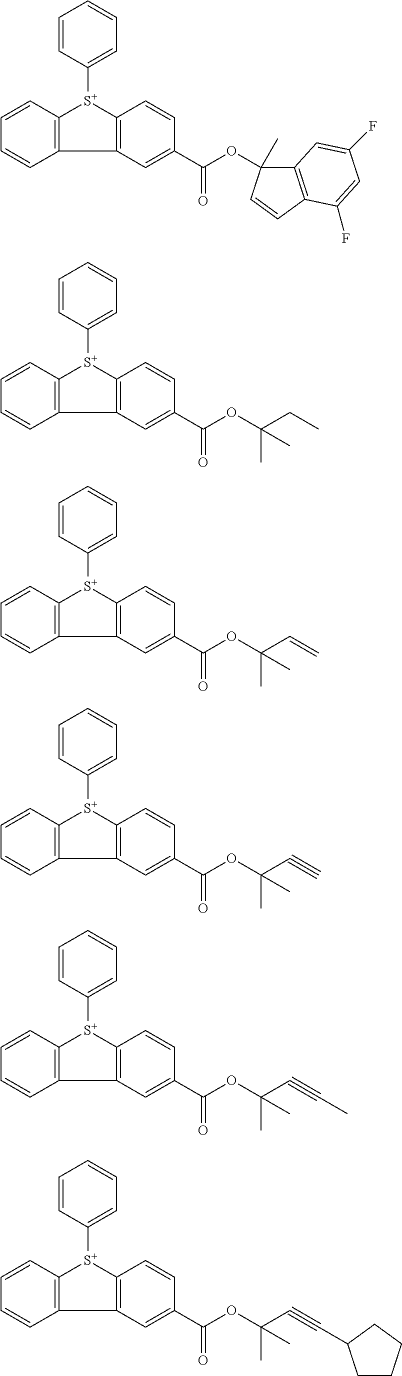 [SMILES: CC1(OC(=O)c2ccc3c(c2)c2ccccc2[s+]3-c2ccccc2)C=Cc2c(F)cc(F)cc21 ; CCC(C)(C)OC(=O)c1ccc2c(c1)c1ccccc1[s+]2-c1ccccc1 ; C=CC(C)(C)OC(=O)c1ccc2c(c1)c1ccccc1[s+]2-c1ccccc1 ; C#CC(C)(C)OC(=O)c1ccc2c(c1)c1ccccc1[s+]2-c1ccccc1 ; CC#CC(C)(C)OC(=O)c1ccc2c(c1)c1ccccc1[s+]2-c1ccccc1 ; CC(C)(C#CC1CCCC1)OC(=O)c1ccc2c(c1)c1ccccc1[s+]2-c1ccccc1]

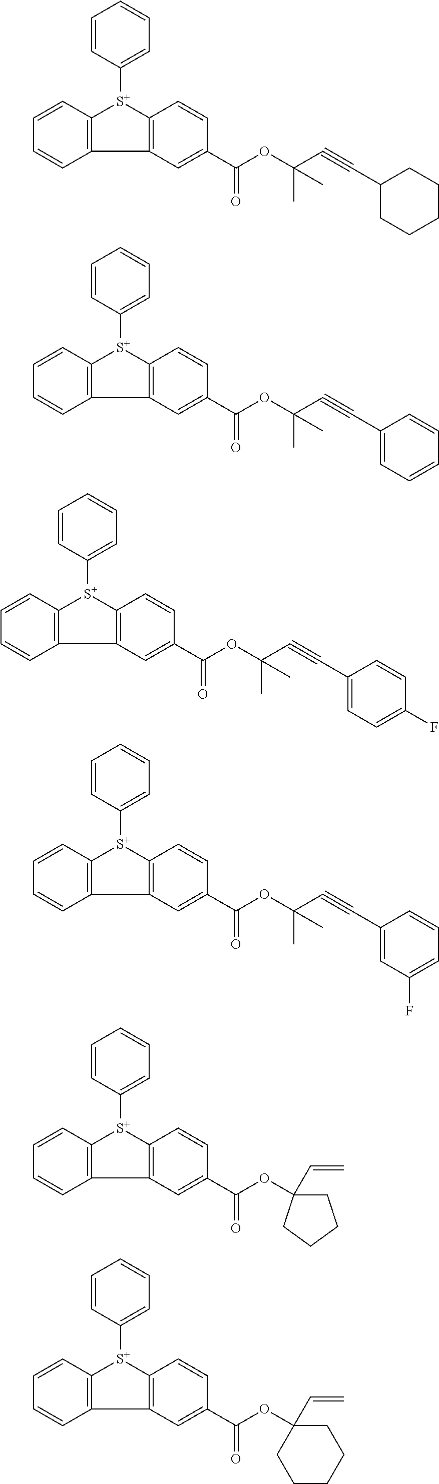 [SMILES: CC(C)(C#CC1CCCCC1)OC(=O)c1ccc2c(c1)c1ccccc1[s+]2-c1ccccc1 ; CC(C)(C#Cc1ccccc1)OC(=O)c1ccc2c(c1)c1ccccc1[s+]2-c1ccccc1 ; CC(C)(C#Cc1ccc(F)cc1)OC(=O)c1ccc2c(c1)c1ccccc1[s+]2-c1ccccc1 ; CC(C)(C#Cc1cccc(F)c1)OC(=O)c1ccc2c(c1)c1ccccc1[s+]2-c1ccccc1 ; C=CC1(OC(=O)c2ccc3c(c2)c2ccccc2[s+]3-c2ccccc2)CCCC1 ; C=CC1(OC(=O)c2ccc3c(c2)c2ccccc2[s+]3-c2ccccc2)CCCCC1]

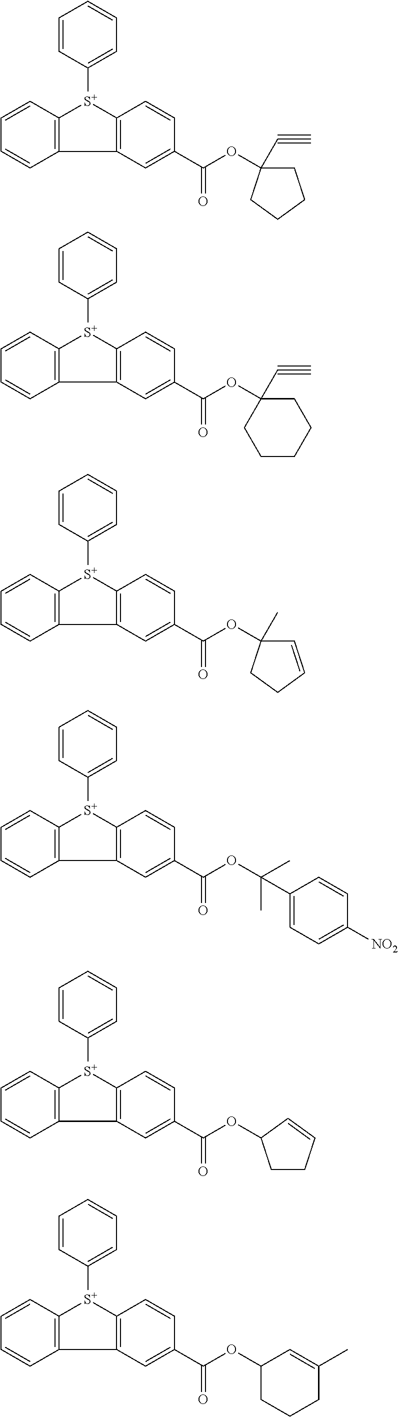 [SMILES: C#CC1(OC(=O)c2ccc3c(c2)c2ccccc2[s+]3-c2ccccc2)CCCC1 ; C#CC1(OC(=O)c2ccc3c(c2)c2ccccc2[s+]3-c2ccccc2)CCCCC1 ; CC1(OC(=O)c2ccc3c(c2)c2ccccc2[s+]3-c2ccccc2)C=CCC1 ; CC(C)(OC(=O)c1ccc2c(c1)c1ccccc1[s+]2-c1ccccc1)c1ccc([N+](=O)[O-])cc1 ; O=C(OC1C=CCC1)c1ccc2c(c1)c1ccccc1[s+]2-c1ccccc1 ; CC1=CC(OC(=O)c2ccc3c(c2)c2ccccc2[s+]3-c2ccccc2)CCC1]

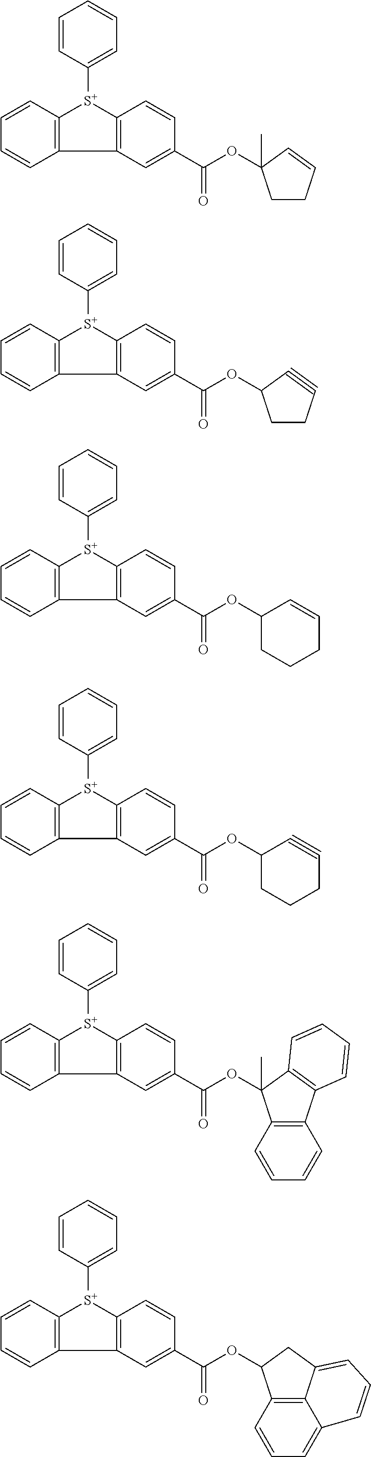 [SMILES: CC1(OC(=O)c2ccc3c(c2)c2ccccc2[s+]3-c2ccccc2)C=CCC1 ; O=C(OC1C#CCC1)c1ccc2c(c1)c1ccccc1[s+]2-c1ccccc1 ; O=C(OC1C=CCCC1)c1ccc2c(c1)c1ccccc1[s+]2-c1ccccc1 ; O=C(OC1C#CCCC1)c1ccc2c(c1)c1ccccc1[s+]2-c1ccccc1 ; CC1(OC(=O)c2ccc3c(c2)c2ccccc2[s+]3-c2ccccc2)c2ccccc2-c2ccccc21 ; O=C(OC1Cc2cccc3cccc1c23)c1ccc2c(c1)c1ccccc1[s+]2-c1ccccc1]

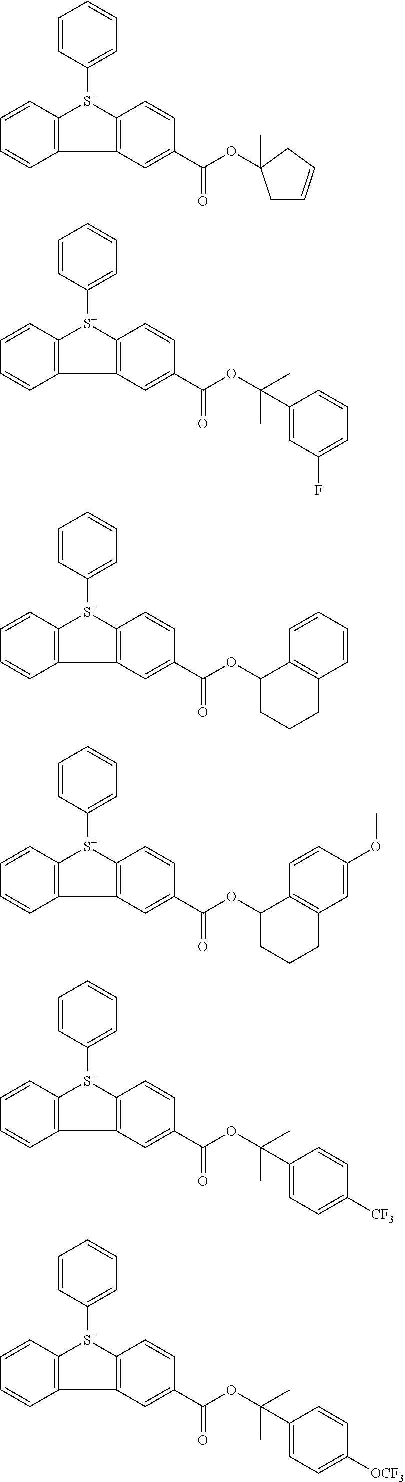 [SMILES: CC1(OC(=O)c2ccc3c(c2)c2ccccc2[s+]3-c2ccccc2)CC=CC1 ; CC(C)(OC(=O)c1ccc2c(c1)c1ccccc1[s+]2-c1ccccc1)c1cccc(F)c1 ; O=C(OC1CCCc2ccccc21)c1ccc2c(c1)c1ccccc1[s+]2-c1ccccc1 ; COc1ccc2c(c1)CCCC2OC(=O)c1ccc2c(c1)c1ccccc1[s+]2-c1ccccc1 ; CC(C)(OC(=O)c1ccc2c(c1)c1ccccc1[s+]2-c1ccccc1)c1ccc(C(F)(F)F)cc1 ; CC(C)(OC(=O)c1ccc2c(c1)c1ccccc1[s+]2-c1ccccc1)c1ccc(OC(F)(F)F)cc1]

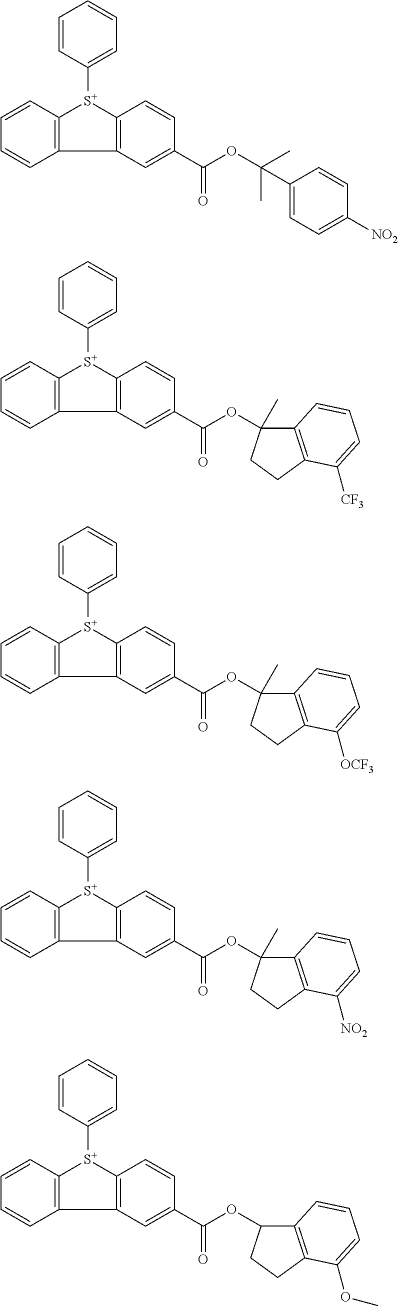 [SMILES: CC(C)(OC(=O)c1ccc2c(c1)c1ccccc1[s+]2-c1ccccc1)c1ccc([N+](=O)[O-])cc1 ; CC1(OC(=O)c2ccc3c(c2)c2ccccc2[s+]3-c2ccccc2)CCc2c(C(F)(F)F)cccc21 ; CC1(OC(=O)c2ccc3c(c2)c2ccccc2[s+]3-c2ccccc2)CCc2c(OC(F)(F)F)cccc21 ; CC1(OC(=O)c2ccc3c(c2)c2ccccc2[s+]3-c2ccccc2)CCc2c([N+](=O)[O-])cccc21 ; COc1cccc2c1CCC2OC(=O)c1ccc2c(c1)c1ccccc1[s+]2-c1ccccc1]

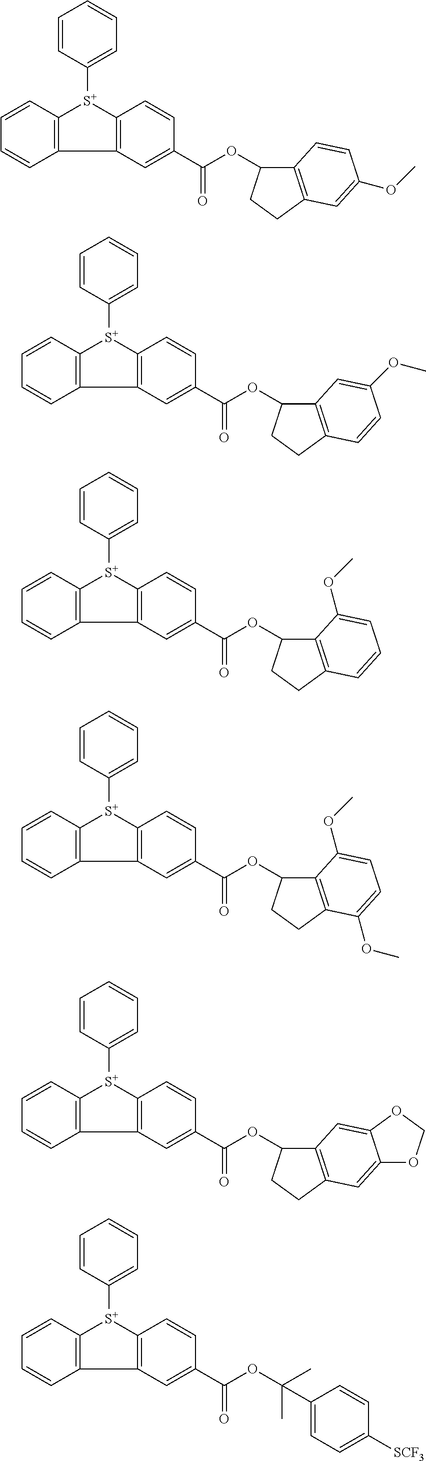

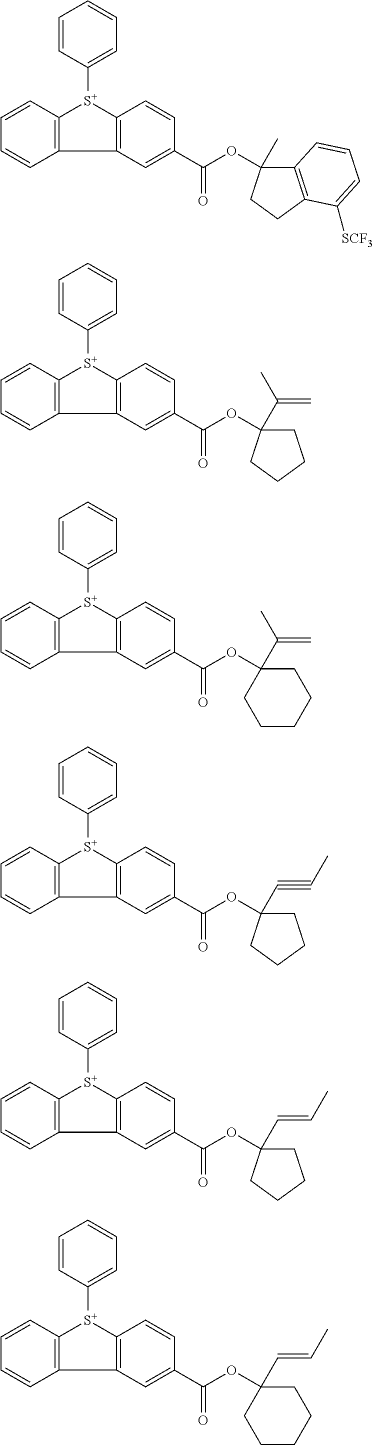

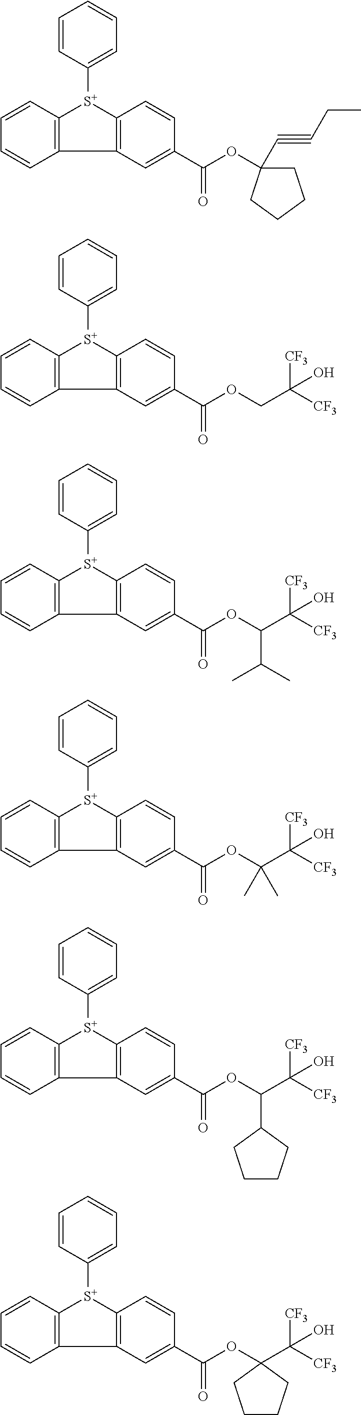 [SMILES: CCC#CC1(OC(=O)c2ccc3c(c2)c2ccccc2[s+]3-c2ccccc2)CCCC1 ; O=C(OCC(O)(C(F)(F)F)C(F)(F)F)c1ccc2c(c1)c1ccccc1[s+]2-c1ccccc1 ; CC(C)C(OC(=O)c1ccc2c(c1)c1ccccc1[s+]2-c1ccccc1)C(O)(C(F)(F)F)C(F)(F)F ; CC(C)(OC(=O)c1ccc2c(c1)c1ccccc1[s+]2-c1ccccc1)C(O)(C(F)(F)F)C(F)(F)F ; O=C(OC(C1CCCC1)C(O)(C(F)(F)F)C(F)(F)F)c1ccc2c(c1)c1ccccc1[s+]2-c1ccccc1 ; O=C(OC1(C(O)(C(F)(F)F)C(F)(F)F)CCCC1)c1ccc2c(c1)c1ccccc1[s+]2-c1ccccc1]

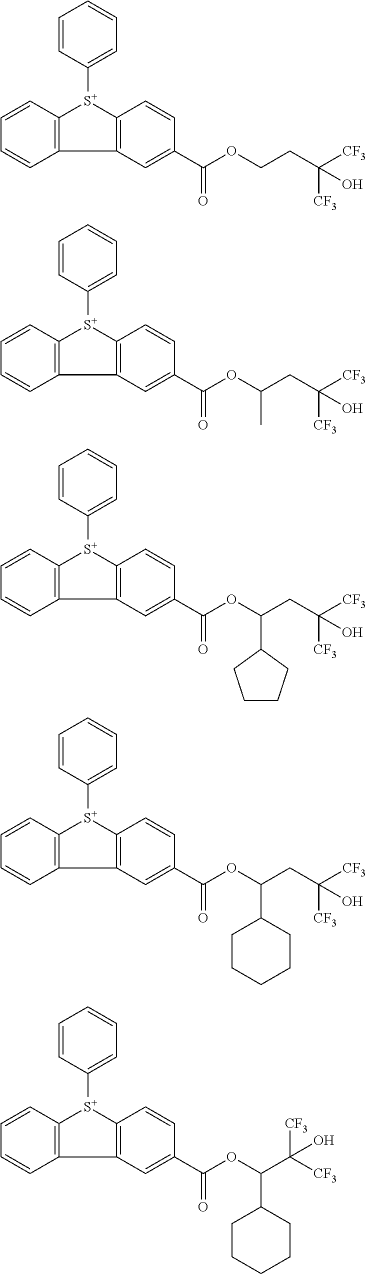 [SMILES: O=C(OCCC(O)(C(F)(F)F)C(F)(F)F)c1ccc2c(c1)c1ccccc1[s+]2-c1ccccc1 ; CC(CC(O)(C(F)(F)F)C(F)(F)F)OC(=O)c1ccc2c(c1)c1ccccc1[s+]2-c1ccccc1 ; O=C(OC(CC(O)(C(F)(F)F)C(F)(F)F)C1CCCC1)c1ccc2c(c1)c1ccccc1[s+]2-c1ccccc1 ; O=C(OC(CC(O)(C(F)(F)F)C(F)(F)F)C1CCCCC1)c1ccc2c(c1)c1ccccc1[s+]2-c1ccccc1 ; O=C(OC(C1CCCCC1)C(O)(C(F)(F)F)C(F)(F)F)c1ccc2c(c1)c1ccccc1[s+]2-c1ccccc1]

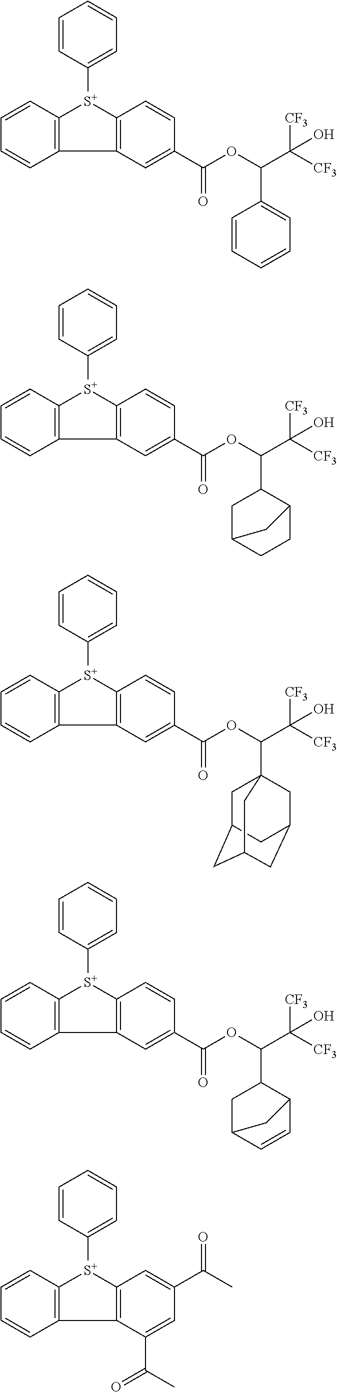 [SMILES: O=C(OC(c1ccccc1)C(O)(C(F)(F)F)C(F)(F)F)c1ccc2c(c1)c1ccccc1[s+]2-c1ccccc1 ; O=C(OC(C1CC2CCC1C2)C(O)(C(F)(F)F)C(F)(F)F)c1ccc2c(c1)c1ccccc1[s+]2-c1ccccc1 ; O=C(OC(C12CC3CC(CC(C3)C1)C2)C(O)(C(F)(F)F)C(F)(F)F)c1ccc2c(c1)c1ccccc1[s+]2-c1ccccc1 ; O=C(OC(C1CC2C=CC1C2)C(O)(C(F)(F)F)C(F)(F)F)c1ccc2c(c1)c1ccccc1[s+]2-c1ccccc1 ; CC(=O)c1cc(C(C)=O)c2c3ccccc3[s+](-c3ccccc3)c2c1]

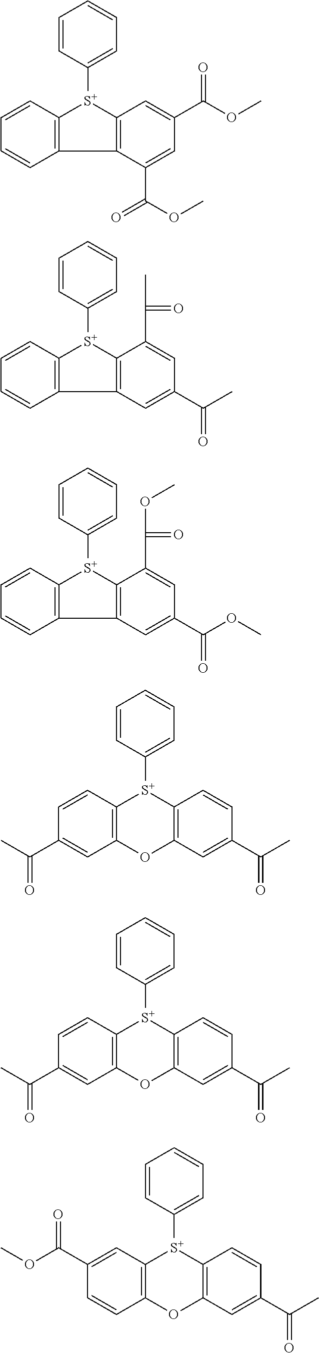

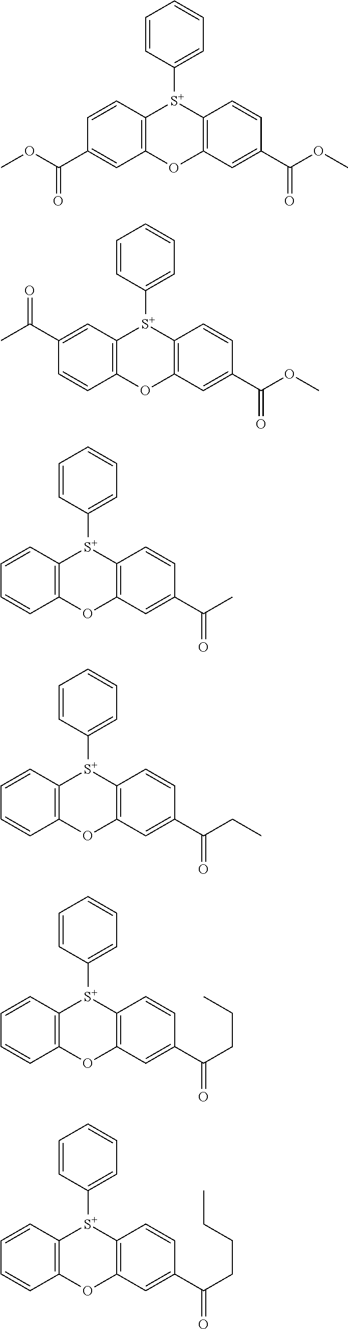

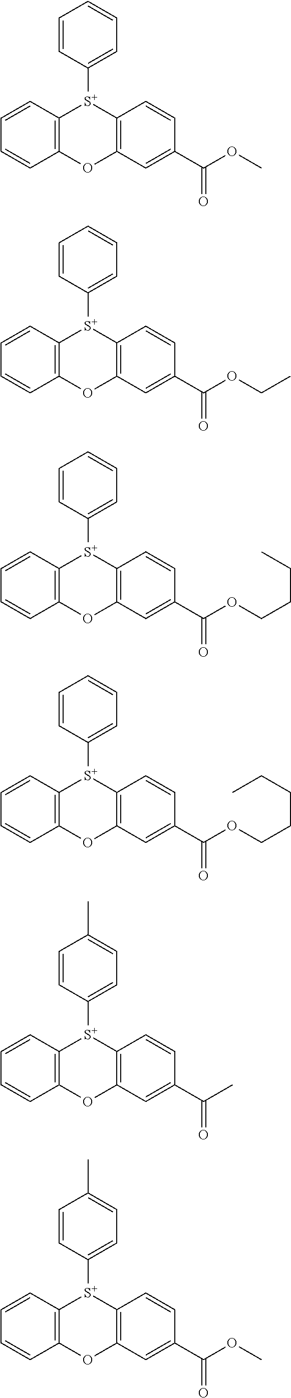 [SMILES: COC(=O)c1ccc2c(c1)Oc1ccccc1[S+]2c1ccccc1 ; CCOC(=O)c1ccc2c(c1)Oc1ccccc1[S+]2c1ccccc1 ; CCCCOC(=O)c1ccc2c(c1)Oc1ccccc1[S+]2c1ccccc1 ; CCCCCOC(=O)c1ccc2c(c1)Oc1ccccc1[S+]2c1ccccc1 ; CC(=O)c1ccc2c(c1)Oc1ccccc1[S+]2c1ccc(C)cc1 ; COC(=O)c1ccc2c(c1)Oc1ccccc1[S+]2c1ccc(C)cc1]

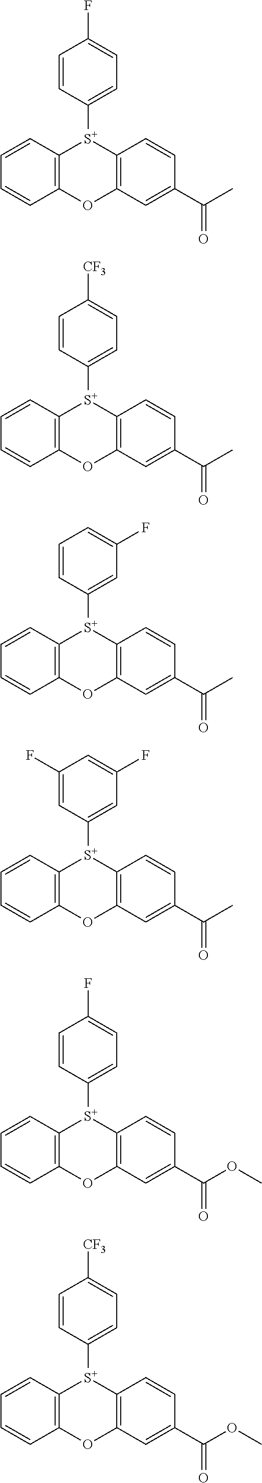 [SMILES: CC(=O)c1ccc2c(c1)Oc1ccccc1[S+]2c1ccc(F)cc1 ; CC(=O)c1ccc2c(c1)Oc1ccccc1[S+]2c1ccc(C(F)(F)F)cc1 ; CC(=O)c1ccc2c(c1)Oc1ccccc1[S+]2c1cccc(F)c1 ; CC(=O)c1ccc2c(c1)Oc1ccccc1[S+]2c1cc(F)cc(F)c1 ; COC(=O)c1ccc2c(c1)Oc1ccccc1[S+]2c1ccc(F)cc1 ; COC(=O)c1ccc2c(c1)Oc1ccccc1[S+]2c1ccc(C(F)(F)F)cc1]

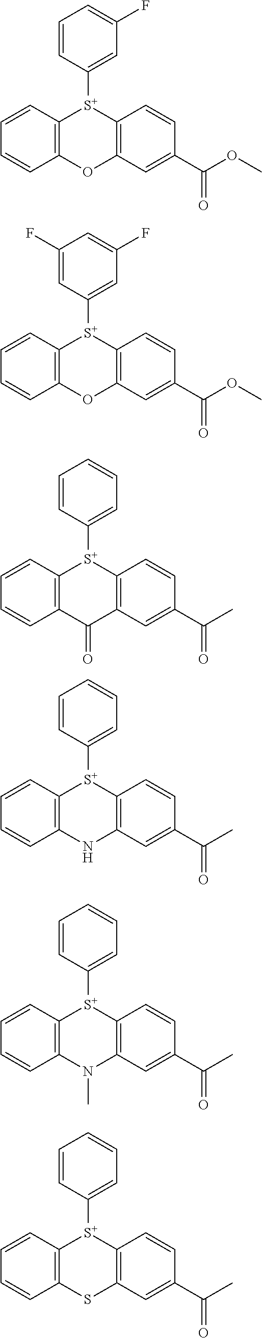 [SMILES: COC(=O)c1ccc2c(c1)Oc1ccccc1[S+]2c1cccc(F)c1 ; COC(=O)c1ccc2c(c1)Oc1ccccc1[S+]2c1cc(F)cc(F)c1 ; CC(=O)c1ccc2c(c1)c(=O)c1ccccc1[s+]2-c1ccccc1 ; CC(=O)c1ccc2c(c1)Nc1ccccc1[S+]2c1ccccc1 ; CC(=O)c1ccc2c(c1)N(C)c1ccccc1[S+]2c1ccccc1 ; CC(=O)c1ccc2c(c1)Sc1ccccc1[S+]2c1ccccc1]

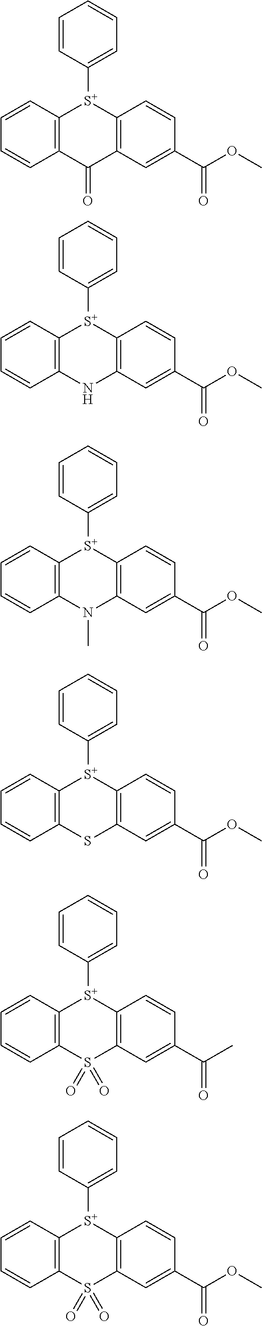 [SMILES: COC(=O)c1ccc2c(c1)c(=O)c1ccccc1[s+]2-c1ccccc1 ; COC(=O)c1ccc2c(c1)Nc1ccccc1[S+]2c1ccccc1 ; COC(=O)c1ccc2c(c1)N(C)c1ccccc1[S+]2c1ccccc1 ; COC(=O)c1ccc2c(c1)Sc1ccccc1[S+]2c1ccccc1 ; CC(=O)c1ccc2c(c1)S(=O)(=O)c1ccccc1[S+]2c1ccccc1 ; COC(=O)c1ccc2c(c1)S(=O)(=O)c1ccccc1[S+]2c1ccccc1]

Examples of the sulfonate anion having a carbon atom to which an iodine atom is bonded include those having the formula (2)-1.

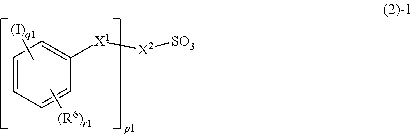

In the formula (2)-1, p1 is an integer of 1 to 3. q1 is an integer of 1 to 5, r1 is an integer of 0 to 4, and q1+r1 is from 1 to 5.

In formula (2)-1, R⁶ is a hydroxy group, a carboxy group, a halogen atom other than an iodine atom, or an amino group; or a C₁-C₂₀ hydrocarbyl group, a C₁-C₂₀ hydrocarbyloxy group, a C₂-C₂₀ hydrocarbylcarbonyl group, a C₂-C₁₀ hydrocarbyloxycarbonyl group, a C₂-C₂₀ hydrocarbylcarbonyloxy group, or a C₁-C₂₀ hydrocarbylsulfonyloxy group, which may contain a halogen atom, a hydroxy group, an amino group, or an ether bond; or —N(R^{6A})(R^{6B}), —N(R^{6C})—C(═O)—R^{6C}, or —N(R^{6C})—C(═O)—O—R^{6C}. R^{6A} and R^{6B} are each independently a hydrogen atom or a C₁-C₆ saturated hydrocarbyl group. R^{6C} is a hydrogen atom or a C₁-C₆ saturated hydrocarbyl group which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. R^{6D} is a C₁-C₁₆ aliphatic hydrocarbyl group, a C₆-C₁₂ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. The aliphatic hydrocarbyl group may be saturated or unsaturated, and may be linear, branched, or cyclic. The hydrocarbyl group and the hydrocarbyl moiety of the hydrocarbyloxy group, the hydrocarbyloxycarbonyl group, the hydrocarbylcarbonyl group, and the hydrocarbylcarbonyloxy group may be saturated or unsaturated, and may be linear, branched, or cyclic. Examples thereof include those same as those exemplified as the hydrocarbyl group of R²¹ to R²⁸ in the description of the formulas (f1) to (f3) described later. When p1 and/or r1 is 2 or more, groups R⁶ may be the same or different from each other.

In the formula (2)-1, X¹ is a single bond, an ether bond, an amide bond, a urethane bond, an ester bond, or a C₁-C₆ saturated hydrocarbylene group which may contain an ether bond or an ester bond. The saturated hydrocarbylene group may be linear, branched, or cyclic.

In the formula (2)-1, X² is a single bond or a C₁-C₂₂ divalent linking group when p1 is 1, and is a C₁-C₂₂ (p1+1)-valent linking group when p1 is 2 or 3, and the linking group may contain an oxygen atom, a sulfur atom, a nitrogen atom, or a halogen atom.

Further, examples of the sulfonate anion having a carbon atom to which an iodine atom is bonded include those having the formula (2)-2.

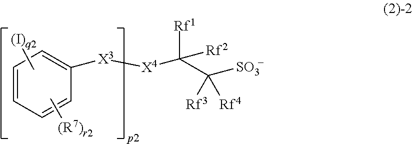

In the formula (2)-2, p2 is an integer of 1 to 3. q2 is an integer of 1 to 5, r2 is an integer of 0 to 4, and q2+r2 is from 1 to 5.

In formula (2)-2, R⁷ is a hydroxy group, a carboxy group, a halogen atom other than an iodine atom, or an amino group; or a C₁-C₂₀ hydrocarbyl group, a C₁-C₂₀ hydrocarbyloxy group, a C₂-C₂₀ hydrocarbylcarbonyl group, a C₂-C₁₀ hydrocarbyloxycarbonyl group, a C₂-C₂₀ hydrocarbylcarbonyloxy group, or a C₁-C₂₀ hydrocarbylsulfonyloxy group, which may contain a halogen atom, a hydroxy group, an amino group, or an ether bond; or —N(R^{7A})(R^{7B}), —N(R^{7C})—C(═O)—R^{7D}, or —N(R^{7C})—C(═O)—O—R^{7D}. R^{7A} and R^{7B} are each independently a hydrogen atom or a C₁-C₆ saturated hydrocarbyl group. R^{7C} is a hydrogen atom or a C₁-C₆ saturated hydrocarbyl group which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. R^{7D} is a C₁-C₁₆ aliphatic hydrocarbyl group, a C₆-C₁₂ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. The aliphatic hydrocarbyl group may be saturated or unsaturated, and may be linear, branched, or cyclic. The hydrocarbyl group and the hydrocarbyl moiety of the hydrocarbyloxy group, the hydrocarbyloxycarbonyl group, the hydrocarbylcarbonyl group, and the hydrocarbylcarbonyloxy group may be saturated or unsaturated, and may be linear, branched, or cyclic. Examples thereof include those same as those exemplified as the hydrocarbyl group of R²¹ to R²⁸ in the description of the formulas (f1) to (f3) described later. When p2 and/or r2 is 2 or more, groups R⁷ may be the same or different from each other.

In the formula (2)-2, X³ is a single bond, an ether bond, an amide bond, a urethane bond, an ester bond, or a C₁-C₆ saturated hydrocarbylene group which may contain an ether bond or an ester bond. The saturated hydrocarbylene group may be linear, branched, or cyclic.

In the formula (2)-2, X⁴ is a single bond or a C₁-C₂₀ divalent linking group when p2 is 1, and is a C₁-C₂₀ (p2+1)-valent linking group when p2 is 2 or 3, and the linking group may contain an oxygen atom, a sulfur atom, or a nitrogen atom.

In formula (2)-2, Rf¹ to Rf⁴ are each independently a hydrogen atom, a fluorine atom, or a trifluoromethyl group, and at least one of Rf¹ to Rf⁴ is a fluorine atom or a trifluoromethyl group. Rf¹ and Rf², taken together, may form a carbonyl group.

Examples of the anion having the formula (2)-1 are shown below, but not limited thereto.

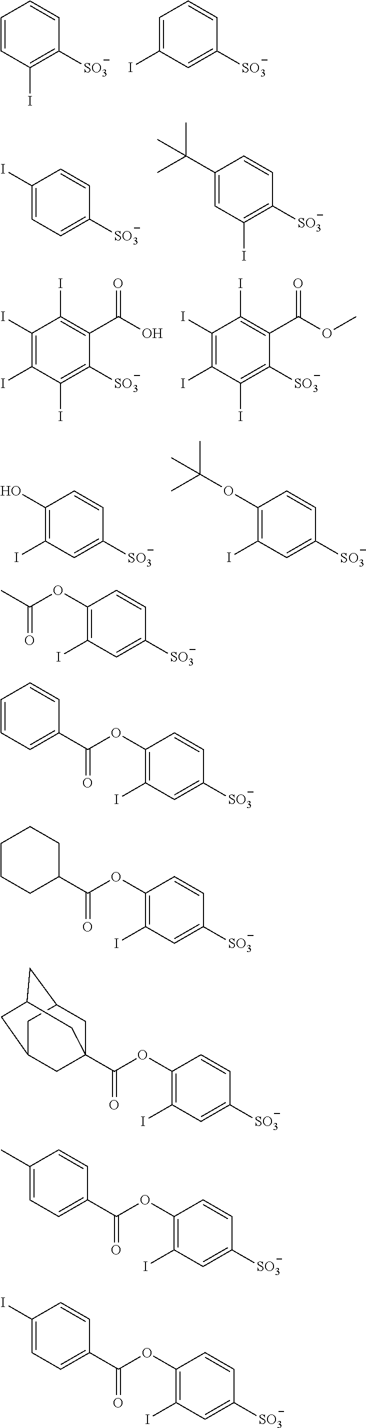

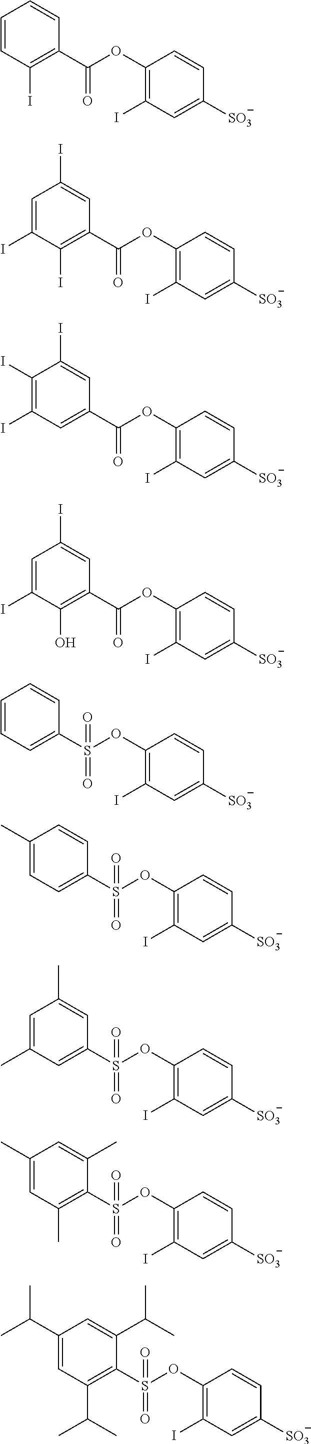

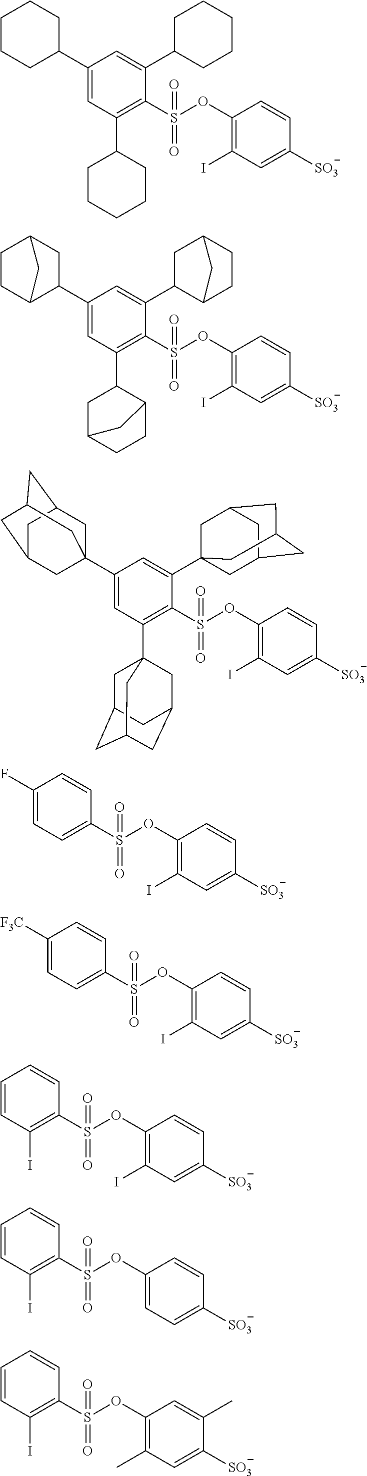

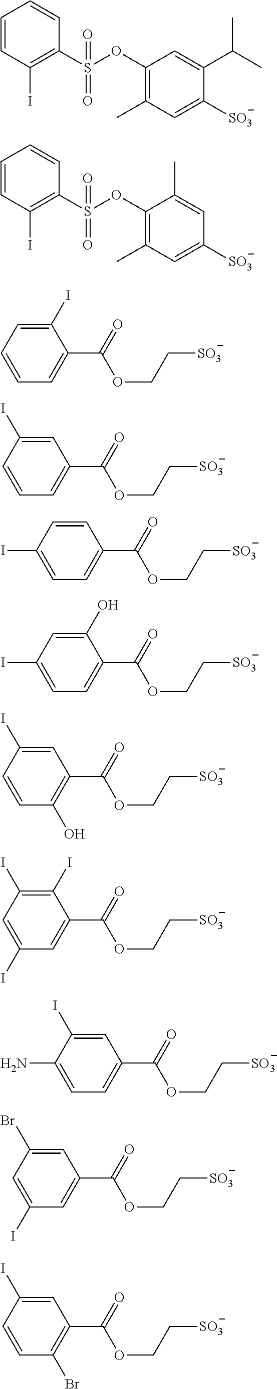

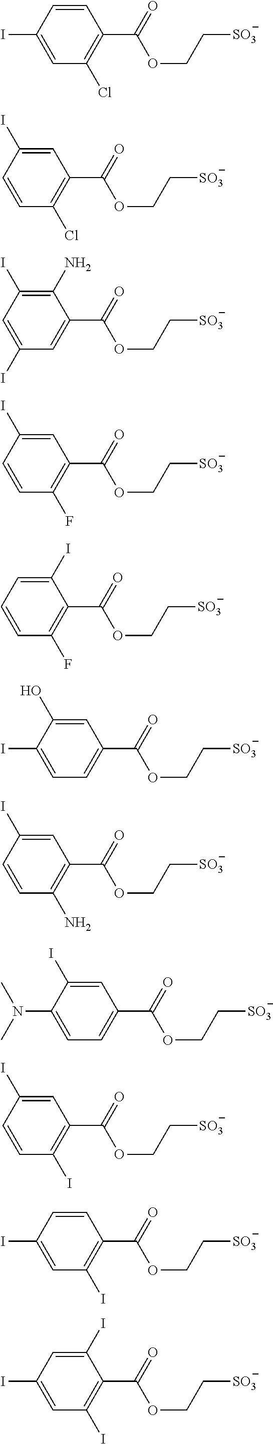

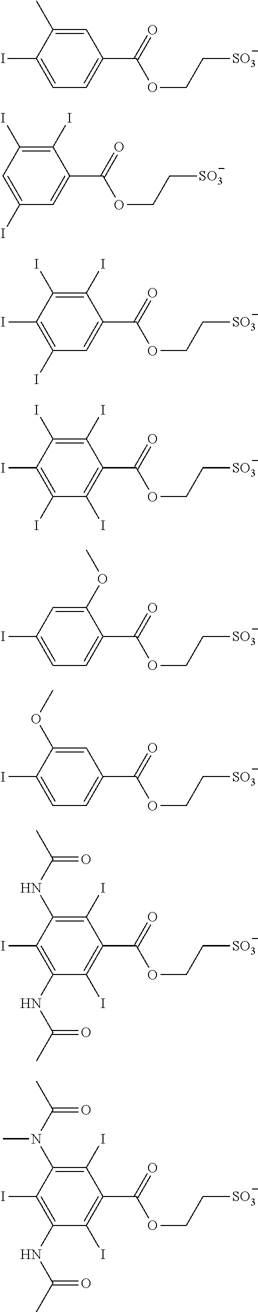

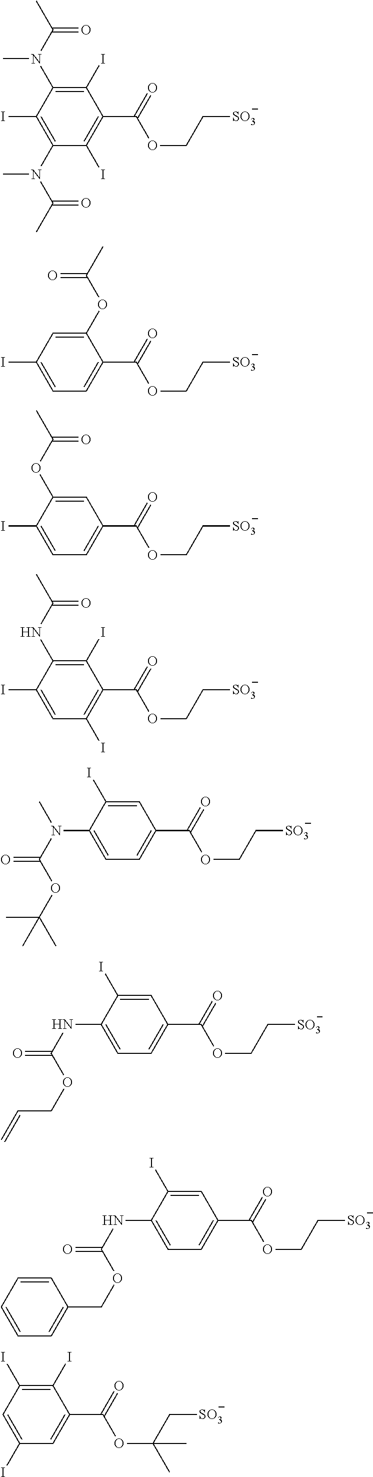

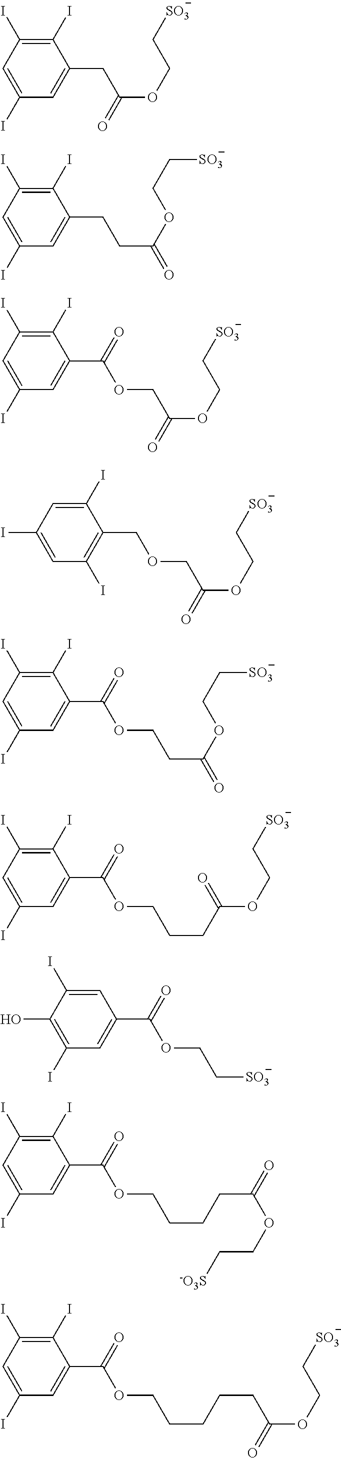

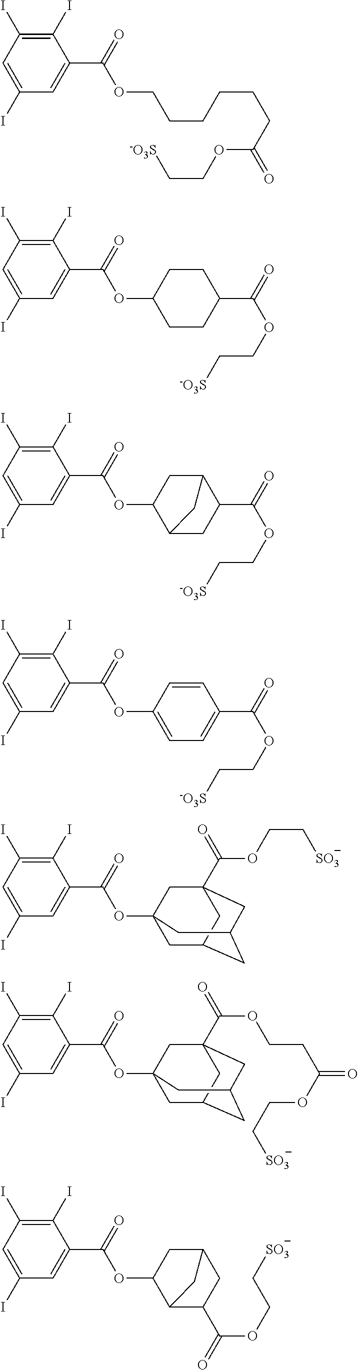

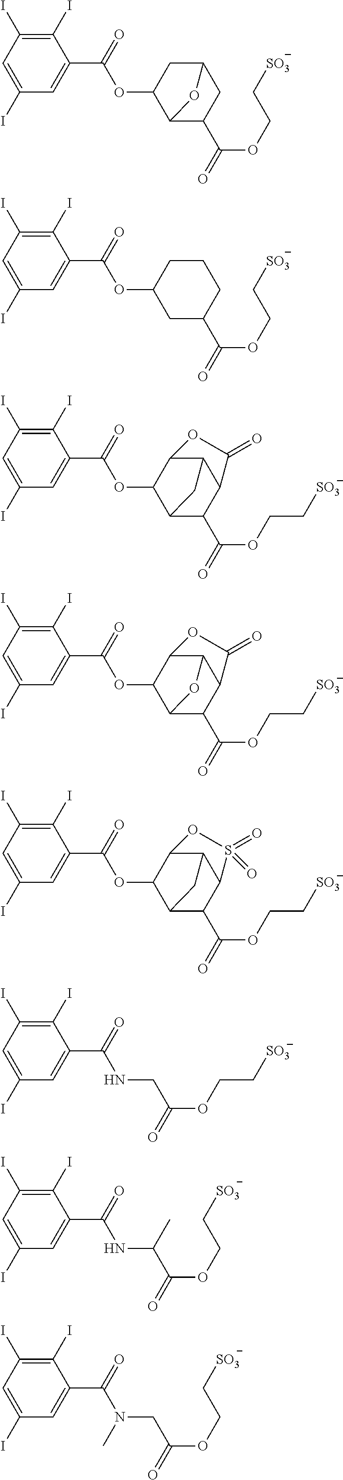

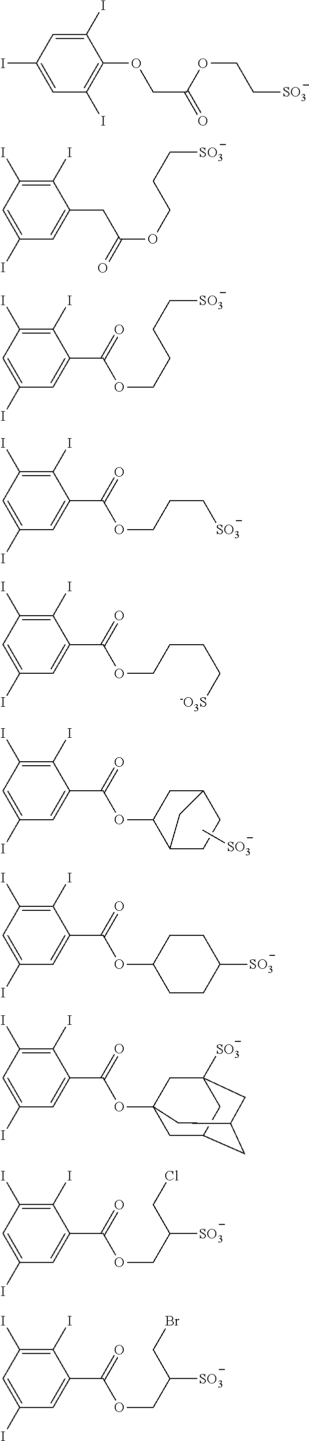

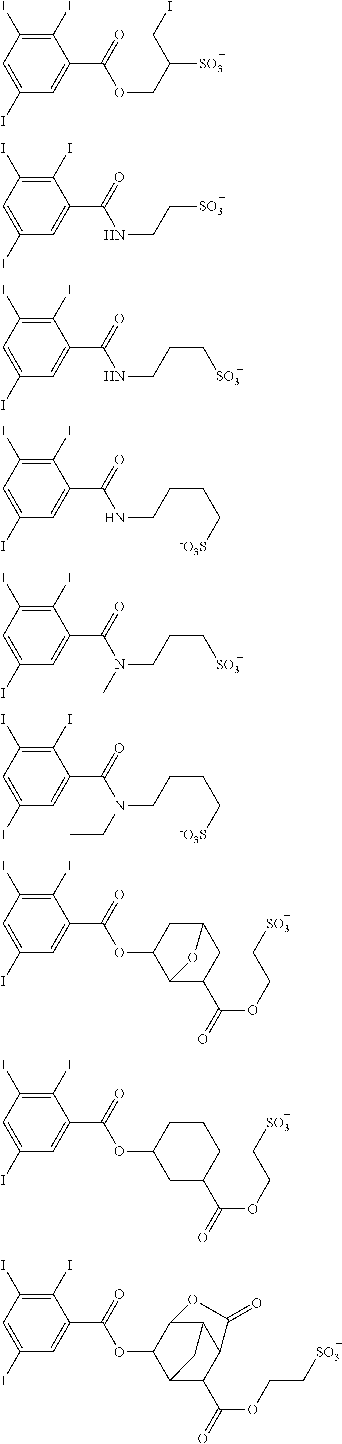

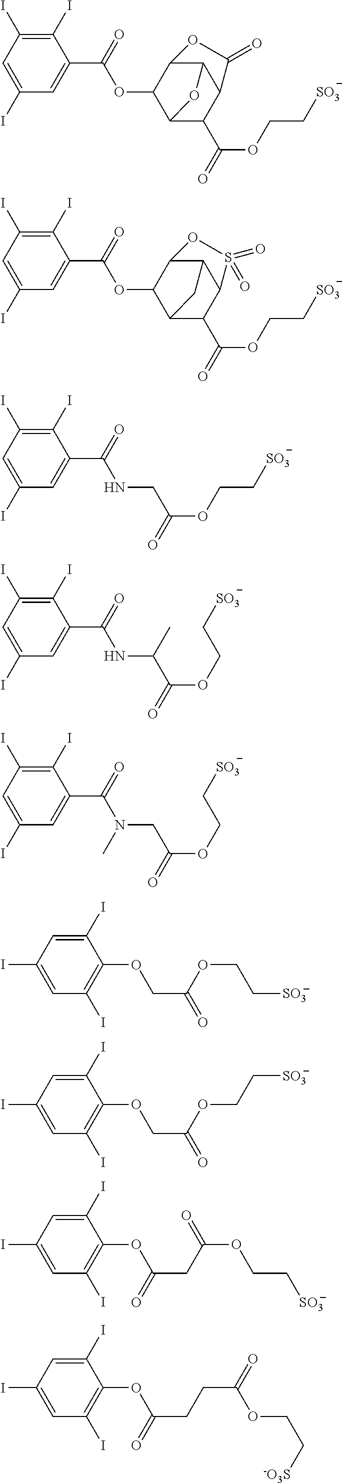

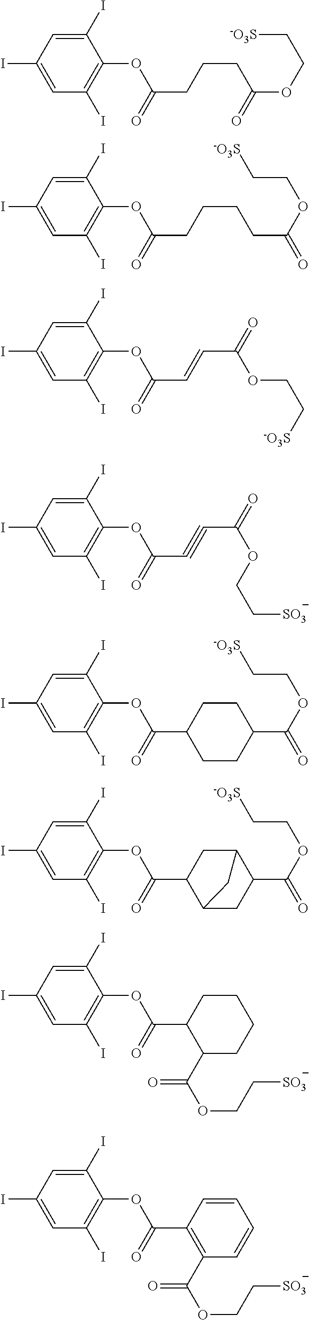

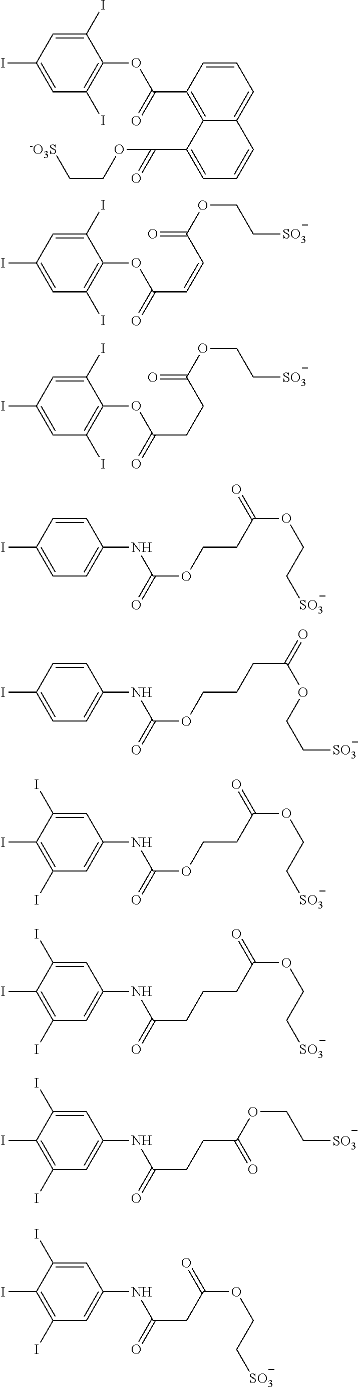

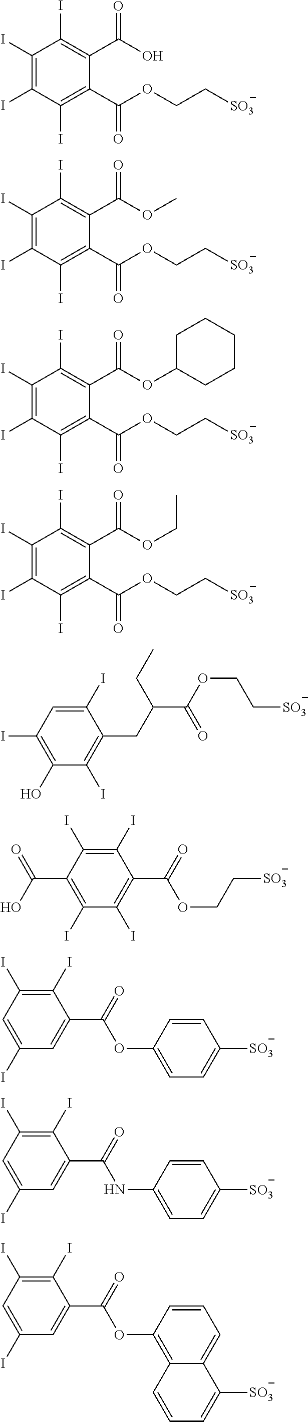

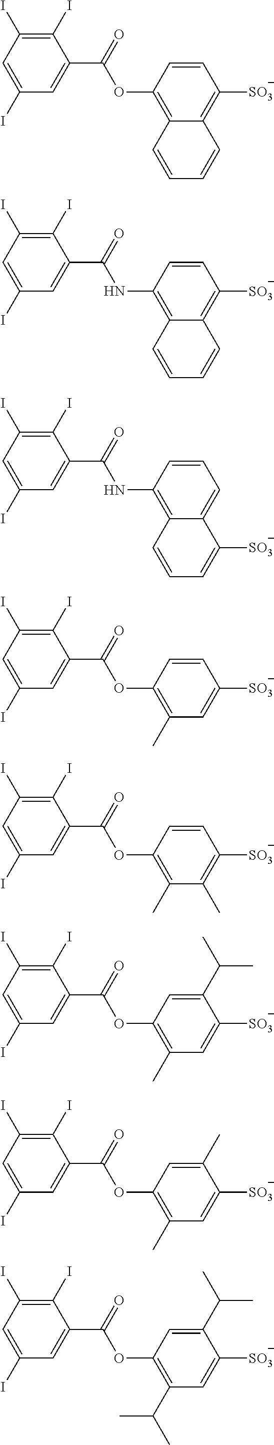

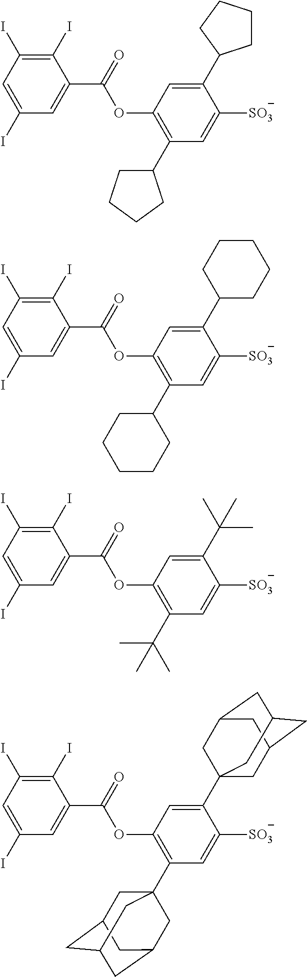

Examples of the anion having the formula (2)-2 are shown below, but not limited thereto.

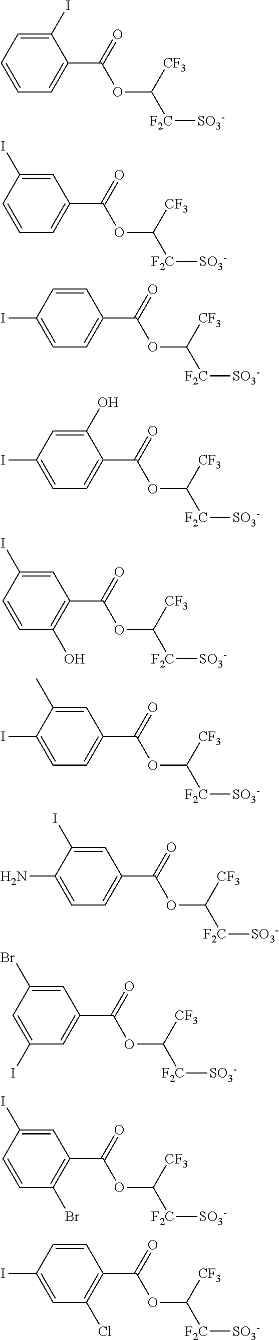

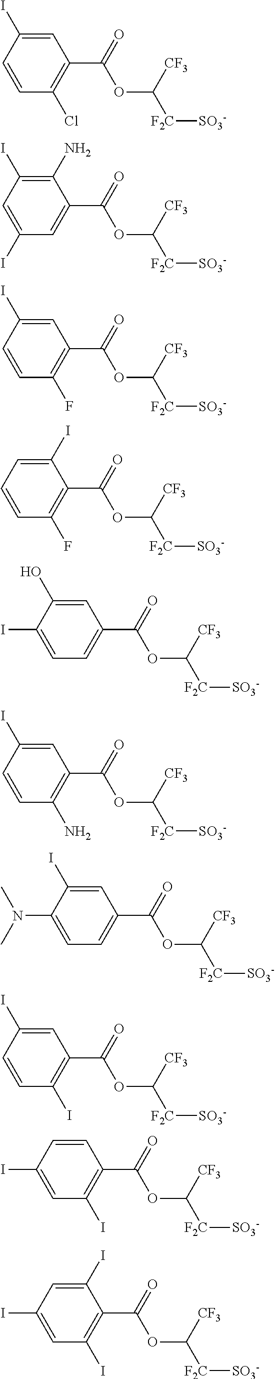

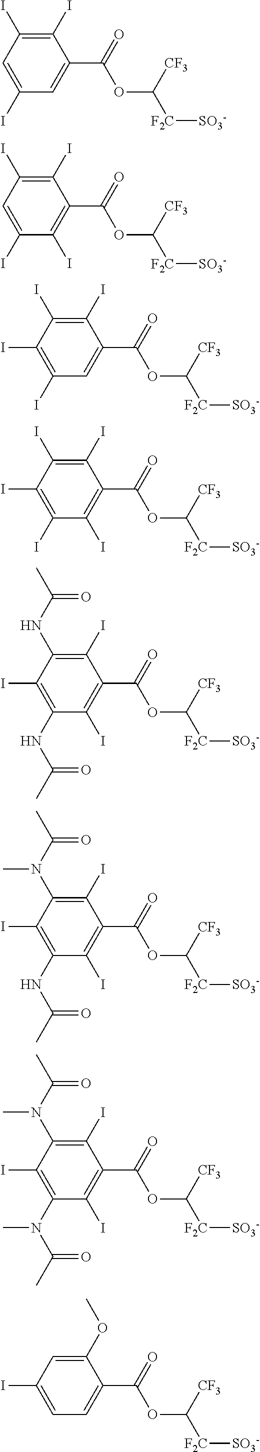

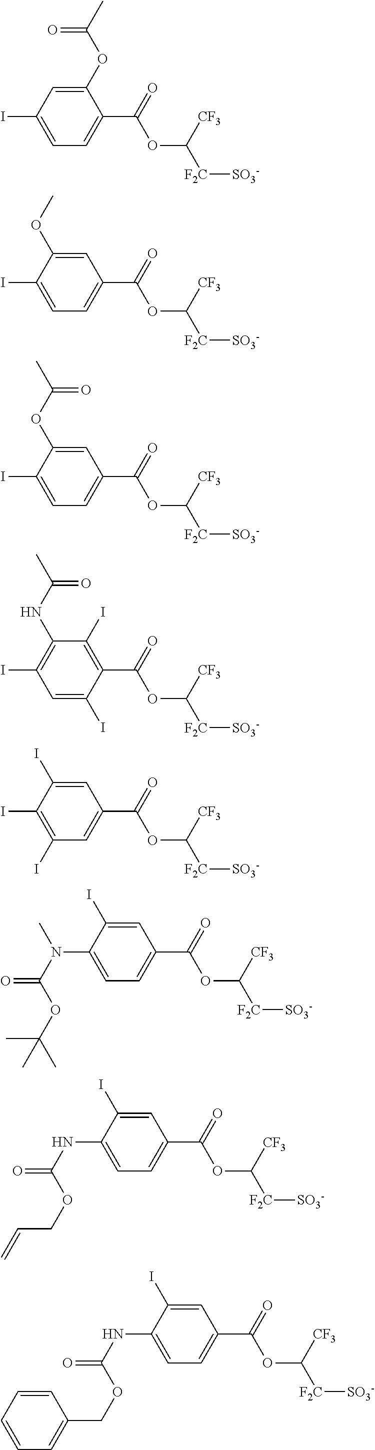

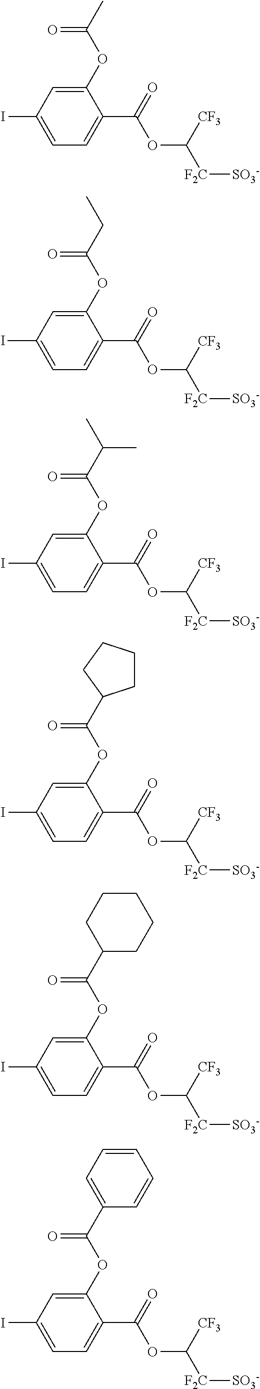

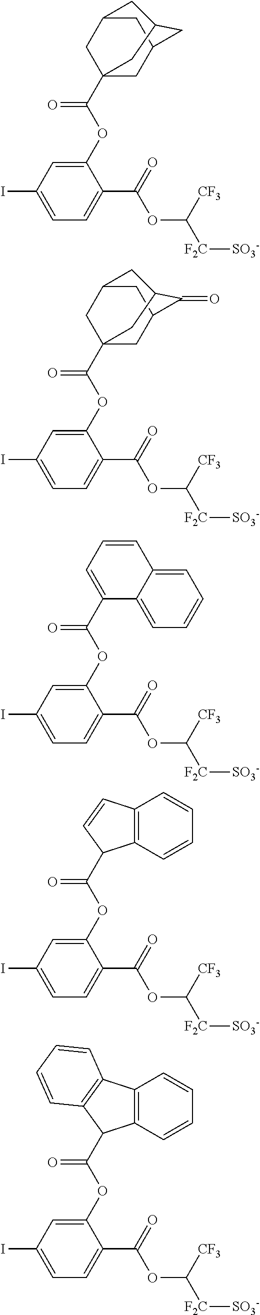

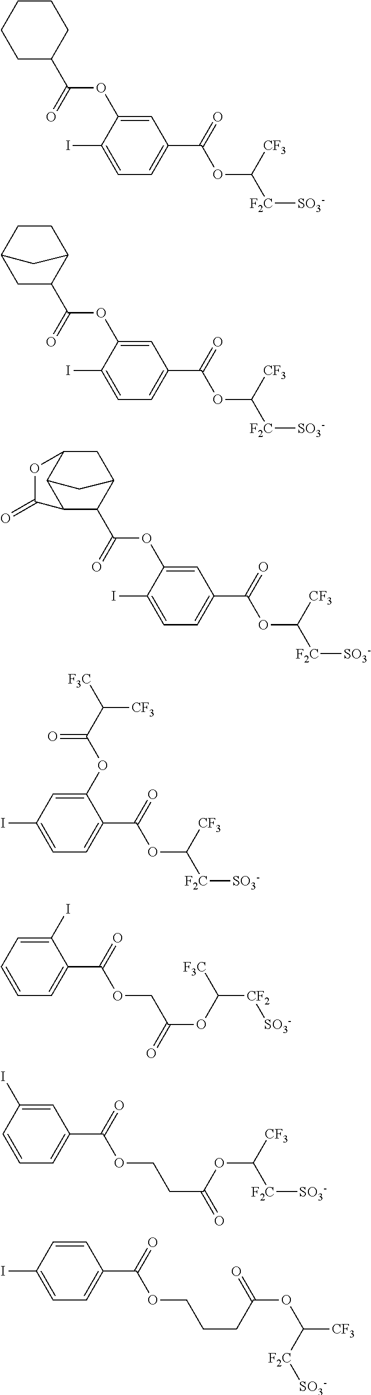

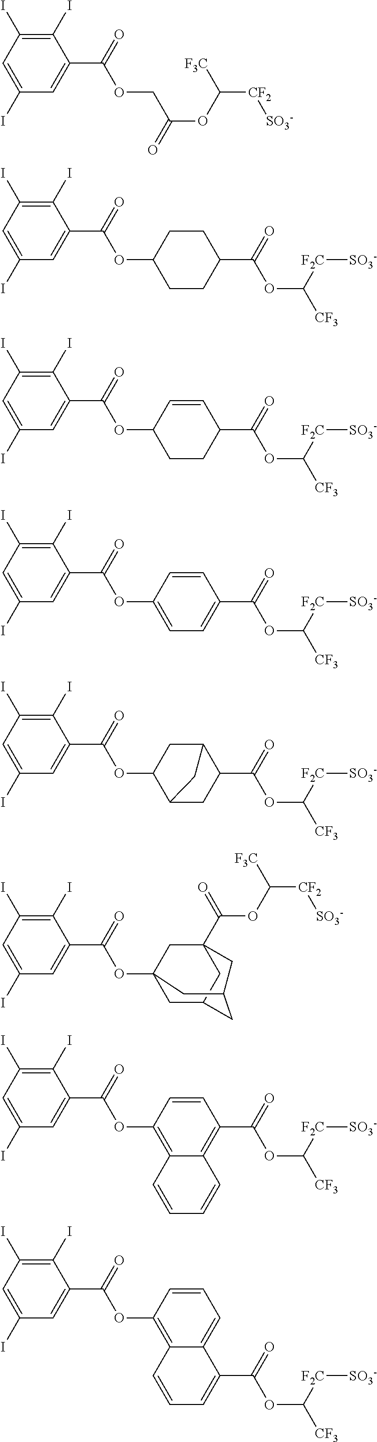

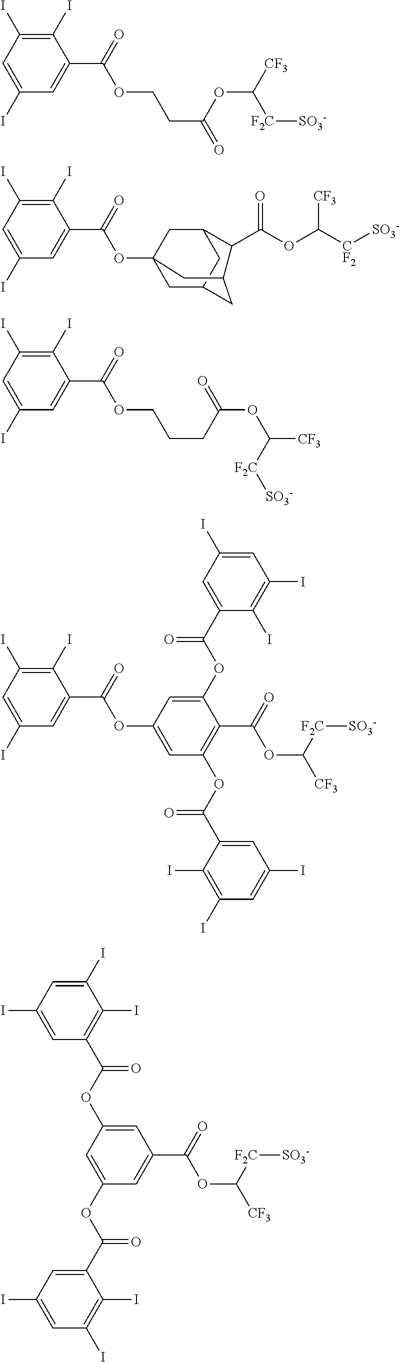

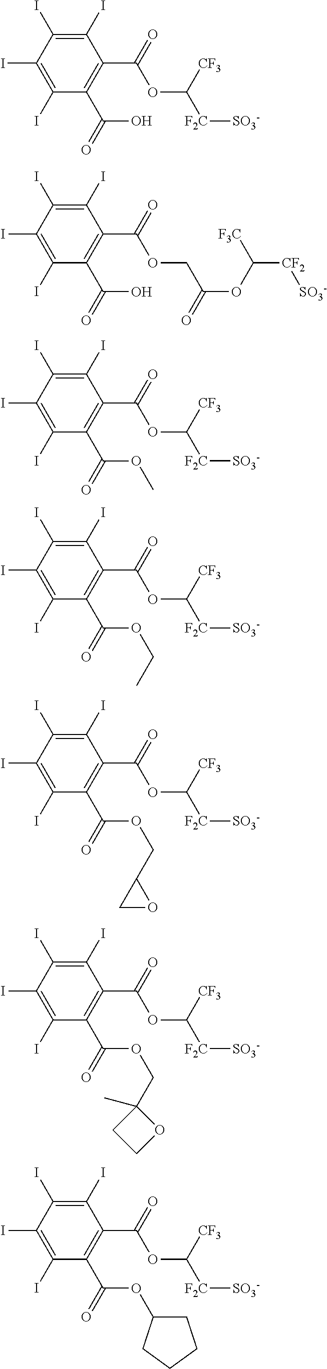

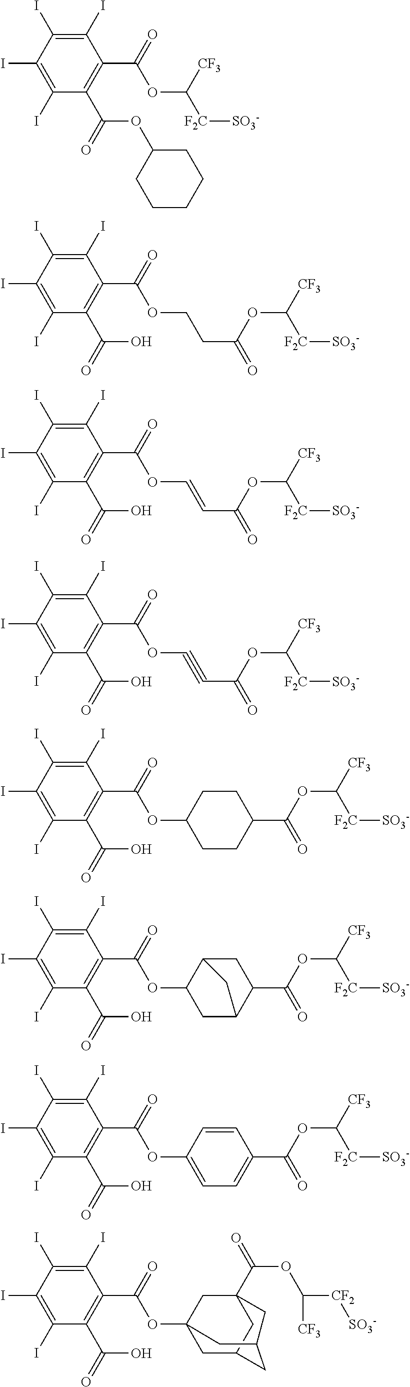

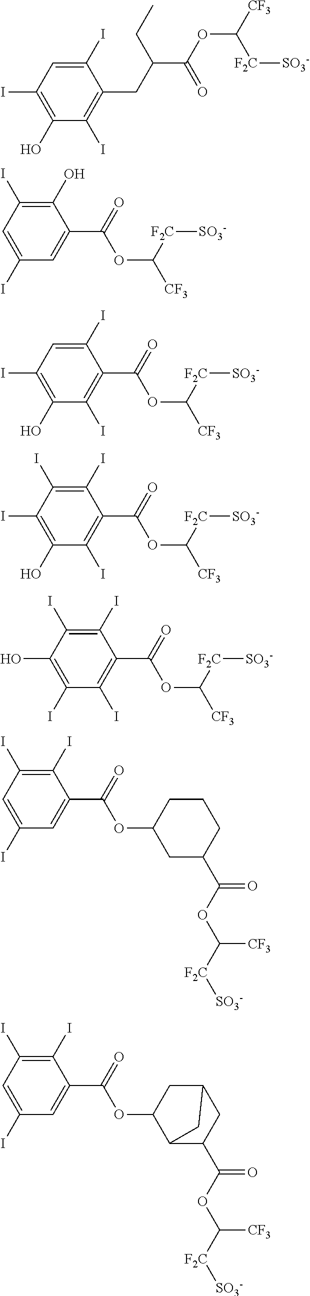

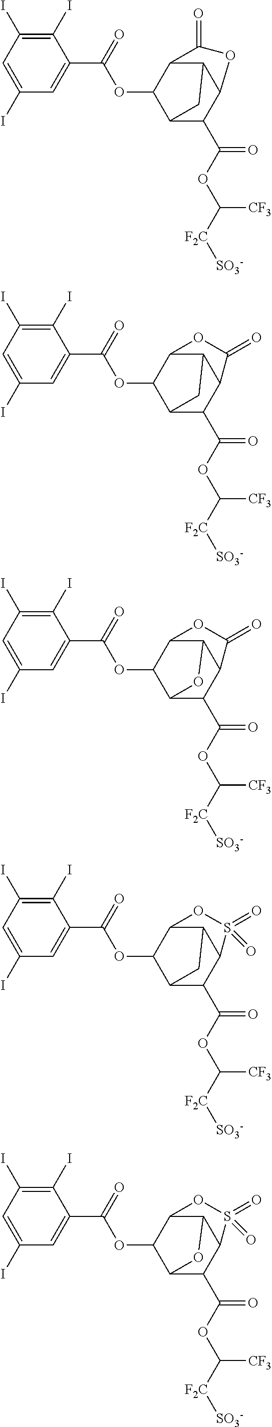

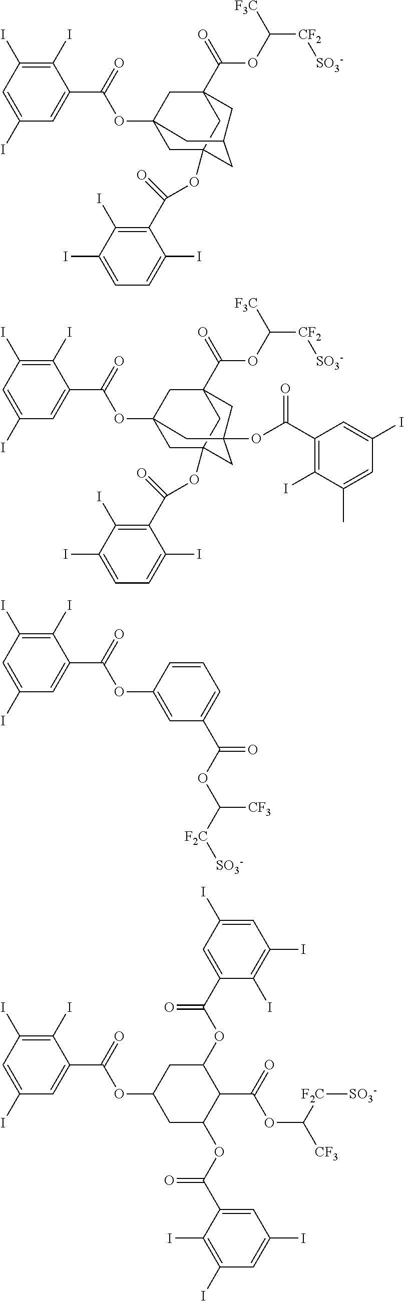

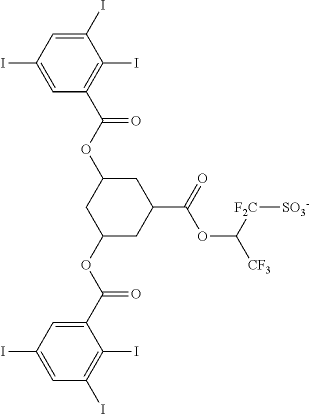

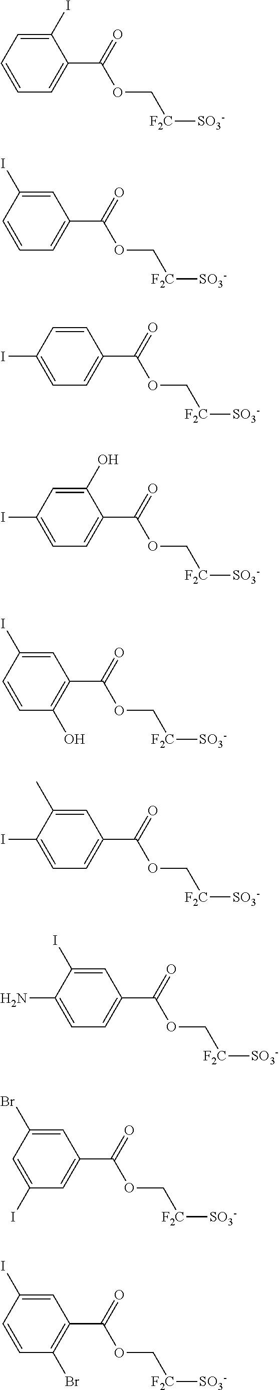

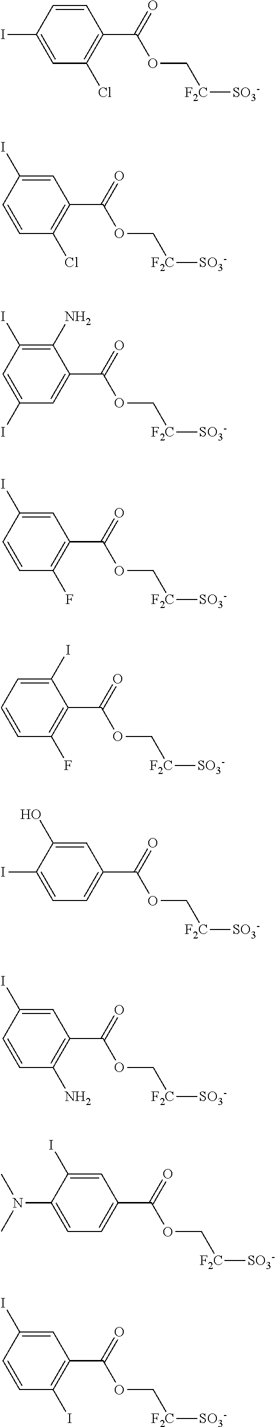

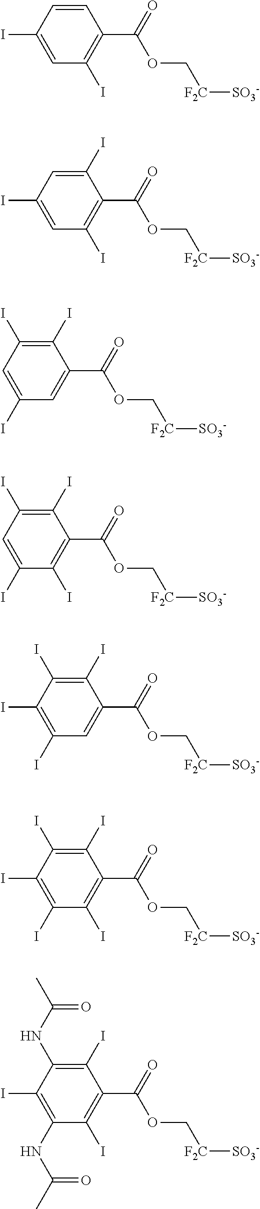

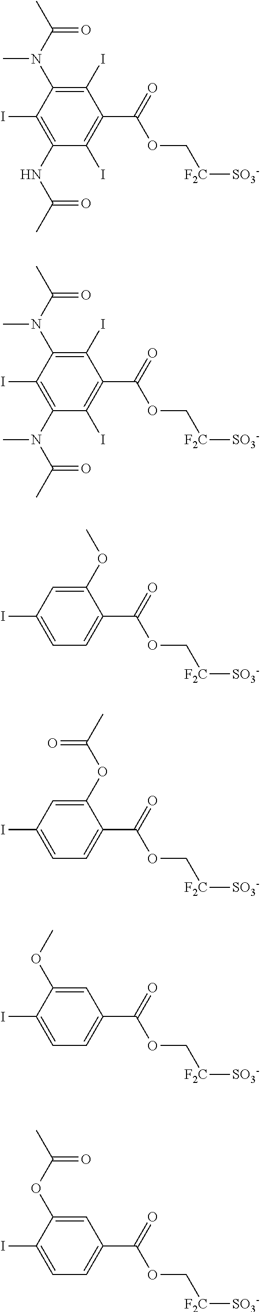

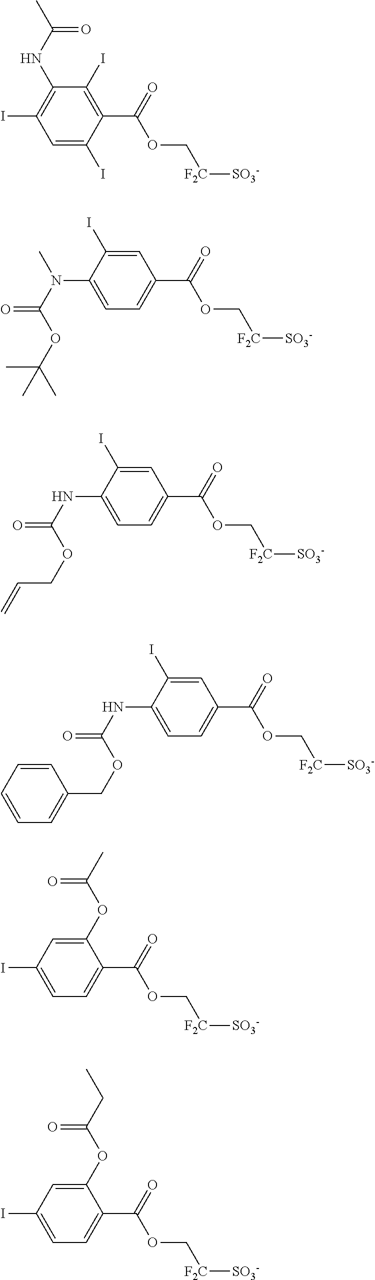

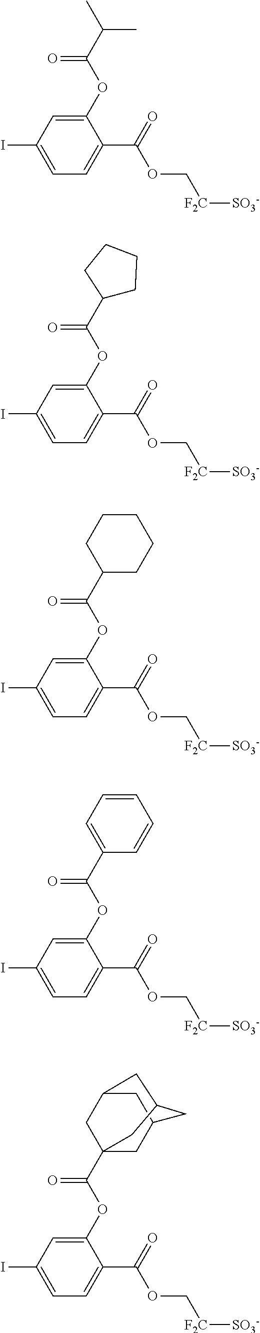

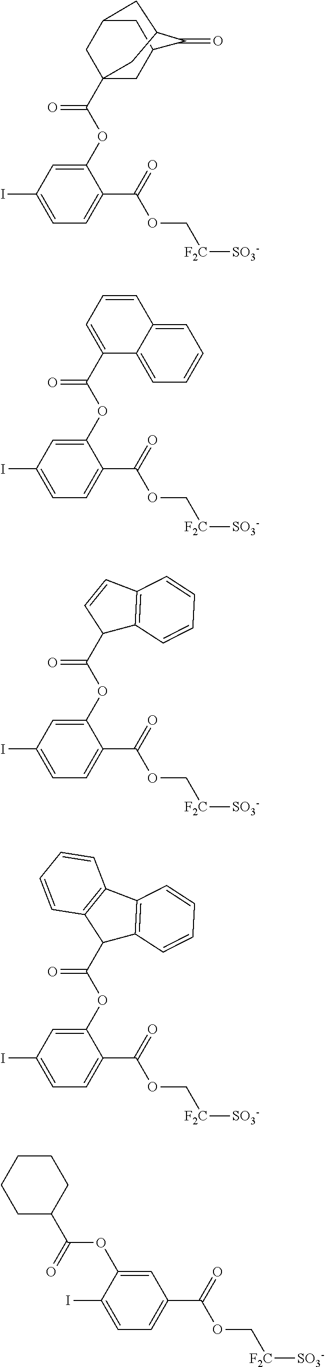

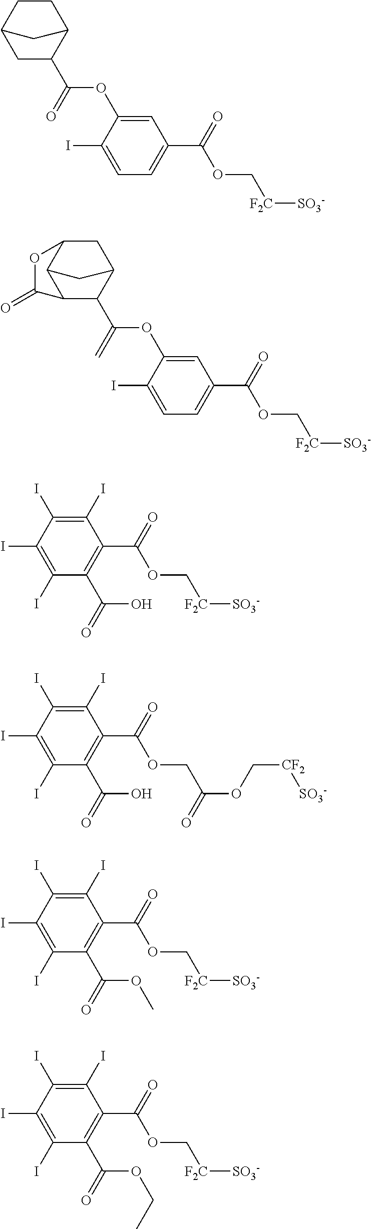

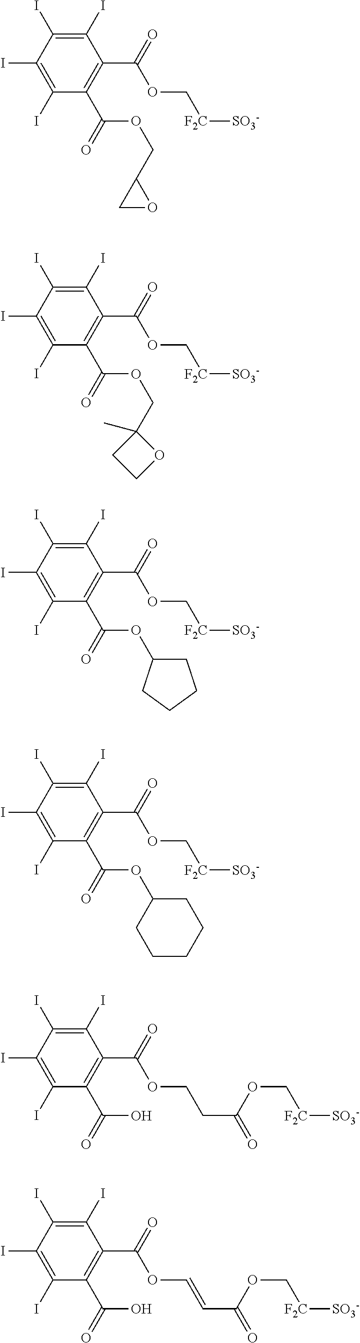

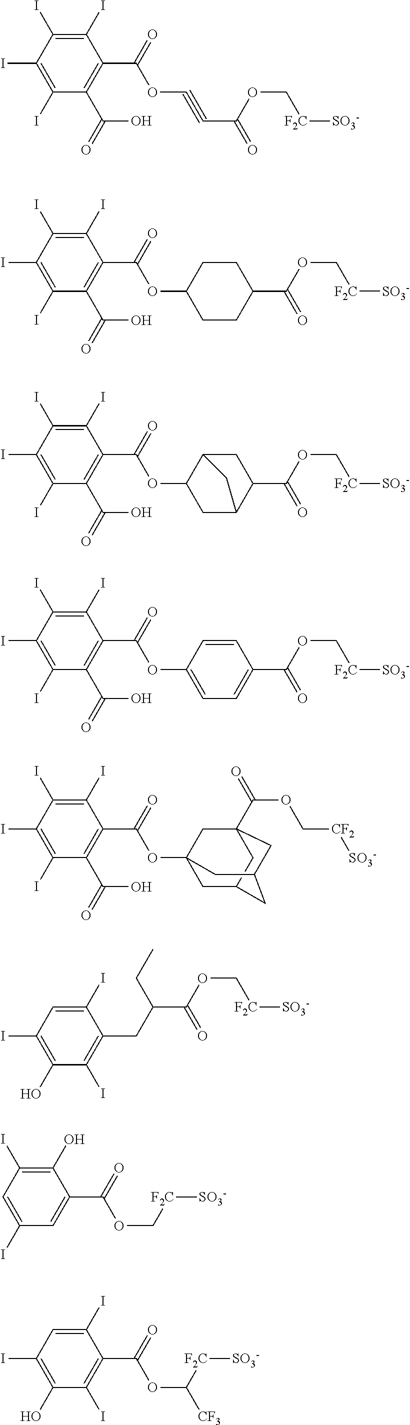

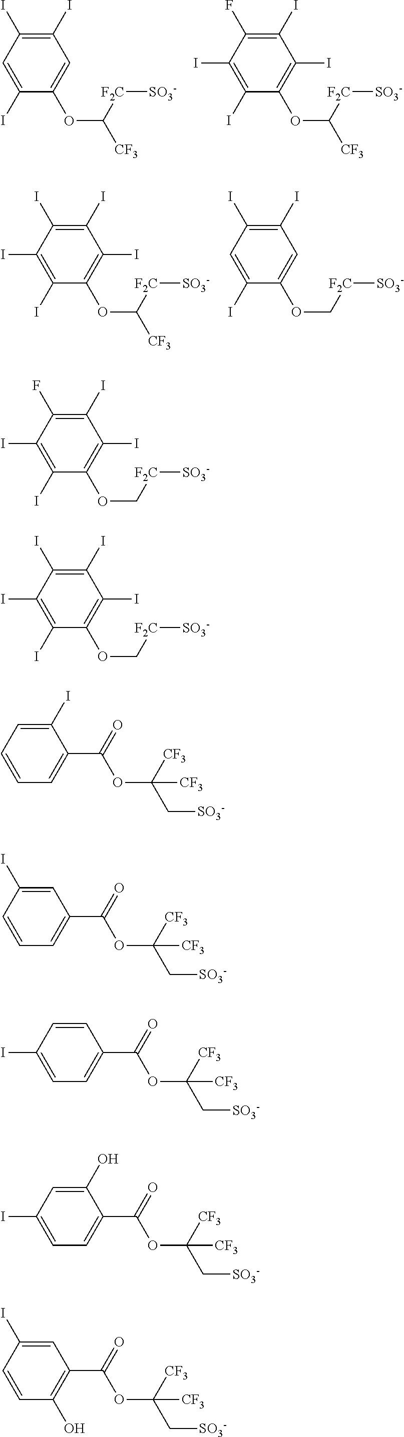

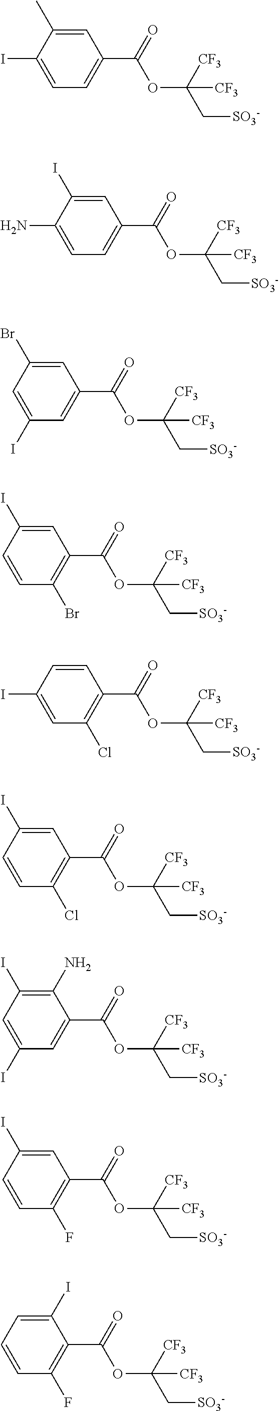

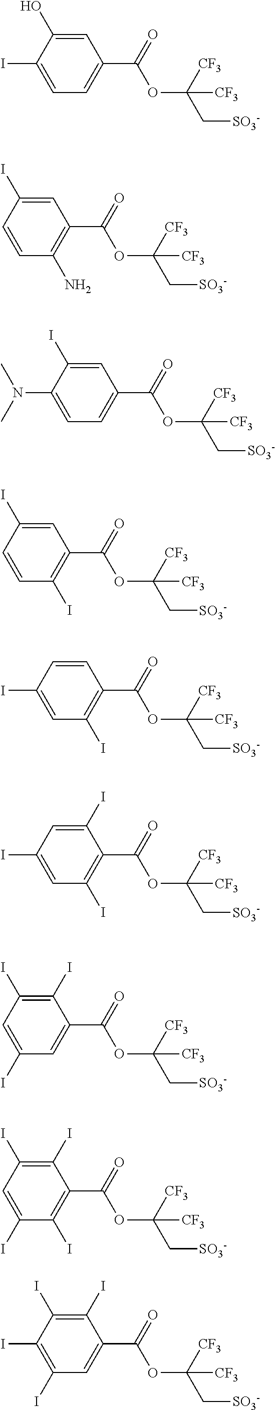

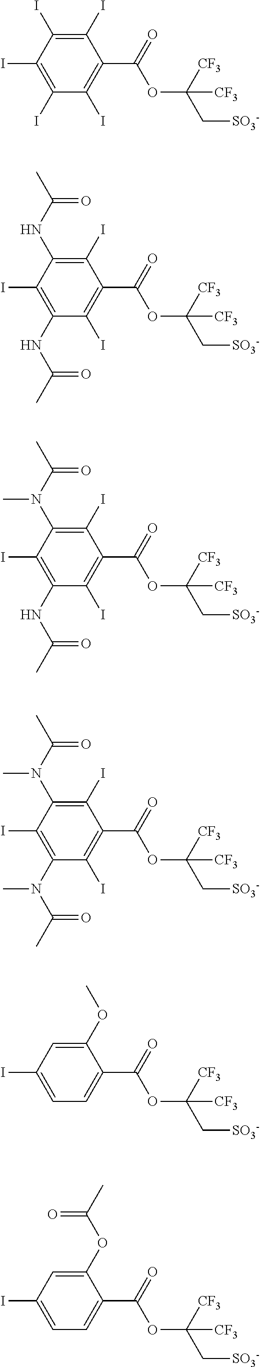

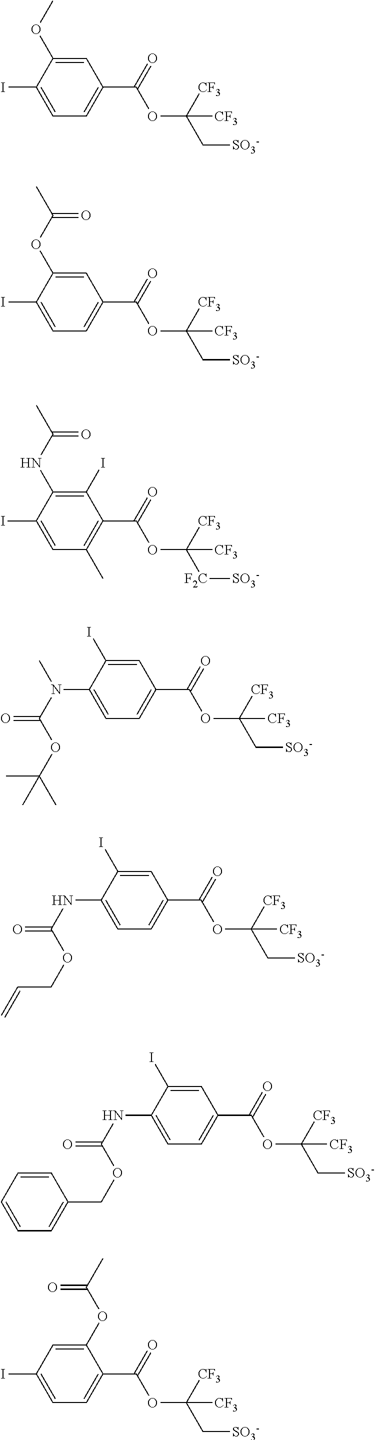

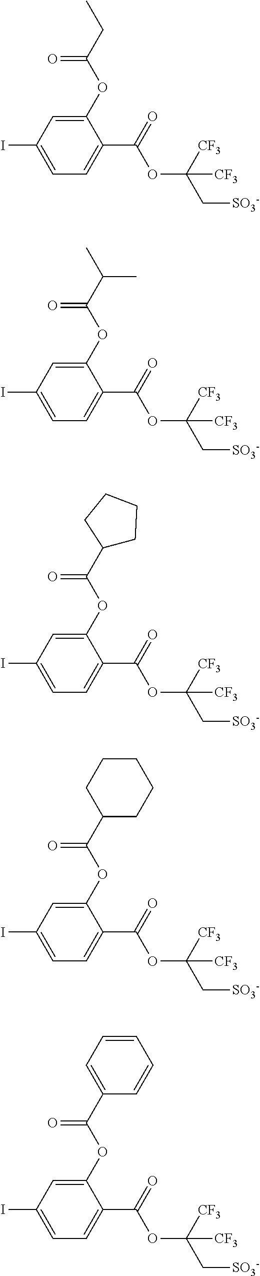

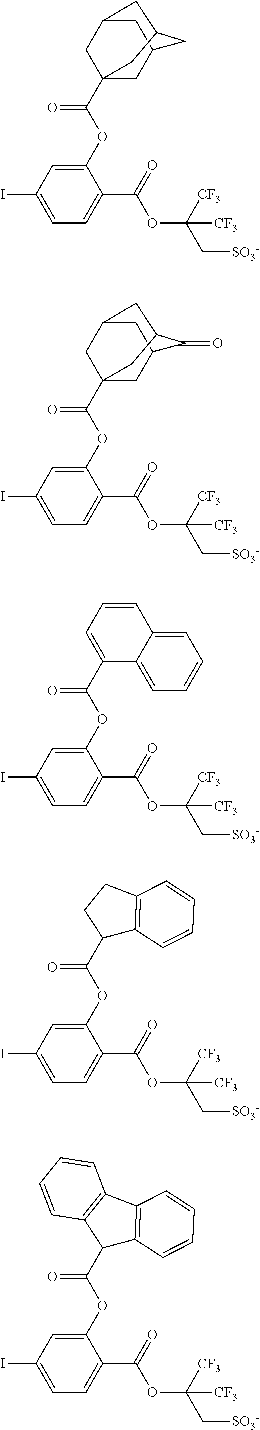

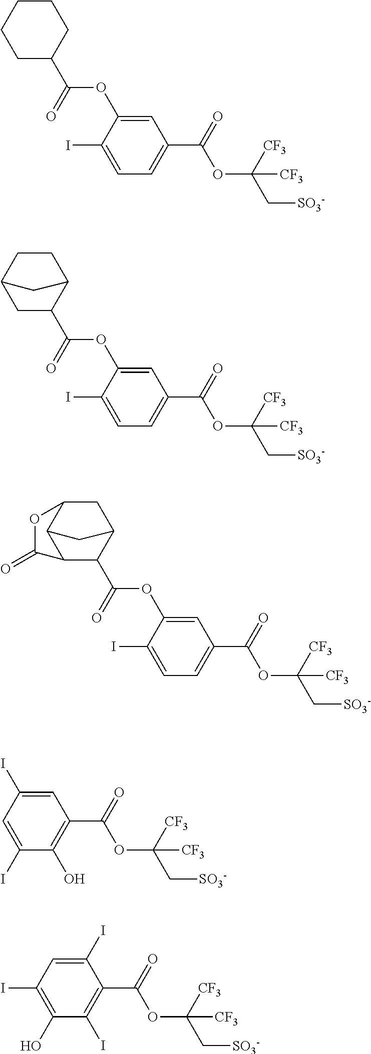

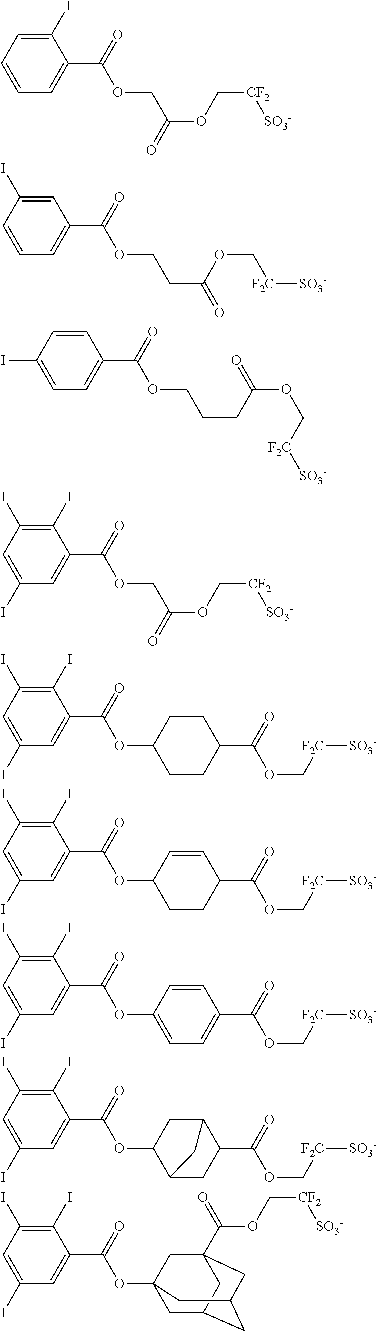

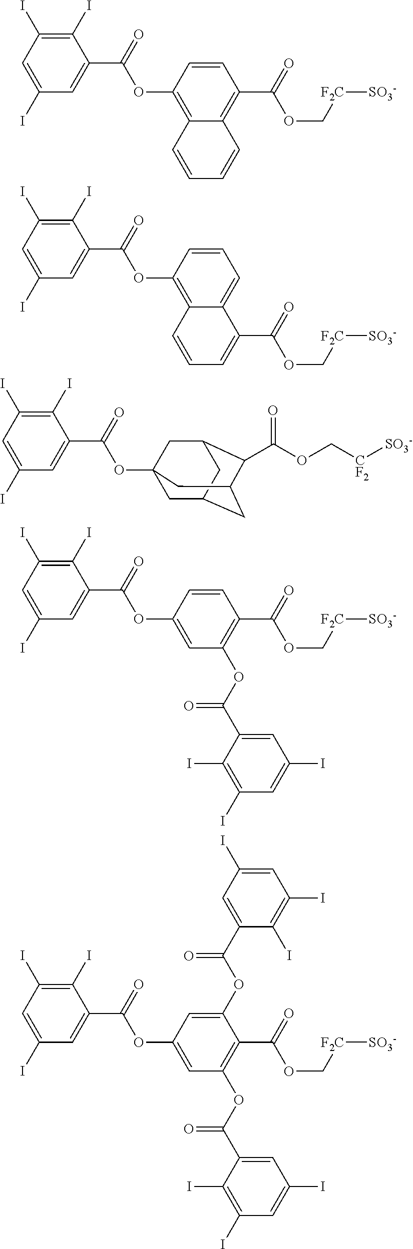

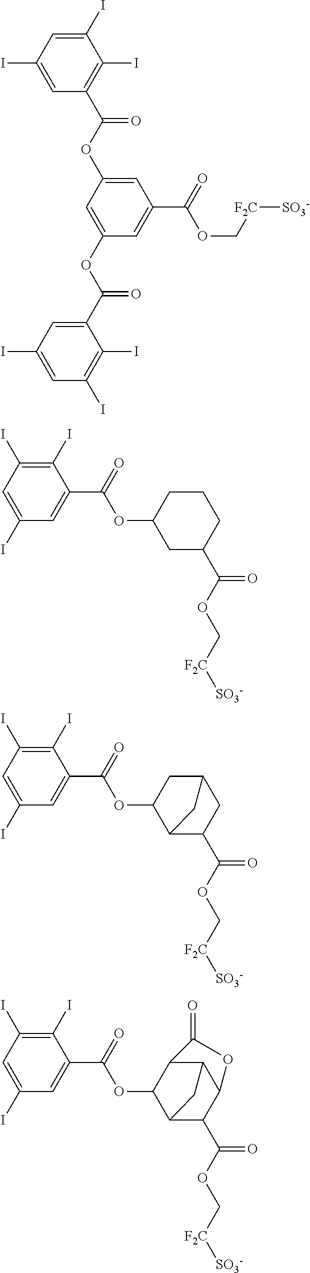

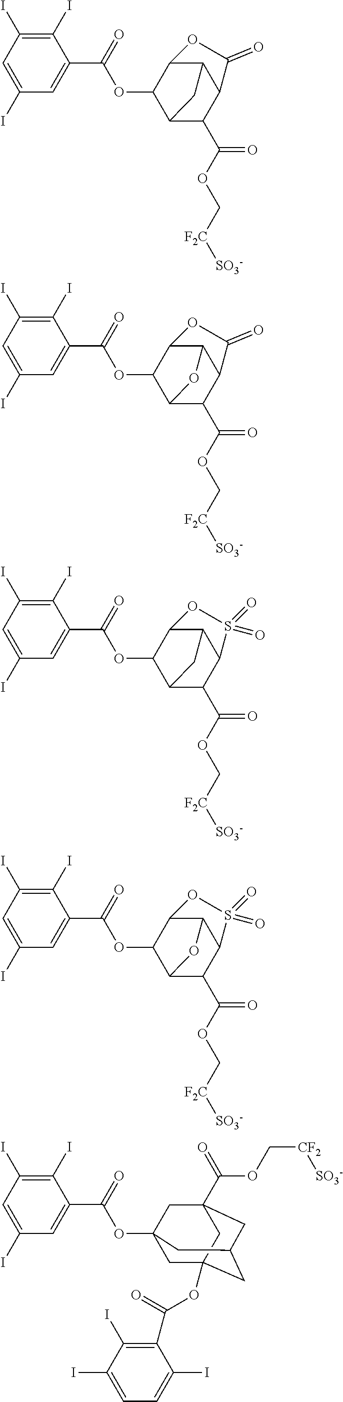

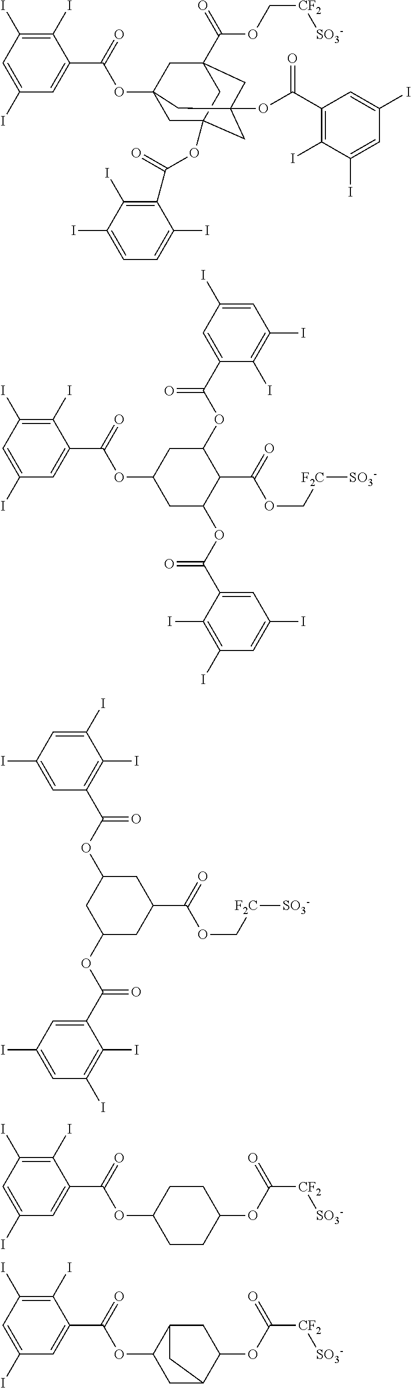

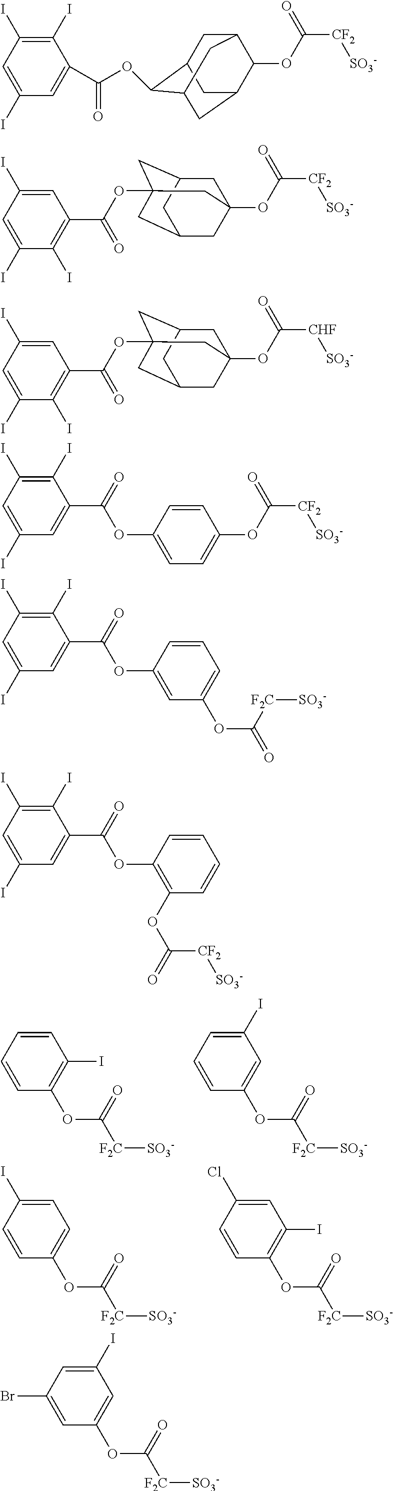

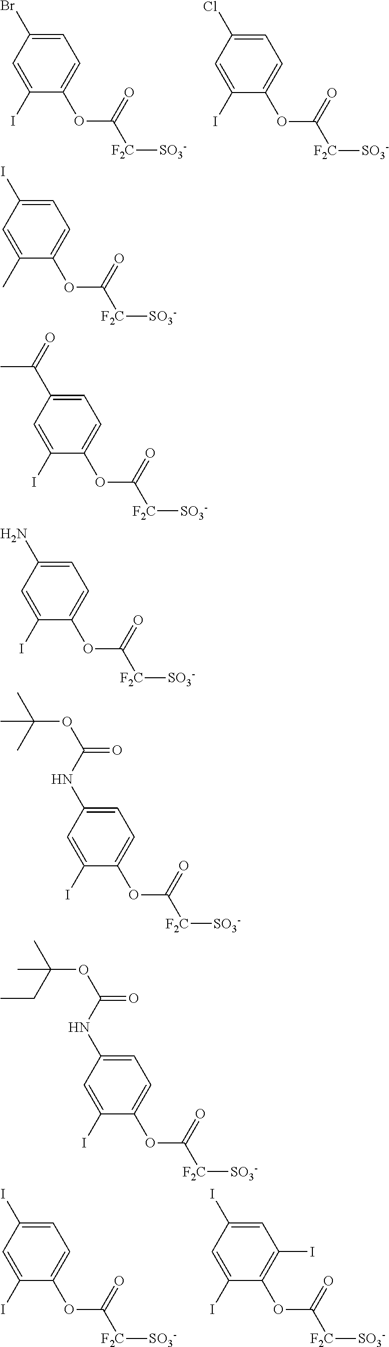

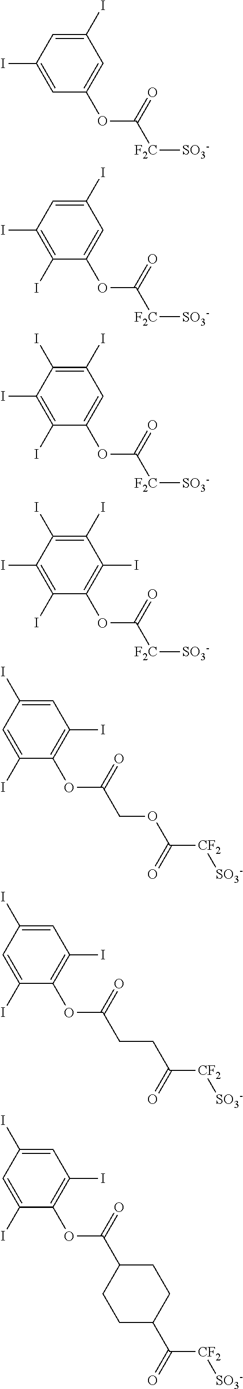

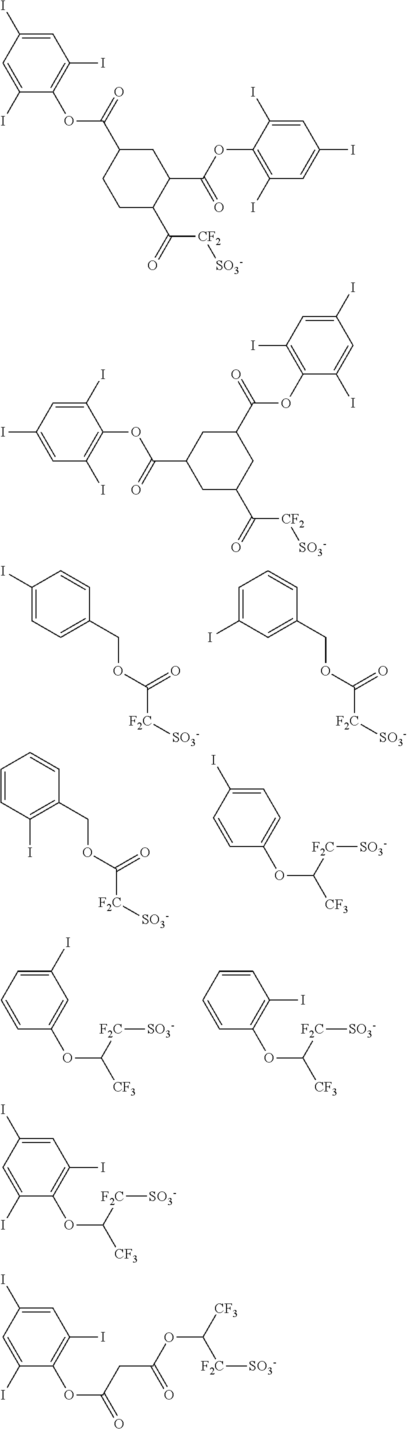

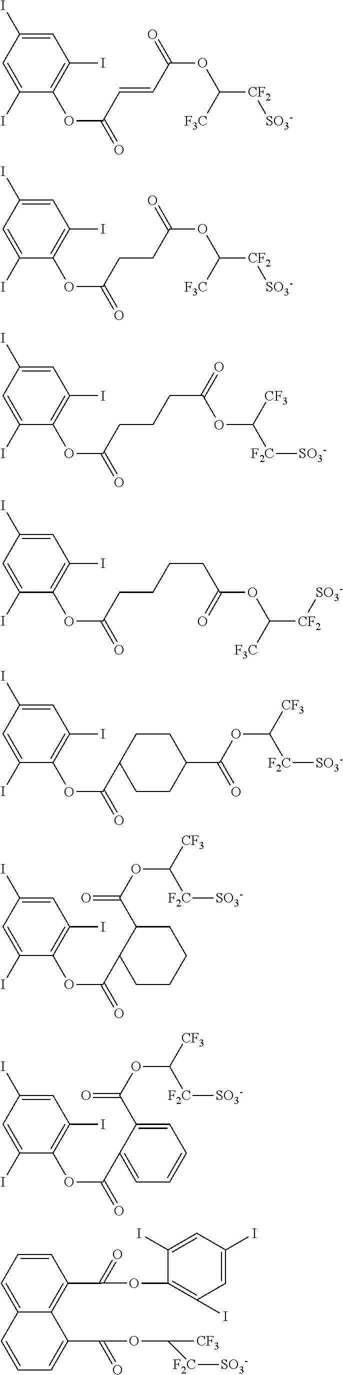

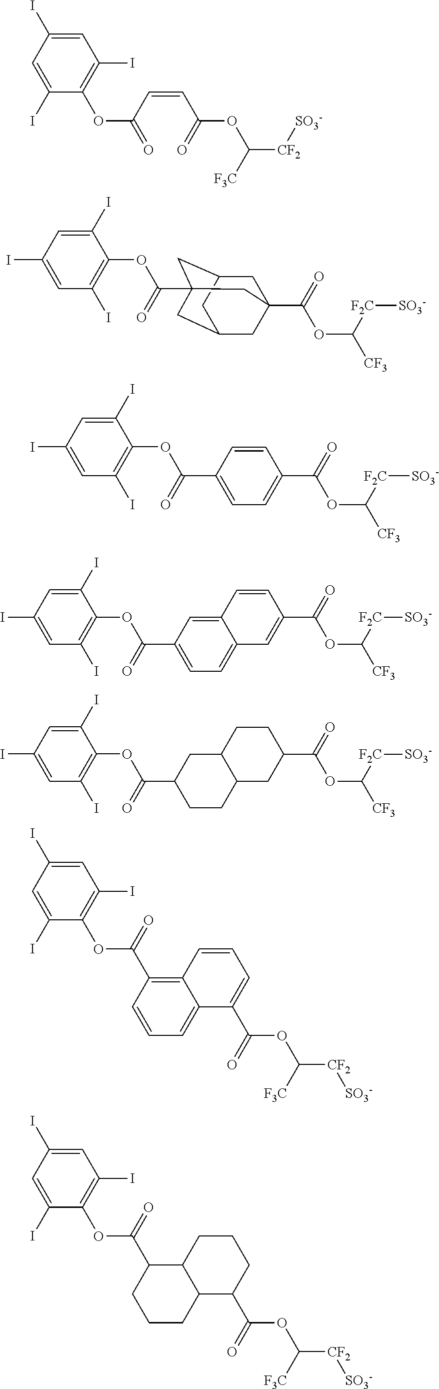

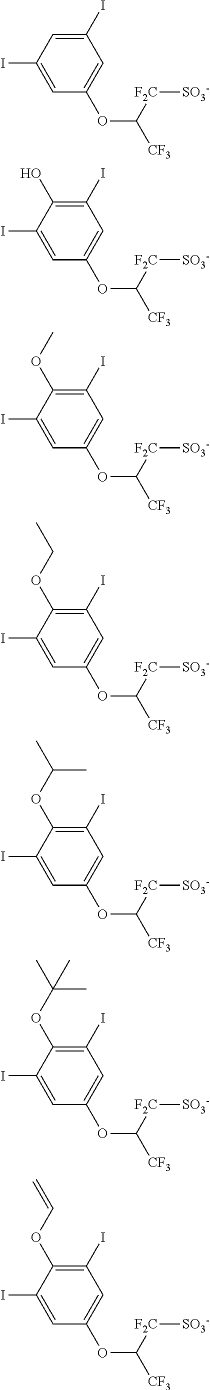

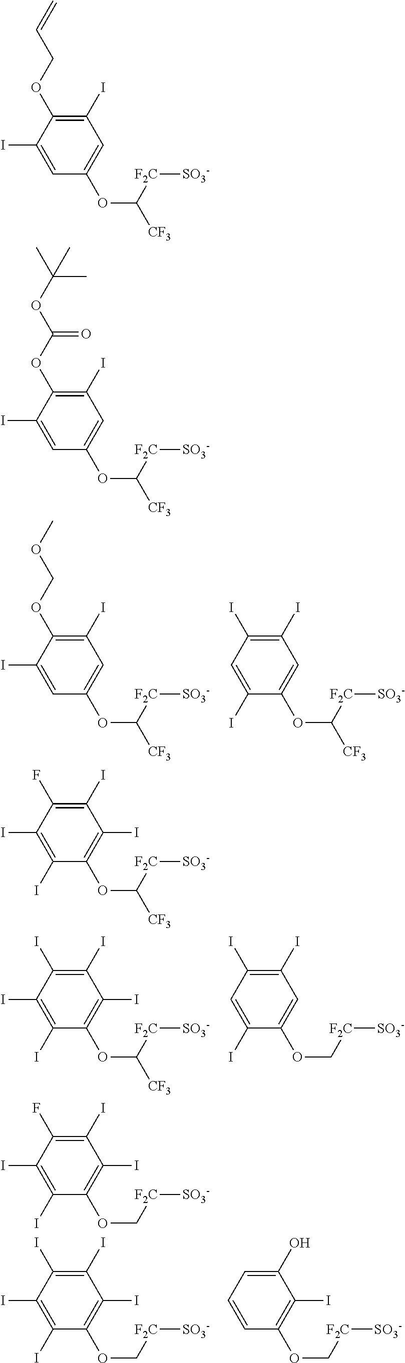

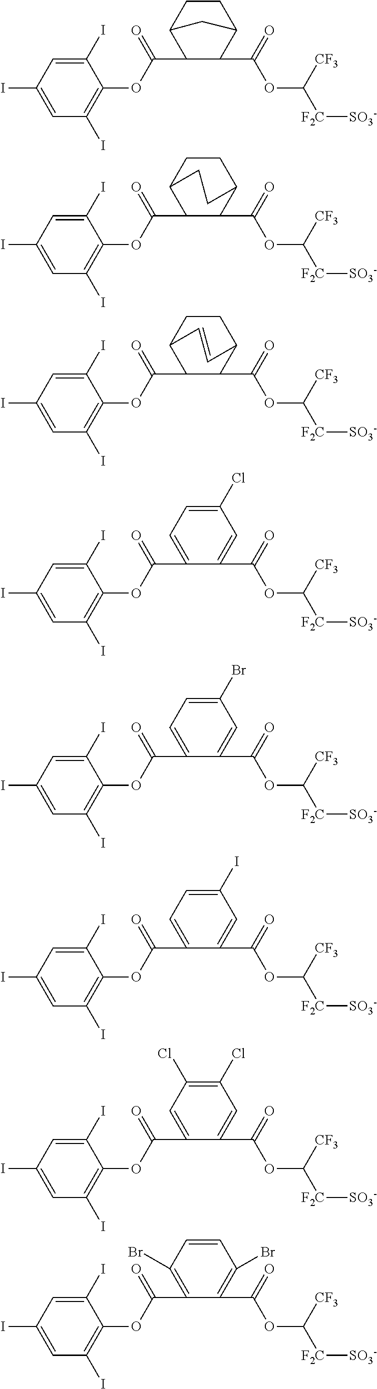

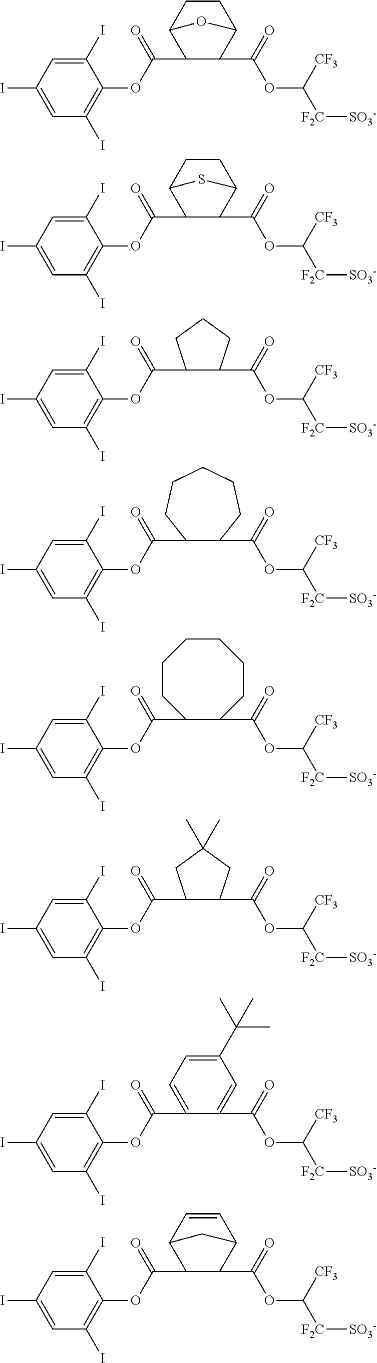

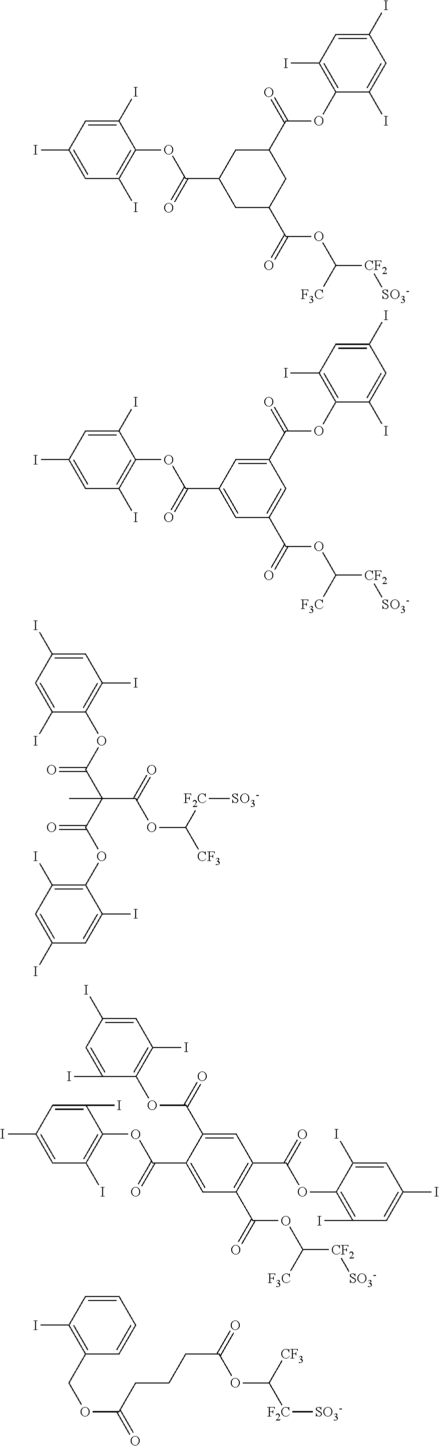

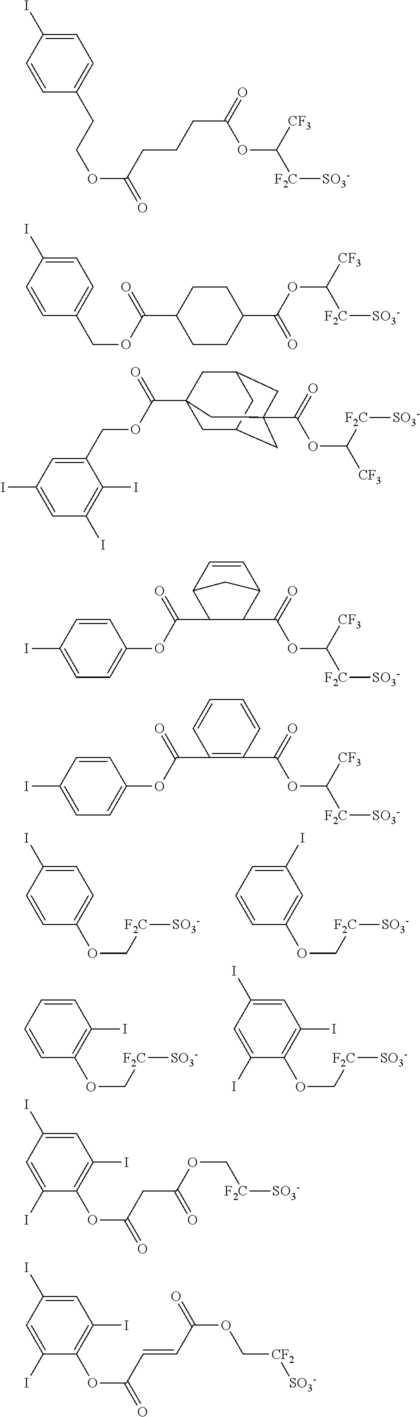

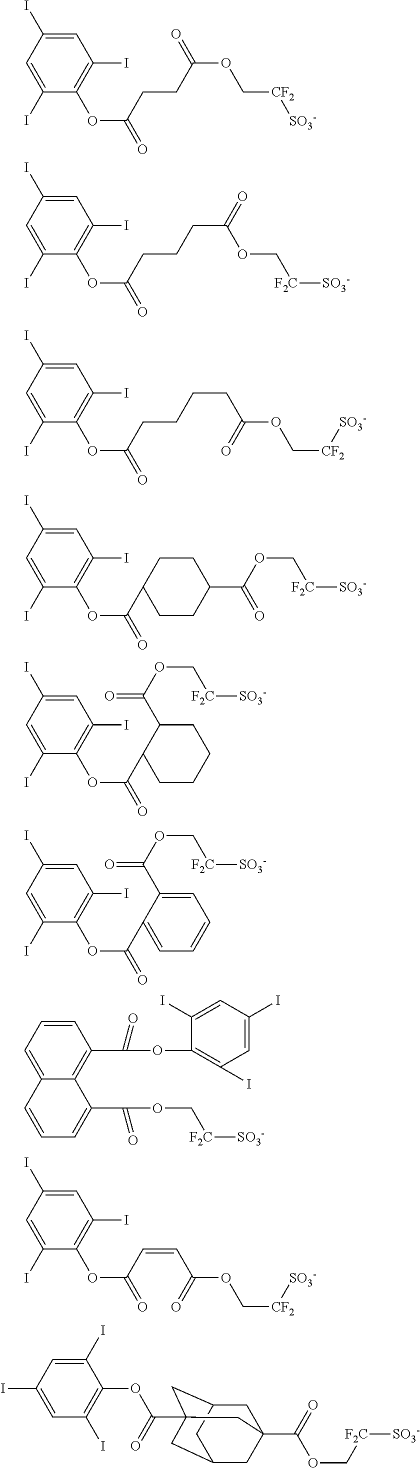

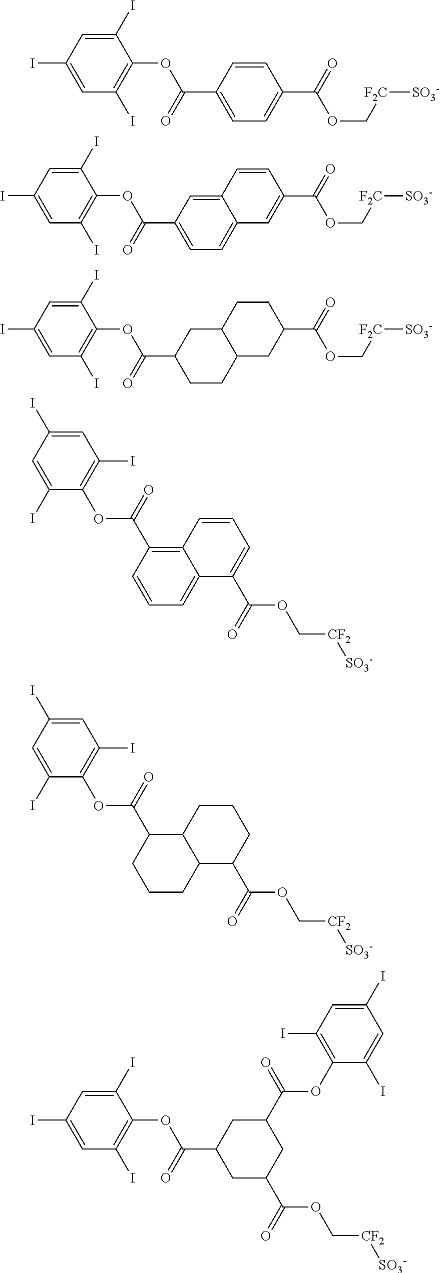

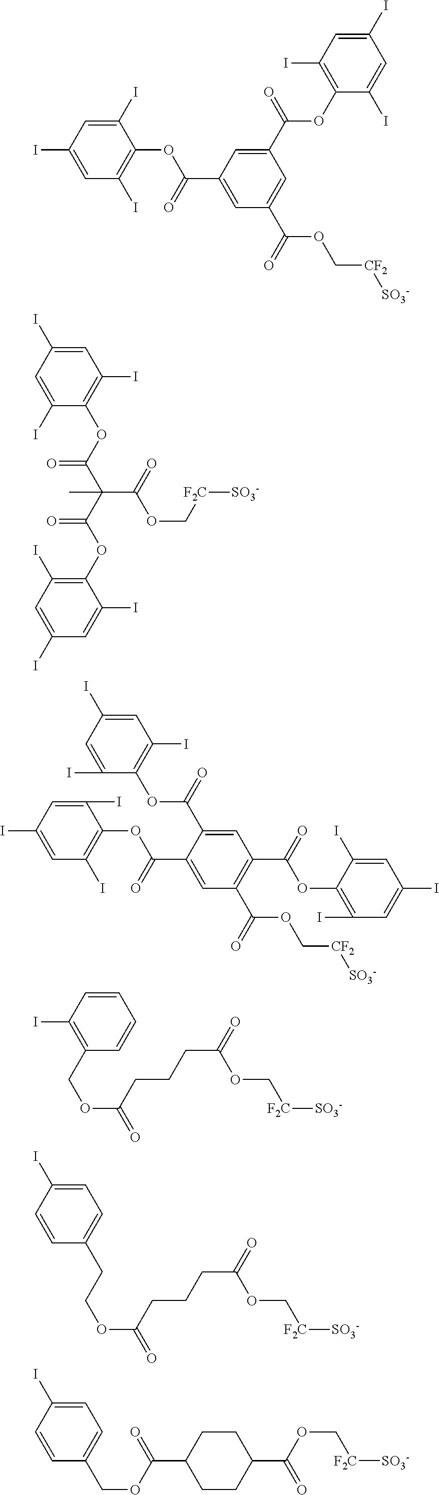

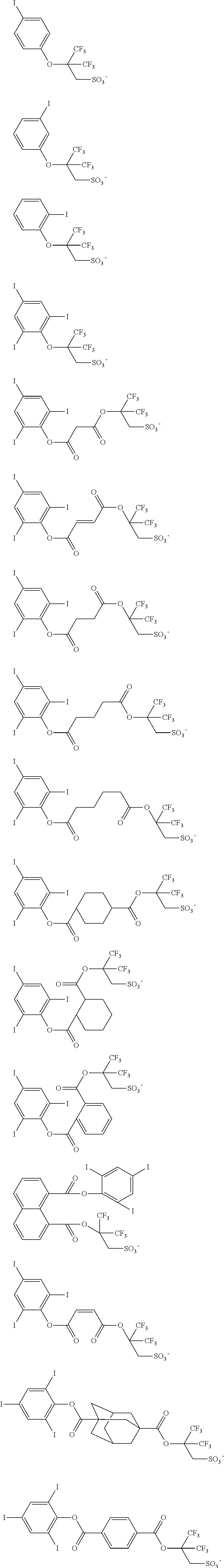

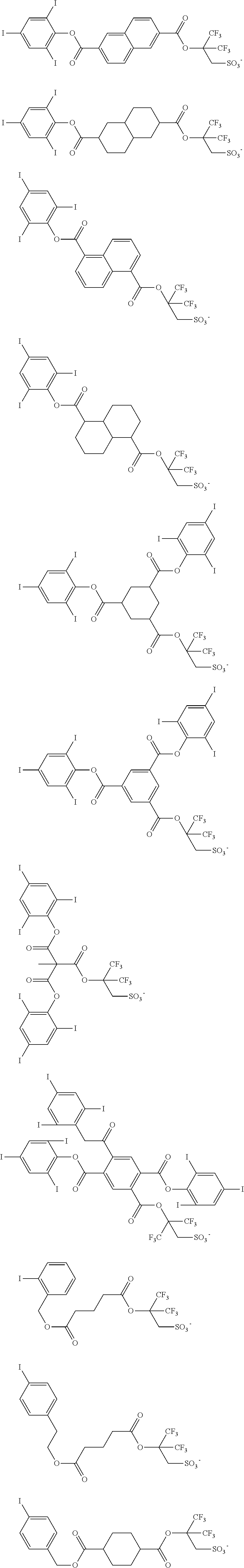

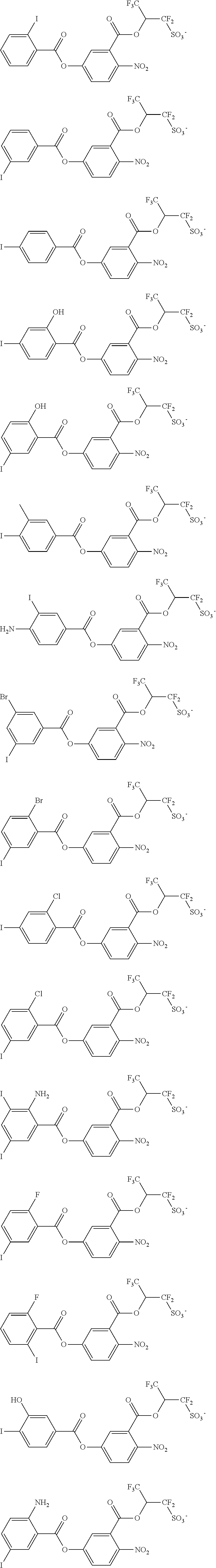

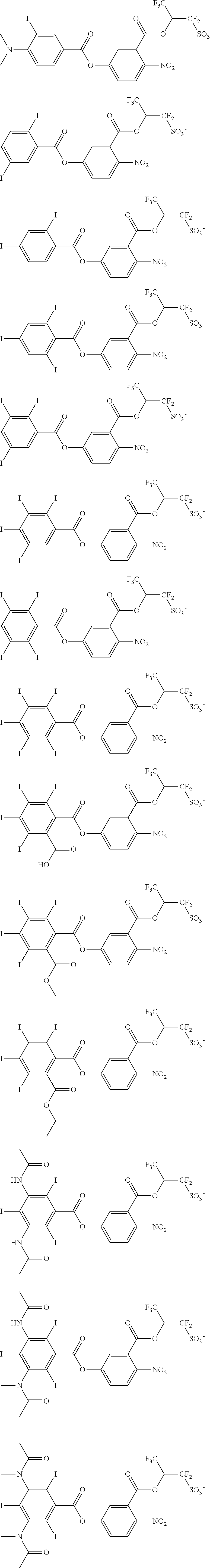

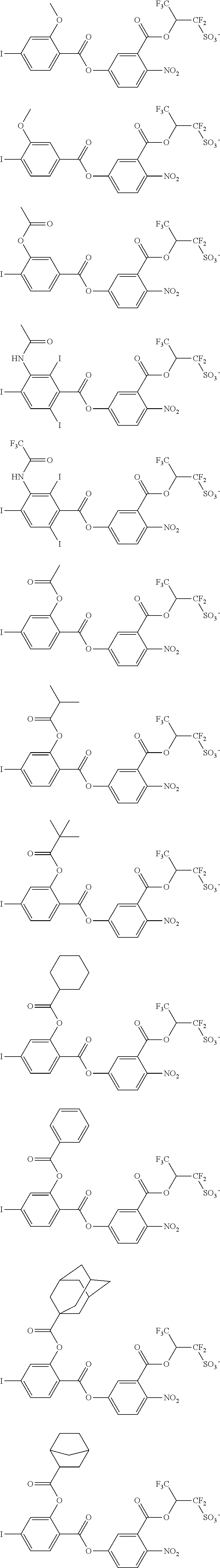

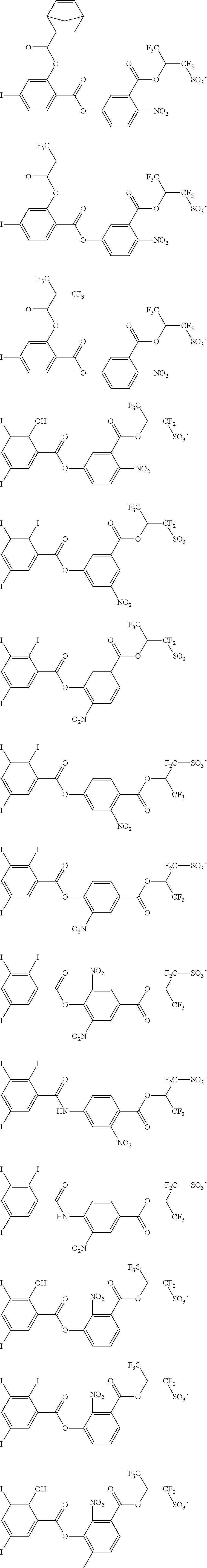

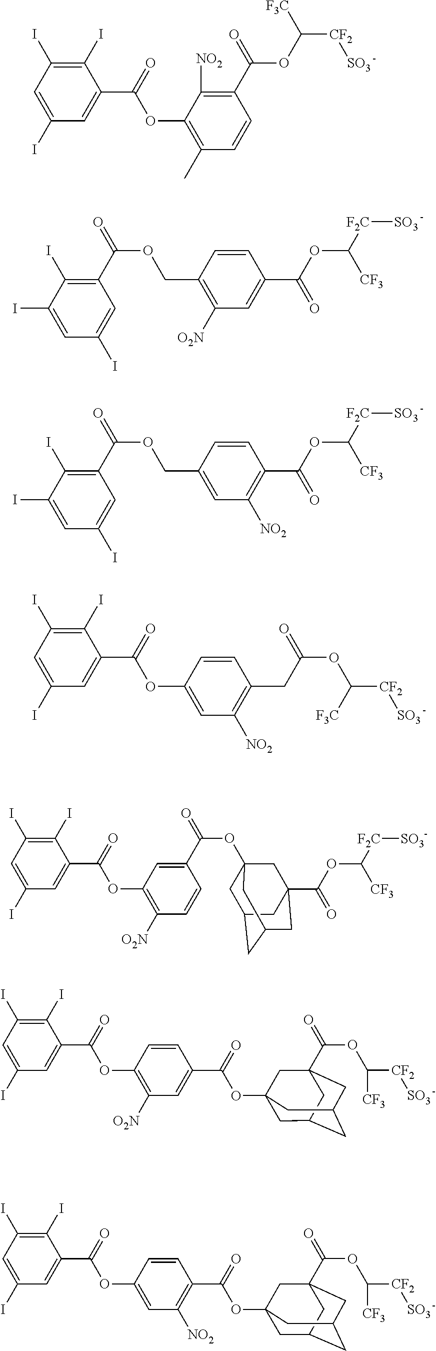

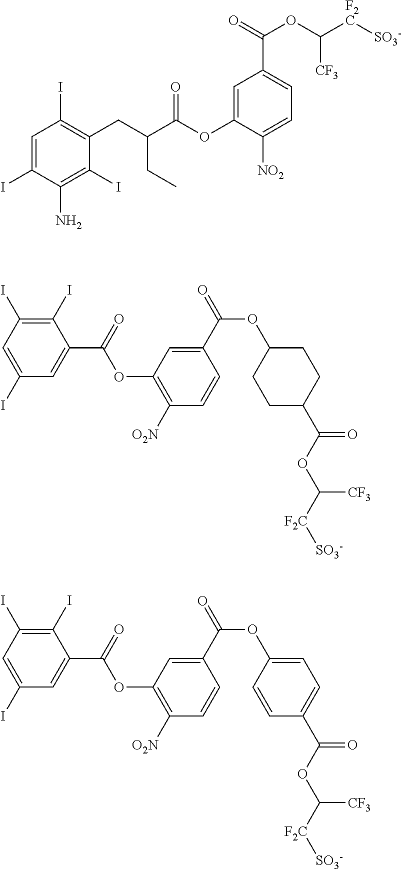

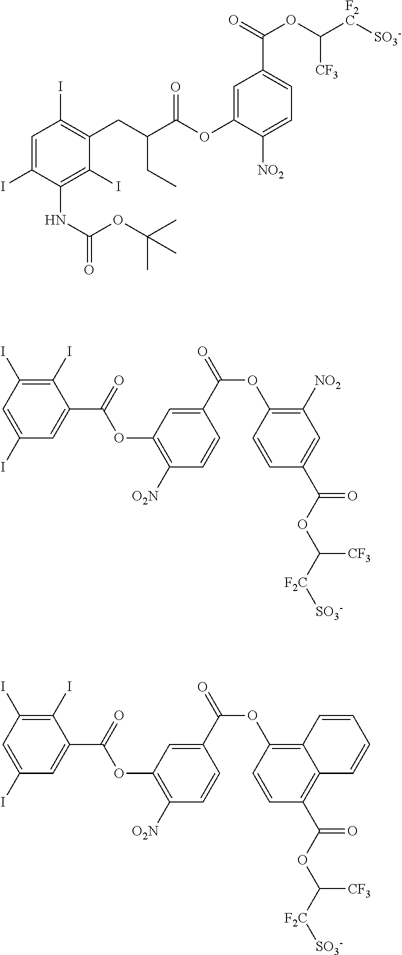

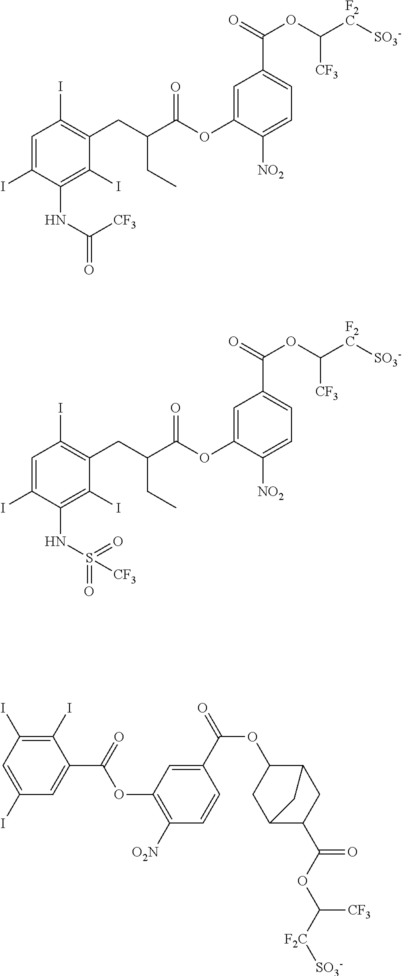

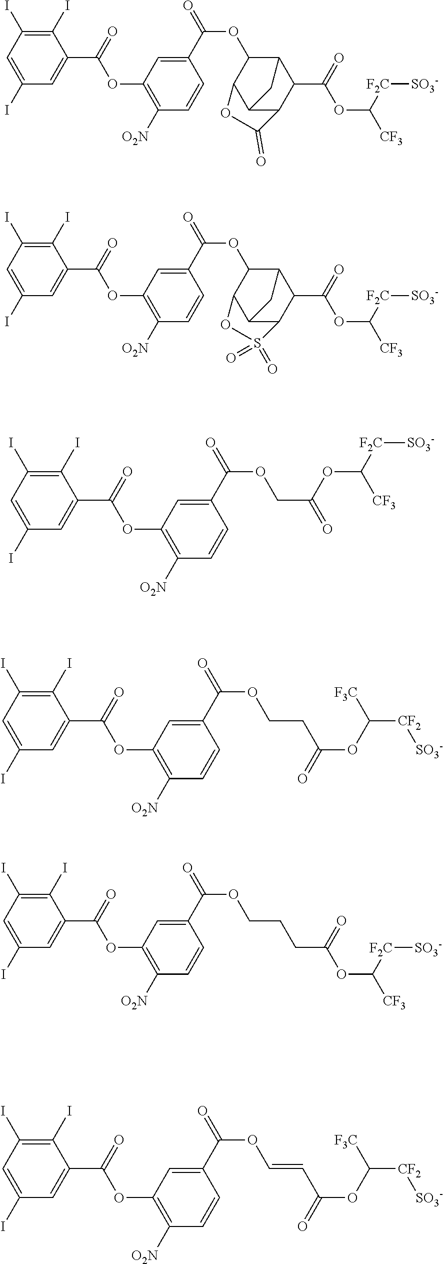

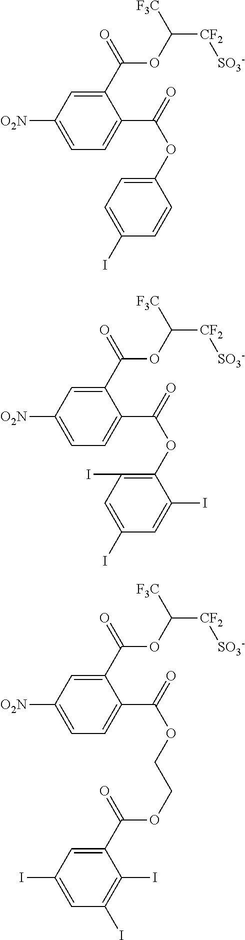

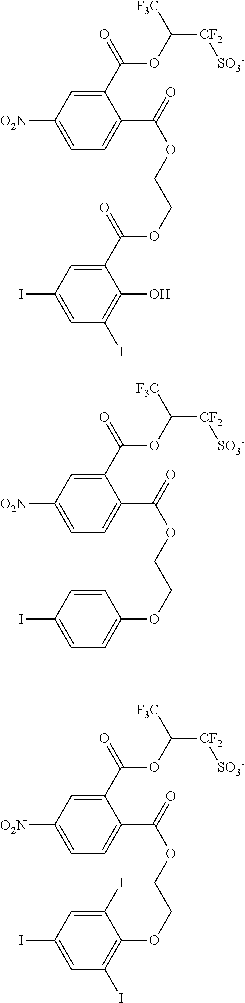

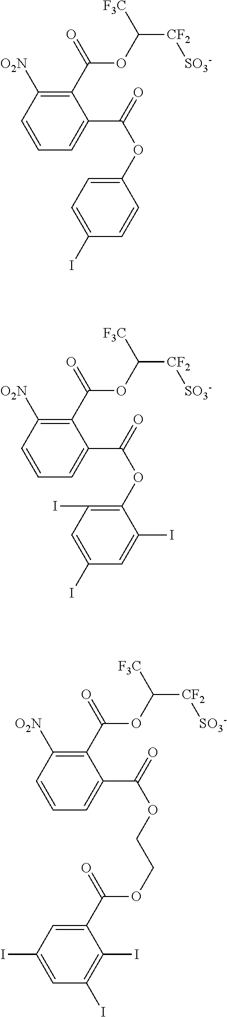

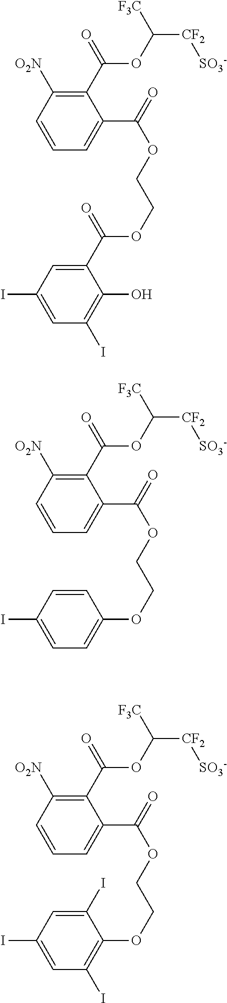

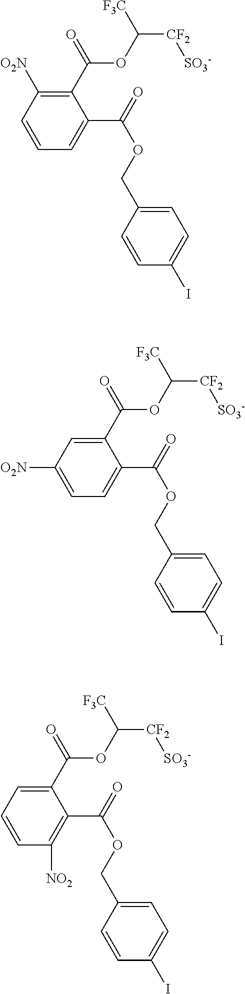

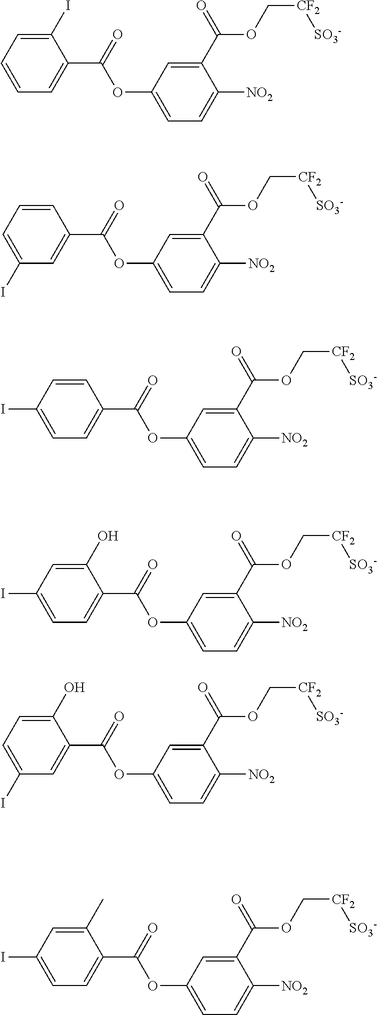

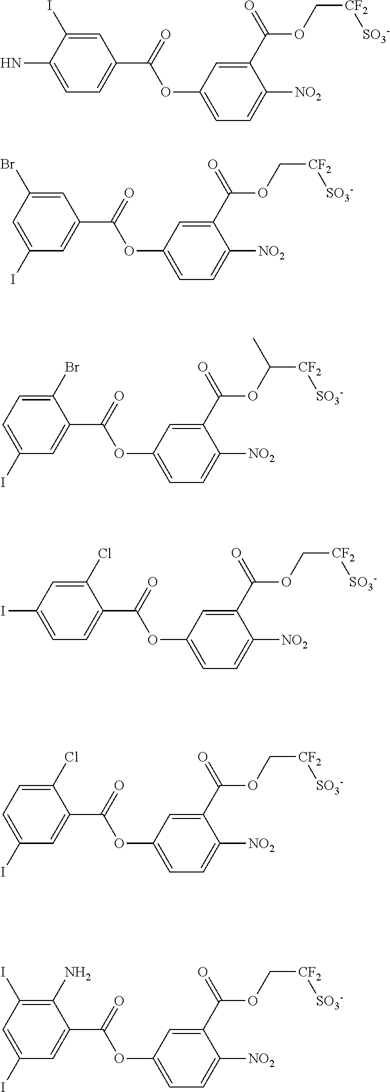

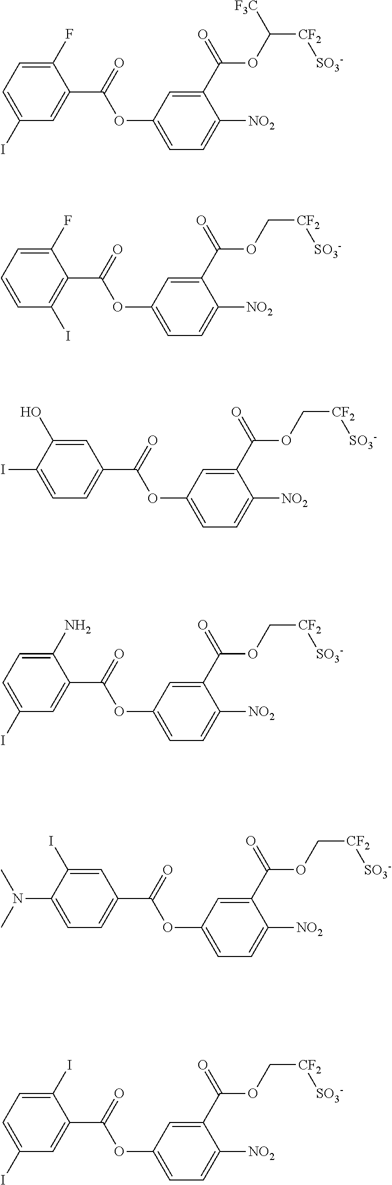

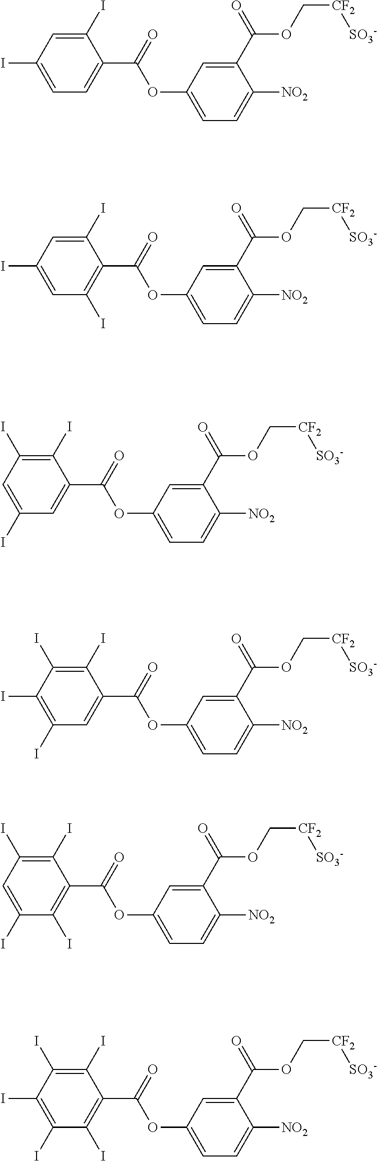

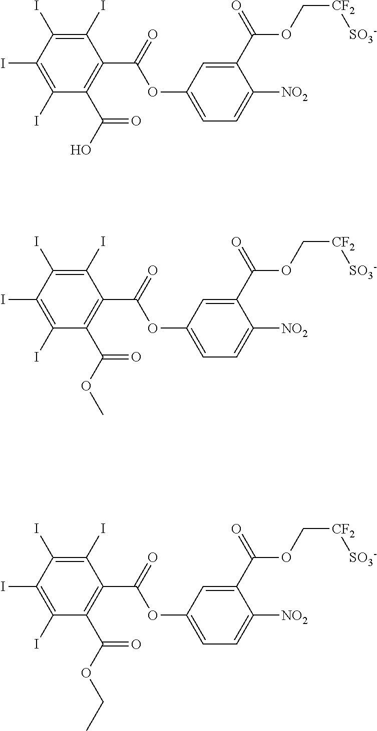

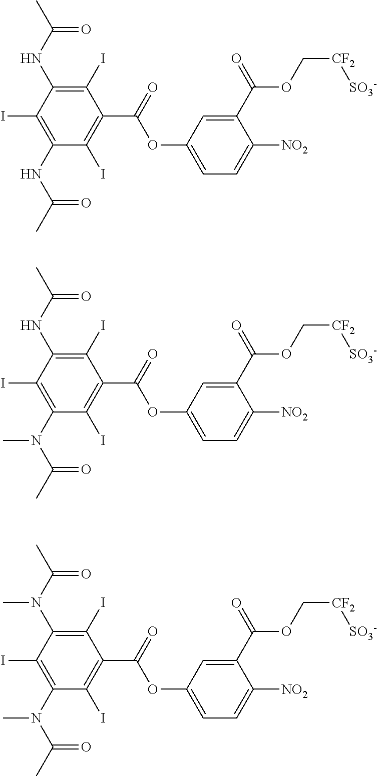

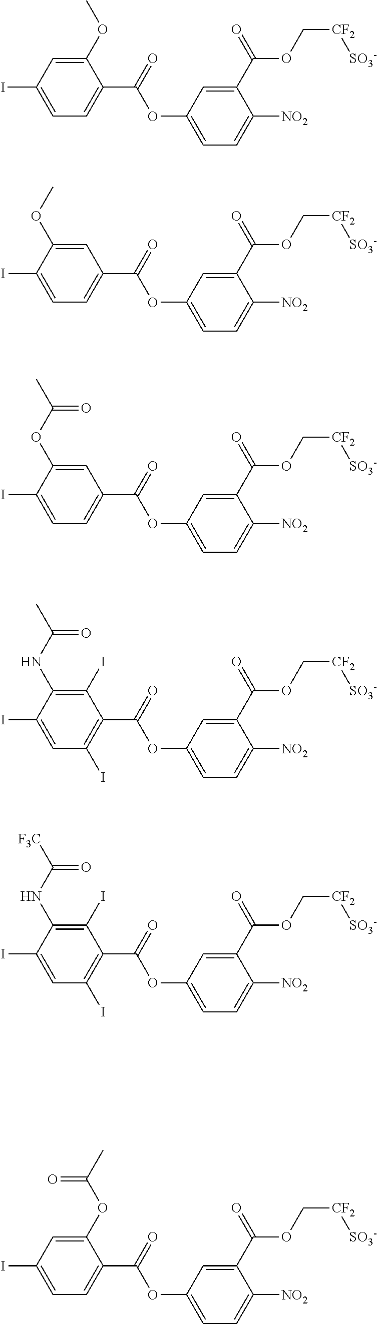

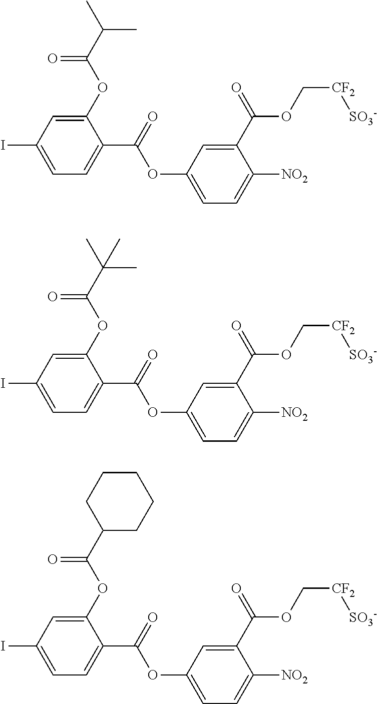

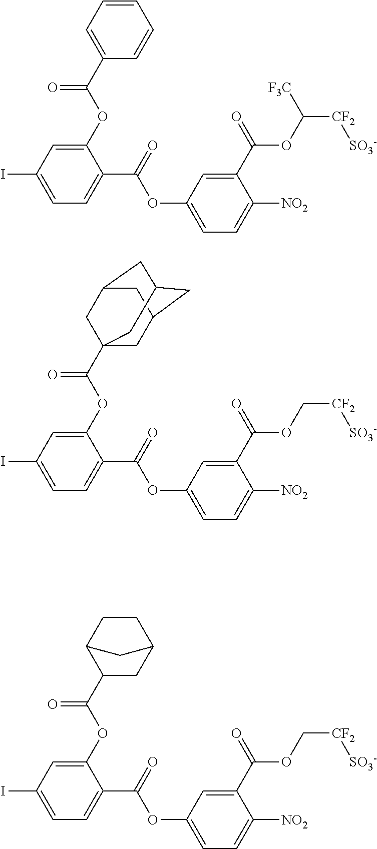

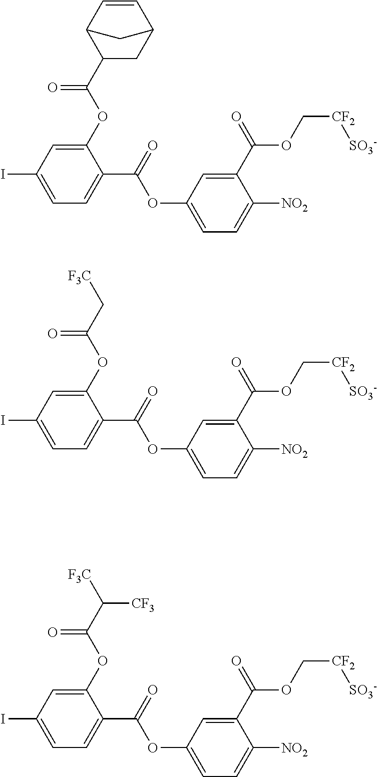

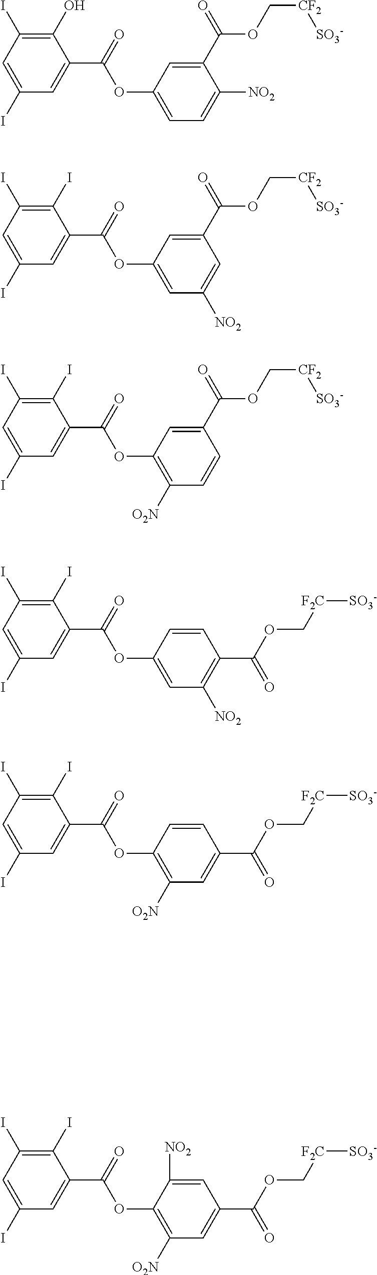

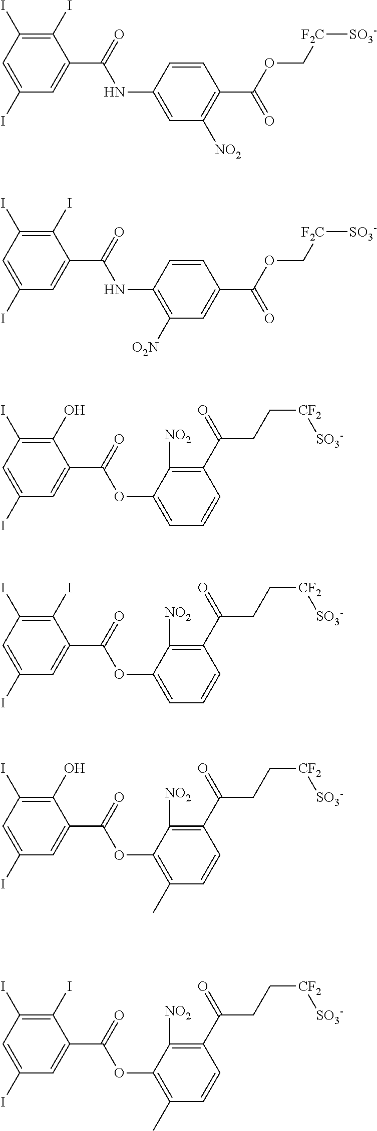

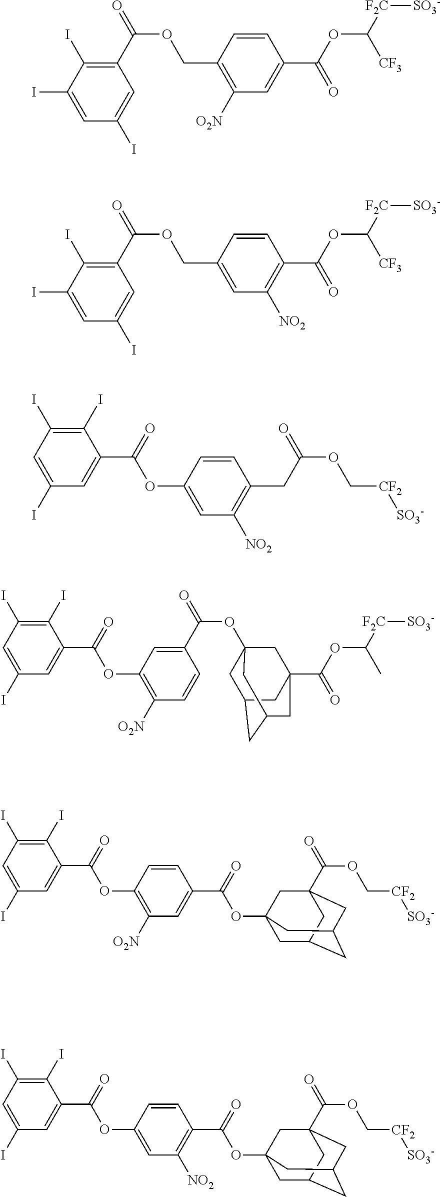

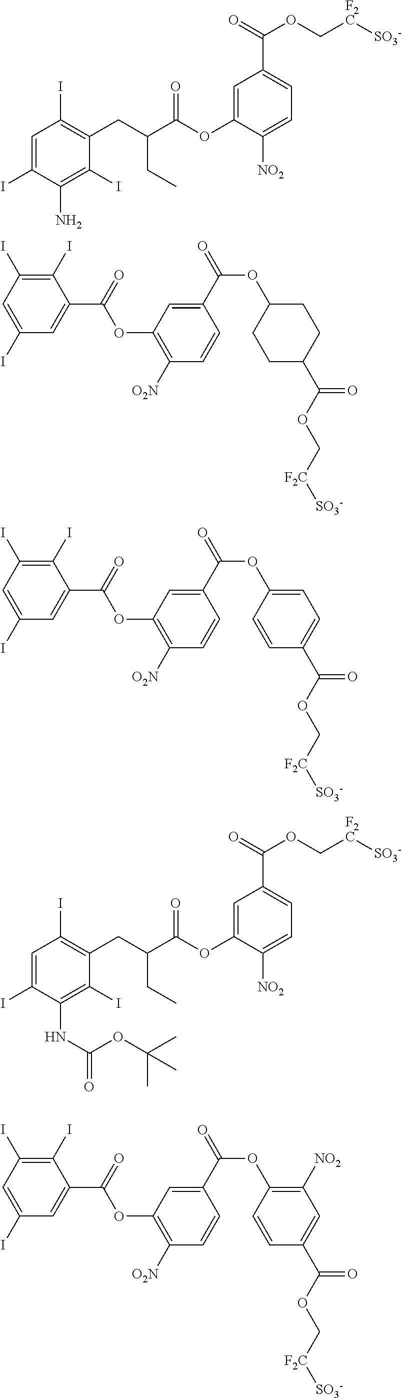

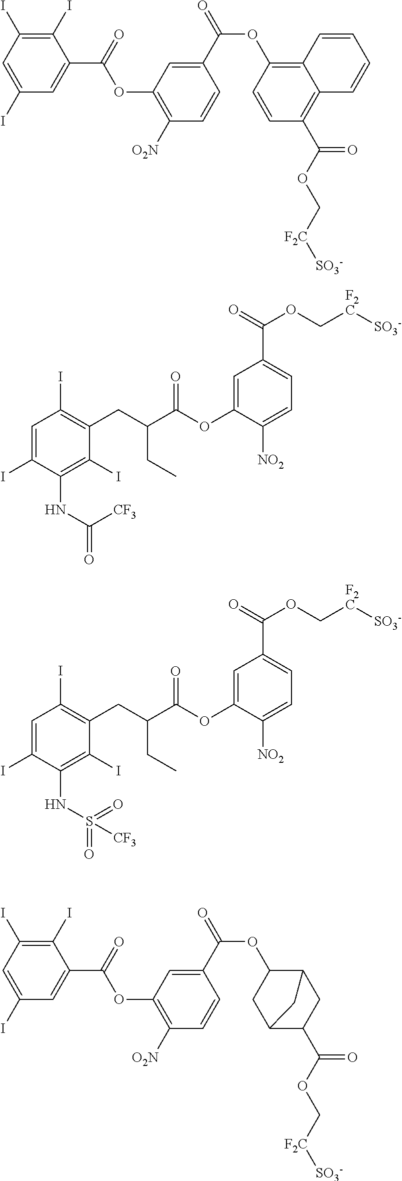

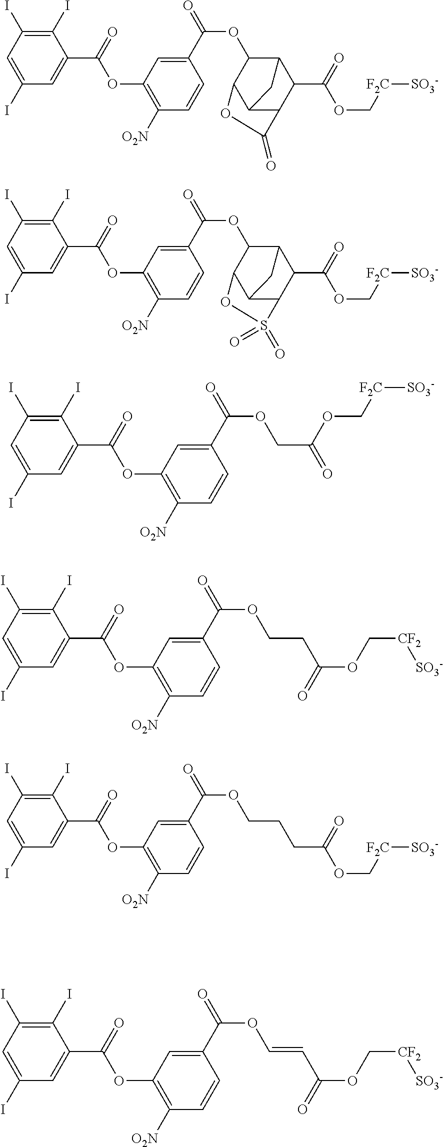

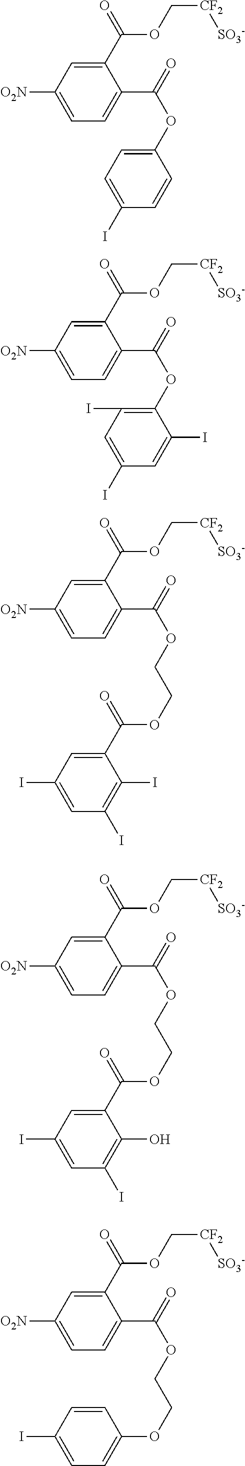

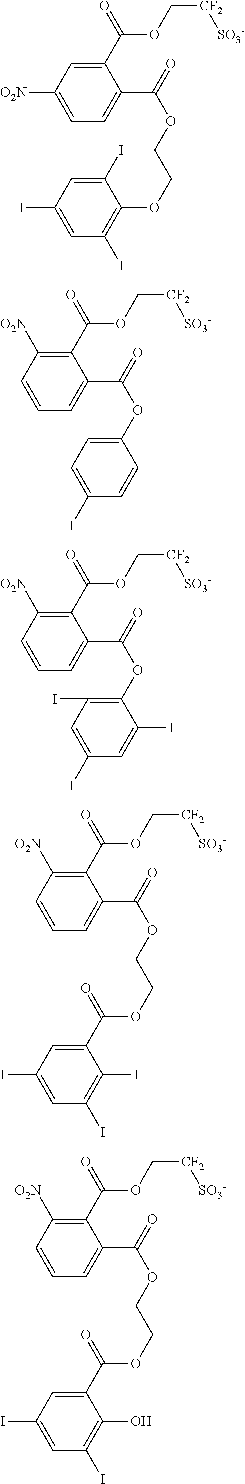

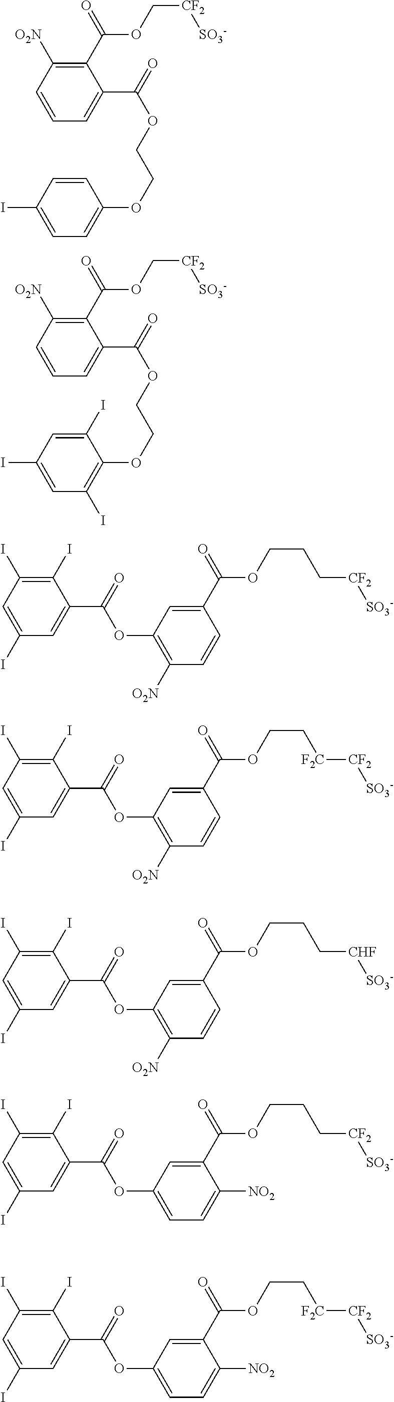

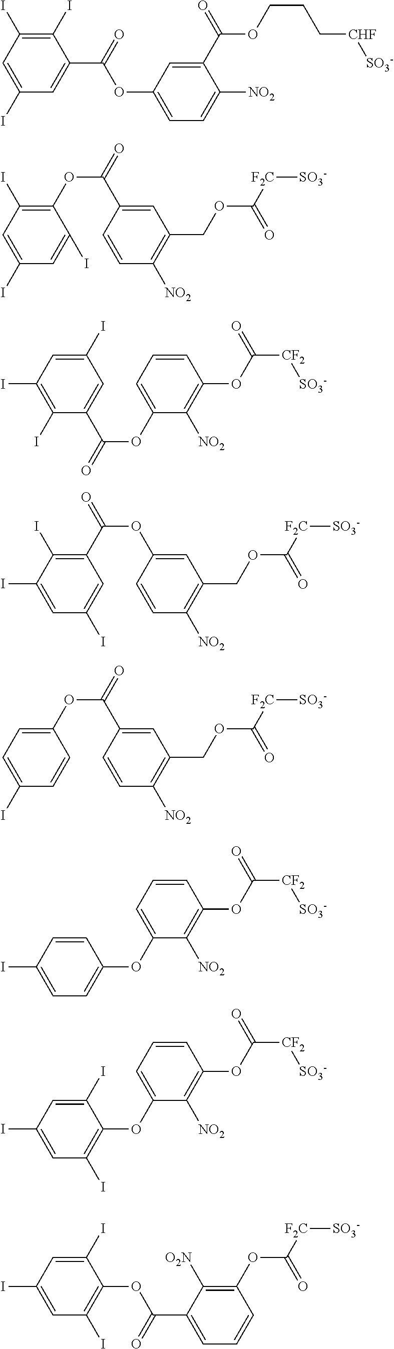

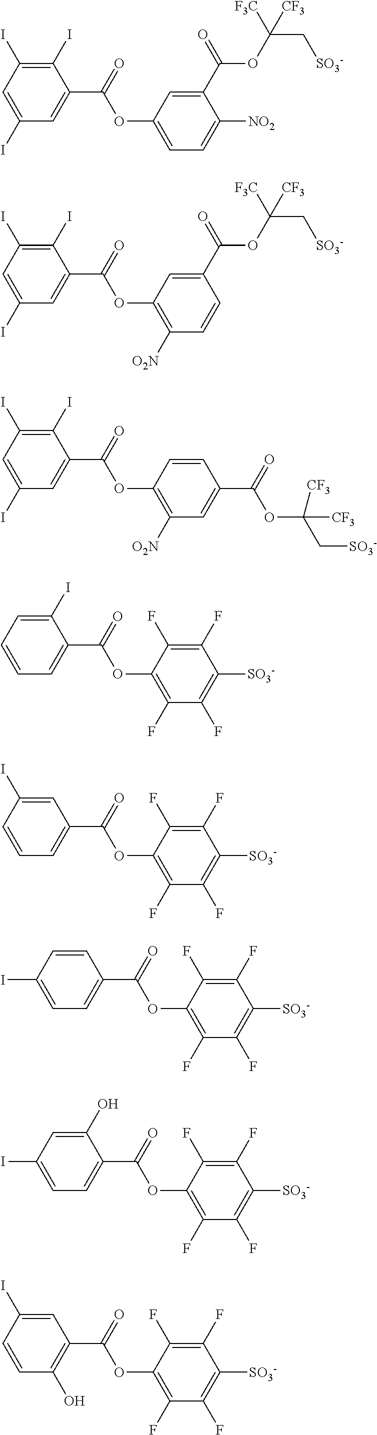

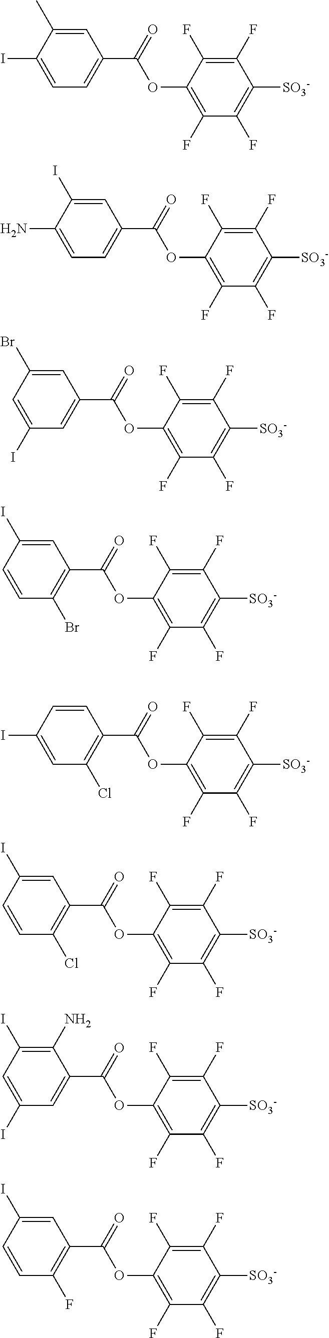

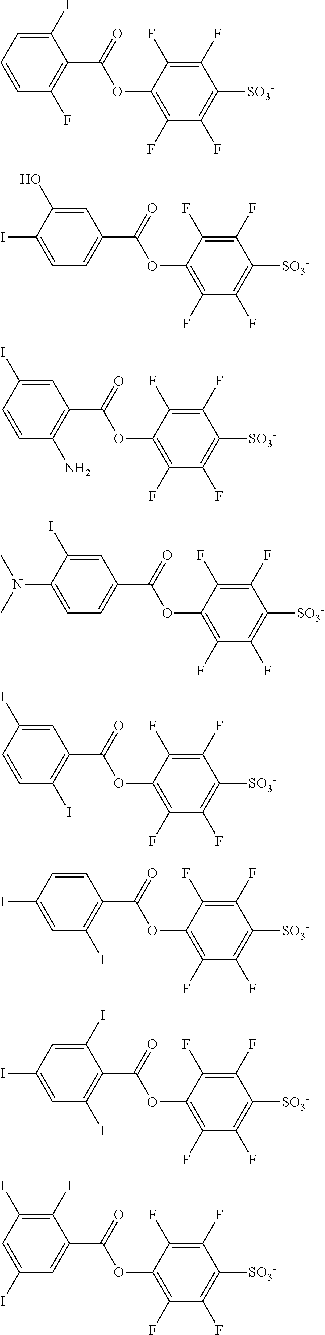

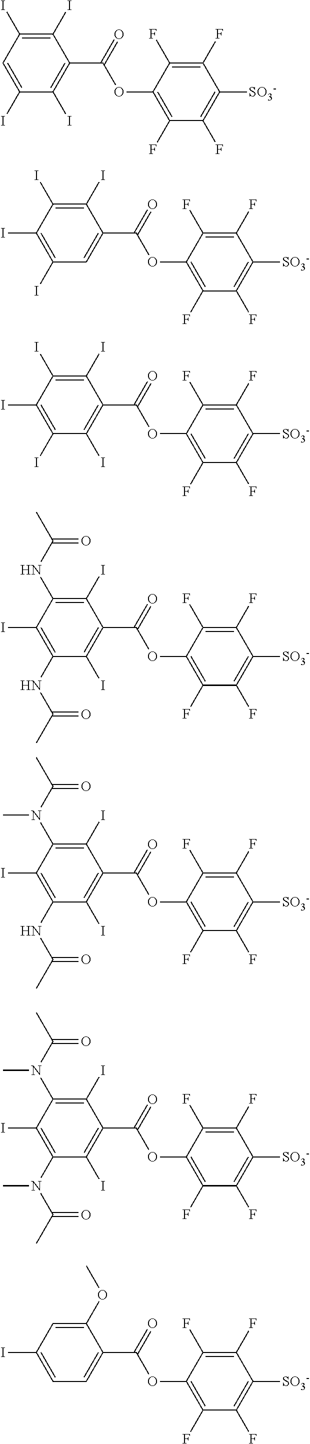

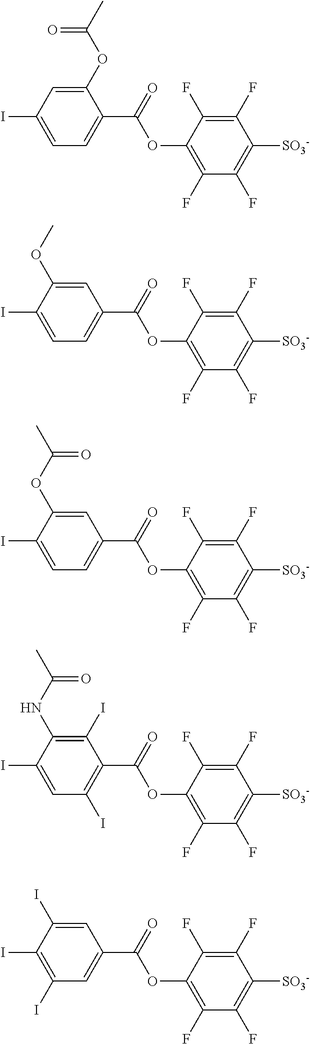

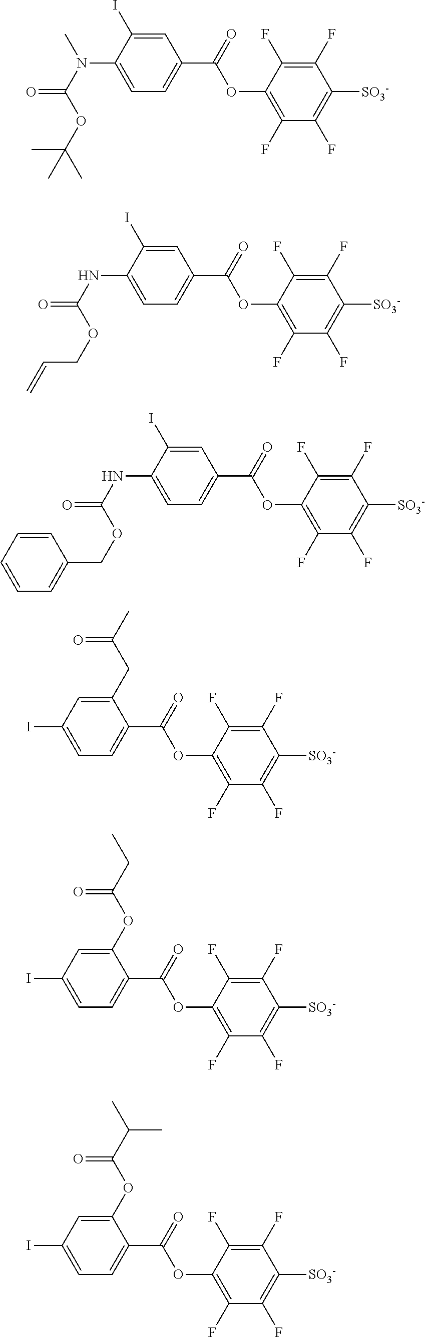

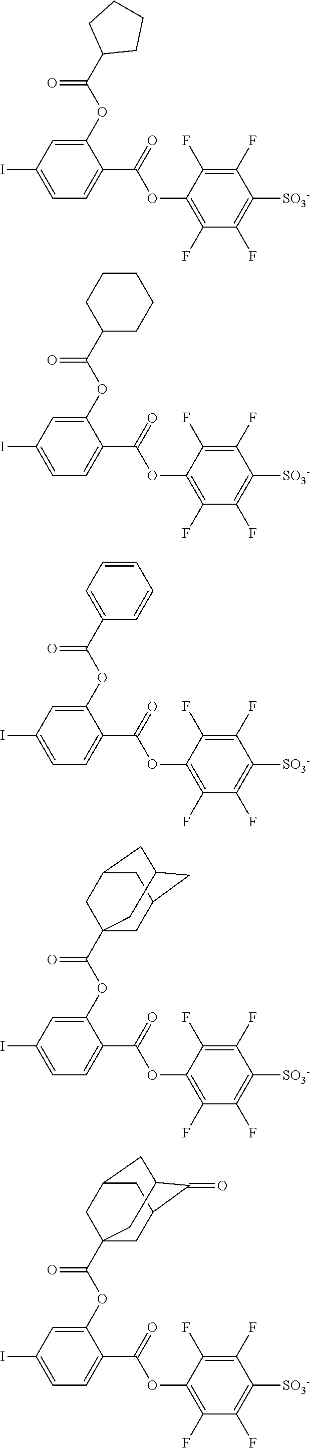

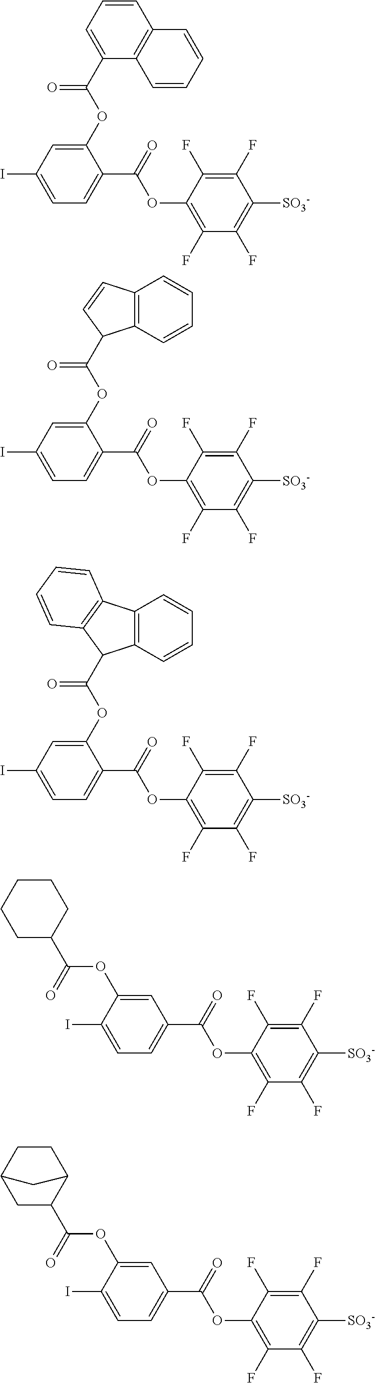

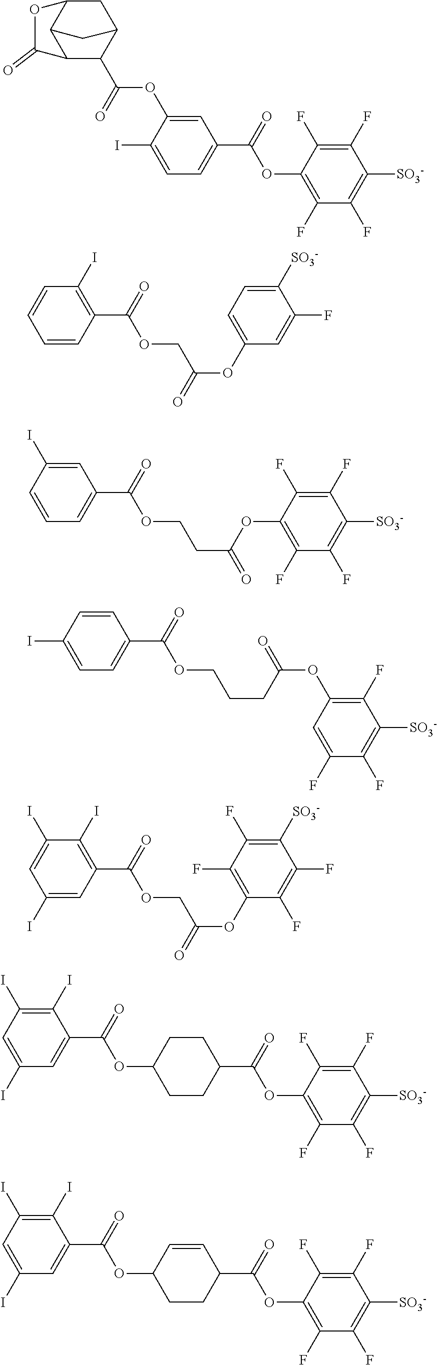

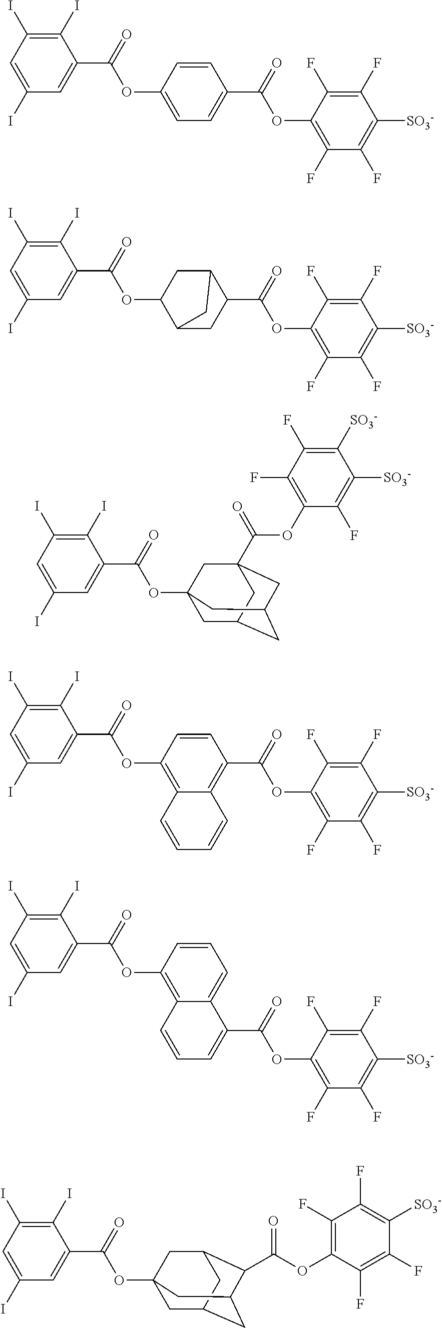

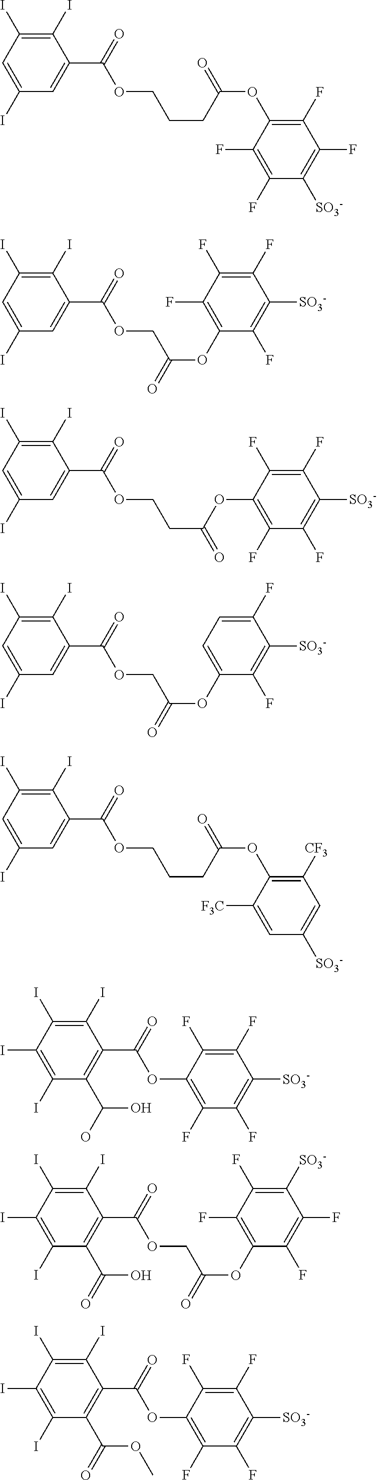

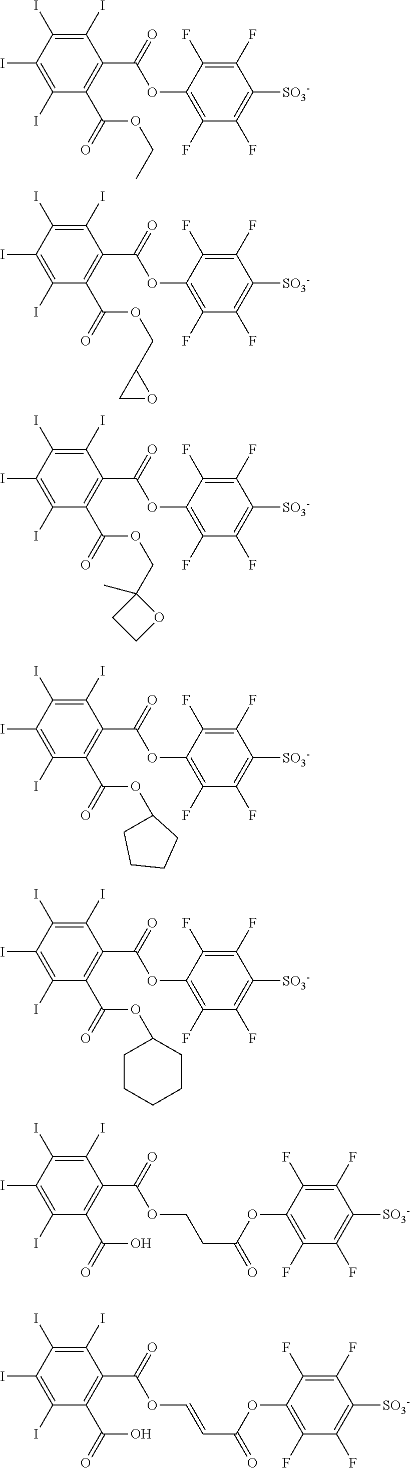

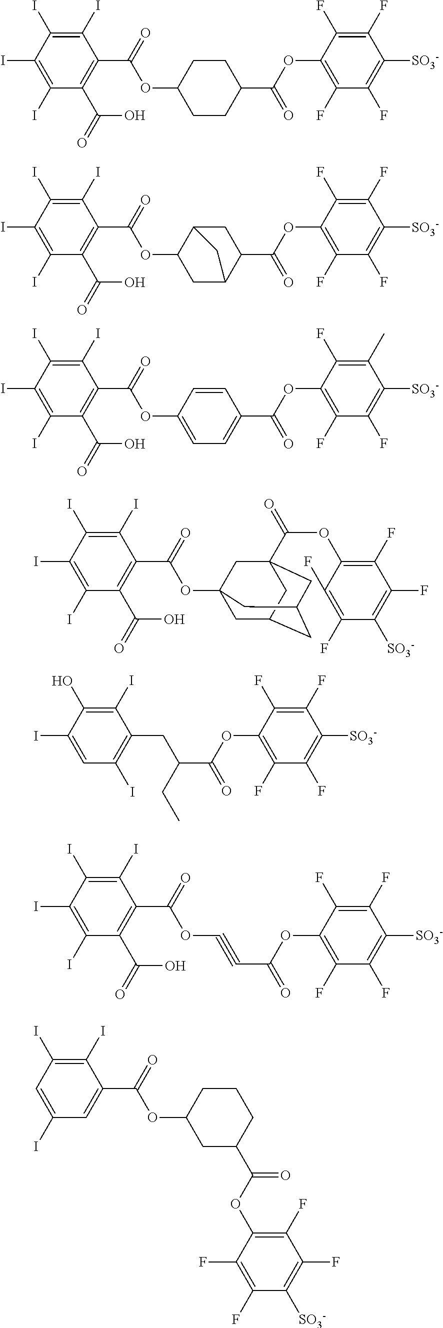

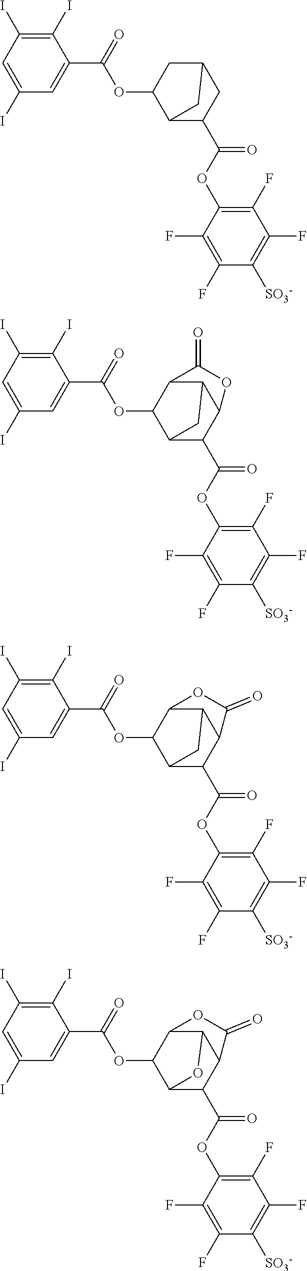

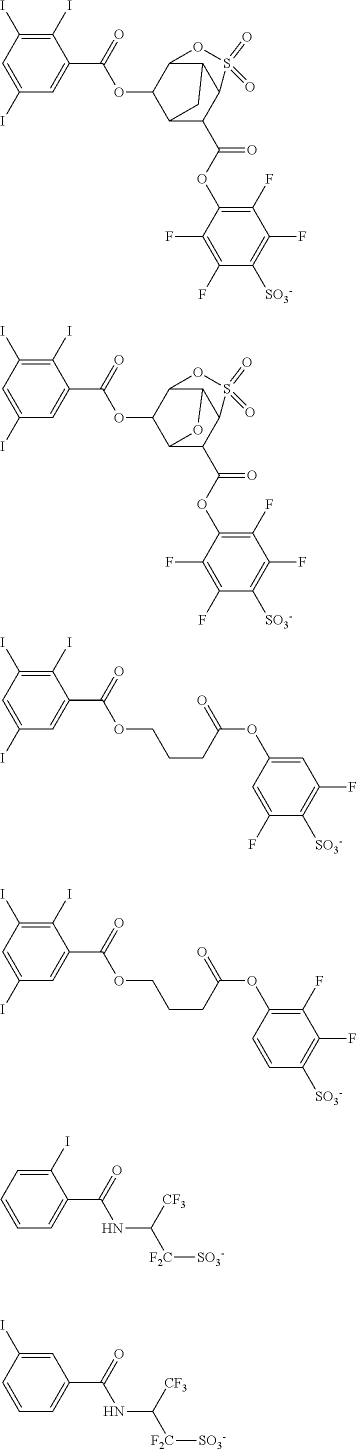

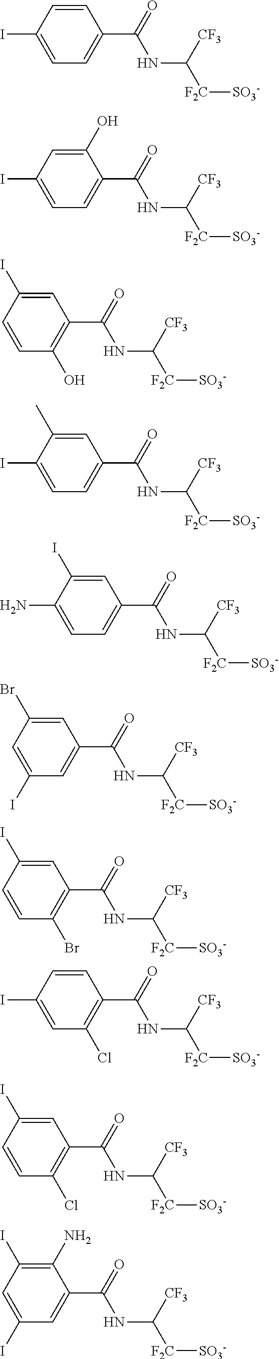

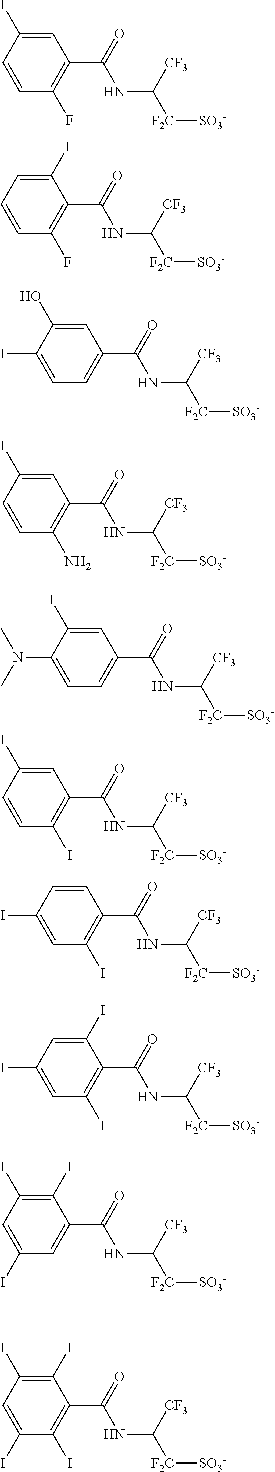

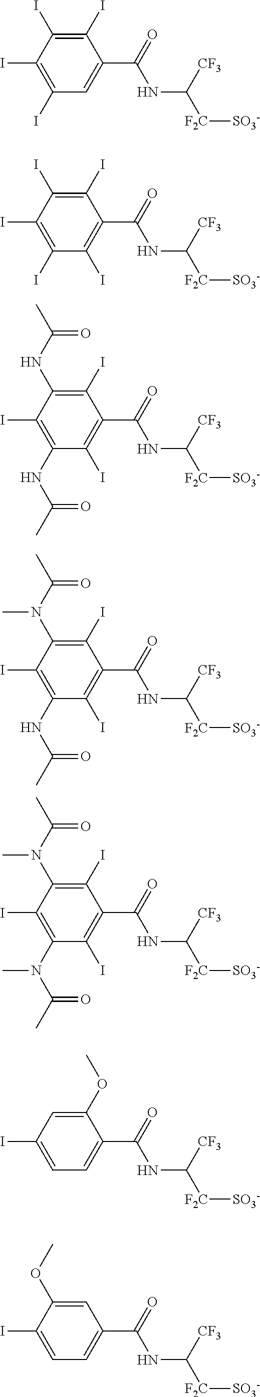

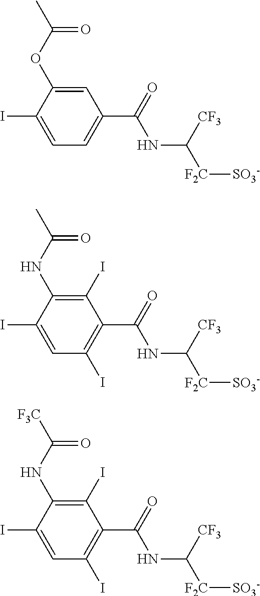

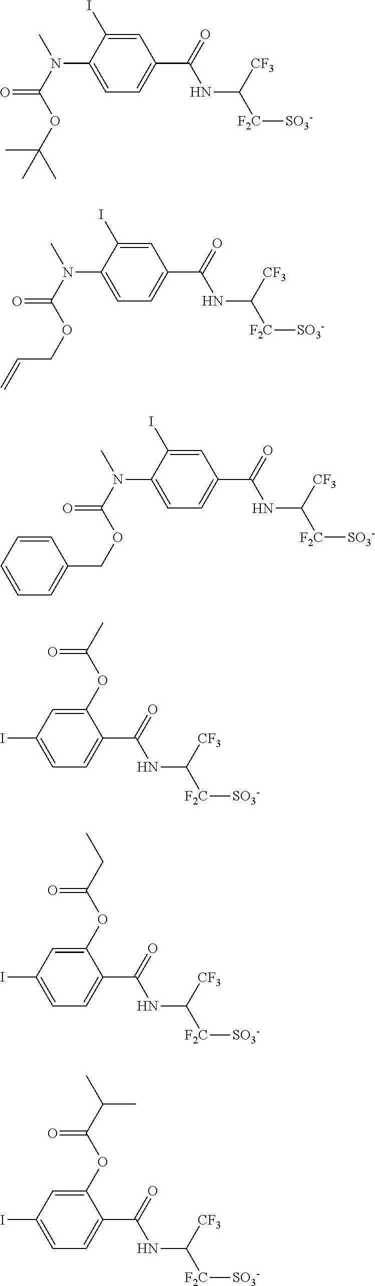

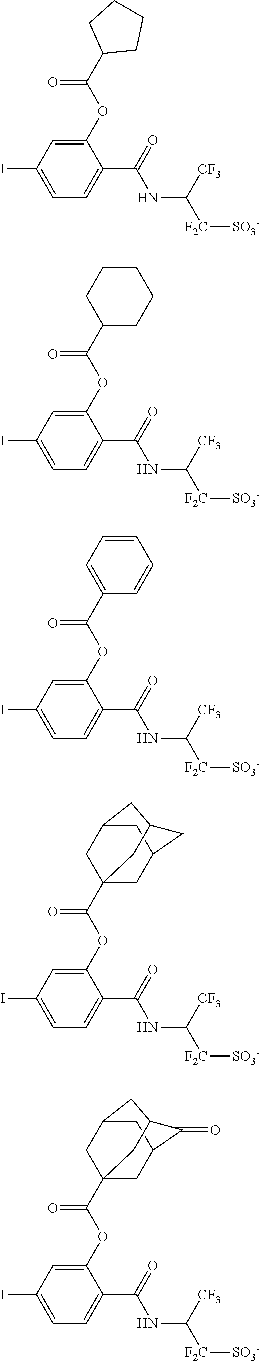

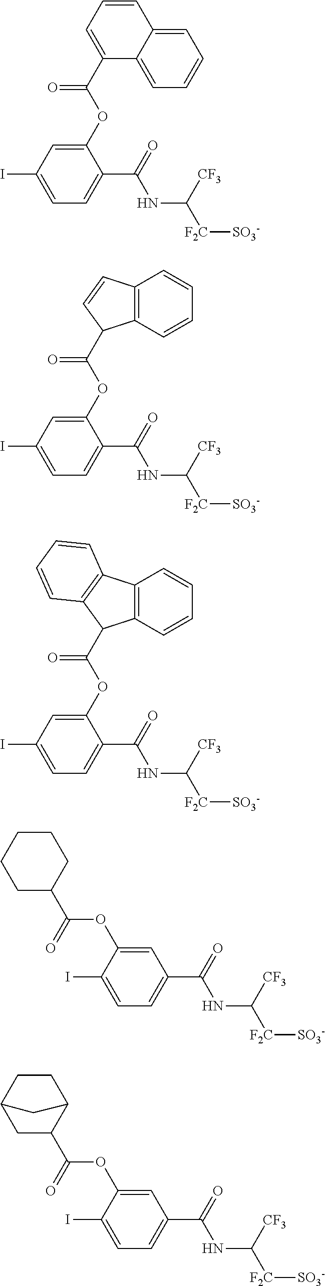

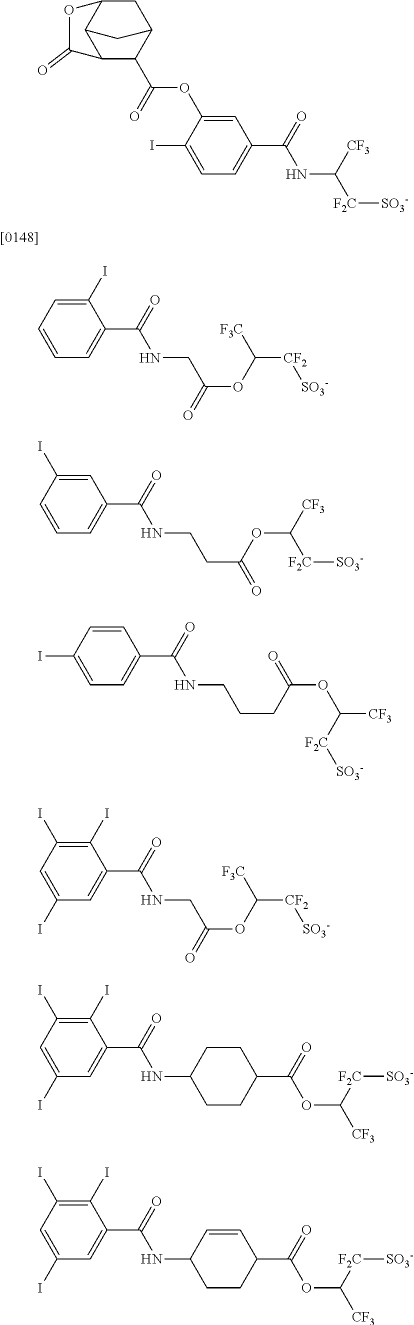

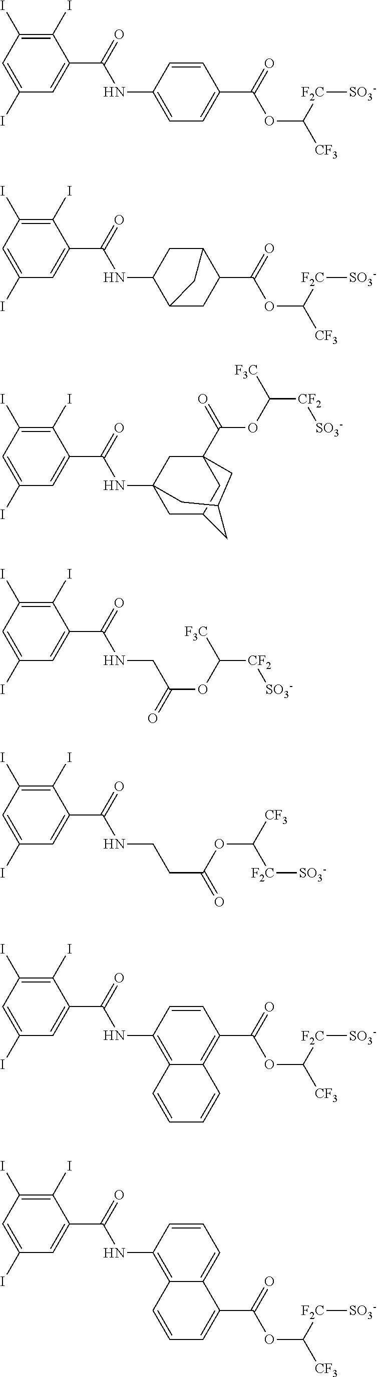

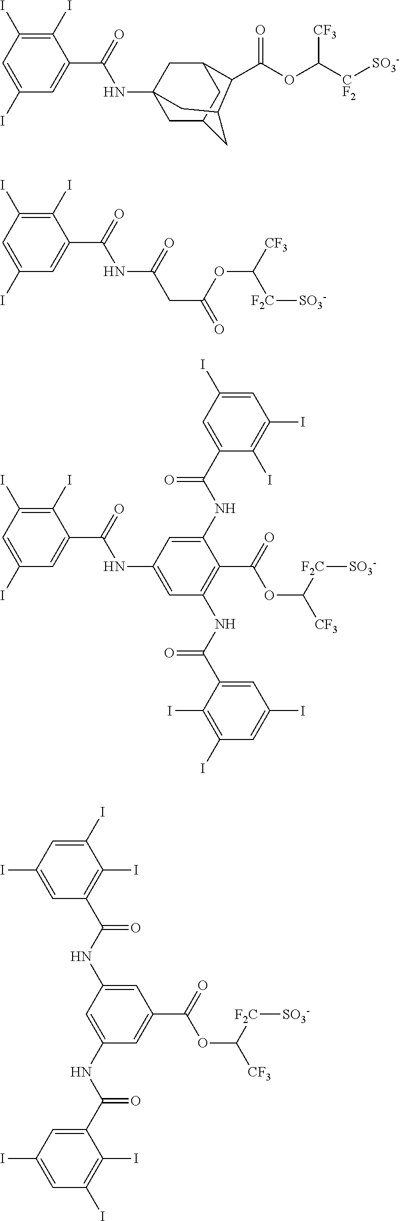

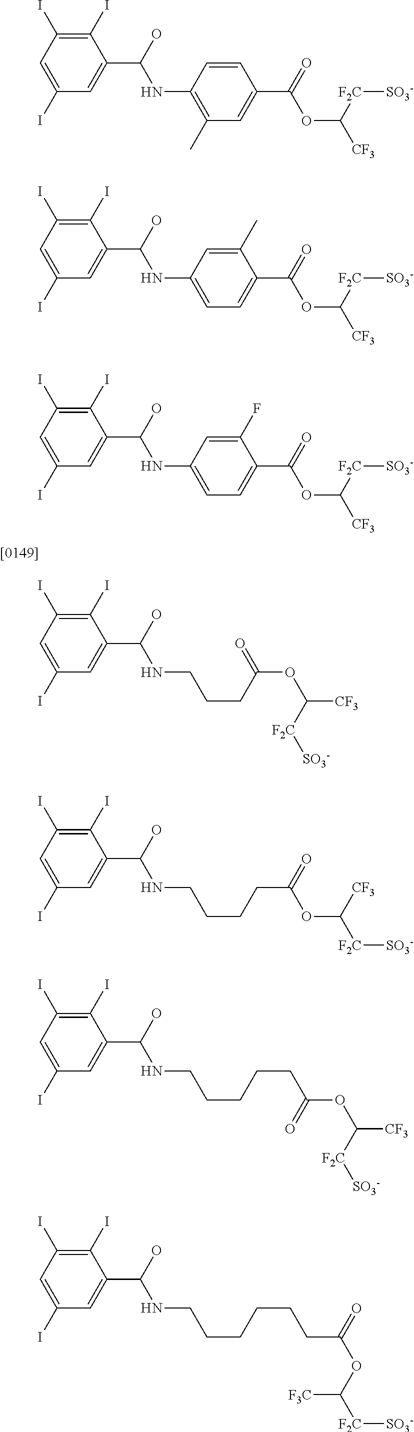

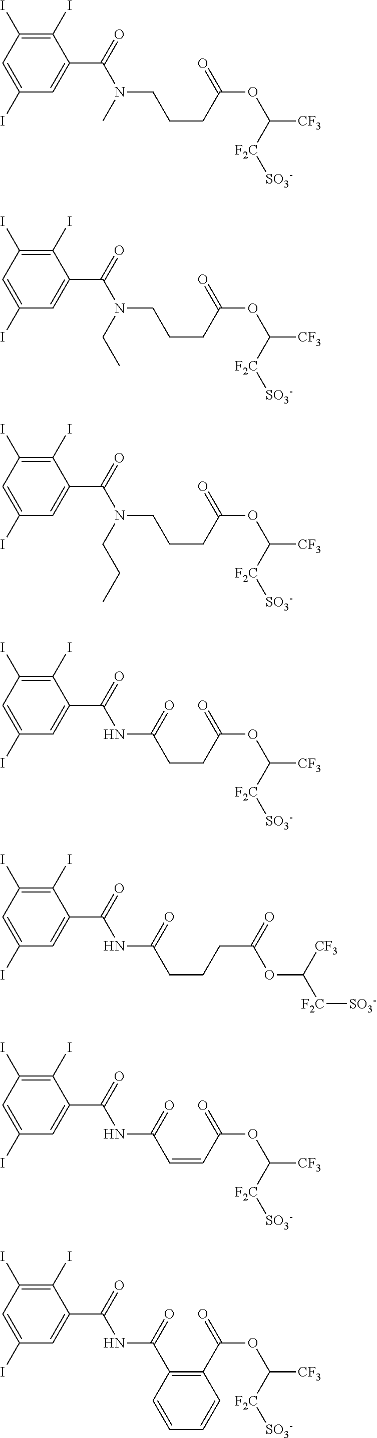

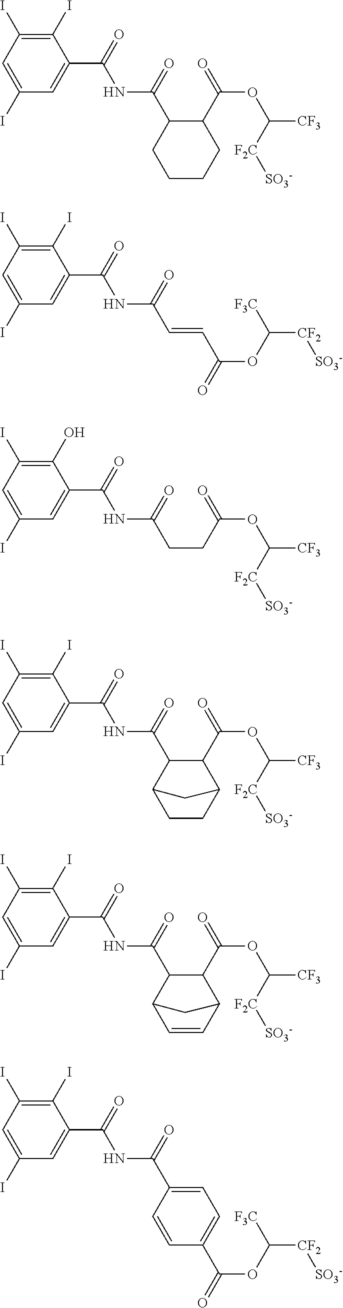

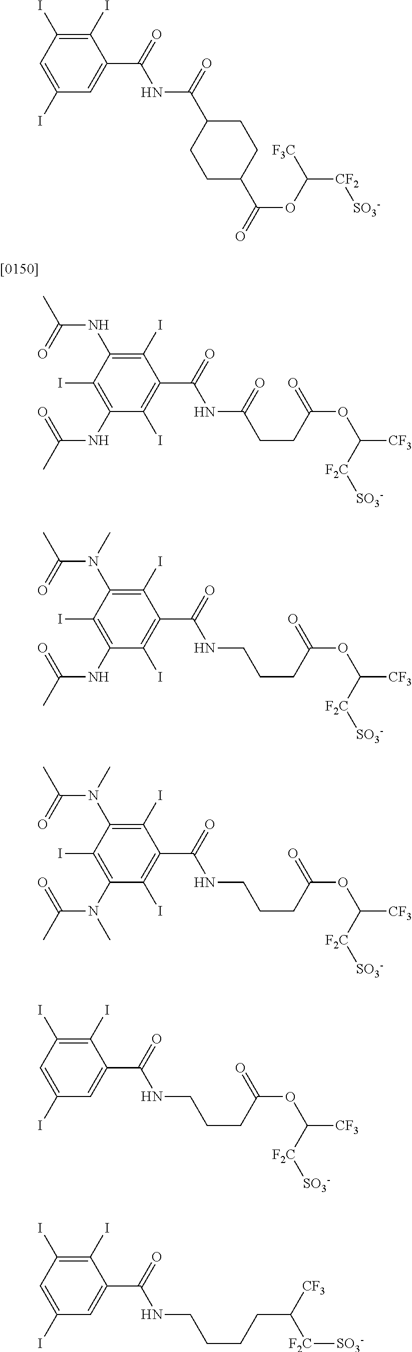

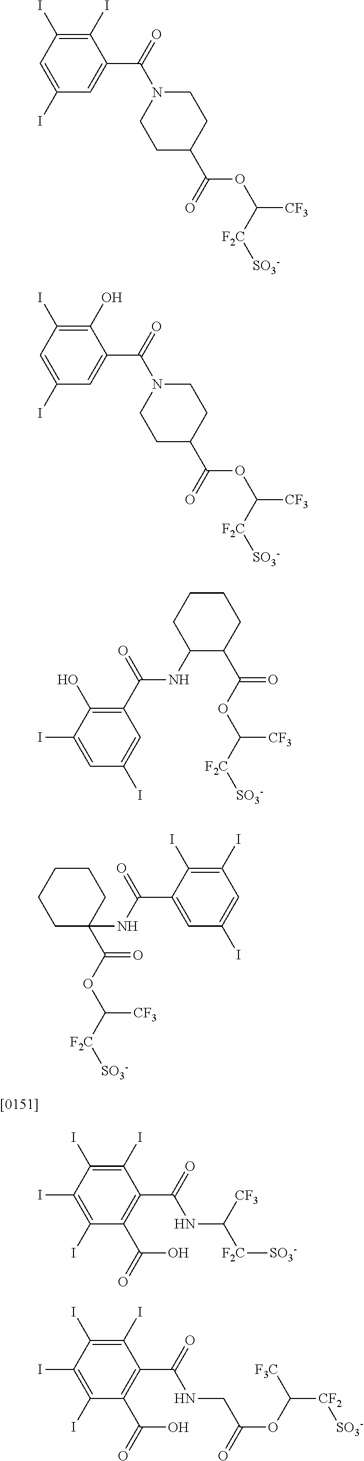

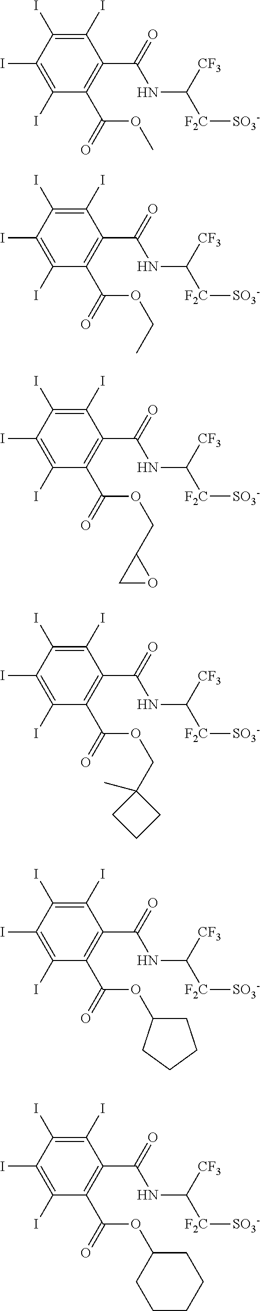

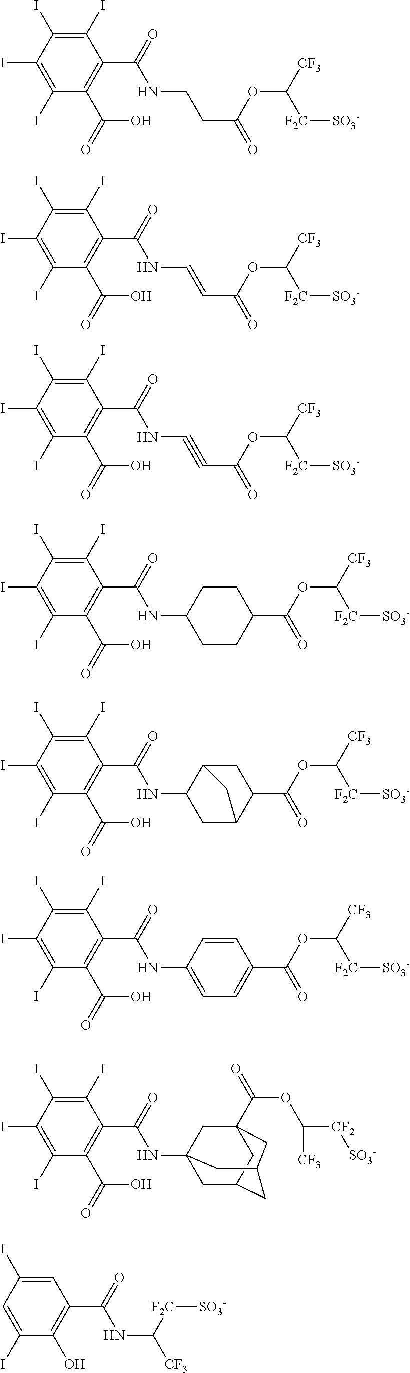

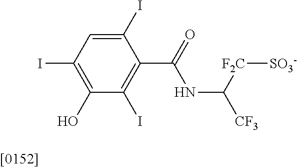

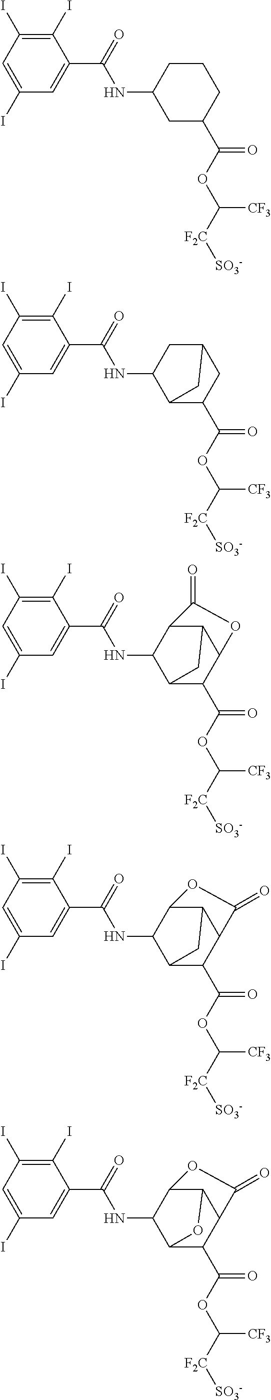

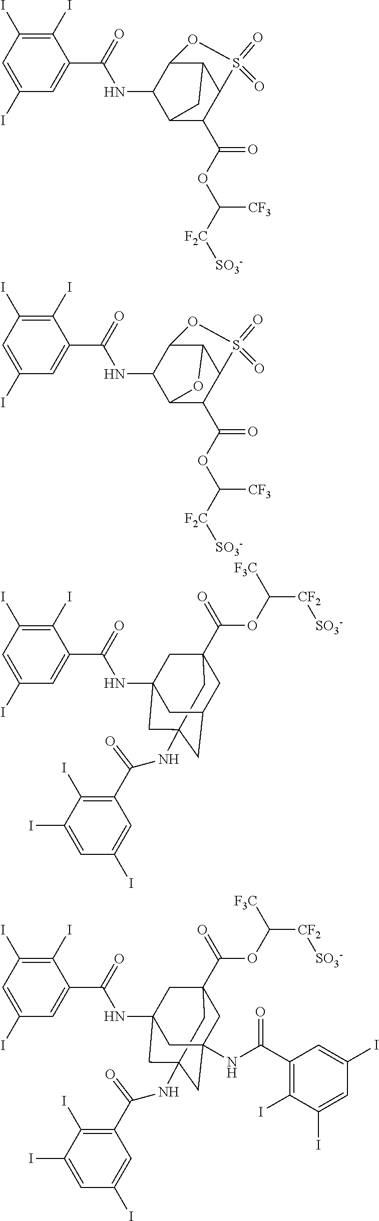

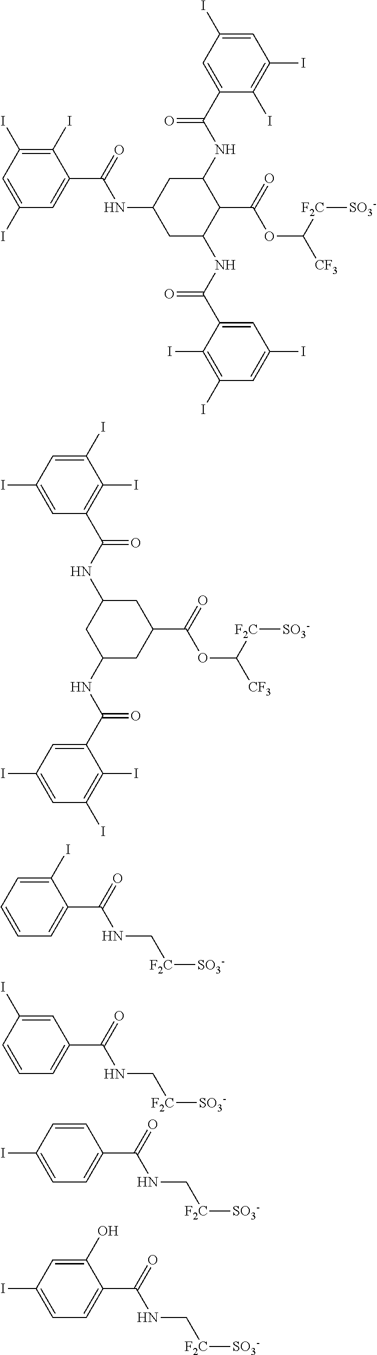

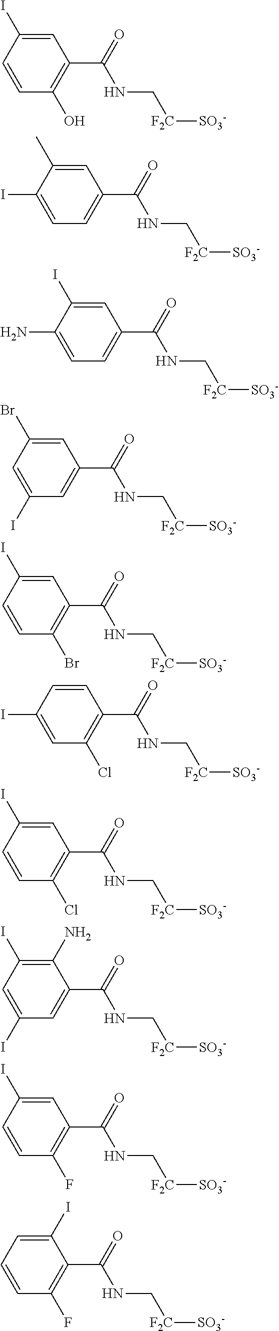

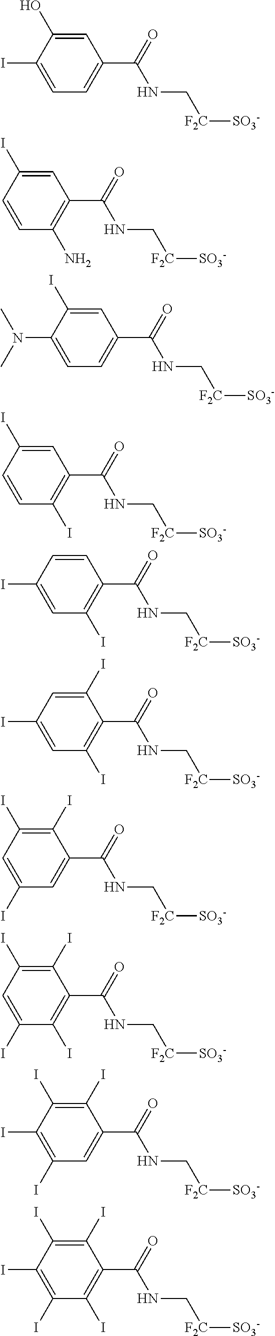

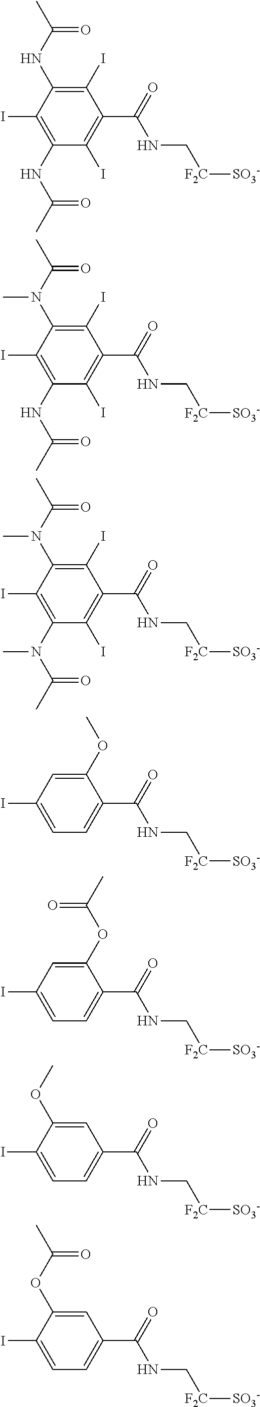

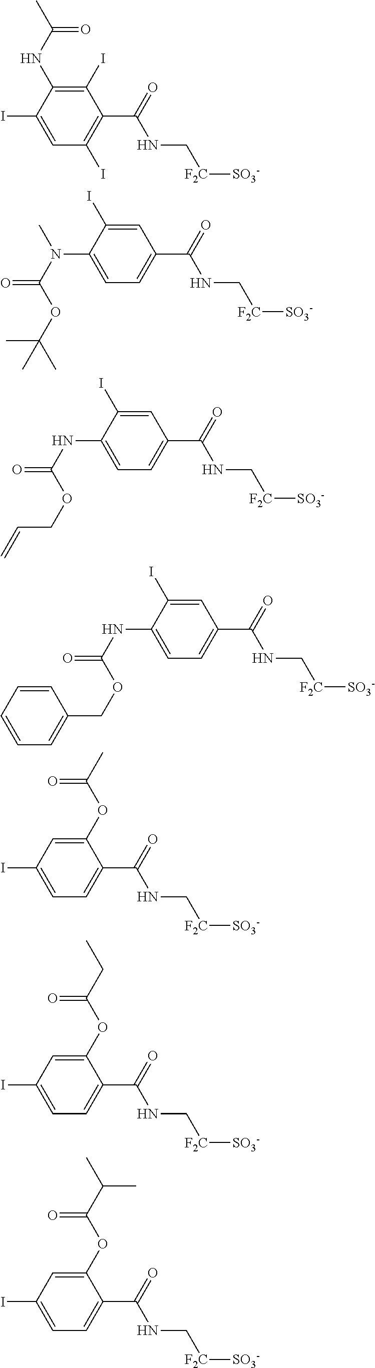

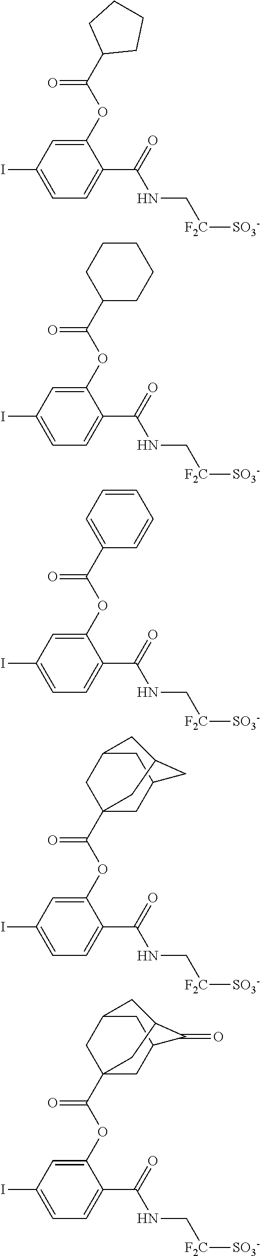

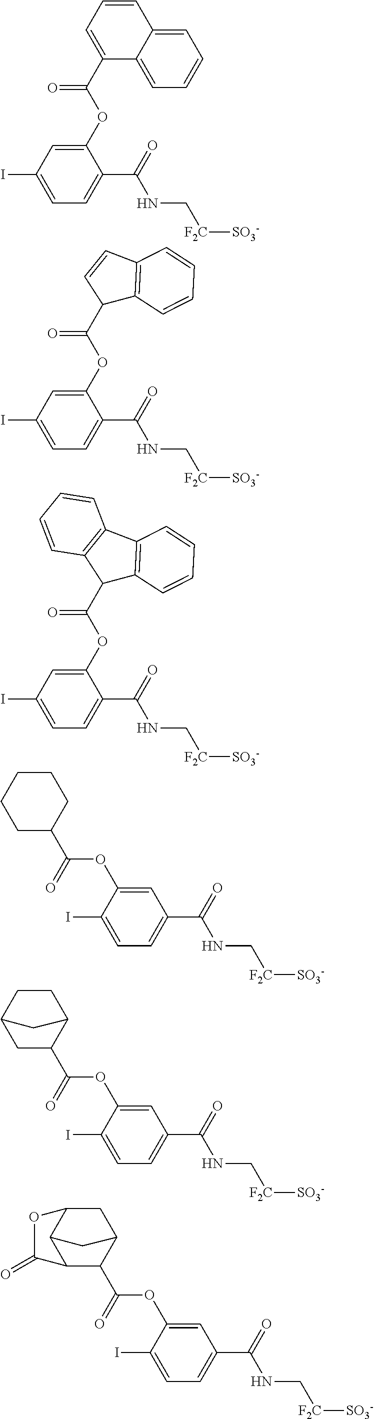

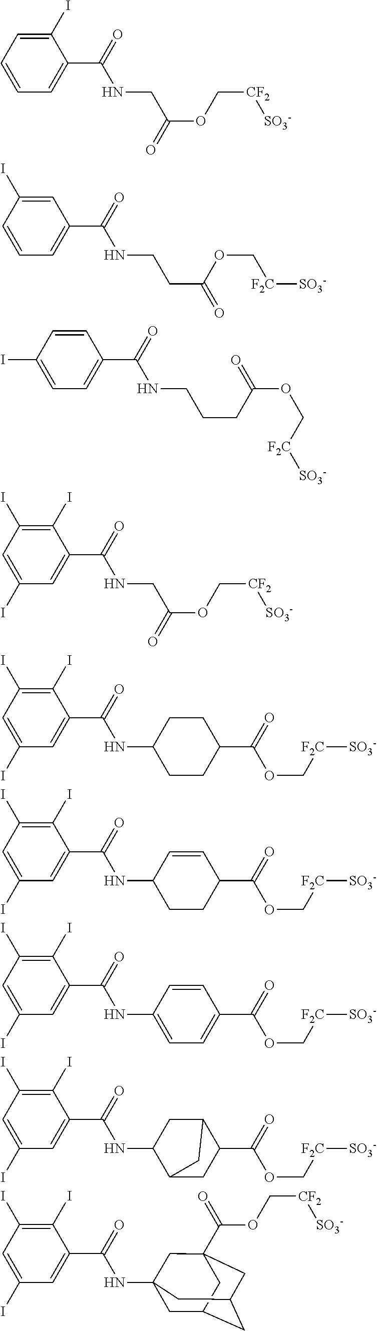

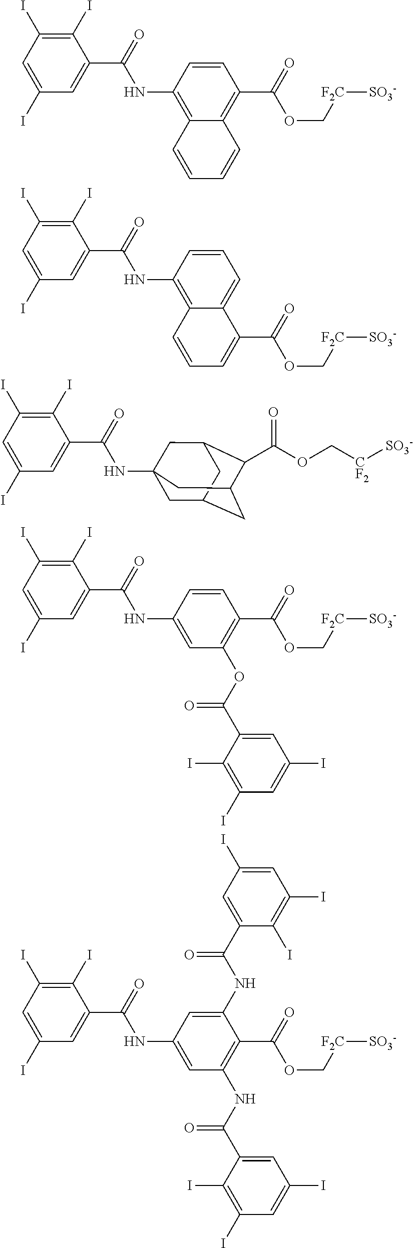

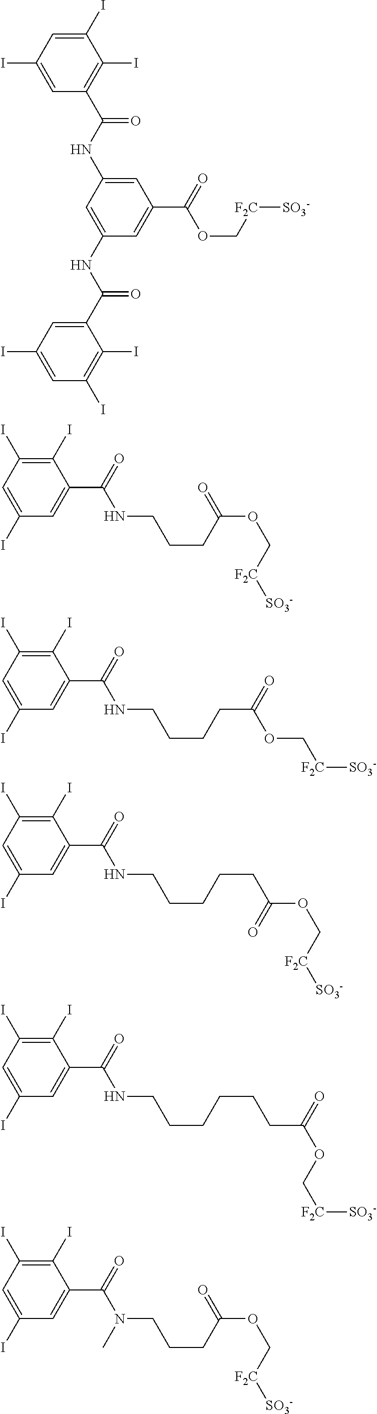

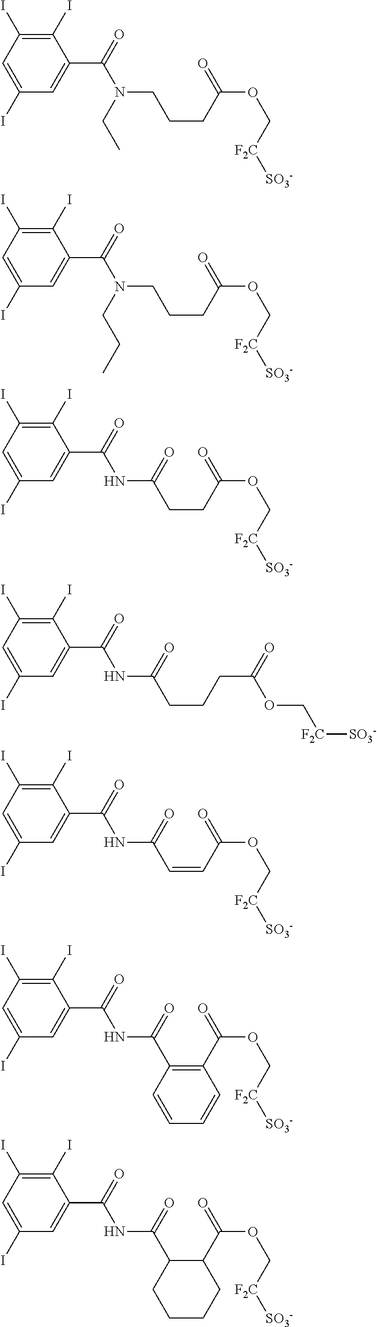

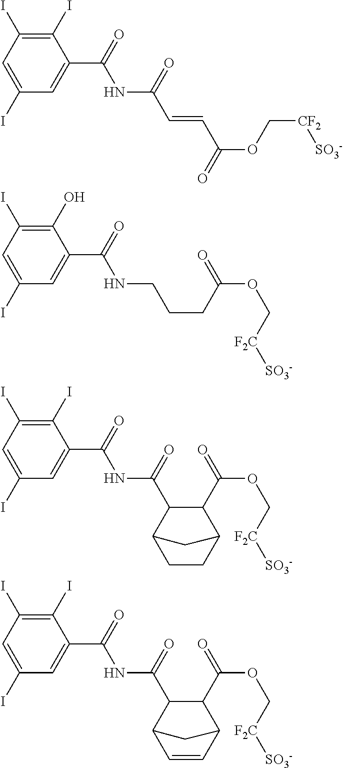

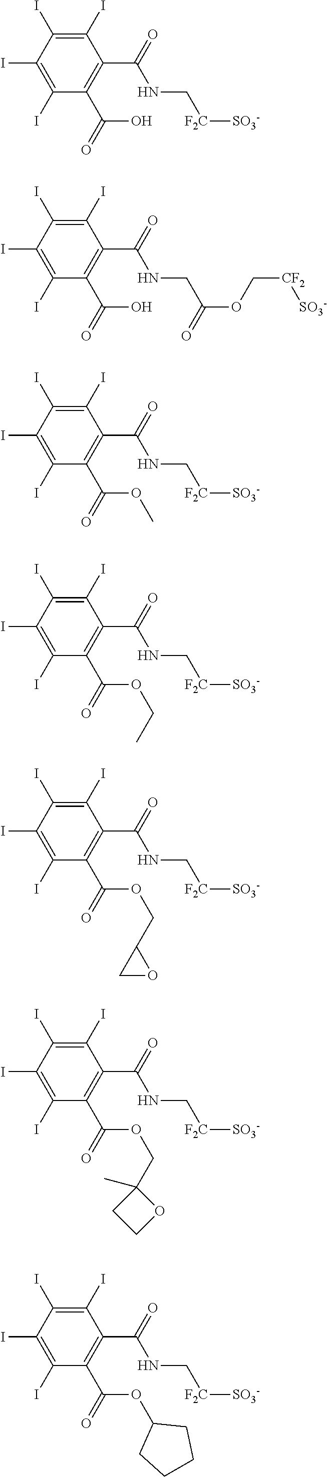

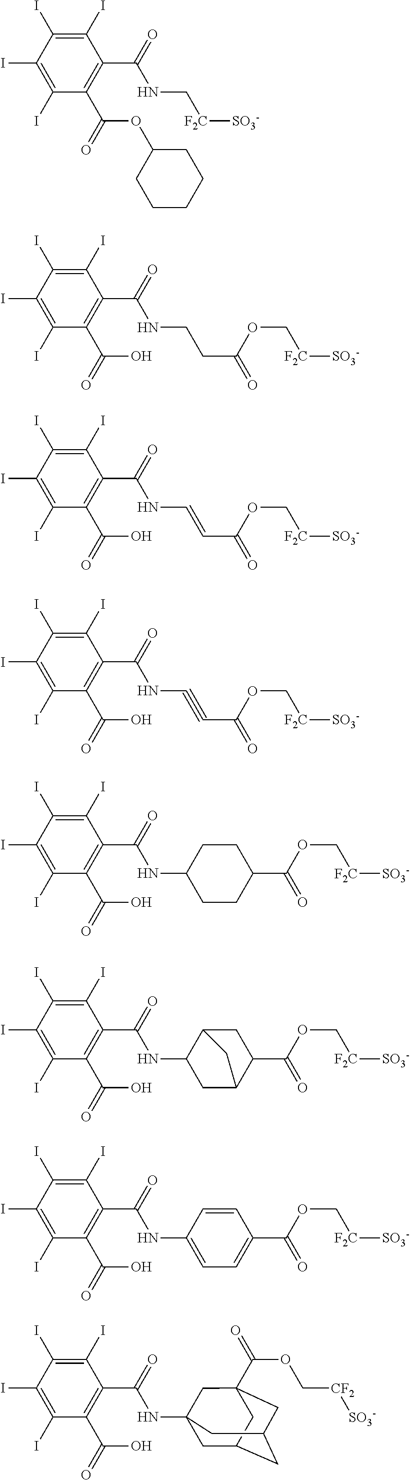

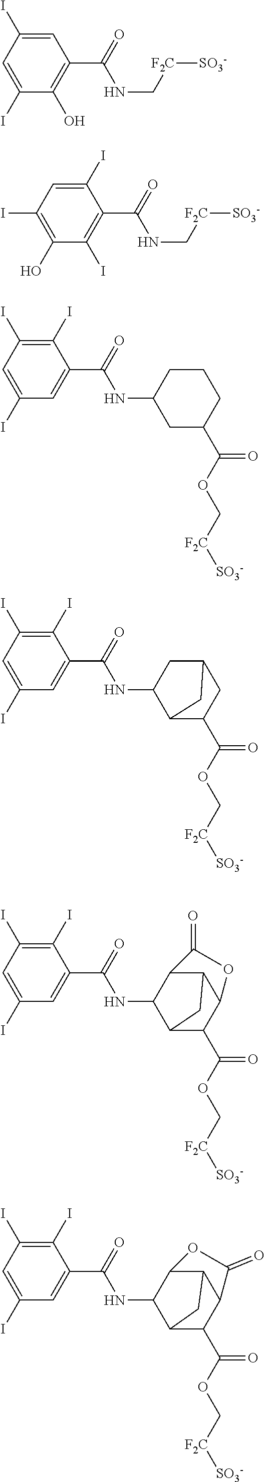

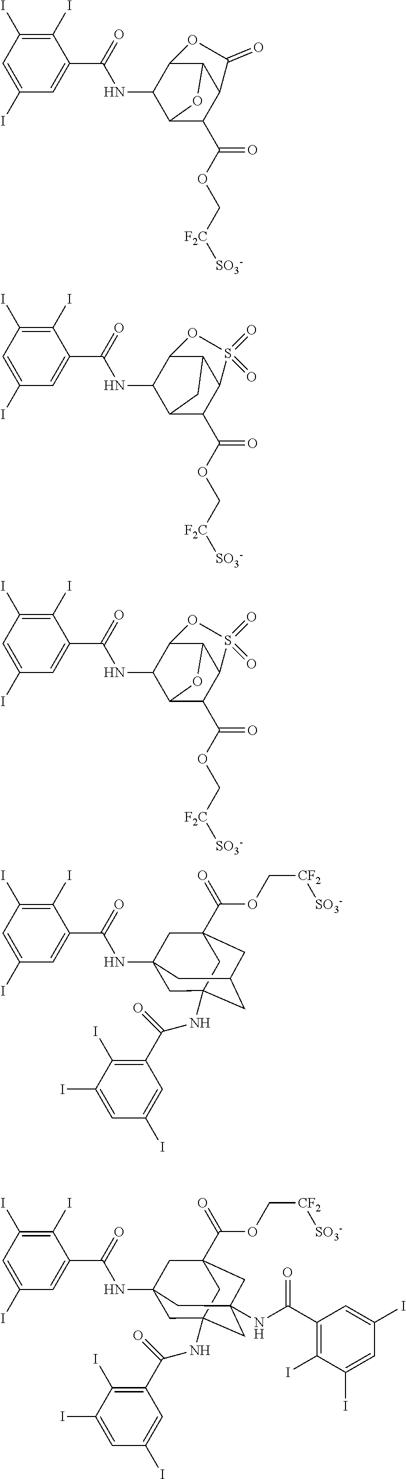

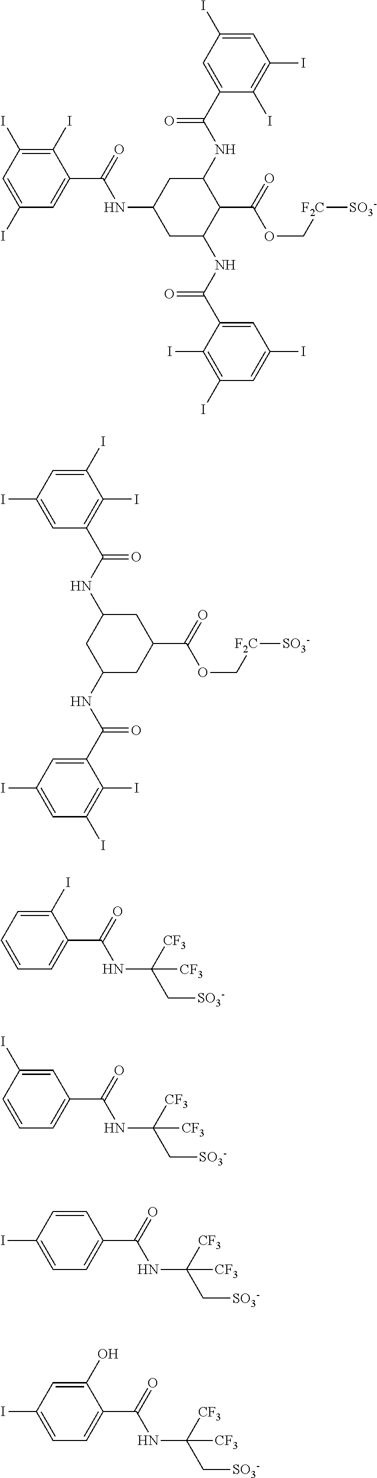

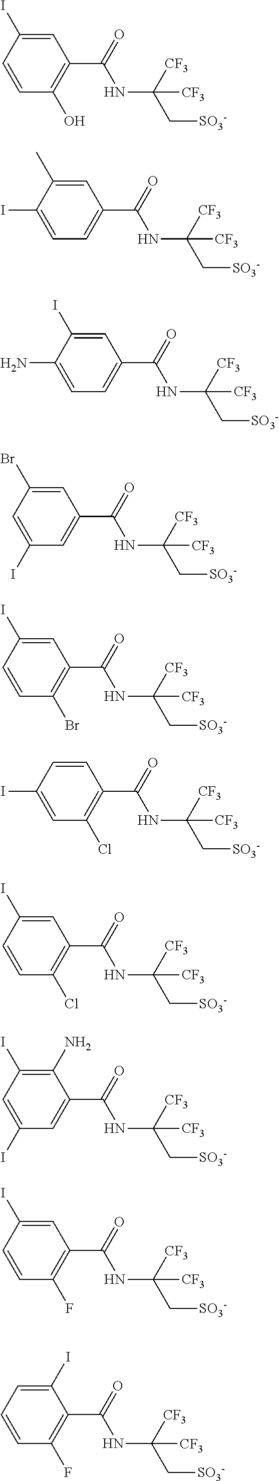

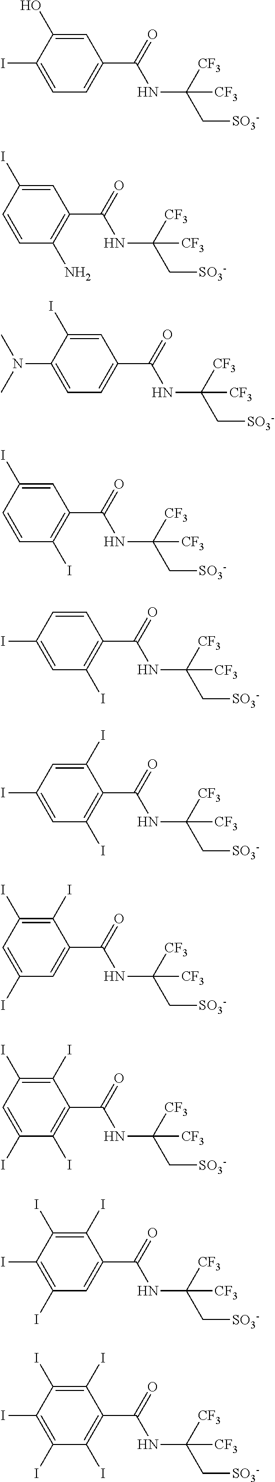

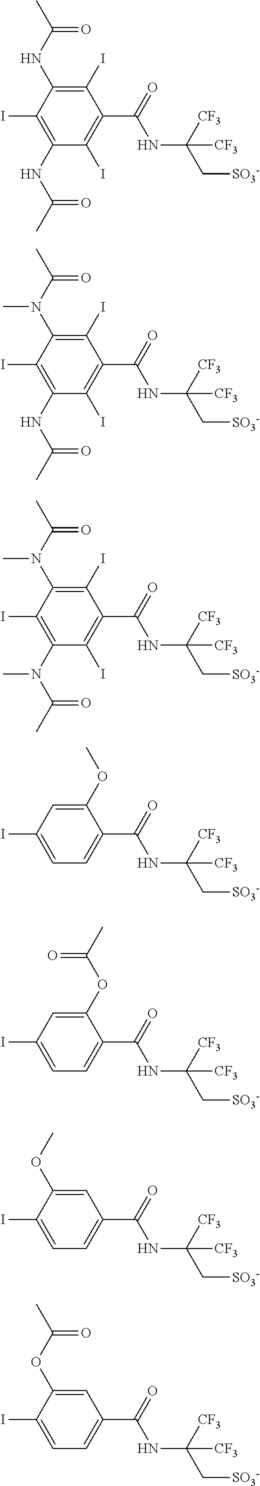

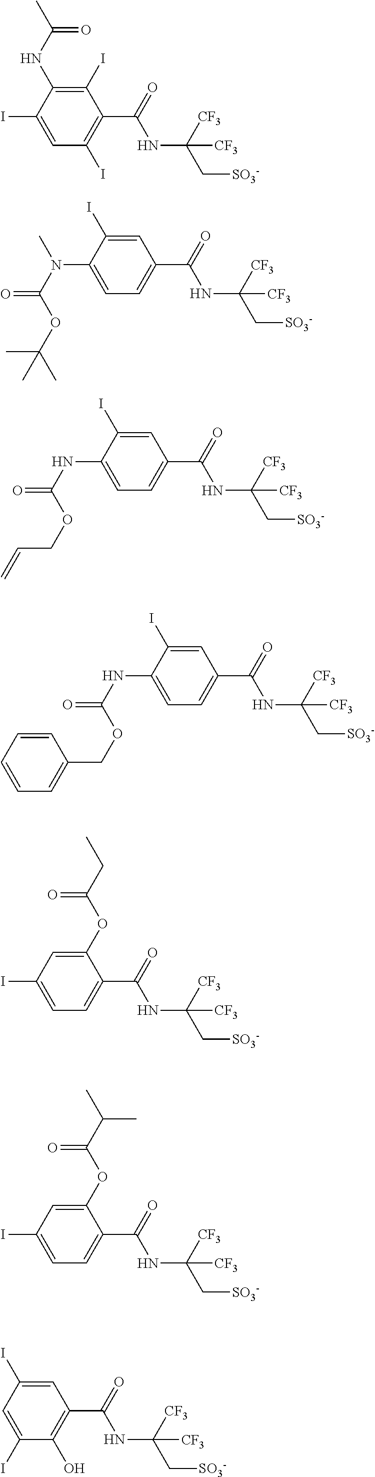

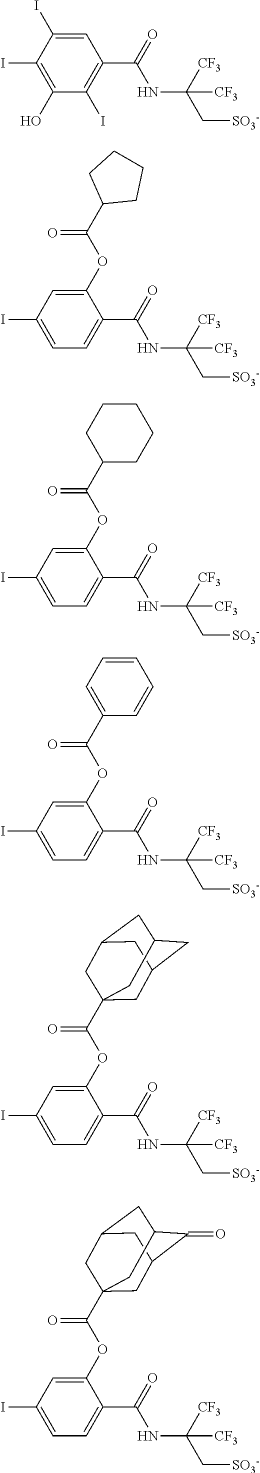

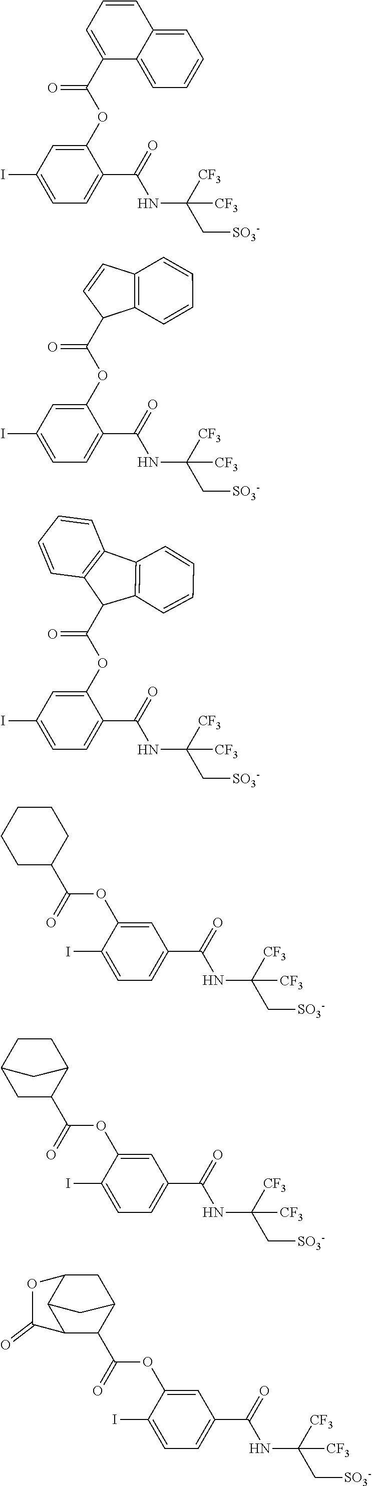

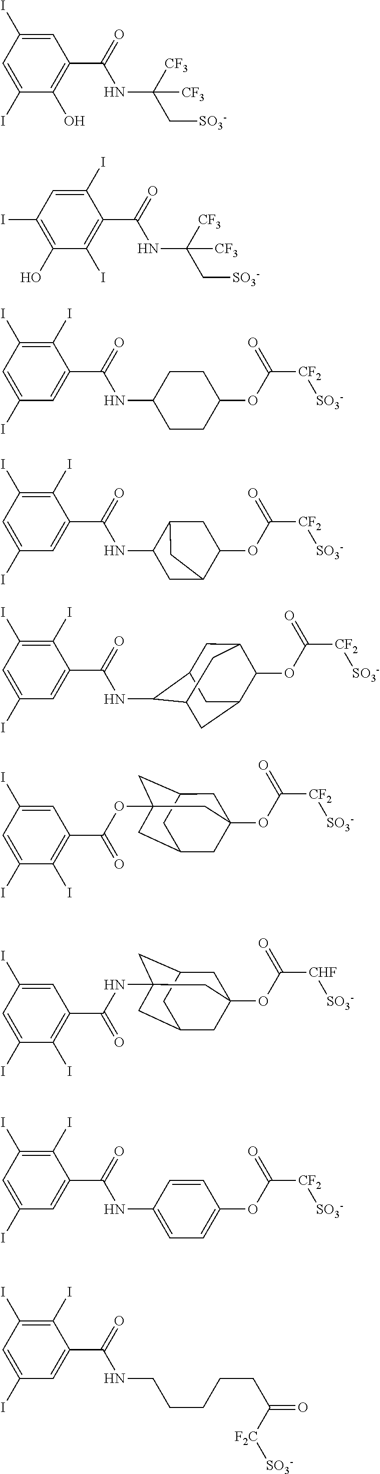

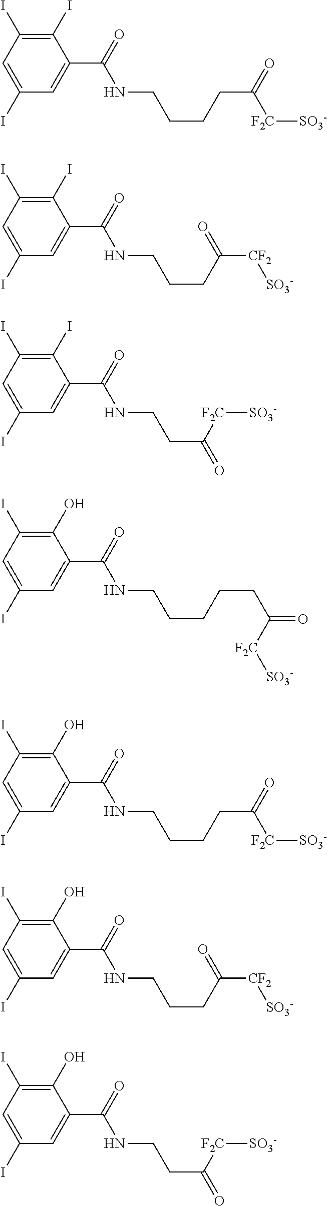

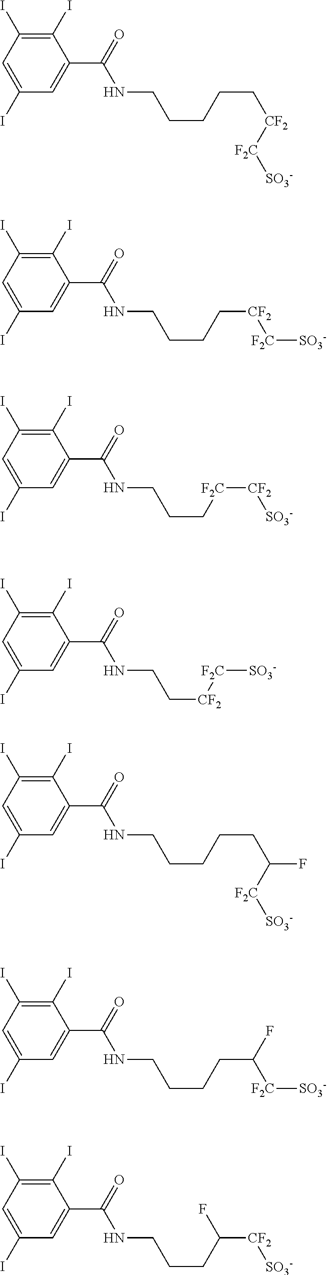

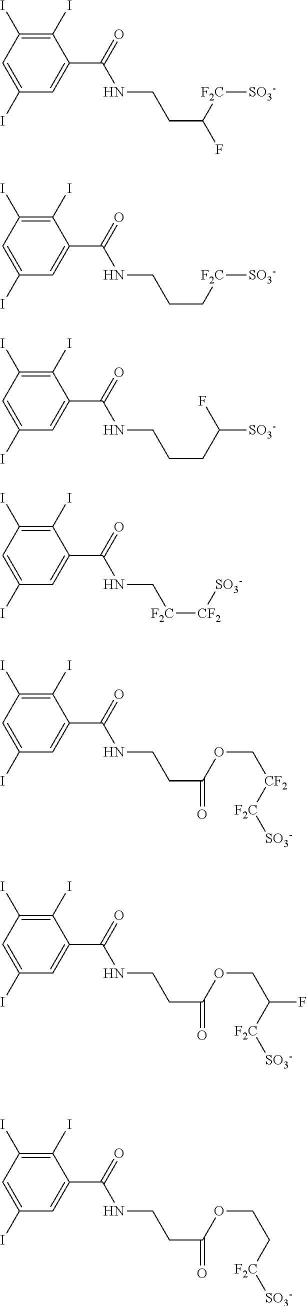

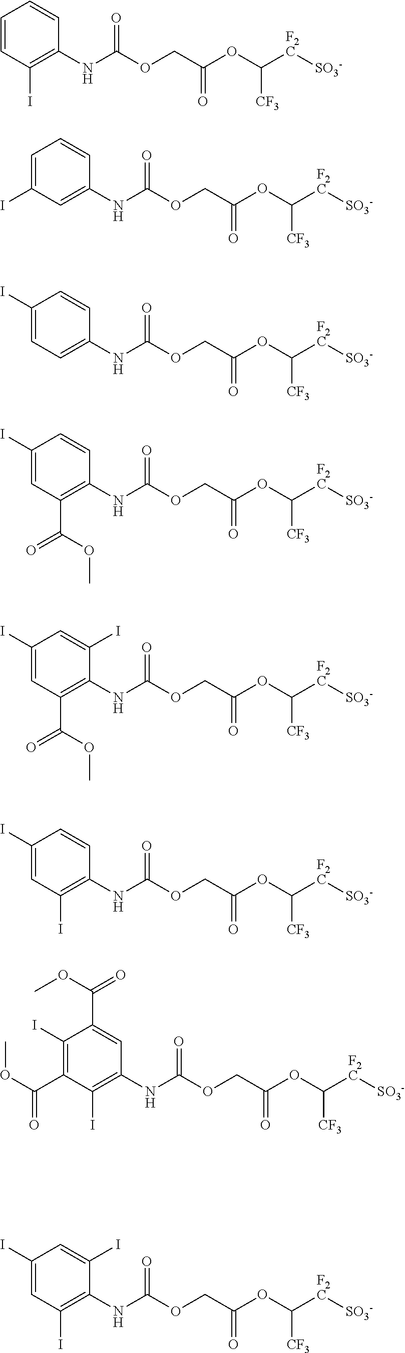

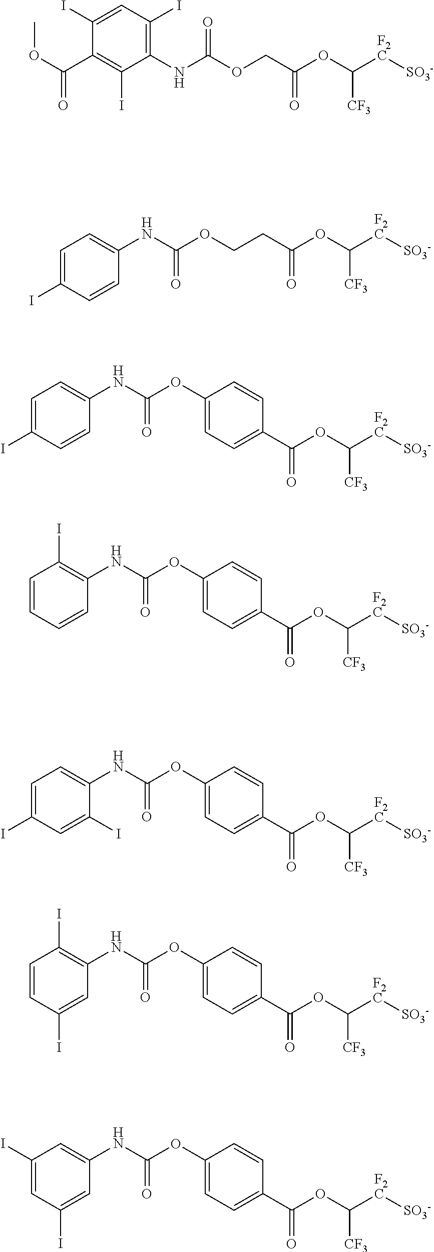

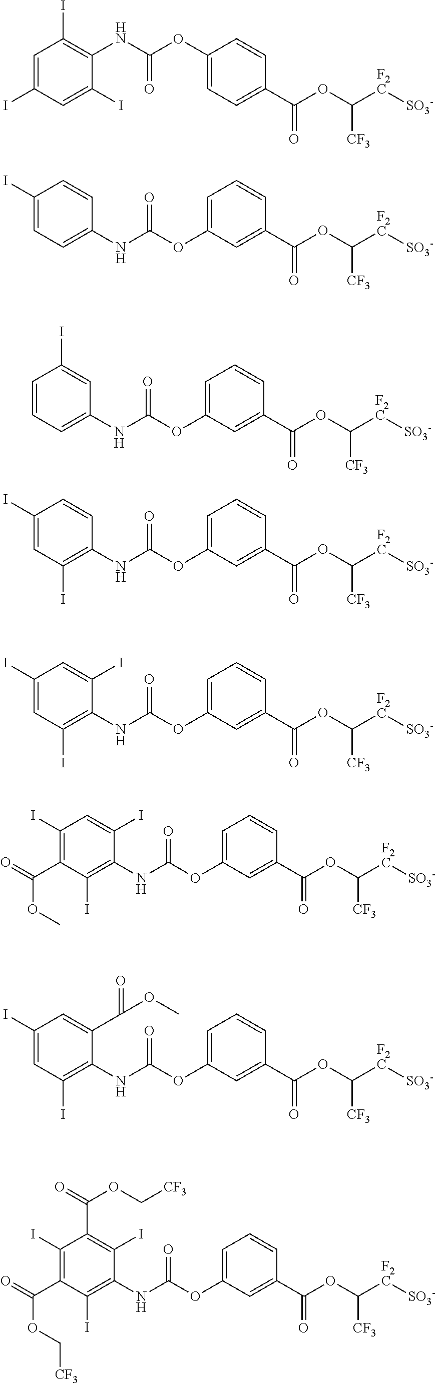

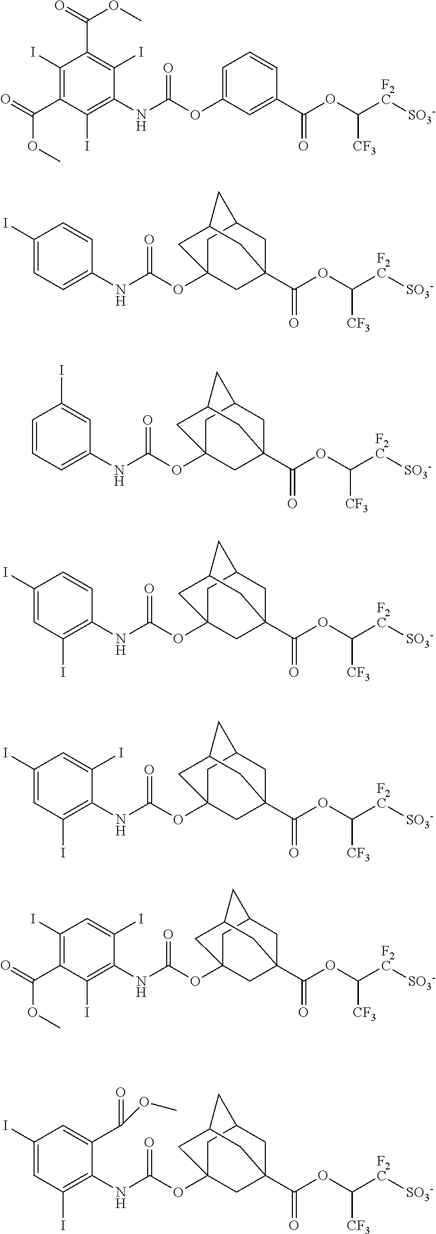

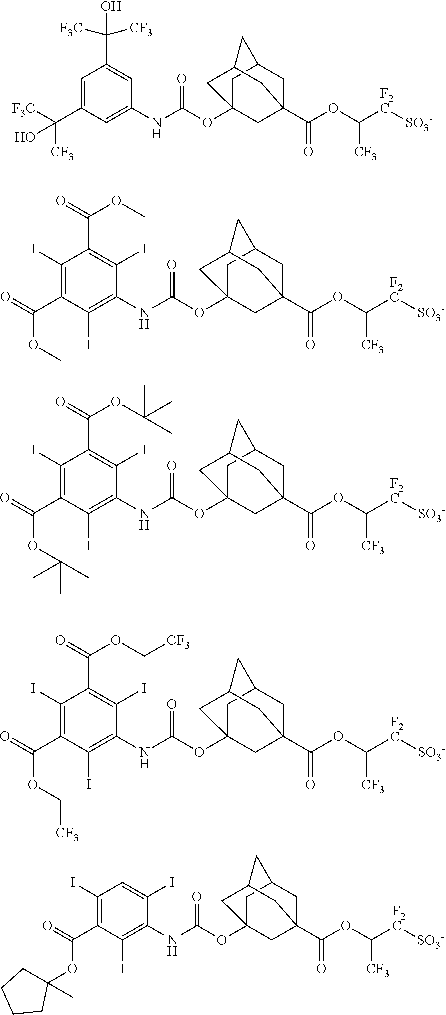

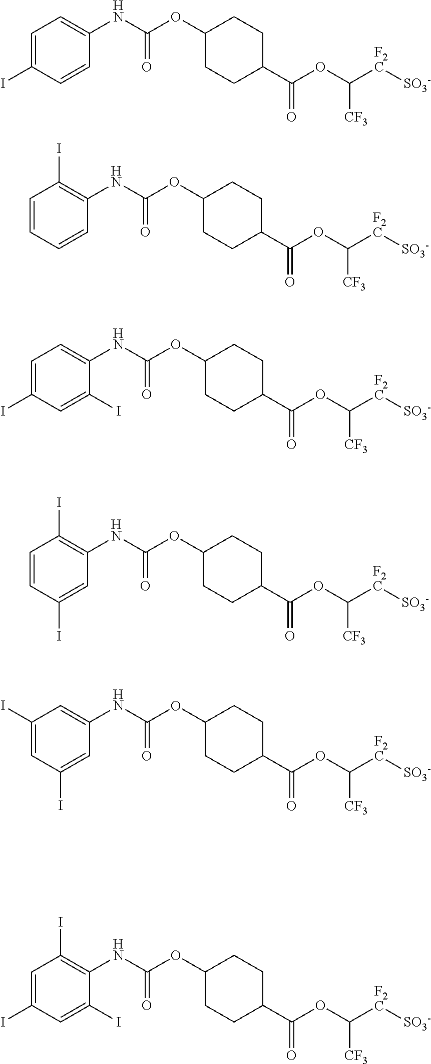

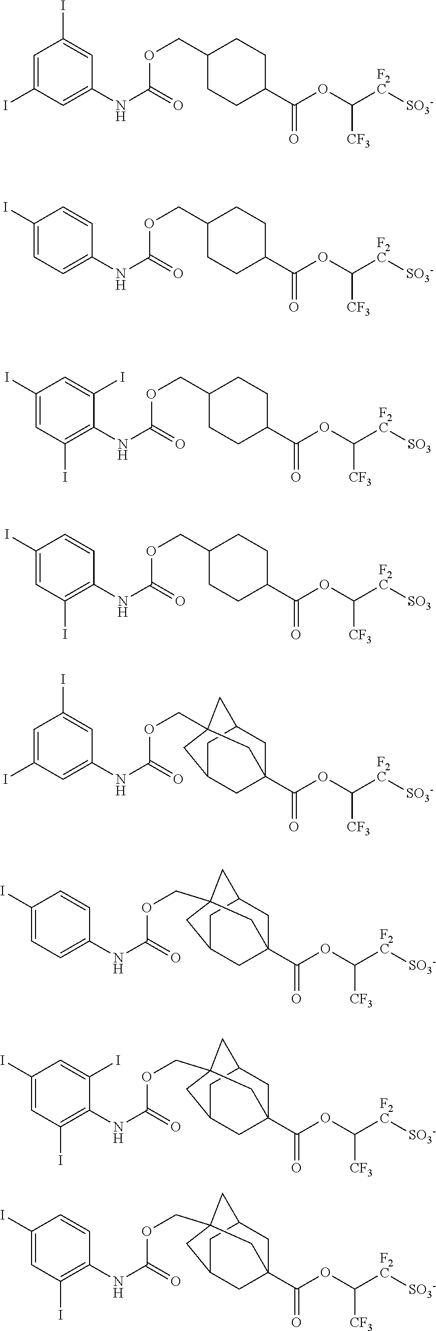

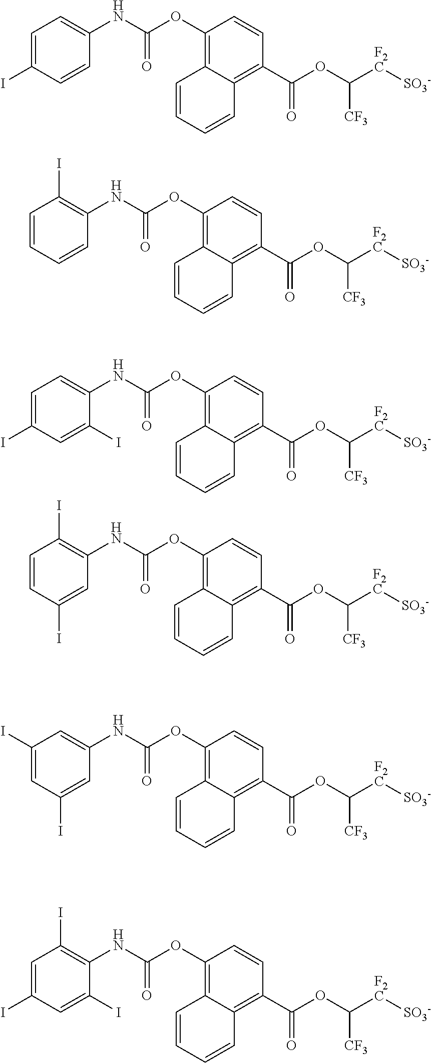

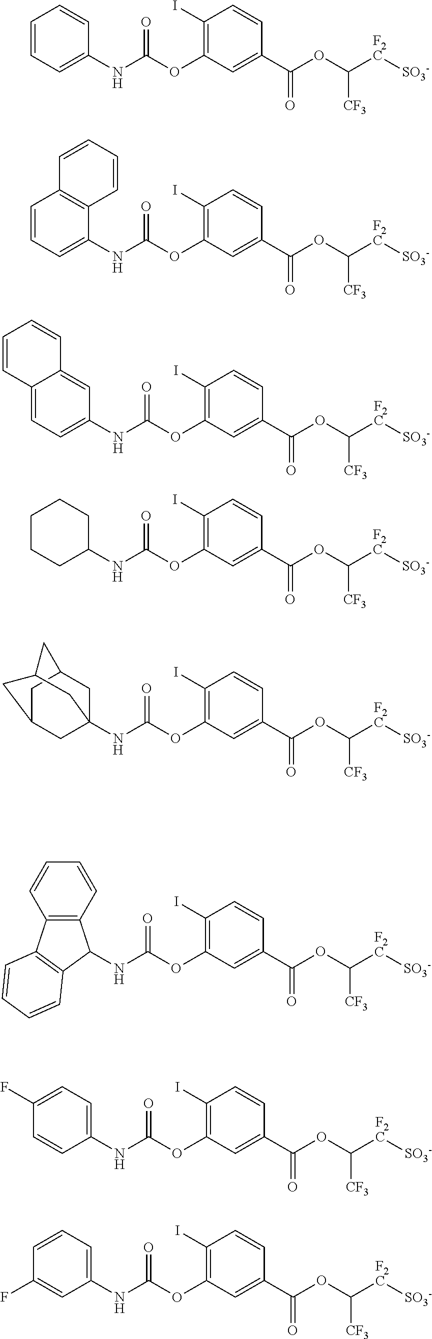

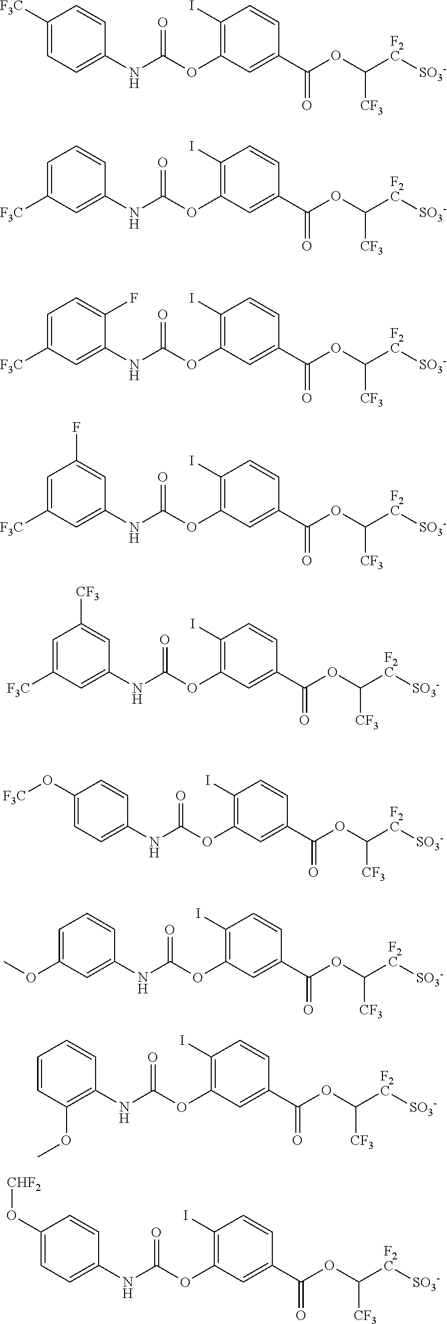

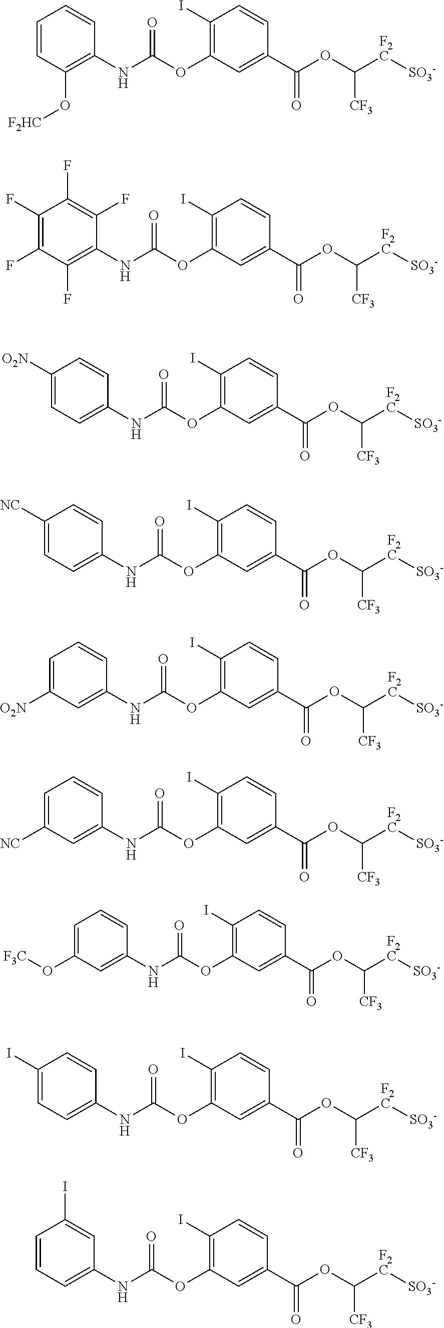

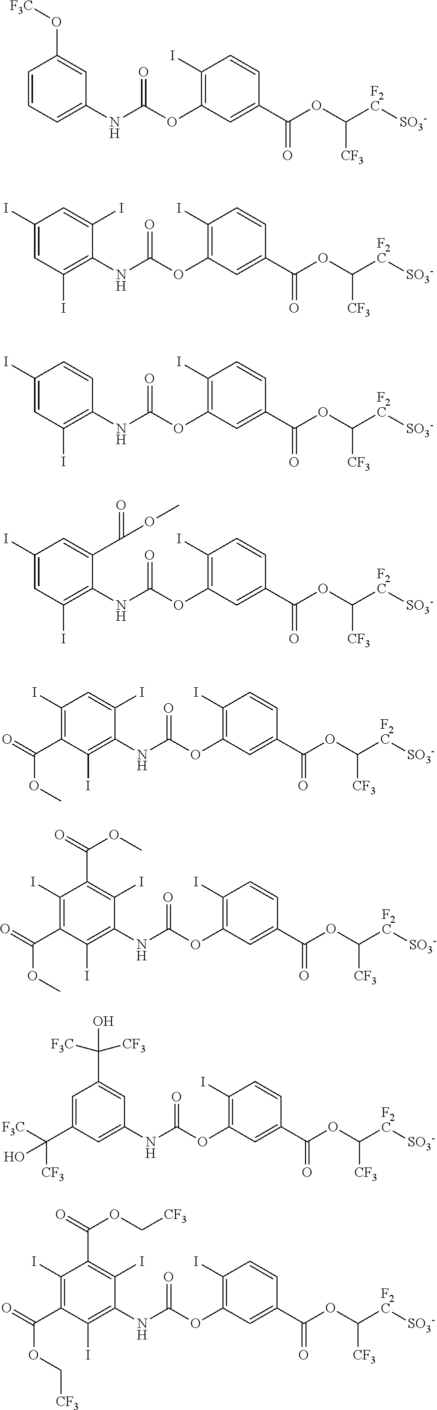

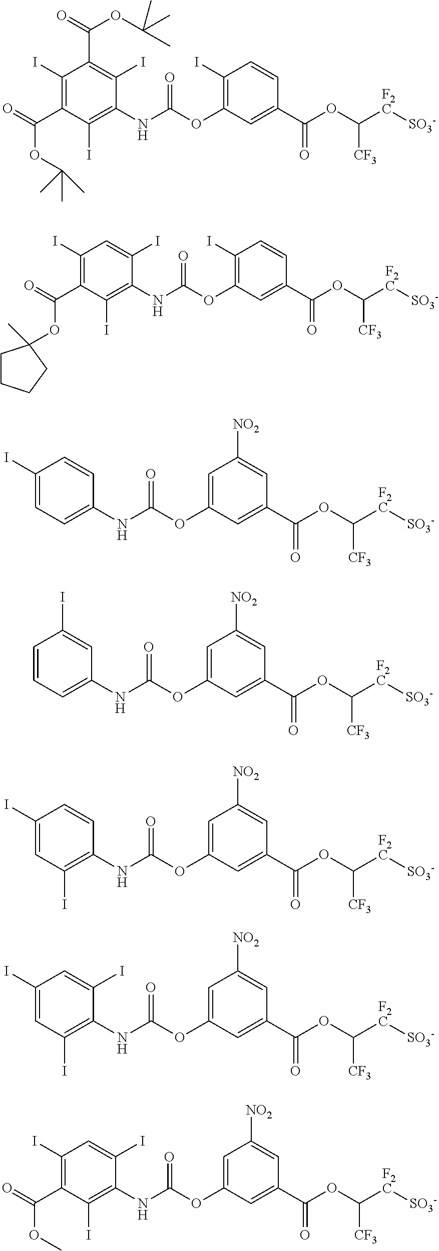

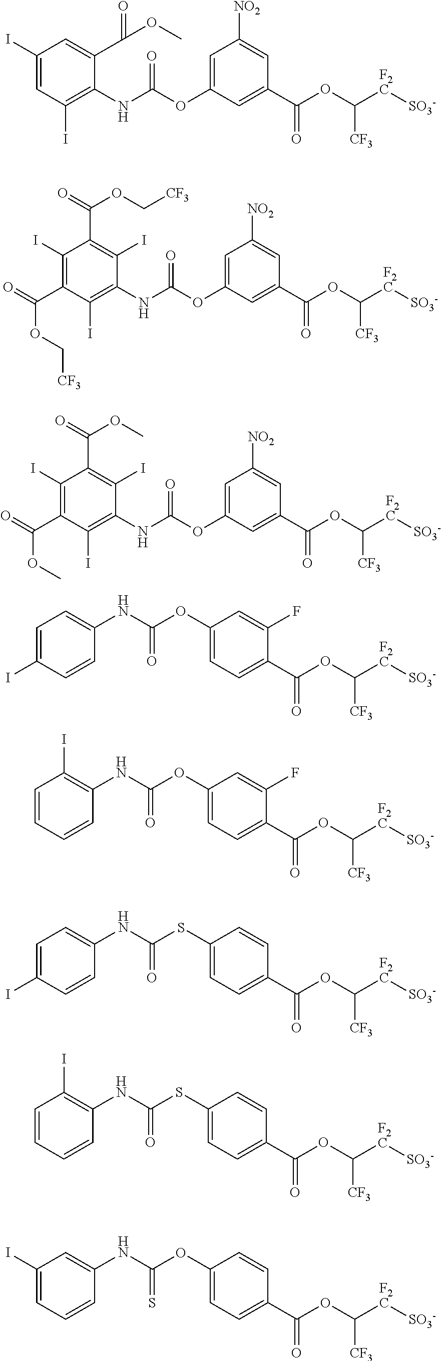

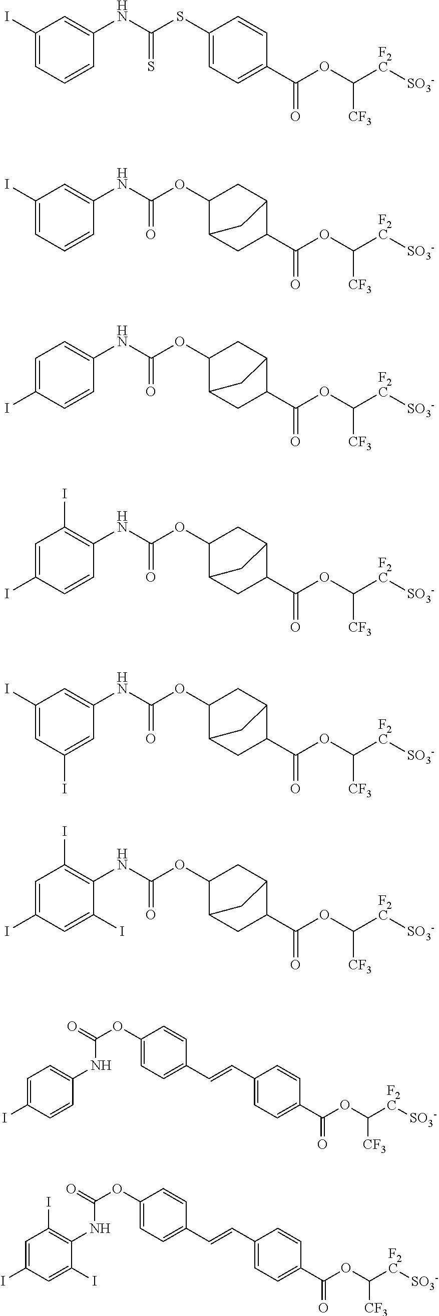

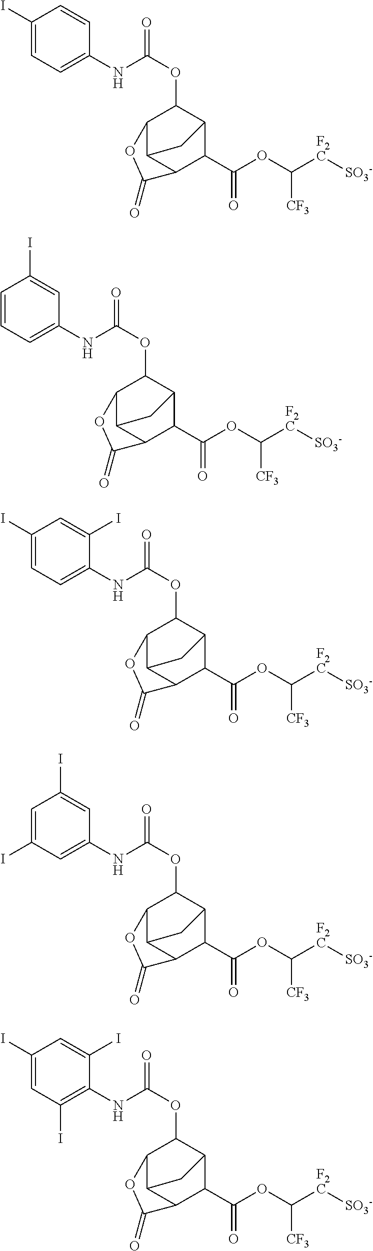

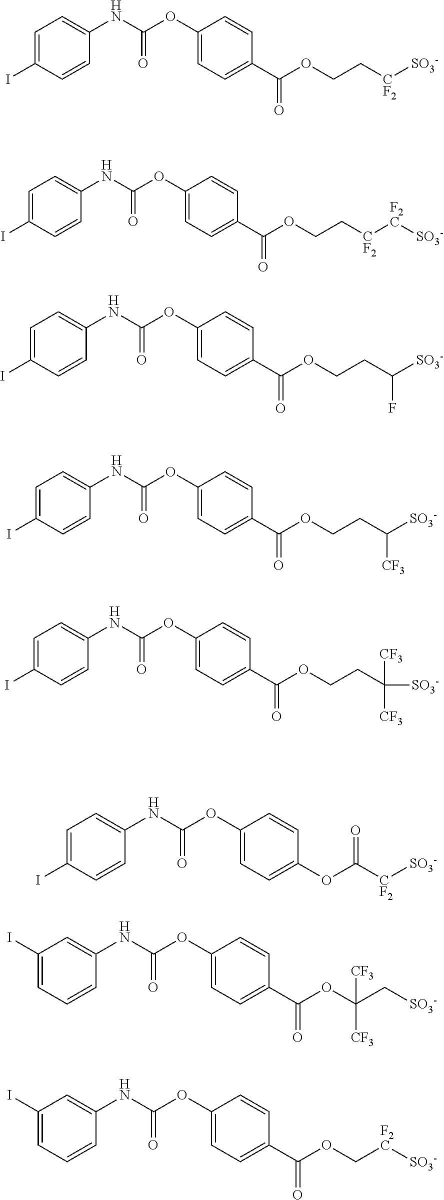

As the sulfonate anion having a carbon atom to which an iodine atom is bonded, the iodine atom-containing anion described in Patent Documents 11 to 16 can also be used.

Examples of the method for synthesizing the sulfonium salt include a method in which a sulfonium salt having the sulfonium cation described above is ion-exchanged with an ammonium salt having the anion described above. The sulfonium cation described above can be obtained, for example, by reaction of a dibenzothiophene compound having a hydrocarbylcarbonyl group or a hydrocarbyloxycarbonyl group with a diphenyliodonium salt.

In the resist composition of the present invention, the sulfonium salt having the formula (1) is preferably added in an amount of 0.01 to 1000 parts by weight, and more preferably 0.05 to 500 parts by weight per 100 parts by weight of the base polymer described later in view of sensitivity and an effect of suppressing acid diffusion.

Base Polymer

The base polymer contained in the resist composition of the present invention comprises repeat units containing an acid labile group when the resist composition is a positive resist composition. The repeat units containing an acid labile group are preferably repeat units having the formula (a1) (hereinafter, the repeat units are also referred to as repeat units a1) or repeat units having the formula (a2) (hereinafter, the repeat units are also referred to as repeat units a2).

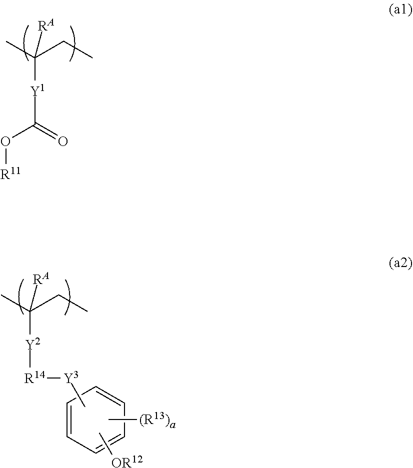

In the formulae (a1) and (a2). R^{A} is independently a hydrogen atom or a methyl group. Y¹ is a single bond, a phenylene group, a naphthylene group, or a C₁-C₁₂ linking group containing at least one moiety selected from an ester bond, an ether bond and a lactone ring. Y² is a single bond or an ester bond. Y³ is a single bond, an ether bond, or an ester bond. R¹¹ and R¹² are each independently an acid labile group. R¹³ is a C₁-C₄ saturated hydrocarbyl group, a halogen atom, a C₂-C₅ saturated hydrocarbylcarbonyl group, a cyano group, or a C₂-C₅ saturated hydrocarbyloxycarbonyl group. R¹⁴ is a single bond or a C₁-C₆ alkanediyl group which may contain an ether bond or an ester bond, a is an integer of 0 to 4.

Examples of the monomer from which repeat units a1 are derived are shown below, but not limited thereto. In the formulae, R^{A} and R¹¹ are the same as described above.

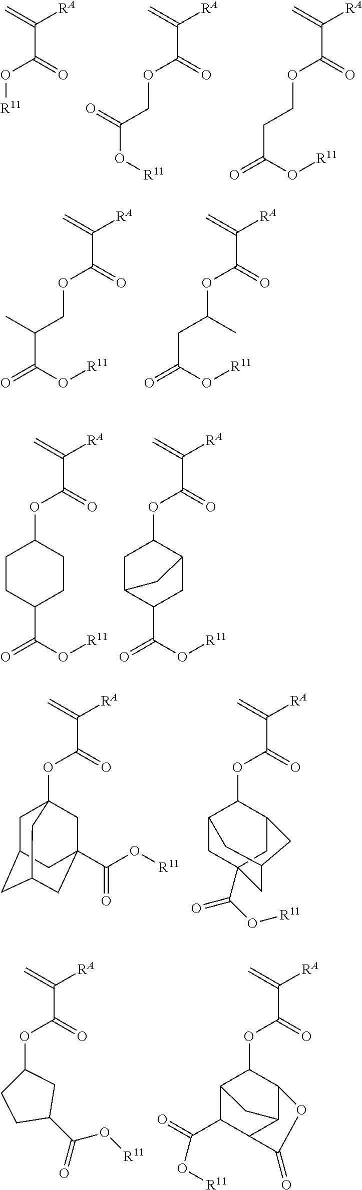

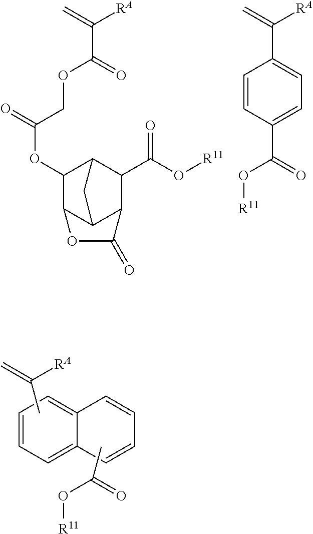

Examples of the monomer from which repeat units a2 are derived are shown below, but not limited thereto. In the formulae, R^{A} and R¹² are the same as described above.

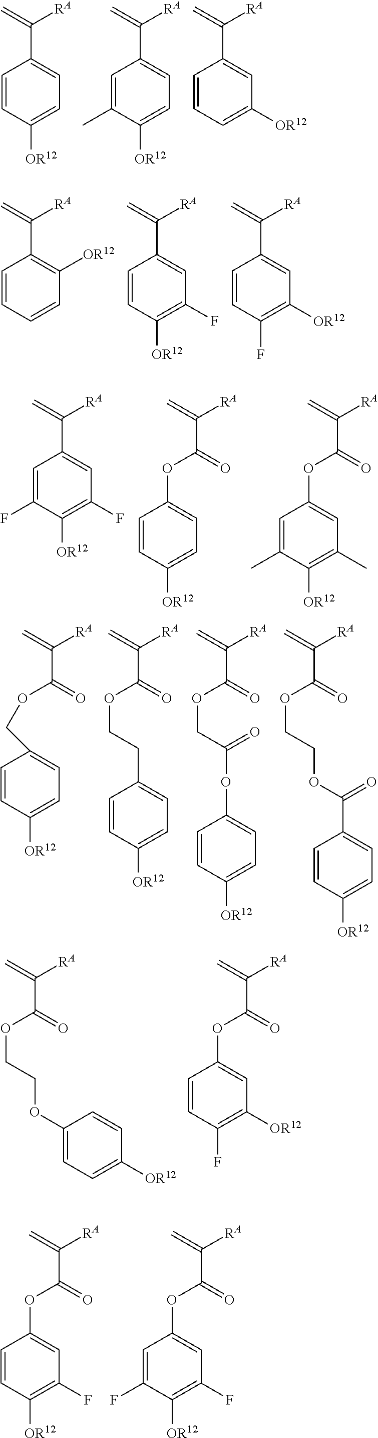

Examples of the acid labile group of R¹¹ and R¹² in the formulae (a1) and (a2) include those described in JP-A 2013-80033 and JP-A 2013-83821.

Typically, examples of the acid labile group include those having the formulas (AL-1) to (AL-3).

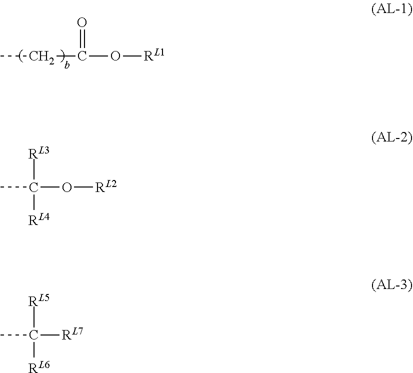

In the formulae, the broken line is a valence bond.

In the formulas (AL-1) and (AL-2), R^{L1} and R^{L2} are each independently a C₁-C₄₀ hydrocarbyl group which may contain a heteroatom such as an oxygen atom, a sulfur atom, a nitrogen atom and a fluorine atom. The hydrocarbyl group may be saturated or unsaturated, and may be linear, branched, or cyclic. As the hydrocarbyl group, a C₁-C₄₀ saturated hydrocarbyl group is preferred, and a C₁-C₂₀ saturated hydrocarbyl group is more preferred.

In the formula (AL-1), b is an integer of 0 to 10, preferably an integer of 1 to 5.

In the formula (AL-2), R^{L3} and R^{L4} are each independently a hydrogen atom or a C₁-C₂₀ hydrocarbyl group which may contain a heteroatom such as an oxygen atom, a sulfur atom, a nitrogen atom, or a fluorine atom. The hydrocarbyl group may be saturated or unsaturated, and may be linear, branched, or cyclic. The hydrocarbyl group is preferably a C₁-C₂₀ saturated hydrocarbyl group. Any two of R^{L2}, R^{L3}, and R^{L4} may bond together to form a C₃-C₂₀ ring with the carbon atom or the carbon atom and the oxygen atom to which they are attached. The ring is preferably a C₄-C₁₆ ring, and particularly preferably an alicyclic ring.

In the formula (AL-3), R^{L5}, R^{L6} and R^{L7} are each independently a C₁-C₂₀ hydrocarbyl group which may contain a heteroatom such as an oxygen atom, a sulfur atom, a nitrogen atom, or a fluorine atom. The hydrocarbyl group may be saturated or unsaturated, and may be linear, branched, or cyclic. The hydrocarbyl group is preferably a C₁-C₂₀ saturated hydrocarbyl group. Any two of R^{L5}, R^{L6} and R^{L7} may bond together to form a C₃-C₂₀ ring with the carbon atom to which they are attached. The ring is preferably a C₄-C₁₆ ring, and particularly preferably an alicyclic ring.

The base polymer may contain repeat units b containing a phenolic hydroxy group as an adhesive group. Examples of the monomer from which repeat units b are derived are shown below, but not limited thereto. In the formulae, R^{A} is the same as described above.

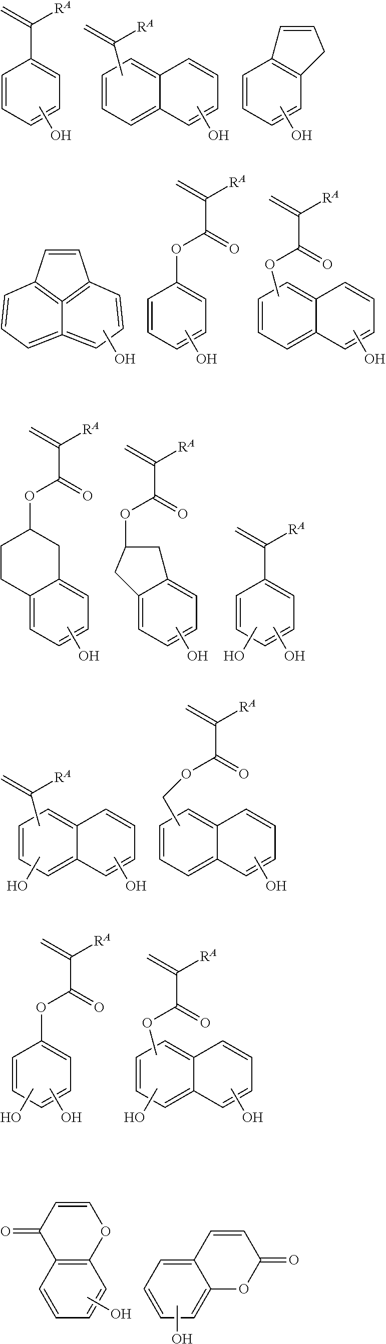

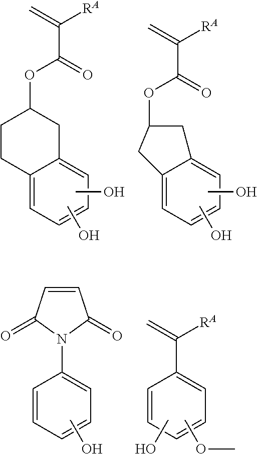

The base polymer may contain, as another adhesive group, repeat units c containing a hydroxy group other than a phenolic hydroxy group, a lactone ring, a sultone ring, an ether bond, an ester bond, a sulfonic acid ester bond, a carbonyl group, a sulfonyl group, a cyano group, or a carboxy group. Examples of the monomer from which repeat units c are derived are shown below, but not limited thereto. In the formulae, R^{A} is the same as described above.

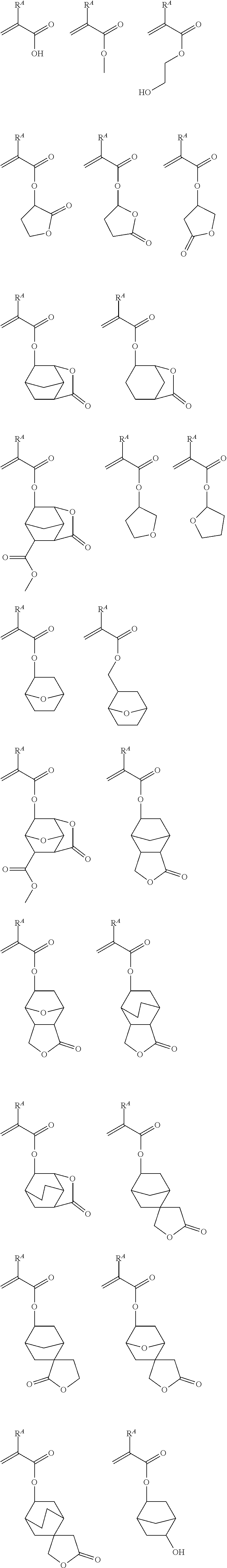

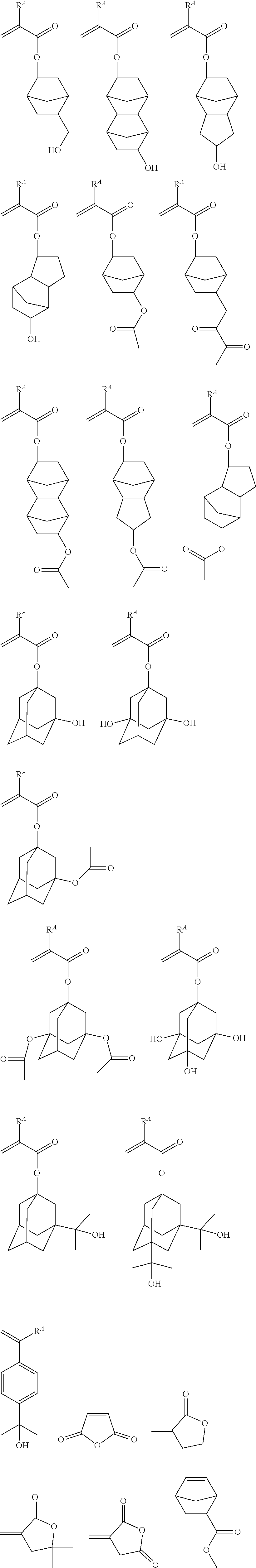

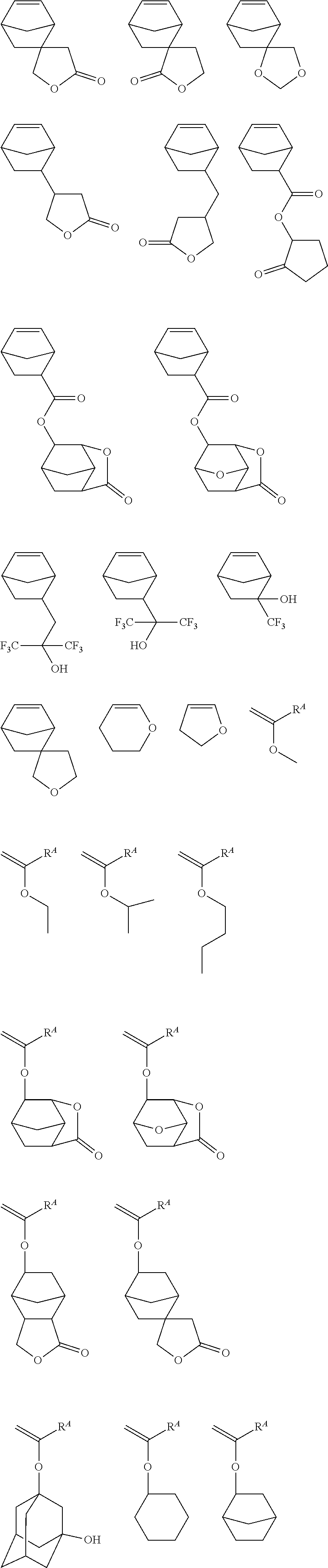

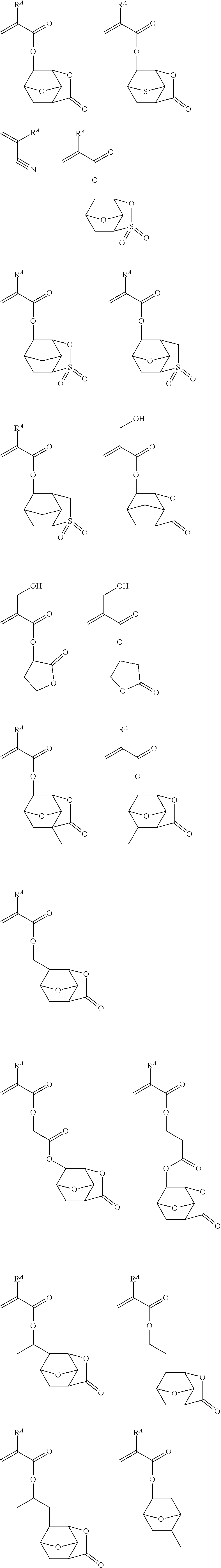

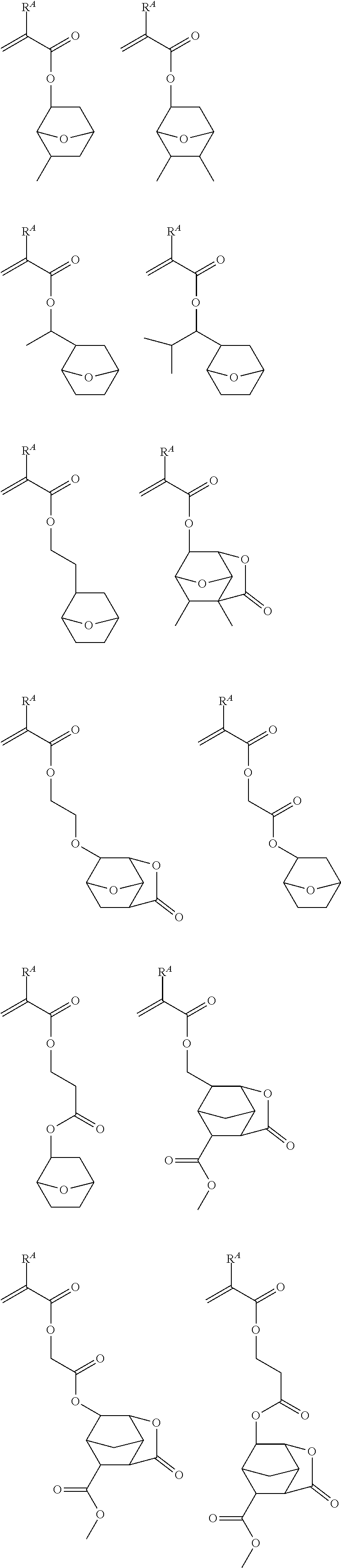

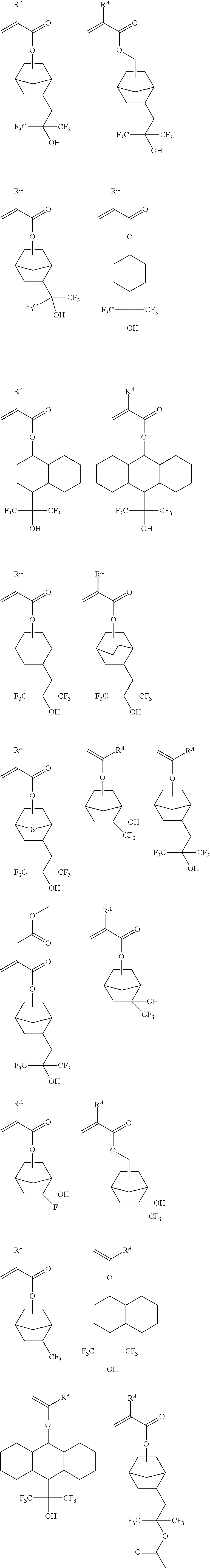

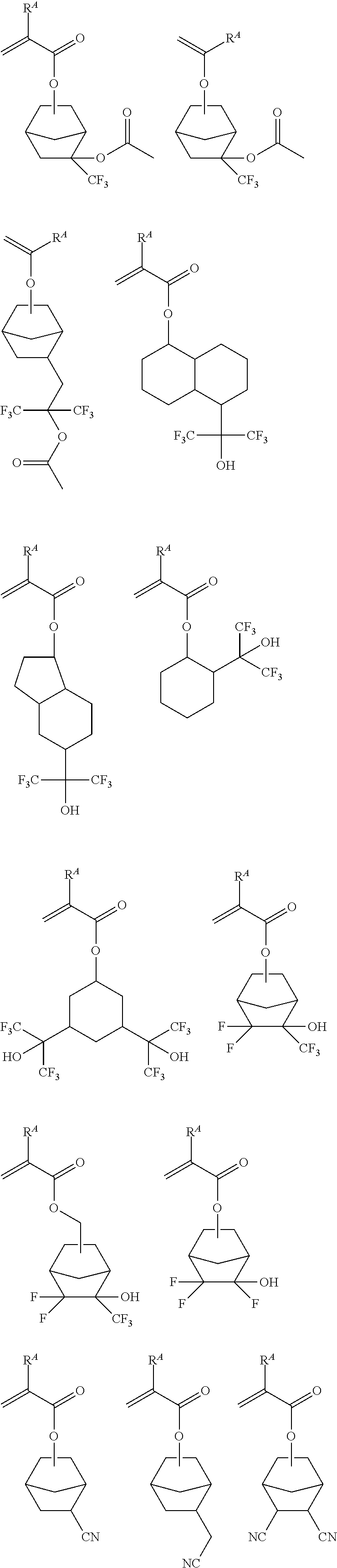

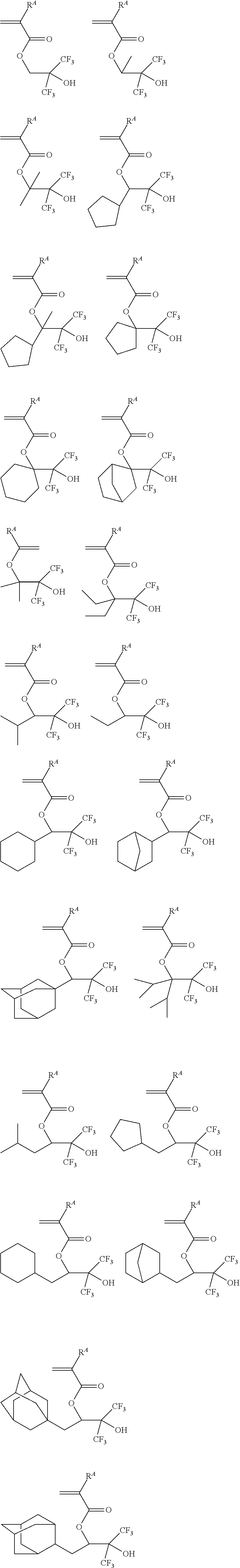

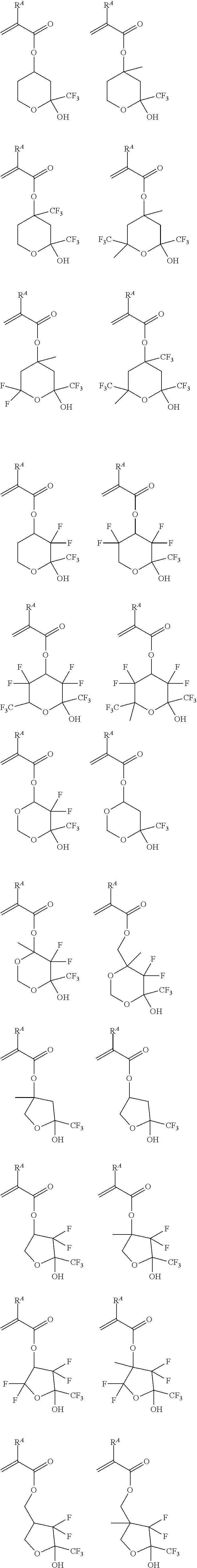

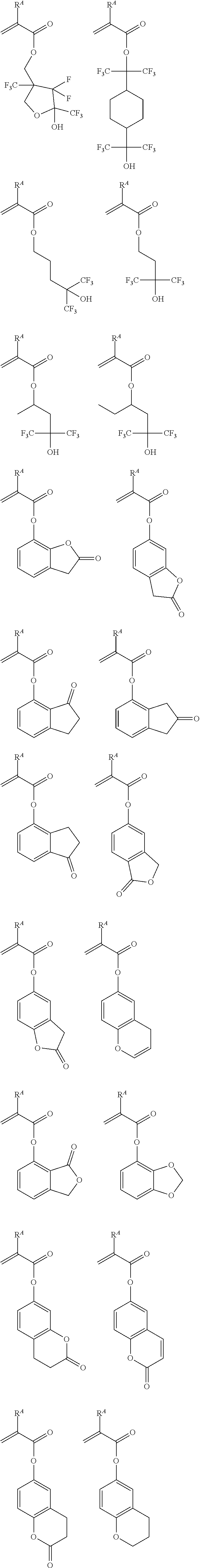

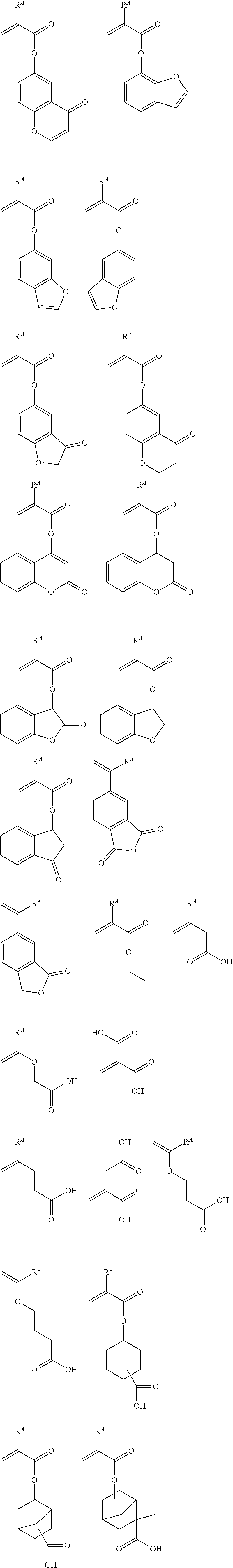

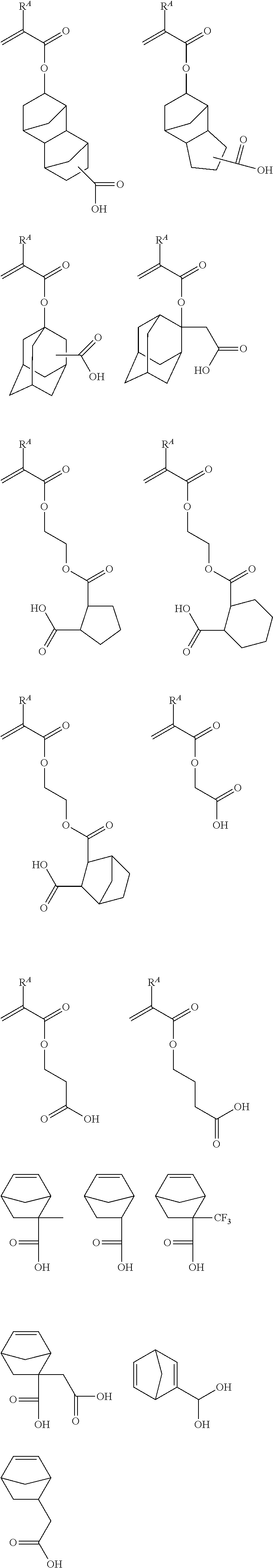

The base polymer may further comprise repeat units d derived from styrene, indene, benzofuran, benzothiophene, acenaphthylene, chromone, coumarin, norbornadiene, or derivatives thereof. Examples of the monomer from which repeat units d are derived are shown below, but not limited thereto. In the formulae, R^{A} is the same as described above.

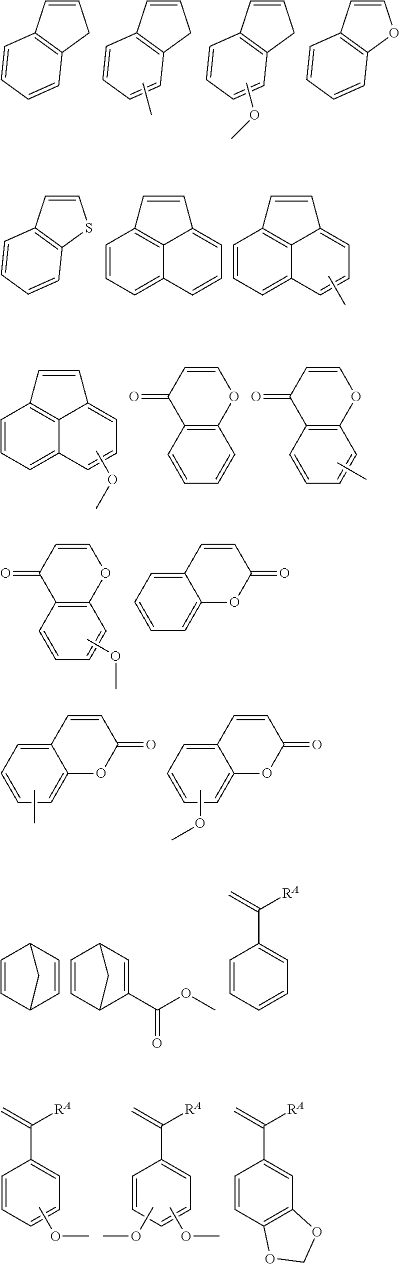

The base polymer may further comprise repeat units e derived from vinylnaphthalene, vinylanthracene, vinylpyrene, methylene indane, vinylpyridine, or vinylcarbazole.

The base polymer may further comprise repeat units f derived from an onium salt containing a polymerizable unsaturated bond. Preferred examples of the repeat units f include repeat units having the formula (f1) (hereinafter, also referred to as repeat units f1.), repeat units having the formula (f2) (hereinafter, also referred to as repeat units f2), and repeat units having the formula (f3) (hereinafter, also referred to as repeat units f3). The repeat units f1 to f3 may be used alone, or may be used in combination of two or more thereof.

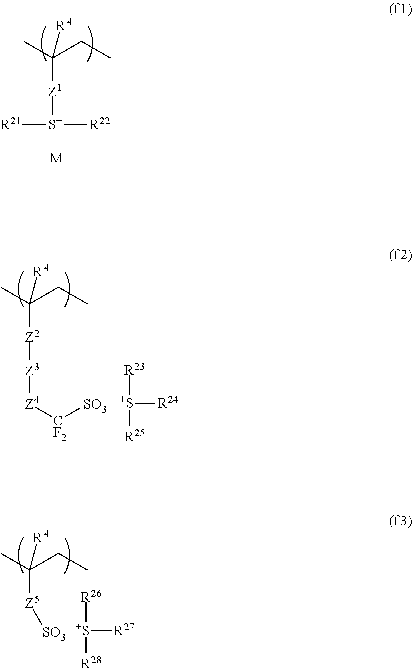

In the formulae (f1) to (f3), R^{A} is each independently a hydrogen atom or a methyl group. Z¹ is a single bond, a C₁-C₆ aliphatic hydrocarbylene group, a phenylene group, a naphthylene group, a C₇-C₁₈ group obtained by combining the foregoing, —O—Z¹¹—. —C(═O)—O—Z¹¹—, or —C(═O)—NH—Z¹¹—. Z¹¹ is a C₁-C₆ aliphatic hydrocarbylene group, a phenylene group, a naphthylene group, or a C₇-C₁₈ group obtained by combining the foregoing, which may contain a carbonyl group, an ester bond, an ether bond, or a hydroxy group. Z² is a single bond or an ester bond. Z³ is a single bond, —Z³¹—C(═O)—O—, —Z³¹—O—, or —Z³¹—O—C(═O)—. Z³¹ is a C₁-C₁₂ aliphatic hydrocarbylene group, a phenylene group, or a C₇-C₁₈ group obtained by combining the foregoing, which may contain a carbonyl group, an ester bond, an ether bond, an iodine atom, or a bromine atom. Z⁴ is a methylene group, a 2,2,2-trifluoro-1,1-ethanediyl group, or a carbonyl group. Z⁵ is a single bond, a methylene group, an ethylene group, a phenylene group, a fluorinated phenylene group, a phenylene group substituted with a trifluoromethyl group, —O—Z⁵¹—, —C(═O)—O—Z⁵¹—, or —C(═O)—NH—Z⁵¹—. Z⁵¹ is a C₁-C₆ aliphatic hydrocarbylene group, a phenylene group, a fluorinated phenylene group, or a phenylene group substituted with a trifluoromethyl group, which may contain a carbonyl group, an ester bond, an ether bond, a hydroxy group, or a halogen atom.

In the formulas (f1) to (f3), R²¹ to R²⁸ are each independently a halogen atom or a C₁-C₂₀ hydrocarbyl group which may contain a heteroatom.

Examples of the halogen atom of R²¹ to R²⁸ include a fluorine atom, a chlorine atom, a bromine atom and an iodine atom.

The hydrocarbyl group of R²¹ to R²⁸ may be saturated or unsaturated, and may be linear, branched, or cyclic. Examples thereof include C₁-C₂₀ alkyl groups such as a methyl group, an ethyl group, an n-propyl group, an isopropyl group, an n-butyl group, an isobutyl group, a sec-butyl group, a tert-butyl group, an n-pentyl group, an n-hexyl group, an n-octyl group, an n-nonyl group, an n-decyl group, an undecyl group, a dodecyl group, a tridecyl group, a tetradecyl group, a pentadecyl group, a heptadecyl group, an octadecyl group, a nonadecyl group and an icosyl group; C₃-C₂₀ cyclic saturated hydrocarbyl groups such as a cyclopropyl group, a cyclopentyl group, a cyclohexyl group, a cyclopropylmethyl group, a 4-methylcyclohexyl group, a cyclohexylmethyl group, a norbornyl group and an adamantyl group; C₂-C₂₀ alkenyl groups such as a vinyl group, a propenyl group, a butenyl group and a hexenyl group; C₂-C₂₀ alkynyl groups such as an ethynyl group, a propynyl group and a butynyl group; C₃-C₂₀ cyclic unsaturated aliphatic hydrocarbyl groups such as a cyclohexenyl group and a norbornenyl group; C₆-C₂₀ aryl groups such as a phenyl group, a methylphenyl group, an ethylphenyl group, an n-propylphenyl group, an isopropylphenyl group, an n-butylphenyl group, an isobutylphenyl group, a sec-butylphenyl group, a tert-butylphenyl group, a naphthyl group, a methylnaphthyl group, an ethylnaphthyl group, an n-propylnaphthyl group, an isopropylnaphthyl group, an n-butylnaphthyl group, an isobutylnaphthyl group, a sec-butylnaphthyl group and a tert-butylnaphthyl group; C₇-C₂₀ aralkyl groups such as a benzyl group and a phenethyl group; and combinations thereof.

Some or all of the hydrogen atoms of the hydrocarbyl group may be replaced by a group containing a heteroatom such as an oxygen atom, a sulfur atom, a nitrogen atom, or a halogen atom, and some constituent —CH₂— of the hydrocarbyl group may be replaced by a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonic acid ester bond, a carbonate bond, a lactone ring, a sultone ring, a carboxylic anhydride (—C(═O)—O—C(═O)—), or a haloalkyl group.

A pair of R²³ and R²⁴, or R²⁶ and R²⁷ may bond together to form a ring with the sulfur atom to which they are attached. Examples of the ring are shown below.

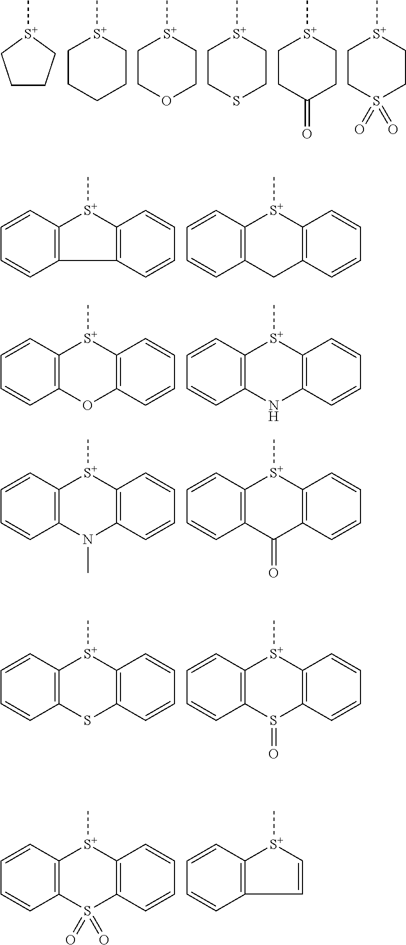

In the formulae, a broken line is a valence bond with R²⁵ or R²⁸.

In the formula (f1), M⁻ is a non-nucleophilic counter ion. Examples of the non-nucleophilic counter ion include halide ions such as chloride ion and bromide ion; fluoroalkyl sulfonate ions such as triflate ion, 1,1,1-trifluoroethane sulfonate ion and nonafluorobutane sulfonate ion; aryl sulfonate ions such as tosylate ion, benzene sulfonate ion, 4-fluorobenzenesulfonate ion, and 1,2,3,4,5-pentafluorobenzenesulfonate ion; alkyl sulfonate ions such as mesylate ion and butanesulfonate ion; imide ions such as bis(trifluoromethylsulfonyl)imide ion, bis(perfluoroethylsulfonyl)imide ion and bis(perfluorobutylsulfonyl)imide ion; and methide ions such as tris(trifluoromethylsulfonyl)methide ion and tris(perfluoroethylsulfonyl)methide ion.

Examples of the non-nucleophilic counter ion further include a sulfonate ion in which the α-position is replaced by a fluorine atom having the formula (f1-1) and a sulfonate ion in which the α-position is replaced by a fluorine atom and the β-position is replaced by a trifluoromethyl group having the formula (f1-2).

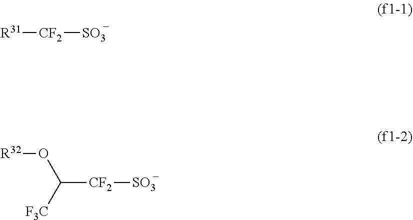

In the formula (f1-1), R³¹ is a hydrogen atom or a C₁-C₂ hydrocarbyl group which may contain an ether bond, an ester bond, a carbonyl group, a lactone ring, or a fluorine atom.

In the formula (f1-2), R³² is a hydrogen atom, a C₁-C₃₀ hydrocarbyl group, or a C₂-C₃₀ hydrocarbyl group, which may contain an ether bond, an ester bond, a carbonyl group, or a lactone ring.

The hydrocarbyl group and the hydrocarbyl moiety of the hydrocarbylcarbonyl group of R³¹ or R³² may be saturated or unsaturated, and may be linear, branched, or cyclic. Examples thereof include alkyl groups such as a methyl group, an ethyl group, an n-propyl group, an isopropyl group, an n-butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group and an icosyl group; cyclic saturated hydrocarbyl groups such as a cyclopentyl group, a cyclohexyl group, a 1-adamantyl group, a 2-adamantyl group, a 1-adamantylmethyl group, a norbornyl group, a norbornylmethyl group, a tricyclodecyl group, a tetracyclododecyl group, a tetracyclododecylmethyl group and a dicyclohexyhmethyl group; alkenyl groups such as an allyl group; cyclic unsaturated hydrocarbyl groups such as a 3-cyclohexenyl group; aryl groups such as a phenyl group, a 1-naphthyl group and a 2-naphthyl group; aralkyl groups such as a benzyl group and a diphenylmethyl group; and combinations thereof.

Some or all of the hydrogen atoms of the hydrocarbyl group and the hydrocarbylcarbonyl group may be replaced by a group containing a heteroatom such as an oxygen atom, a sulfur atom, a nitrogen atom, or a halogen atom, and some constituent —CH₂— of the hydrocarbyl group and the hydrocarbylcarbonyl group may be replaced by a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a carbonyl group, an ether bond, an ester bond, a sulfonic acid ester bond, a carbonate bond, a lactone ring, a sultone ring, a carboxylic anhydride (—C(═O)—O—C(═O)—), or a haloalkyl group. Examples of the hydrocarbyl group containing a heteroatom include a tetrahydrofuryl group, a methoxymethyl group, an ethoxymethyl group, a methylthiomethyl group, an acetamidomethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group and a 3-oxocyclohexyl group.

Examples of the cation of the monomer from which repeat units f1 are derived are shown below, but not limited thereto. In the formulae, R^{A} is the same as described above.

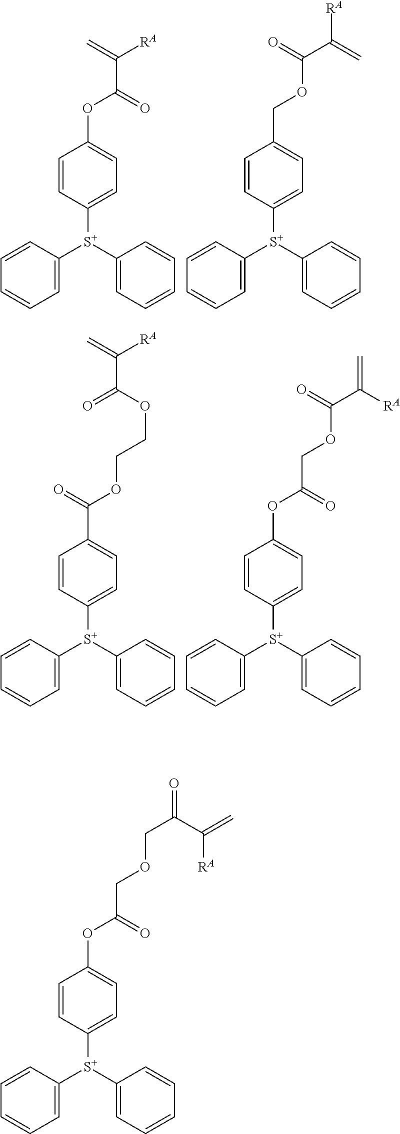

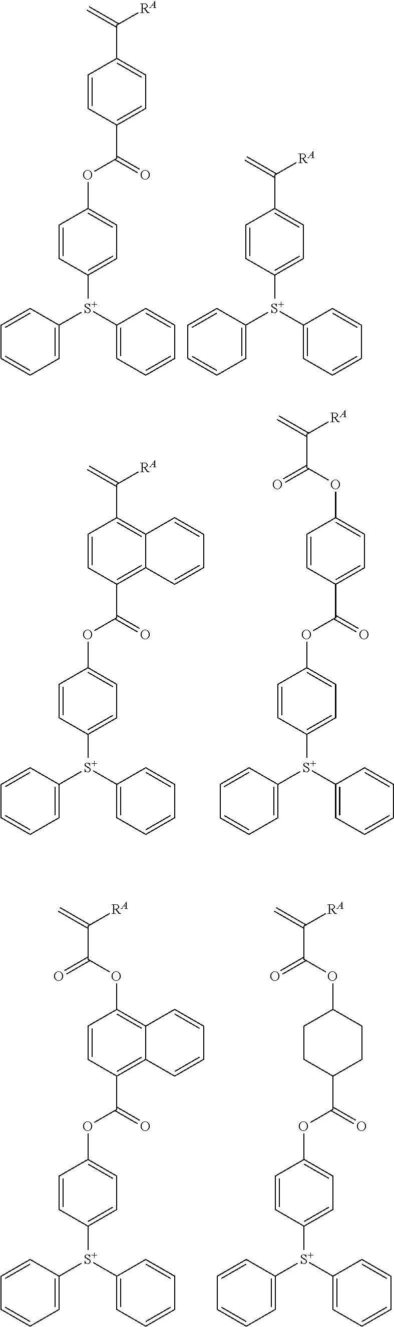

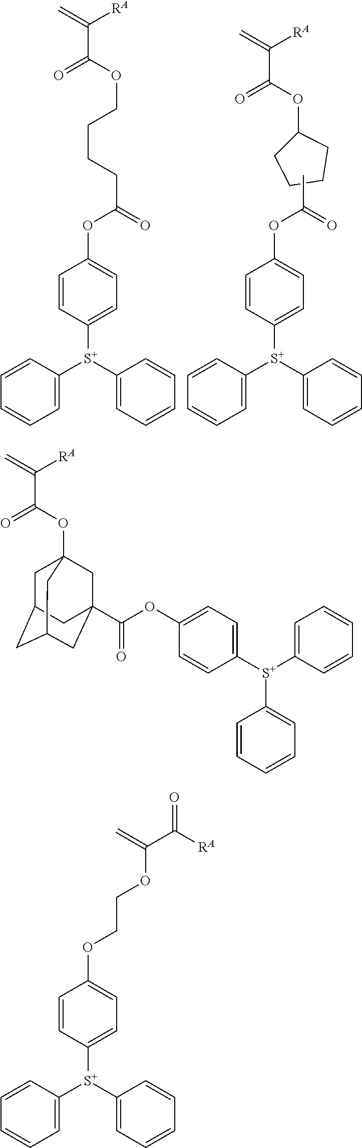

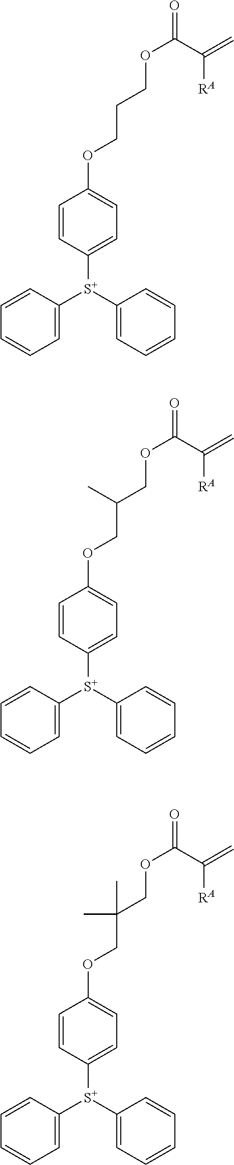

Examples of the cation of the monomer from which repeat units f2 or f3 are derived include the sulfonium cation having the formula (1) described above and the same as those exemplified as the cation of the sulfonium salt having the formula (1-1) described in JP-A 2022-125970.

Examples of the anion of the monomer from which repeat units f2 are derived are shown below, but not limited thereto. In the formulae, R^{A} is the same as described above.

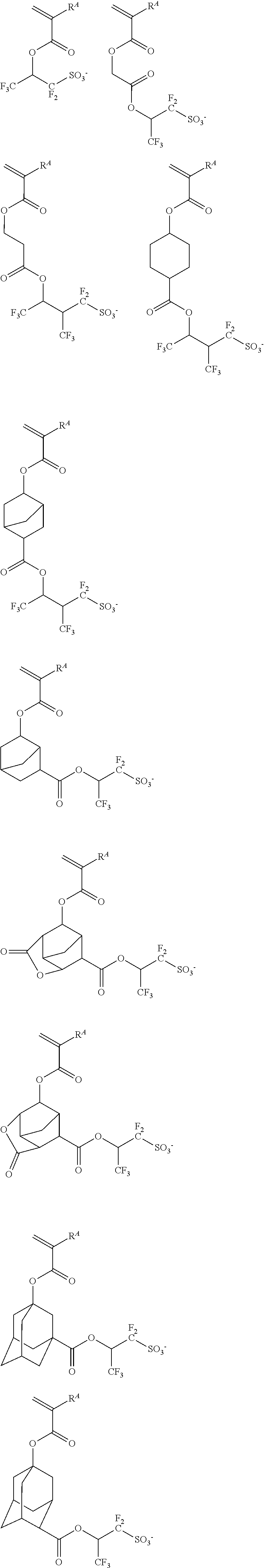

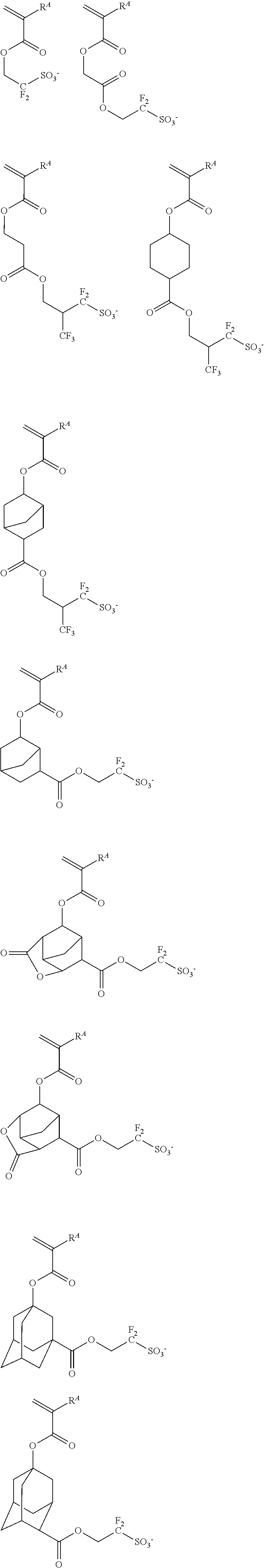

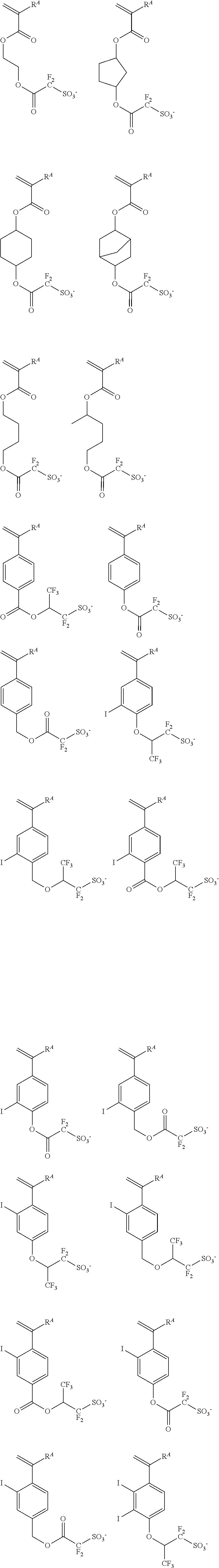

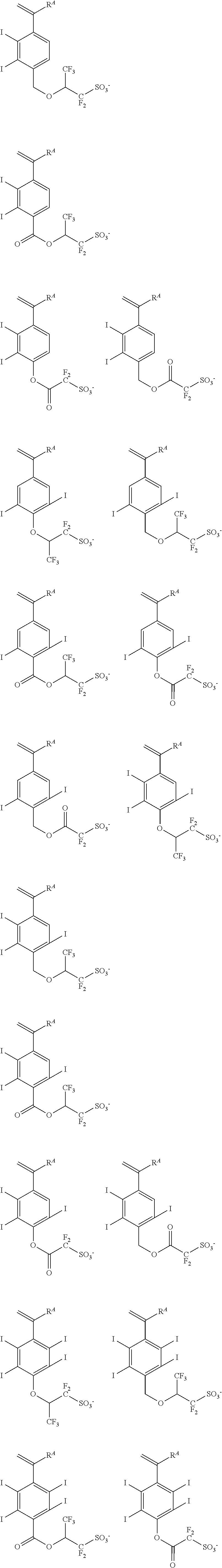

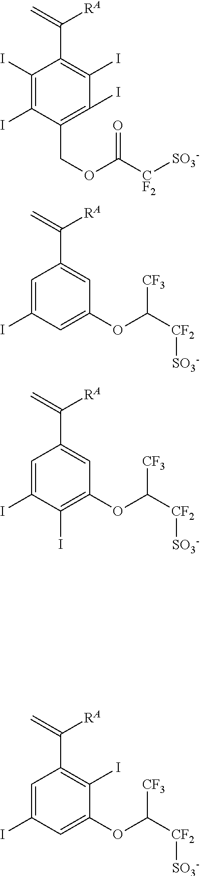

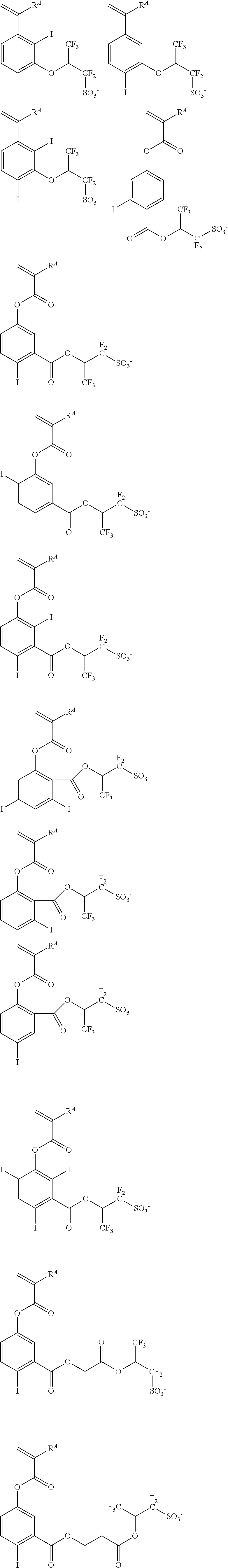

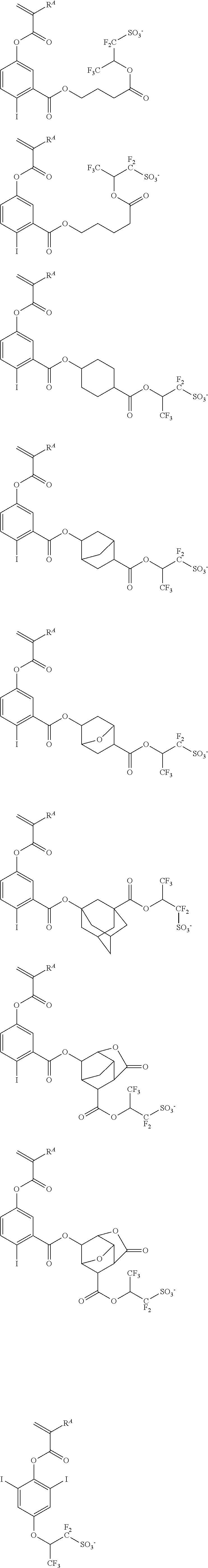

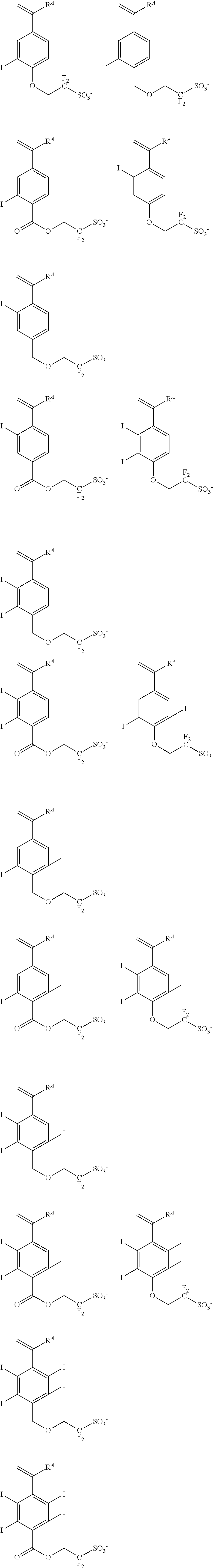

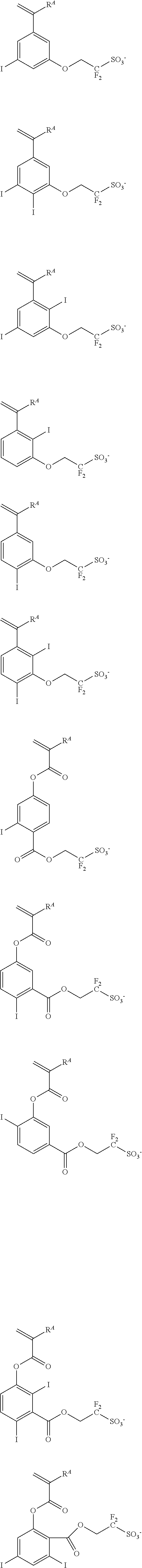

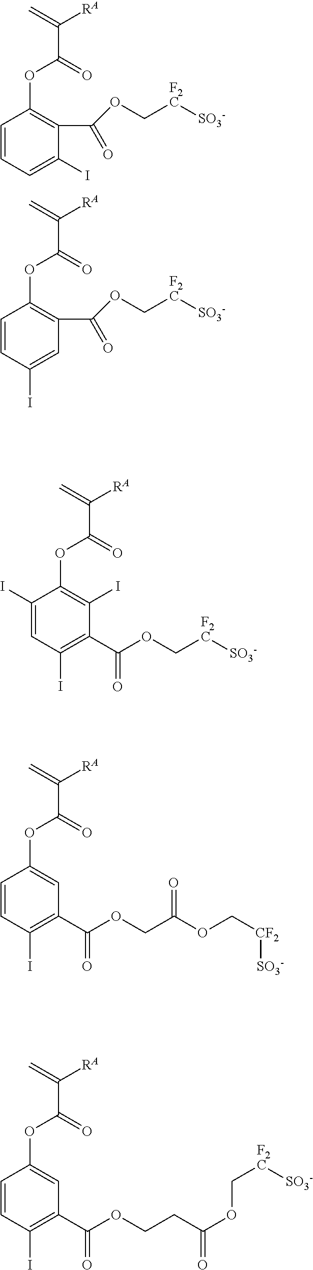

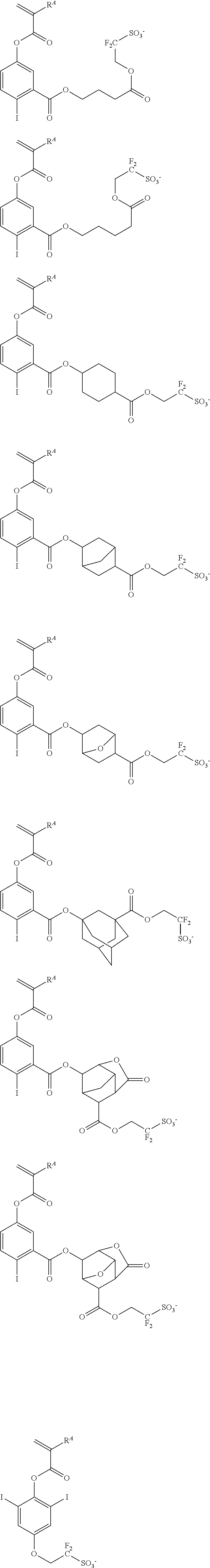

Examples of the anion of the monomer from which repeat units f3 are derived are shown below, but not limited thereto. In the formulae, R^{A} is the same as described above.

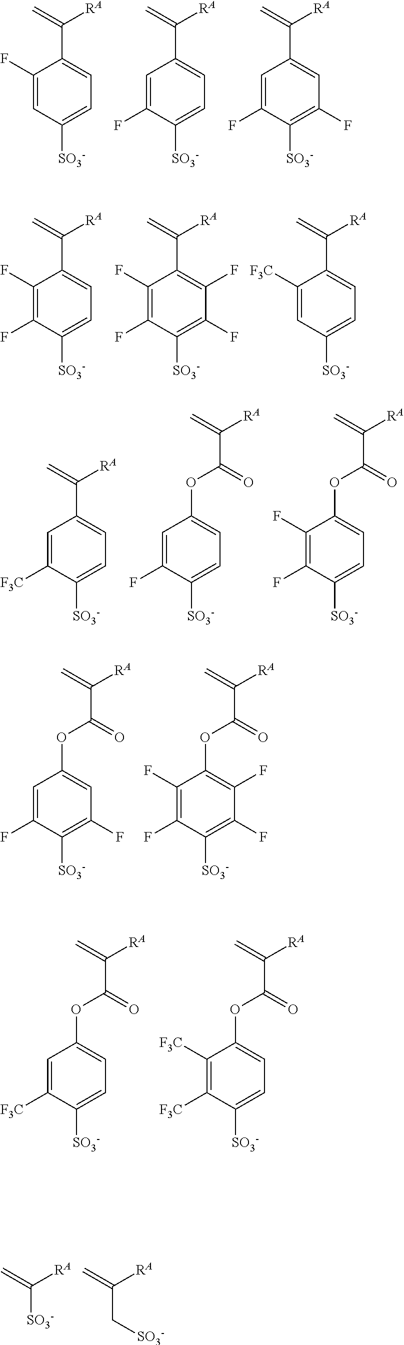

The attachment of an acid generator to the polymer main chain is effective in restraining acid diffusion, thereby preventing a reduction of resolution due to blur by acid diffusion. Also LWR and CDU is improved since the acid generator is uniformly distributed.

The base polymer for formulating the positive resist composition comprises repeat units (a1) or (a2) having an acid labile group as essential component and additional repeat units (b), (c), (d), (e) and (f) as optional components. A fraction of units (a1), (a2), (b), (c), (d), (e) and (f) is: preferably 0≤a1<1.0, 0≤a2<1.0, 0<a1+a2<1.0, 0≤b≤0.9, 0≤c≤0.9, 0≤d≤0.8, 0≤e≤0.8, and 0≤f≤0.5; more preferably 0≤a1≤0.9, 0≤a2≤0.9, 0.1≤a1+a2≤0.9, 0≤b≤0.8, 0≤c≤0.8, 0≤d≤0.7, 0≤e≤0.7, and 0≤f≤0.4; and even more preferably 0≤a1≤0.8, 0≤a≤0.8, 0.1≤a1+a2≤0.8, 0≤b≤0.75, 0≤c≤0.75, 0≤d≤0.6, 0≤e≤0.6, and 0≤f≤0.3. Notably, f=f1+f2+f3, meaning that unit (f) is at least one of units (f1) to (f3), and a1+a2+b+c+d+e+f=1.0.

For the base polymer for formulating the negative resist composition, an acid labile group is not necessarily essential. The base polymer comprises repeat units (b), and optionally repeat units (c), (d), (e), and/or (f). A fraction of these units is: preferably 0<b≤1.0, 0≤c≤0.9, 0≤d≤0.8, 0≤e≤0.8, and 0≤f≤0.5; more preferably 0.2≤b≤1.0, 0≤c≤0.8, 0≤d≤0.7, 0≤e≤0.7, and 0≤f≤0.4; and even more preferably 0.3≤b≤1.0, 0≤c≤0.75, 0≤d≤0.6, 0≤e≤0.6, and 0≤f≤0.3. Notably, f=f1+f2+f3, meaning that unit (f) is at least one of units (f1) to (f3), and b+c+d+e+f=1.0.

The base polymer may be synthesized by any desired methods, for example, by dissolving one or more monomers selected from the monomers corresponding to the foregoing repeat units in an organic solvent, adding a radical polymerization initiator thereto, and heating for polymerization.

Examples of the organic solvent which can be used for polymerization include toluene, benzene, tetrahydrofuran, diethyl ether and dioxane. Examples of the polymerization initiator used herein include 2,2′-azobisisobutyronitrile (AIBN), 2,2′-azobis(2,4-dimethylvaleronitrile), dimethyl 2,2-azobis(2-methylpropionate), benzoyl peroxide and lauroyl peroxide. Preferably the polymerization temperature is 50 to 80° C., and the reaction time is 2 to 100 hours, more preferably 5 to 20 hours.

Where a monomer having a hydroxy group is copolymerized, the hydroxy group may be replaced by an acetal group susceptible to deprotection with acid, typically ethoxyethoxy, prior to polymerization, and the polymerization be followed by deprotection with weak acid and water. Alternatively, the hydroxy group may be replaced by an acetyl group, a formyl group, a pivaloyl group or a similar group prior to polymerization, and the polymerization be followed by alkaline hydrolysis.

When hydroxystyrene or hydroxyvinylnaphthalene is copolymerized, an alternative method is possible. Specifically, acetoxystyrene or acetoxyvinylnaphthalene is used instead of hydroxystyrene or hydroxyvinylnaphthalene, and after polymerization, the acetoxy group is deprotected by alkaline hydrolysis, for thereby converting the polymer product to hydroxystyrene or hydroxyvinylnaphthalene.

For alkaline hydrolysis, a base such as aqueous ammonia or triethylamine may be used. Preferably the reaction temperature is 20° C. to 100° C., more preferably 0° C. to 60° C., and the reaction time is 0.2 to 100 hours, more preferably 0.5 to 20 hours.

The base polymer should preferably have a weight average molecular weight (Mw) in the range of 1,000 to 500,000, and more preferably 2.000 to 30,000, as measured by GPC versus polystyrene standards using tetrahydrofuran (THF) solvent. A Mw in the range ensures that the resist film has heat resistance and high solubility in alkaline developer.

If a base polymer has a wide molecular weight distribution or dispersity (Mw/Mn), which indicates the presence of lower and higher molecular weight polymer fractions, there is a possibility that foreign matter is left on the pattern or the pattern profile is degraded. The influences of Mw and Mw/Mn become stronger as the pattern rule becomes finer. Therefore, the base polymer should preferably have a narrow dispersity (Mw/Mn) of 1.0 to 2.0, especially 1.0 to 1.5, in order to provide a resist composition suitable for micropatterning to a small feature size.

It is understood that a blend of two or more polymers which differ in compositional ratio, Mw or Mw/Mn is acceptable.

Organic Solvent

An organic solvent may be added to the resist composition. The organic solvent used herein is not particularly limited as long as the foregoing and other components are soluble therein.

Examples of the organic solvent are described in JP-A 2008-111103, paragraphs [0144]-[0145] (U.S. Pat. No. 7,537,880). Exemplary solvents include ketones such as cyclohexanone, cyclopentanone, methyl-2-n-pentyl ketone and 2-heptanone; alcohols such as 3-methoxybutanol, 3-methyl-3-methoxybutanol, 1-methoxy-2-propanol, 1-ethoxy-2-propanol and diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, propylene glycol mono-tert-butyl ether acetate; and lactones such as γ-butyrolactone, which may be used alone or in admixture.

In the resist composition of the present invention, the organic solvent is preferably added in an amount of 100 to 10,000 parts, and more preferably 200 to 8,000 parts by weight per 100 parts by weight of the base polymer.

Quencher

The resist composition may further comprise a quencher. As used herein, the “quencher” refers to a compound capable of trapping the acid generated from the acid generator for thereby preventing the acid from diffusing to the unexposed region.

The quencher is typically selected from conventional basic compounds. Conventional basic compounds include primary, secondary and tertiary aliphatic amines, mixed amines, aromatic amines, heterocyclic amines, nitrogen-containing compounds with carboxy group, nitrogen-containing compounds with sulfonyl group, nitrogen-containing compounds with hydroxy group, nitrogen-containing compounds with hydroxyphenyl group, alcoholic nitrogen-containing compounds, amide derivatives, imide derivatives and carbamate derivatives. Also included are primary, secondary and tertiary amine compounds, specifically amine compounds having a hydroxy group, ether bond, ester bond, lactone ring, cyano group, or sulfonic ester bond as described in JP-A 2008-111103, paragraphs [0146]-[0164], and compounds having a carbamate group as described in JP 3790649. Addition of a basic compound may be effective for further suppressing the diffusion rate of acid in the resist film or correcting the pattern profile.

Suitable quenchers also include onium salts such as sulfonium salts, iodonium salts and ammonium salts of sulfonic acids which are not fluorinated at α-position and carboxylic acids, as described in JP-A 2008-158339. While an α-fluorinated sulfonic acid, imide acid and methide acid are necessary to deprotect the acid labile group of carboxylic acid ester, an α-non-fluorinated sulfonic acid or carboxylic acid is released by salt exchange with an α-non-fluorinated onium salt. The α-non-fluorinated sulfonic acid and carboxylic acid function as a quencher because they do not induce deprotection reaction.

Exemplary such quenchers include a compound (onium salt of α-non-fluorinated sulfonic acid) having the formula (3) and a compound (onium salt of carboxylic acid) having the formula (4).

R¹⁰¹—SO₃⁻Mq⁺ (3)

R¹⁰²—CO₂⁻Mq⁺ (4)

In formula (3), R¹⁰¹ is a hydrogen atom or a C₁-C₄ hydrocarbyl group which may contain a heteroatom, exclusive of the hydrocarbyl group in which the hydrogen atom bonded to the carbon atom at α-position of the sulfo group is substituted by a fluorine atom or fluoroalkyl group.

The C₁-C₄₀ hydrocarbyl group may be saturated or unsaturated, and may be linear, branched, or cyclic. Examples thereof include C₁-C₄₀ alkyl groups such as a methyl group, an ethyl group, an n-propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group and an n-decyl group; C₃-C₄₀ cyclic saturated hydrocarbyl groups such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, an adamantyl group and an adamantylmethyl group; C₂-C₄₀ alkenyl groups such as a vinyl group, an allyl group, a propenyl group, a butenyl group and a hexenyl group; C₃-C₄ cyclic unsaturated aliphatic hydrocarbyl groups such as a cyclohexenyl group; C₆-C₄₀ aryl groups such as a phenyl group, a naphthyl group, alkylphenyl groups (e.g., a 2-methylphenyl group, a 3-methylphenyl group, a 4-methylphenyl group, a 4-ethylphenyl group, a 4-tert-butylphenyl group, a 4-n-butylphenyl group), dialkylphenyl groups (e.g., a 2,4-dimethylphenyl group and 2,4,6-triisopropylphenyl group), alkylnaphthyl groups (e.g., a methylnaphthyl group and an ethylnaphthyl group), dialkylnaphthyl groups (e.g., a dimethylnaphthyl group and a diethylnaphthyl group); and C₇-C₄₀ aralkyl groups such as a benzyl group, a 1-phenylethyl group and a 2-phenylethyl group.

In the hydrocarbyl group, some or all of the hydrogen atoms may be replaced by a group containing a heteroatom such as an oxygen atom, a sulfur atom, a nitrogen atom or a halogen atom, and some constituent —CH₂— may be replaced by a group containing a heteroatom such as an oxygen atom, a sulfur atom or a nitrogen atom, so that the group may contain a hydroxy group, a cyano group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group. Suitable heteroatom-containing hydrocarbyl groups include heteroaryl groups such as a thienyl group, a 4-hydroxyphenyl group, alkoxyphenyl groups such as a 4-methoxyphenyl group, a 3-methoxyphenyl group, a 2-methoxyphenyl group, a 4-ethoxyphenyl group, a 4-tert-butoxyphenyl group, and a 3-tert-butoxyphenyl group; alkoxynaphthyl groups such as a methoxynaphthyl group, an ethoxynaphthyl group, an n-propoxynaphthyl group and an n-butoxynaphthyl group; dialkoxynaphthyl groups such as a dimethoxynaphthyl group and a diethoxynaphthyl group; and aryloxoalkyl groups, typically 2-aryl-2-oxoethyl groups such as a 2-phenyl-2-oxoethyl group, a 2-(1-naphthyl)-2-oxoethyl group and a 2-(2-naphthyl)-2-oxoethyl group.

In formula (4), R¹⁰² is a C₁-C₄₀ hydrocarbyl group which may contain a heteroatom. Examples of the hydrocarbyl group R¹⁰² are as exemplified above for the hydrocarbyl group R¹⁰¹. Also included are fluorinated alkyl groups such as a trifluoromethyl group, a trifluoroethyl group, a 2,2,2-trifluoro-1-methyl-1-hydroxyethyl group, a 2,2,2-trifluoro-1-(trifluoromethyl)-1-hydroxyethyl group; and fluorinated aryl groups such as a pentafluorophenyl group and a 4-trifluoromethylphenyl group.

In formulae (3) and (4), Mq⁺ is an onium cation. The onium cation is preferably a sulfonium, iodonium or ammonium cation, with the sulfonium cation or the iodonium cation being more preferred.

A sulfonium salt of iodized benzene ring-containing carboxylic acid having the formula (5) is also useful as the quencher.

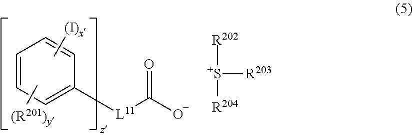

In formula (5). R²⁰¹ is a hydroxy group, a fluorine atom, a chlorine atom, a bromine atom, an amino group, a nitro group, a cyano group, or a C₁-C₆ saturated hydrocarbyl group, a C₁-C₆ saturated hydrocarbyloxy group, a C₂-C₆ saturated hydrocarbylcarbonyloxy group, or a C₁-C₄ saturated hydrocarbylsulfonyloxy group, in which some or all hydrogen atoms may be substituted by a halogen atom, or —N(R^{201A})-C(═O)—R^{201B}, or —N(R^{201A})—C(═O)—O—R^{201B}, wherein R^{201A} is a hydrogen atom or a C₁-C₆ saturated hydrocarbyl group and R^{201B} is a C₁-C₆ saturated hydrocarbyl group or C₂-C₈ unsaturated aliphatic hydrocarbyl group.

In formula (5), x′ is an integer of 1 to 5, y′ is an integer of 0 to 3, and z′ is an integer of 1 to 3. L¹¹ is a single bond, or a C₁-C₂₀ (z′+1)-valent linking group which may contain an ether bond, a carbonyl group, an ester bond, an amide bond, a sultone ring, a lactam ring, a carbonate bond, a halogen atom, a hydroxy group or a carboxy group, or a mixture thereof. The saturated hydrocarbyl, saturated hydrocarbyloxy, saturated hydrocarbylcarbonyloxy and saturated hydrocarbylsulfonyloxy groups may be linear, branched or cyclic. Groups R²⁰¹ may be identical or different when y′ and/or z′ is 2 or more.

In formula (5), R²⁰², R²⁰³ and R²⁰⁴ are each independently a halogen atom or a C₁-C₂₀ hydrocarbyl group which may contain a heteroatom. The hydrocarbyl group may be saturated or unsaturated, and may be linear, branched, or cyclic. Examples thereof are as exemplified for the hydrocarbyl groups R²¹ to R²⁸ in the description of formulae (f1) to (f3). In these hydrocarbyl groups, some or all hydrogen atoms may be replaced by a hydroxy group, a carboxy group, a halogen atom, an oxo group, a cyano group, a nitro group, a sultone ring, a sulfone ring, or a sulfonium salt-containing group, or some constituent —CH₂— may be replaced by an ether bond, an ester bond, a carbonyl group, an amide bond, a carbonate bond or a sulfonic ester bond. A pair of R²⁰² and R²⁰³ may bond together to form a ring with the sulfur atom to which they are attached.

Examples of the compound having formula (5) include those described in U.S. Pat. No. 10,295,904 (JP-A 2017-219836).

Also useful are quenchers of polymer type as described in U.S. Pat. No. 7,598,016 (JP-A 2008-239918). The polymeric quencher segregates at the resist film surface and thus enhances the rectangularity of resist pattern. When a protective film is applied as is often the case in the immersion lithography, the polymeric quencher is also effective for preventing a film thickness loss of resist pattern or rounding of pattern top.

In the resist composition of the present invention, the quencher is preferably added in an amount of 0 to 5 parts, more preferably 0 to 4 parts by weight per 100 parts by weight of the base polymer.

Other Components

In addition to the foregoing components, the resist composition may contain other components such as an acid generator other than the sulfonium salt composed of a sulfonate anion having a carbon atom to which an iodine atom is bonded and a sulfonium cation having the formula (1)(hereinafter, also referred to as other acid generator), surfactant, dissolution inhibitor, crosslinker, water repellency improver and acetylene alcohol.

The other acid generator is typically a compound (PAG) capable of generating an acid upon exposure to actinic ray or radiation. Although the PAG used herein may be any compound capable of generating an acid upon exposure to high-energy radiation, those compounds capable of generating sulfonic acid, imide acid (imidic acid) or methide acid are preferred. Suitable PAGs include sulfonium salts, iodonium salts, sulfonyldiazomethane, N-sulfonyloxyimide and oxime-O-sulfonate acid generators. Exemplary PAGs are described in JP-A 2008-111103, paragraphs [0122]-[0142] (USP 7,537,880). JP-A 2018-5224 and JP-A 2018-025789. The other acid generator is preferably used in an amount of 0 to 200 parts, more preferably 0.1 to 100 parts by weight per 100 parts by weight of the base polymer. The other acid generator may be used alone, or may be used in combination of two or more thereof.

Exemplary surfactants are described in JP-A 2008-111103, paragraphs [0165]-[0166]. Inclusion of a surfactant may improve or control the coating characteristics of the resist composition. The surfactant is preferably added in an amount of 0.0001 to 10 parts by weight per 100 parts by weight of the base polymer. The surfactant may be used alone, or may be used in combination of two or more thereof.

In the embodiment wherein the resist composition is of positive tone, the inclusion of a dissolution inhibitor may lead to an increased difference in dissolution rate between exposed and unexposed areas and a further improvement in resolution. The dissolution inhibitor is typically a compound having at least two phenolic hydroxy groups on the molecule, in which an average of from 0 to 100 mol % of all the hydrogen atoms on the phenolic hydroxy groups are replaced by acid labile groups or a compound having at least one carboxy group on the molecule, in which an average of 50 to 100 mol % of all the hydrogen atoms on the carboxy groups are replaced by acid labile groups, both the compounds having a molecular weight of 100 to 1,000, and preferably 150 to 800. Typical are bisphenol A, trisphenol, phenolphthalein, cresol novolac, naphthalenecarboxylic acid, adamantanecarboxylic acid and cholic acid derivatives in which the hydrogen atom on the hydroxy or carboxy group is replaced by an acid labile group, as described in U.S. Pat. No. 7,771,914 (JP-A 2008-122932, paragraphs [0155]-[0178]).

The dissolution inhibitor is preferably added in an amount of 0 to 50 parts, more preferably 5 to 40 parts by weight per 100 parts by weight of the base polymer. The dissolution inhibitor may be used alone, or may be used in combination of two or more thereof.

In the case of negative resist compositions, a negative pattern may be formed by adding a crosslinker to reduce the dissolution rate of exposed area. Suitable crosslinkers which can be used herein include epoxy compounds, melamine compounds, guanamine compounds, glycoluril compounds and urea compounds having substituted thereon at least one group selected from among methylol, alkoxymethyl and acyloxymethyl groups, isocyanate compounds, azide compounds and compounds having a double bond such as an alkenyloxy group. These compounds may be used as an additive or introduced into a polymer side chain as a pendant. Hydroxy-containing compounds may also be used as the crosslinker.

Suitable epoxy compounds include tris(2,3-epoxypropyl) isocyanurate, trimethylolmethane triglycidyl ether, trimethylolpropane triglycidyl ether and triethylolethane triglycidyl ether.

Examples of the melamine compound include hexamethylol melamine, hexamethoxymethyl melamine, hexamethylol melamine compounds having 1 to 6 methylol groups methoxymethylated and mixtures thereof, hexamethoxyethyl melamine, hexaacyloxymethyl melamine, hexamethylol melamine compounds having 1 to 6 methylol groups acyloxymethylated and mixtures thereof.

Examples of the guanamine compound include tetramethylol guanamine, tetramethoxymethyl guanamine, tetramethylol guanamine compounds having 1 to 4 methylol groups methoxymethylated and mixtures thereof, tetramethoxyethyl guanamine, tetraacyloxyguanamine, tetramethylol guanamine compounds having 1 to 4 methylol groups acyloxymethylated and mixtures thereof.

Examples of the glycoluril compound include tetramethylol glycoluril, tetramethoxyglycoluril, tetramethoxymethyl glycoluril, tetramethylol glycoluril compounds having 1 to 4 methylol groups methoxymethylated and mixtures thereof, tetramethylol glycoluril compounds having 1 to 4 methylol groups acyloxymethylated and mixtures thereof. Examples of the urea compound include tetramethylol urea, tetramethoxymethyl urea, tetramethylol urea compounds having 1 to 4 methylol groups methoxymethylated and mixtures thereof, and tetramethoxyethyl urea.

Suitable isocyanate compounds include tolylene diisocyanate, diphenylmethane diisocyanate, hexamethylene diisocyanate and cyclohexane diisocyanate.

Suitable azide compounds include 1,1′-biphenyl-4,4′-bisazide, 4,4′-methylidenebisazide and 4,4′-oxybisazide.

Examples of the alkenyloxy group-containing compound include ethylene glycol divinyl ether, triethylene glycol divinyl ether, 1,2-propanediol divinyl ether, 1,4-butanediol divinyl ether, tetramethylene glycol divinyl ether, neopentyl glycol divinyl ether, trimethylol propane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether and trimethylol propane trivinyl ether.

In the negative resist composition, the crosslinker is preferably added in an amount of 0.1 to 50 parts, more preferably 1 to 40 parts by weight per 100 parts by weight of the base polymer. The crosslinker may be used alone, or may be used in combination of two or more thereof.

To the resist composition, a water repellency improver may also be added for improving the water repellency on surface of a resist film after spin coating. The water repellency improver may be used in the topcoatless immersion lithography. Suitable water repellency improvers include polymers having a fluoroalkyl group and polymers having a specific structure with a 1,1,1,3,3,3-hexafluoro-2-propanol residue and are described in JP-A 2007-297590 and JP-A 2008-111103, for example. The water repellency improver to be added to the resist composition should be soluble in alkaline developers and organic solvent developers. The water repellency improver of specific structure with a 1,1,1,3,3,3-hexafluoro-2-propanol residue is well soluble in the developer. A polymer having an amino group or amine salt copolymerized as repeat units may serve as the water repellent additive and is effective for preventing evaporation of acid during PEB, thus preventing any hole pattern opening failure after development. An appropriate amount of the water repellency improver is 0 to 20 parts, preferably 0.5 to 10 parts by weight per 100 parts by weight of the base polymer. The water repellency improver may be used alone, or may be used in combination of two or more thereof.

Also, an acetylene alcohol may be blended in the resist composition. Suitable acetylene alcohols are described in JP-A 2008-122932, paragraphs [0179]-[0182]. An appropriate amount of the acetylene alcohol blended is 0 to 5 parts by weight per 100 parts by weight of the base polymer. The acetylene alcohol may be used alone, or may be used in combination of two or more thereof.

Pattern Forming Process

The resist composition is used in the fabrication of various integrated circuits. Pattern formation using the resist composition may be performed by well-known lithography processes. The process generally involves the steps of applying the resist composition onto a substrate to form a resist film thereon, exposing the resist film to high-energy radiation, and developing the exposed resist film in a developer. If necessary, any additional steps may be added.

Specifically, the resist composition is first applied onto a substrate on which an integrated circuit is to be formed (e.g., Si, SiO2, SiN, SiON, TiN, WSi, BPSG, SOG, or organic antireflective coating) or a substrate on which a mask circuit is to be formed (e.g., Cr, CrO, CrON, MoSi₂, or SiO₂) by a suitable coating technique such as spin coating, roll coating, flow coating, dipping, spraying or doctor coating. The coating is prebaked on a hotplate preferably at a temperature of 60 to 150° C. for 10 seconds to 30 minutes, more preferably at 80 to 120° C. for 30 seconds to 20 minutes. The resulting resist film is generally 0.01 to 2 μm thick.

The resist film is then exposed to a desired pattern of high-energy radiation such as UV, deep-UV, EB, EUV of wavelength 3 to 15 nm, x-ray, soft x-ray, excimer laser light, γ-ray or synchrotron radiation. When UV, deep-LV, EUV, x-ray, soft x-ray, excimer laser light, γ-ray or synchrotron radiation is used as the high-energy radiation, the resist film is exposed thereto through a mask having a desired pattern in a dose of preferably about 1 to 200 mJ/cm², more preferably about 10 to 100 mJ/cm². When EB is used as the high-energy radiation, the resist film is exposed thereto directly or through a mask having a desired pattern in a dose of preferably about 0.1 to 300 μC/cm², more preferably about 0.5 to 200 μC/cm². It is appreciated that the inventive resist composition is suited in micropatterning using KrF excimer laser, ArF excimer laser, EB, EUV, x-ray, soft x-ray, γ-ray or synchrotron radiation, especially in micropatterning using EB or EUV.

After the exposure, the resist film may be baked (PEB) on a hotplate or in an oven preferably at 30 to 150° C. for 10 seconds to 30 minutes, more preferably at 50 to 120° C. for 30 seconds to 20 minutes.

After the exposure or PEB, the resist film is developed in a developer in the form of an aqueous base solution for 3 seconds to 3 minutes, preferably 5 seconds to 2 minutes by conventional techniques such as dip, puddle and spray techniques. A typical developer is preferably a 0.1 to 10 wt %, more preferably 2 to 5 wt % aqueous solution of tetramethylammonium hydroxide (TMAH), tetraethylammonium hydroxide (TEAH), tetrapropylammonium hydroxide (TPAH), or tetrabutylammonium hydroxide (TBAH). In the case of positive tone, the resist film in the exposed area is dissolved in the developer whereas the resist film in the unexposed area is not dissolved. In this way, the desired positive pattern is formed. In the case of negative tone, inversely the resist film in the exposed area is insolubilized whereas the resist film in the unexposed area is dissolved away.

In an alternative embodiment, a negative pattern can be obtained from the positive resist composition comprising a base polymer containing acid labile groups by effecting organic solvent development. The developer used herein is preferably selected from among 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate and 2-phenylethyl acetate, and mixtures thereof. The organic solvent may be used alone, or may be used in combination of two or more thereof.

At the end of development, the resist film is rinsed. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents.

Specifically, suitable alcohols of 3 to 10 carbon atoms include n-propyl alcohol, isopropyl alcohol, 1-butyl alcohol, 2-butyl alcohol, isobutyl alcohol, t-butyl alcohol, 1-pentanol, 2-pentanol, 3-pentanol, t-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol and 1-octanol.

Suitable ether compounds of 8 to 12 carbon atoms include di-n-butyl ether, diisobutyl ether, di-s-butyl ether, di-n-pentyl ether, diisopentyl ether, di-s-pentyl ether, di-t-pentyl ether and di-n-hexyl ether.

Suitable alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane and cyclononane. Suitable alkenes of 6 to 12 carbon atoms include hexene, heptene, octene, cyclohexene, methylcyclohexene, dimethylcyclohexene, cycloheptene and cyclooctene. Suitable alkynes of 6 to 12 carbon atoms include hexyne, heptyne and octyne.

Suitable aromatic solvents include toluene, xylene, ethylbenzene, isopropylbenzene, t-butylbenzene and mesitylene.

Rinsing is effective for minimizing the risks of resist pattern collapse and defect formation. However, rinsing is not essential. If rinsing is omitted, the amount of solvent used may be reduced.

A hole or trench pattern after development may be shrunk by the thermal flow, RELACS® or DSA process. A hole pattern is shrunk by coating a shrink agent thereto, and baking such that the shrink agent may undergo crosslinking at the resist surface as a result of the acid catalyst diffusing from the resist layer during bake, and the shrink agent may attach to the sidewall of the hole pattern. The bake is preferably at a temperature of 70 to 180° C., more preferably 80 to 170° C., for a time of 10 to 300 seconds. The extra shrink agent is stripped and the hole pattern is shrunk.

### EXAMPLES

Examples of the invention are given below by way of illustration and not by way of limitation.

The structures of the acid generators PAG-1 to PAG-26 used for the resist composition are shown below. PAG-1 to PAG-26 were synthesized by ion exchange between a sulfonium salt composed of a cation having the formula (1) and a triflumethylsulfonic acid anion and an ammonium salt composed of an ammonium cation and a sulfonate anion having a carbon atom to which an iodine atom is bonded.

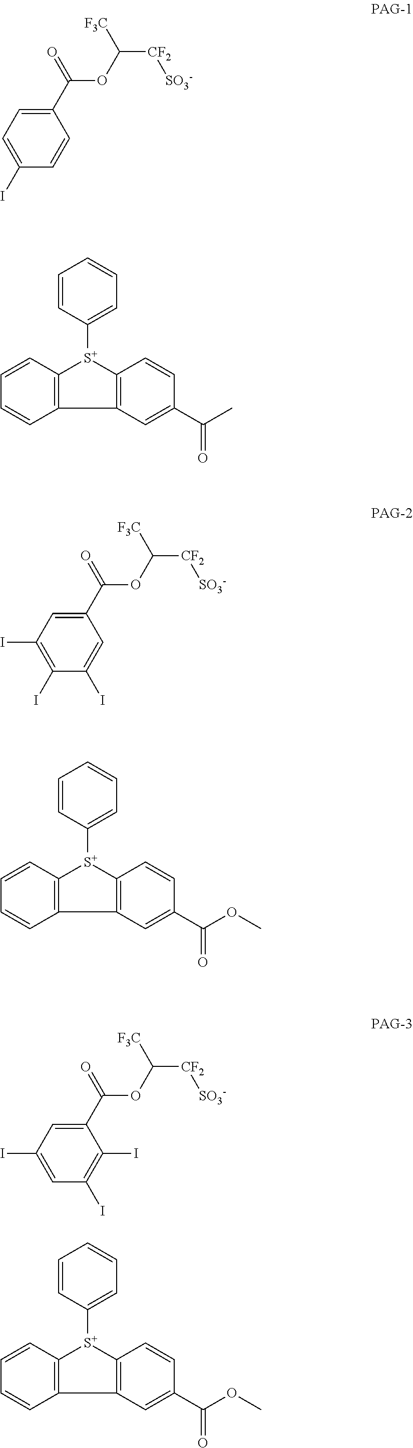

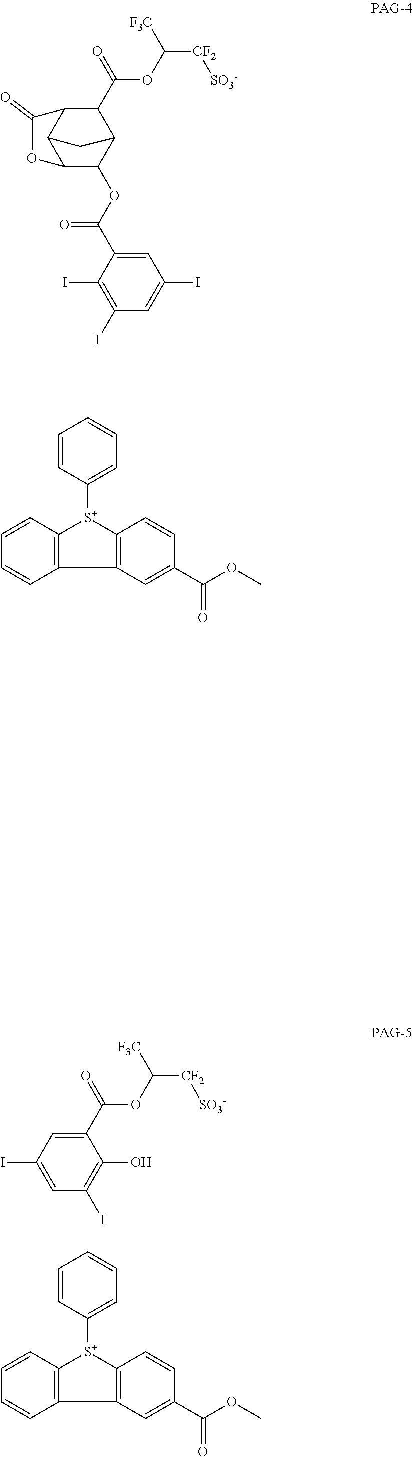

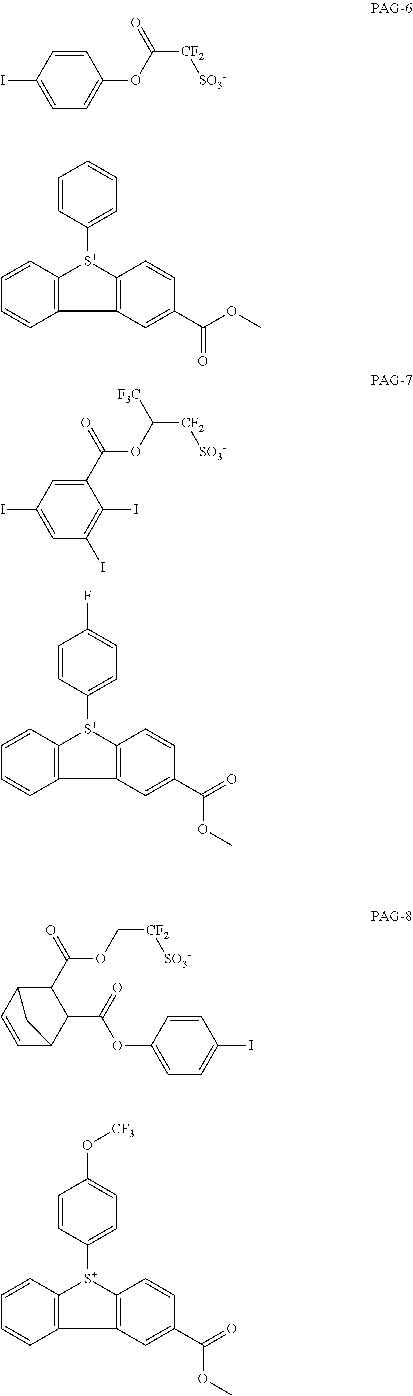

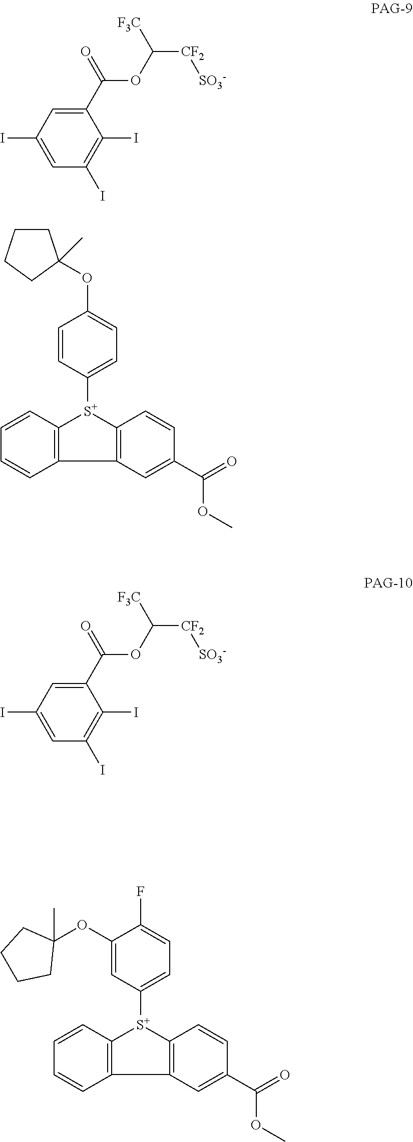

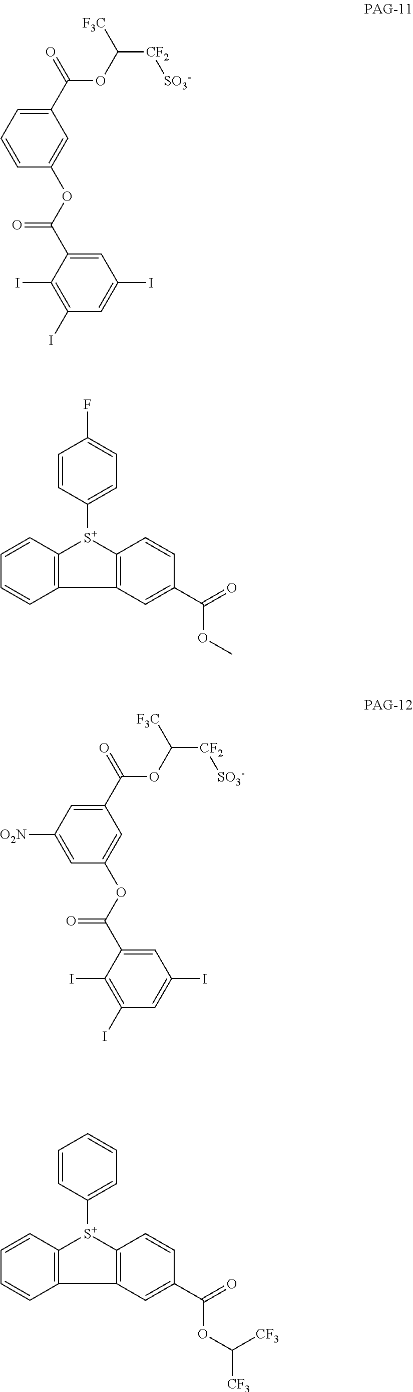

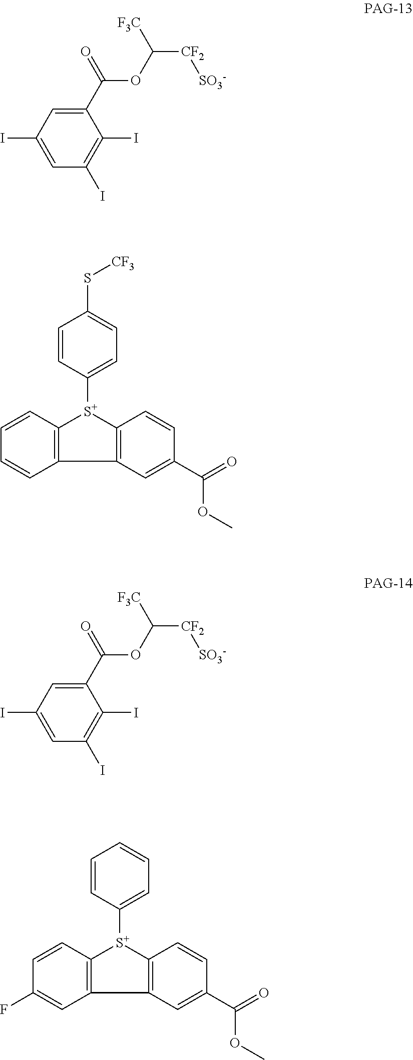

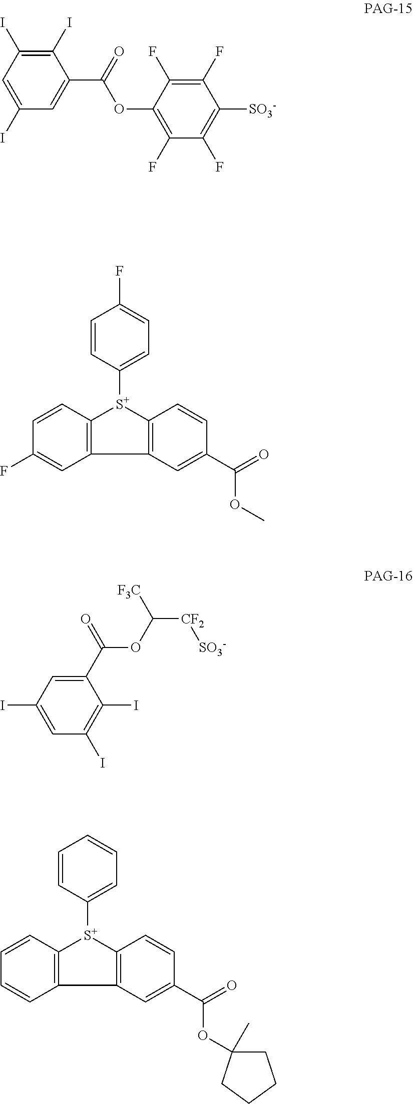

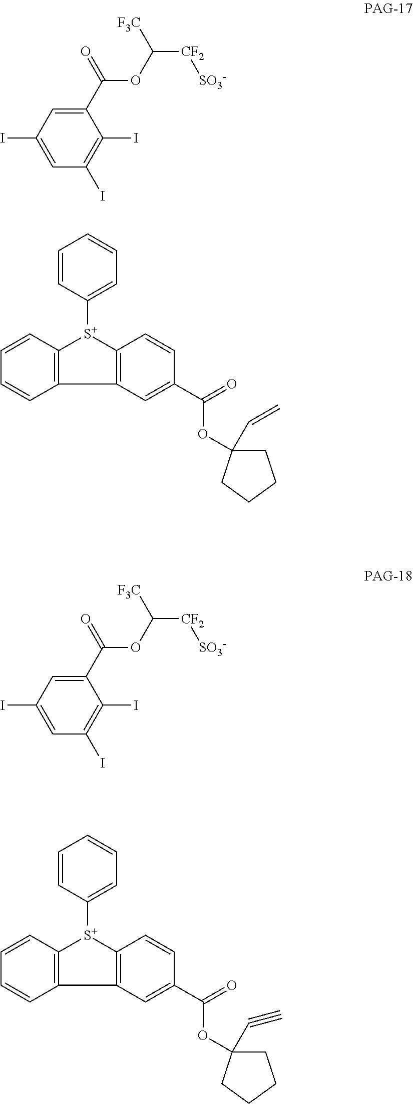

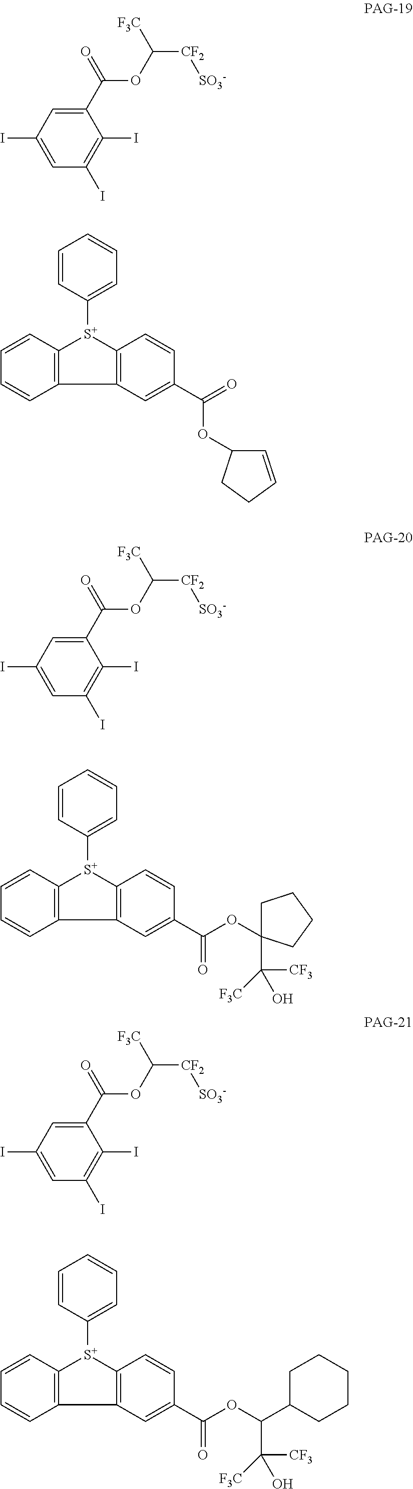

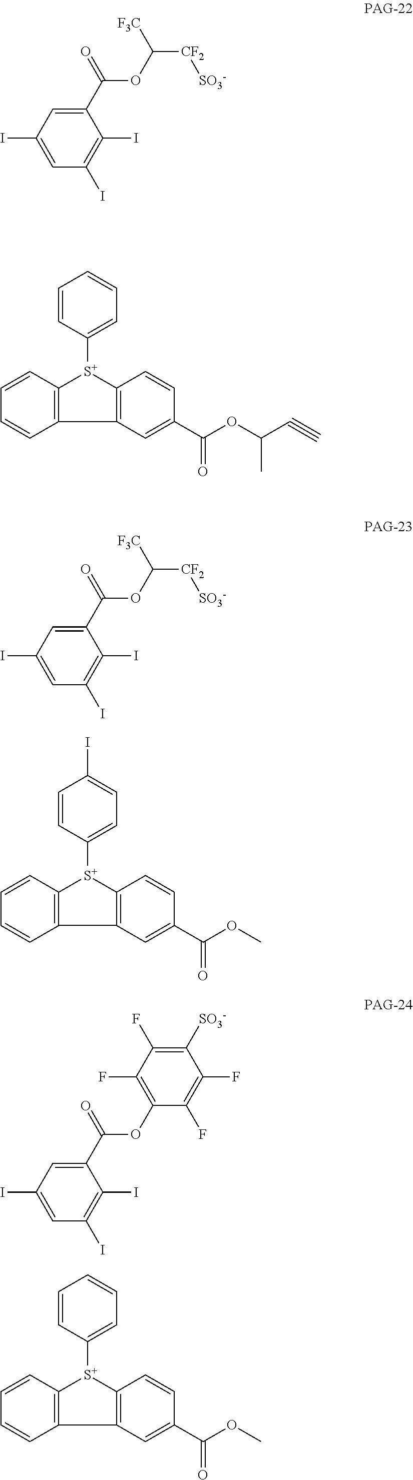

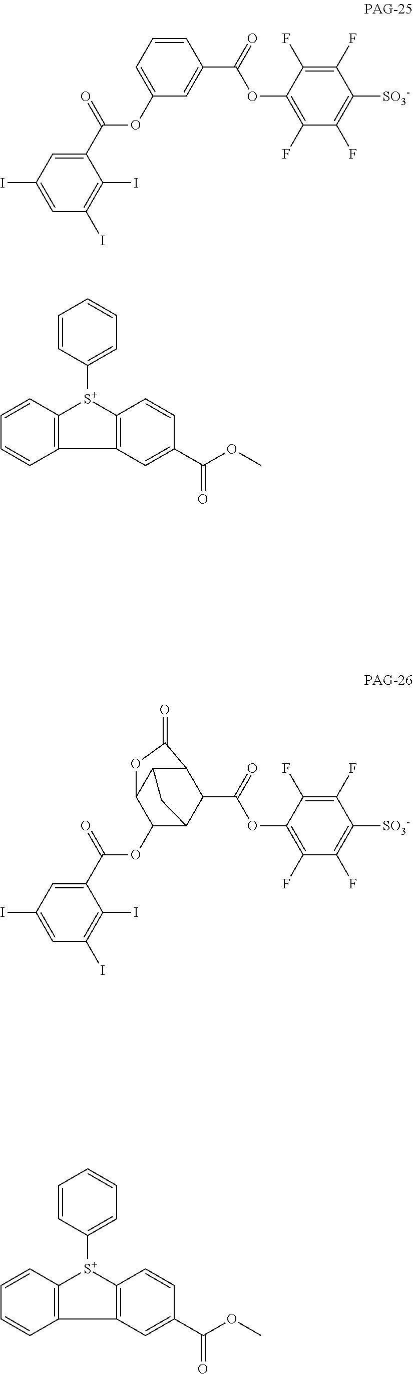

### Synthesis Example Synthesis of Base Polymers (Polymers P-1 to P-5)

Base polymers (Polymers P-1 to P-5) of the structure shown below were synthesized by combining selected monomers, effecting copolymerization reaction in THF solvent, crystallizing the reaction solution into methanol, further washing the solid precipitate with hexane repeatedly, isolating, and drying. The base polymers were analyzed for composition by ¹H-NMR spectroscopy and for Mw and Mw/Mn by GPC versus polystyrene standards using THF solvent.

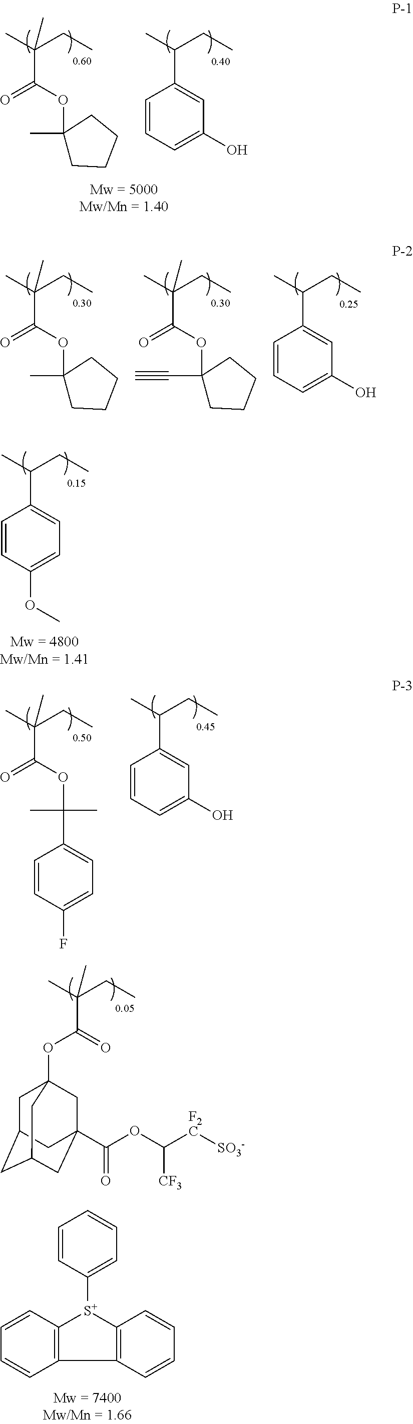

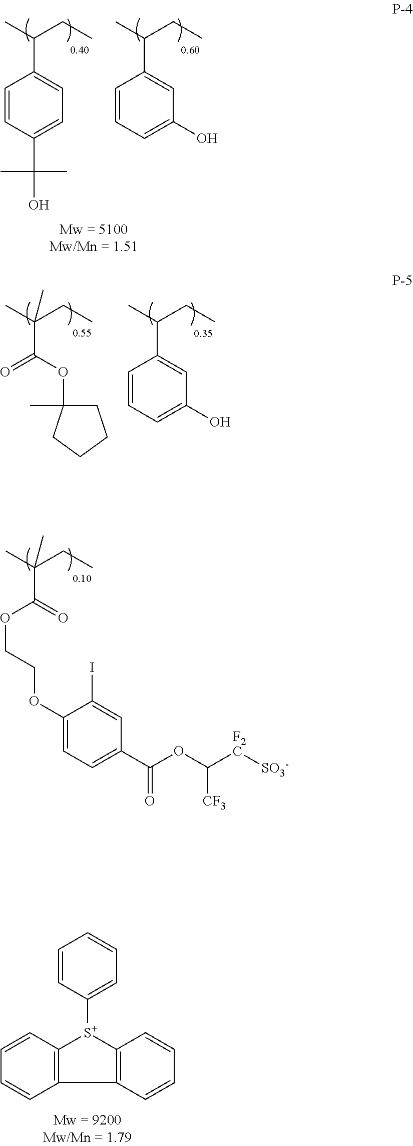

### Examples 1 to 30 and Comparative Examples 1 to 3 Preparation and Evaluation of Resist Compositions

(1) Preparation of Resist Compositions

Resist compositions were prepared by dissolving components in a solvent in accordance with the recipe shown in Tables 1 to 3, and filtering the solution through a filter having a pore size of 0.2 μm. The solvent contained 40 ppm of surfactant Polyfox PF-636 (Onmova Solutions, Inc.).

The components in Tables 1 to 3 are identified below.

Organic Solvents:
PGMEA (propylene glycol monomethyl ether acetate)
EL (ethyl lactate)
DAA (diacetone alcohol)

Comparative acid generators: cPAG-1 and cPAG-2

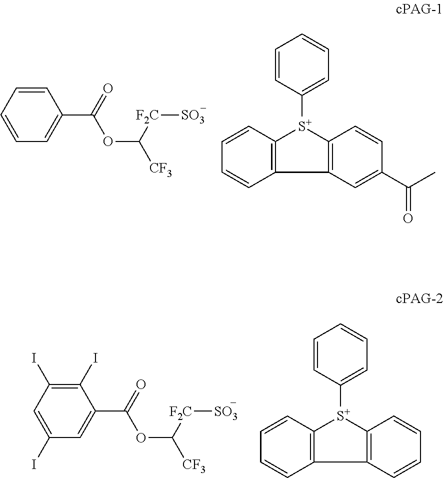

Quenchers: Q-1 and Q-2

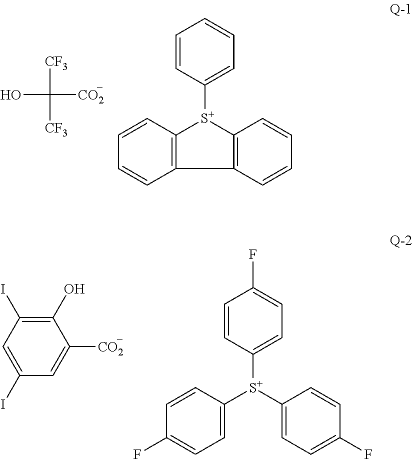

(2) EUV Lithography Test

Each of the resist compositions in Tables 1 to 3 was spin coated on a silicon substrate having a 20-nm coating of silicon-containing spin-on hard mask SHB-A940 (Shin-Etsu Chemical Co., Ltd., Si content 43 wt %) and prebaked on a hotplate at 105° C. for 60 seconds to form a resist film of 50 nm thick. Using an EUV scanner NXE3400 (ASML, NA 0.33, σ0.9/0.6, quadrupole illumination), the resist film was exposed to EUV through a mask bearing a hole pattern at a pitch 40 nm (on-wafer size) and +20% bias. The resist film was baked (PEB) on a hotplate at the temperature shown in Tables 1 to 3 for 60 seconds and developed in a 2.38 wt % TMAH aqueous solution for 30 seconds to obtain a hole pattern having a size of 20 nm in Examples 1 to 25 and 27 to 30, and Comparative Examples 1 and 2, and a dot pattern having a size of 20 nm in Example 26 and Comparative Example 3. The resist pattern was observed under CD-SEM (CG6300, Hitachi High-Technologies Corp.). The exposure dose that provides a hole pattern or a dot pattern is reported as sensitivity. The size of 50 holes or 50 dots printed at that dose was measured, from which a 3 fold value (3σ) of the standard deviation (σ) was computed and reported as Critical Dimension Uniformity (CDU). The results are also shown in Tables 1 to 3.

TABLE 1

| | | Polymer | Acid generator | Quencher | Organic solvent | PEB | Sensitivity | CDU |
|---|---|---|---|---|---|---|---|---|
| | | (pbw) | (pbw) | (pbw) | (pbw) | (° C.) | (mJ/cm²) | (nm) |
| Example | 1 | P-1 | PAG-1 | Q-1 | PGMEA (500) | 80 | 29 | 2.9 |
| | | (100) | (16.2) | (4.72) | EL (2000) | | | |
| | 2 | P-1 | PAG-2 | Q-1 | PGMEA (500) | 80 | 25 | 2.7 |
| | | (100) | (30.9) | (4.72) | EL (2000) | | | |
| | 3 | P-1 | PAG-3 | Q-1 | PGMEA (500) | 80 | 26 | 2.8 |
| | | (100) | (30.9) | (4.72) | EL (2000) | | | |
| | 4 | P-1 | PAG-4 | Q-1 | PGMEA (2000) | 80 | 26 | 2.7 |
| | | (100) | (36.3) | (4.72) | DAA (500) | | | |
| | 5 | P-1 | PAG-5 | Q-1 | PGMEA (2000) | 80 | 26 | 2.6 |
| | | (100) | (27.6) | (4.72) | DAA (500) | | | |
| | 6 | P-1 | PAG-6 | Q-1 | PGMEA (2000) | 80 | 29 | 2.9 |
| | | (100) | (20.8) | (4.72) | DAA (500) | | | |
| | 7 | P-1 | PAG-7 | Q-1 | PGMEA (2000) | 80 | 25 | 2.7 |
| | | (100) | (31.4) | (4.72) | DAA (500) | | | |
| | 8 | P-1 | PAG-8 | Q-1 | PGMEA (2000) | 80 | 28 | 2.7 |
| | | (100) | (27.9) | (4.72) | DAA (500) | | | |
| | 9 | P-1 | PAG-9 | Q-1 | PGMEA (2000) | 80 | 28 | 2.6 |
| | | (100) | (33.8) | (4.72) | DAA (500) | | | |
| | 10 | P-1 | PAG-10 | Q-1 | PGMEA (2000) | 80 | 27 | 2.6 |
| | | (100) | (34.4) | (4.72) | DAA (500) | | | |
| | 11 | P-1 | PAG-11 | Q-1 | PGMEA (2000) | 80 | 27 | 2.6 |
| | | (100) | (35.0) | (4.72) | DAA (500) | | | |
| | 12 | P-1 | PAG-12 | Q-1 | PGMEA (2000) | 80 | 28 | 2.6 |
| | | (100) | (39.9) | (4.72) | DAA (500) | | | |
| | 13 | P-1 | PAG-13 | Q-1 | PGMEA (2000) | 80 | 28 | 2.5 |
| | | (100) | (33.9) | (4.72) | DAA (500) | | | |
| | 14 | P-1 | PAG-14 | Q-1 | PGMEA (2000) | 80 | 25 | 2.7 |
| | | (100) | (31.4) | (4.72) | DAA (500) | | | |
| | 15 | P-1 | PAG-15 | Q-2 | PGMEA (2000) | 80 | 24 | 2.7 |
| | | (100) | (32.9) | (7.06) | DAA (500) | | | |
| | 16 | P-1 | PAG-16 | Q-2 | PGMEA (2000) | 80 | 27 | 2.5 |
| | | (100) | (32.9) | (7.06) | DAA (500) | | | |
| | 17 | P-1 | PAG-17 | Q-2 | PGMEA (2000) | 80 | 26 | 2.4 |
| | | (100) | (33.3) | (7.06) | DAA (500) | | | |
| | 18 | P-1 | PAG-18 | Q-2 | PGMEA (2000) | 80 | 25 | 2.4 |
| | | (100) | (33.2) | (7.06) | DAA (500) | | | |
| | 19 | P-1 | PAG-19 | Q-2 | PGMEA (2000) | 80 | 28 | 2.4 |
| | | (100) | (32.5) | (7.06) | DAA (500) | | | |

TABLE 2

| | | Polymer | Acid generator | Quencher | Organic solvent | PEB | Sensitivity | CDU |
|---|---|---|---|---|---|---|---|---|
| | | (pbw) | (pbw) | (pbw) | (pbw) | (° C.) | (mJ/cm²) | (nm) |
| Example | 20 | P-1 | PAG-20 | Q-2 | PGMEA (2000) | 80 | 27 | 2.5 |
| | | (100) | (31.3) | (7.06) | DAA (500) | | | |
| | 21 | P-1 | PAG-21 | Q-2 | PGMEA (2000) | 80 | 26 | 2.5 |
| | | (100) | (31.9) | (7.06) | DAA (500) | | | |
| | 22 | P-1 | PAG-22 | Q-2 | PGMEA (2000) | 80 | 27 | 2.6 |
| | | (100) | (26.7) | (7.06) | DAA (500) | | | |
| | 23 | P-1 | PAG-23 | Q-2 | PGMEA (2000) | 80 | 28 | 2.5 |
| | | (100) | (28.9) | (7.06) | DAA (500) | | | |
| | 24 | P-2 | PAG-7 | Q2 | PGMEA (2000) | 80 | 28 | 2.3 |
| | | (100) | (31.4) | (8.16) | DAA (500) | | | |
| | 25 | P-3 | PAG-7 | Q-2 | PGMEA (2000) | 80 | 28 | 2.4 |
| | | (100) | (10.5) | (8.16) | DAA (500) | | | |
| | 26 | P-4 | PAG-5 | Q-1 | PGMEA (2000) | 130 | 36 | 3.0 |
| | | (100) | (21.8) | (2.72) | DAA (500) | | | |
| | 27 | P-5 | PAG-3 | Q-2 | PGMEA (2000) | 80 | 23 | 2.6 |
| | | (100) | (10.3) | (7.06) | DAA (500) | | | |
| | 28 | P-1 | PAG-24 | Q-2 | PGMEA (2000) | 80 | 26 | 2.5 |
| | | (100) | (26.1) | (7.06) | DAA (500) | | | |
| | 29 | P-1 | PAG-25 | Q-2 | PGMEA (2000) | 80 | 27 | 2.6 |
| | | (100) | (29.2) | (7.06) | DAA (500) | | | |
| | 30 | P-1 | PAG-26 | Q-2 | PGMEA (2000) | 80 | 28 | 2.5 |
| | | (100) | (30.6) | (7.06) | DAA (500) | | | |

TABLE 3

| | | Polymer | Acid generator | Quencher | Organic solvent | PEB | Sensitivity | CDU |
|---|---|---|---|---|---|---|---|---|
| | | (pbw) | (pbw) | (pbw) | (pbw) | (° C.) | (mJ/cm²) | (nm) |
| Comparative | 1 | P-1 | cPAG-1 | Q-1 | PGMEA (2000) | 80 | 30 | 3.8 |
| Example | | (100) | (19.1) | (4.72) | DAA (500) | | | |
| | 2 | P-1 | cPAG-2 | Q-1 | PGMEA (2000) | 80 | 28 | 3.0 |
| | | (100) | (29.1) | (4.72) | DAA (500) | | | |
| | 3 | P-4 | cPAG-1 | Q-1 | PGMEA (2000) | 130 | 42 | 4.0 |
| | | (100) | (12.7) | (2.72) | DAA (500) | | | |

It is demonstrated in Tables 1 to 3 that resist compositions comprising a sulfonium salt composed of a sulfonate anion having a carbon atom to which an iodine atom is bonded and a sulfonium cation having the formula (1) as the acid generator offer a high sensitivity and excellent CDU.

Japanese Patent Application No. 2022-162350 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising an acid generator containing a sulfonium salt composed of a sulfonate anion having a carbon atom to which an iodine atom is bonded and a sulfonium cation having the formula (1): 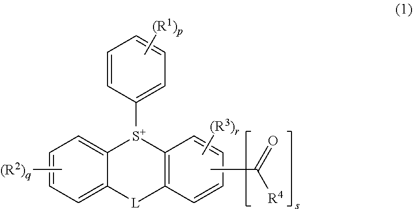
wherein p, q, and r are each independently an integer of 0 to 3, s is 1 or 2, and r+s is from 1 to 3,
R¹ and R² are each independently a halogen atom, a trifluoromethyl group, a trifluoromethoxy group, a trifluoromethylthio group, a nitro group, a cyano group, —C(═O)—R⁴, —O—C(═O)—R⁵, or —O—R⁵,
R³ is a halogen atom, a trifluoromethyl group, a trifluoromethoxy group, a trifluoromethylthio group, a nitro group, a cyano group, —O—C(═O)—R⁵, or —O—R⁵,
R⁴ is a C₁-C₁₀ hydrocarbyl group, a C₁-C₁₀ hydrocarbyloxy group, or —O—R^{4A}, the hydrocarbyl group and the hydrocarbyloxy group may be substituted with a fluorine atom or a hydroxy group, and R^{4A} is an acid labile group,
R⁵ is a C₁-C₁₀ hydrocarbyl group, and
L is a single bond, an ether bond, a carbonyl group, —N(R)—, a sulfide bond, or a sulfonyl group, and R is a hydrogen atom or a C₁-C₆ saturated hydrocarbyl group.

2. The resist composition of claim 1 wherein the sulfonate anion having a carbon atom to which an iodine atom is bonded has the formula (2)-1: 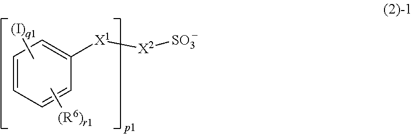
wherein p1 is an integer of 1 to 3, q1 is an integer of 1 to 5, r1 is an integer of 0 to 4, and q1+r1 is from 1 to 5,
R⁶ is a hydroxy group, a carboxy group, a halogen atom other than an iodine atom, or an amino group; or a C₁-C₂₀ hydrocarbyl group, a C₁-C₂₀ hydrocarbyloxy group, a C₂-C₂₀ hydrocarbylcarbonyl group, a C₂-C₁₀ hydrocarbyloxycarbonyl group, a C₂-C₂₀ hydrocarbylcarbonyloxy group, or a C₁-C₂₀ hydrocarbylsulfonyloxy group, which may contain a halogen atom, a hydroxy group, an amino group, or an ether bond; or
—N(R^{6A})(R^{6B}), —N(R^{6C})—C(═O)—R^{6D}, or —N(R^{6C})—C(═O)—O—R^{6D}, R^{6A} and R^{6B} are each independently a hydrogen atom or a C₁-C₆ saturated hydrocarbyl group, R^{6C} is a hydrogen atom or a C₁-C₆ saturated hydrocarbyl group which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group, and R^{6D} is a C₁-C₁₆ aliphatic hydrocarbyl group, a C₆-C₁₂ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group,
X¹ is a single bond, an ether bond, an amide bond, a urethane bond, an ester bond, or a C₁-C₆ saturated hydrocarbylene group which may contain an ether bond or an ester bond, and
X² is a single bond or a C₁-C₂ divalent linking group when p1 is 1, and is a C₁-C₂₂ (p1+1)-valent linking group when p1 is 2 or 3, and the linking group may contain an oxygen atom, a sulfur atom, a nitrogen atom, or a halogen atom.

3. The resist composition of claim 1 wherein the sulfonate anion having a carbon atom to which an iodine atom is bonded has the formula (2)-2: 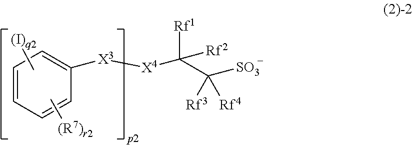
wherein p2 is an integer of 1 to 3, q2 is an integer of 1 to 5, r2 is an integer of 0 to 4, and q2+r2 is from 1 to 5,
R⁷ is a hydroxy group, a carboxy group, a halogen atom other than an iodine atom, or an amino group; or a C₁-C₂₀ hydrocarbyl group, a C₁-C₂₀ hydrocarbyloxy group, a C₂-C₂₀ hydrocarbylcarbonyl group, a C₂-C₁₀ hydrocarbyloxycarbonyl group, a C₂-C₂₀ hydrocarbylcarbonyloxy group, or a C₁-C₂₀ hydrocarbylsulfonyloxy group, which may contain a halogen atom, a hydroxy group, an amino group, or an ether bond; or
—N(R^{7A})(R^{7B}), —N(R^{7C})—C(═O)—R^{7D}, or —N(R^{7C})—C(═O)—O—R^{7D}, R^{7A} and R^{7B} are each independently a hydrogen atom or a C₁-C₆ saturated hydrocarbyl group, R^{7C} is a hydrogen atom or a C₁-C₆ saturated hydrocarbyl group which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group, and R⁷ is a C₁-C₁₆ aliphatic hydrocarbyl group, a C₆-C₁₂ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group,
X³ is a single bond, an ether bond, an amide bond, a urethane bond, an ester bond, or a C₁-C₆ saturated hydrocarbylene group which may contain an ether bond or an ester bond,
X⁴ is a single bond or a C₁-C₂ divalent linking group when p2 is 1, and is a C₁-C₂₀ (p2+1)-valent linking group when p2 is 2 or 3, and the linking group may contain an oxygen atom, a sulfur atom, or a nitrogen atom, and
Rf¹ to Rf⁴ are each independently a hydrogen atom, a fluorine atom, or a trifluoromethyl group, at least one of R¹ to Rf⁴ is a fluorine atom or a trifluoromethyl group, and R¹ and Rf², taken together, may form a carbonyl group.

4. The resist composition of claim 1, further comprising a base polymer.

5. The resist composition of claim 4 wherein the base polymer further comprises repeat units having the formula (a1) or (a2): 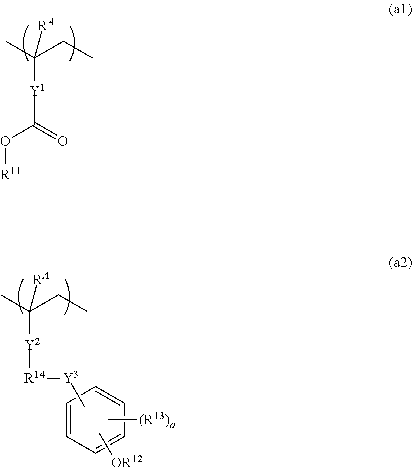
wherein R^{A} is each independently a hydrogen atom or a methyl group,
Y¹ is a single bond, a phenylene group, a naphthylene group, or a C₁-C₁₂ linking group containing at least one moiety selected from an ester bond, an ether bond, and a lactone ring,
Y² is a single bond or an ester bond,
Y³ is a single bond, an ether bond, or an ester bond,
R¹¹ and R¹² are each independently an acid labile group,
R¹³ is a C₁-C₄ saturated hydrocarbyl group, a halogen atom, a C₂-C₅ saturated hydrocarbylcarbonyl group, a cyano group, or a C₂-C₅ saturated hydrocarbyloxycarbonyl group,
R¹⁴ is a single bond or a C₁-C₆ alkanediyl group which may contain an ether bond or an ester bond, and
a is an integer of 0 to 4.

6. The resist composition of claim 5 which is a chemically amplified positive resist composition.

7. The resist composition of claim 4 wherein the base polymer is free of an acid labile group.

8. The resist composition of claim 7 which is a chemically amplified negative resist composition.

9. The resist composition of claim 1, further comprising an organic solvent.

10. The resist composition of claim 1, further comprising a quencher.

11. The resist composition of claim 1, further comprising a surfactant.

12. A pattern forming process comprising the steps of applying the resist composition of claim 1 onto a substrate to form a resist film thereon, exposing the resist film to high-energy radiation, and developing the exposed resist film in a developer.

13. The pattern forming process of claim 12 wherein the high-energy radiation is ArF excimer laser of wavelength 193 nm, KrF excimer laser of wavelength 248 nm, EB, or EUV of wavelength 3 to 15 nm.
